(19) United States
(12) Patent Application Publication
(10) Pub. No.: US 2024/0023439 A1
(43) Pub. Date: Jan. 18, 2024

(54) LIGHT EMITTING DEVICE AND POLYCYCLIC COMPOUND FOR THE SAME

(71) Applicant: Samsung Display Co., Ltd., Yongin-si (KR)

(72) Inventors: CHANSEOK OH, Yongin-si (KR); TAEIL KIM, Yongin-si (KR); JANG YEOL BAEK, Yongin-si (KR); MinJae SUNG, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 18/322,751

(22) Filed: May 24, 2023

(30) Foreign Application Priority Data
Jul. 1, 2022 (KR) 10-2022-0081145

(51) Int. Cl. H10K 85/60; C07F 5/02; C09K 11/06

(52) U.S. Cl. CPC H10K 85/658; H10K 50/121; C09K 11/06; C07F 5/027

(57) ABSTRACT

Embodiments provide a light emitting device that includes a first electrode, a second electrode facing the first electrode, and at least one functional layer disposed between the first electrode and the second electrode. The at least one functional layer includes: a first compound represented by Formula 1; and at least one of a second compound represented by Formula HT or a third compound represented by Formula ET, wherein Formula 1, Formula HT, and Formula ET are each explained in the specification. The light emitting device exhibits low voltage, high efficiency, and long service life characteristics.

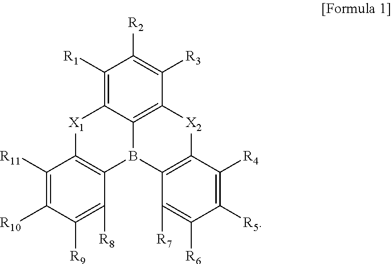

### CROSS-REFERENCE TO RELATED APPLICATION(S)

This application claims priority to and benefits of Korean Patent Application No. 10-2022-0081145 under 35 U.S.C. § 119, filed on Jul. 1, 2022 in the Korean Intellectual Property Office, the entire contents of which are incorporated herein by reference.

### BACKGROUND

### 1. Technical Field

The disclosure relates to a light emitting device including a novel polycyclic compound in an emission layer.

### 2. Description of the Related Art

Active development continues for an organic electroluminescence display apparatus as an image display apparatus. The organic electroluminescence display apparatus includes a so-called self-luminescent light emitting device in which holes and electrons respectively injected from a first electrode and a second electrode recombine in an emission layer, so that a luminescent material of the emission layer emits light to achieve display.

In the application of a light emitting device to a display apparatus, there is a demand for a light emitting device having a low driving voltage, high luminous efficiency, and a long service life, and continuous development is required on materials for a light emitting device that is capable of stably achieving such characteristics.

In order to implement an organic electroluminescence device with high efficiency, technologies pertaining to phosphorescence emission using triplet state energy or to delayed fluorescence emission which uses the generating phenomenon of singlet excitons by the collision of triplet excitons (triplet-triplet annihilation, TTA) are being developed, and development is presently directed to thermally activated delayed fluorescence (TADF) which utilize a delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and device service life are improved.

The disclosure also provides a polycyclic compound that is capable of improving luminous efficiency and device service life of a light emitting device.

An embodiment provides a light emitting device which may include a first electrode, a second electrode facing the first electrode, and at least one functional layer disposed between the first electrode and the second electrode, wherein the at least one functional layer may include:
a first compound represented by Formula 1; and at least one of a second compound represented by Formula HT or a third compound represented by Formula ET:

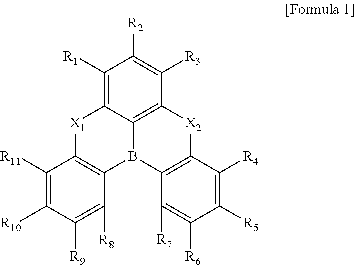

In Formula 1, X₁ and X₂ may each independently be N(R₁₂) or O; R₁ to R₁₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and at least one of R₆ or R₉ may be a group represented by Formula 2:

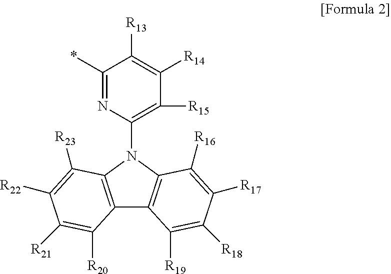

In Formula 2, R₁₃ to R₂₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and —* represents a bonding site to Formula 1;

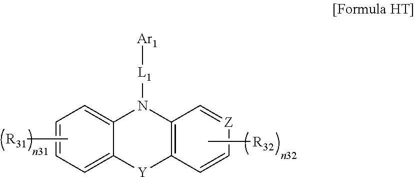

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms; Ar₁ may be a substituted or unsubstituted aryl group having 6 to 30 ring-forming carbon atoms, or a substituted or unsubstituted heteroaryl group having 2 to 30 ring-forming carbon atoms; Y may be a direct linkage, C(R_{y1})(R_{y2}), or Si(R_{y3})(R_{y4}); Z may be C(R_{z}) or N; R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n31 may be an integer from 0 to 4; and n32 may be an integer from 0 to 3;

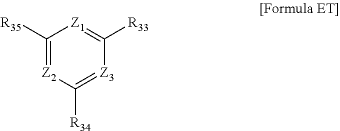

In Formula ET, Z₁ to Z₃ may each independently be N or C(R₃₆); at least one of Z₁ to Z₃ may be N; and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

In an embodiment, the at least one functional layer may further include a fourth compound represented by Formula PS:

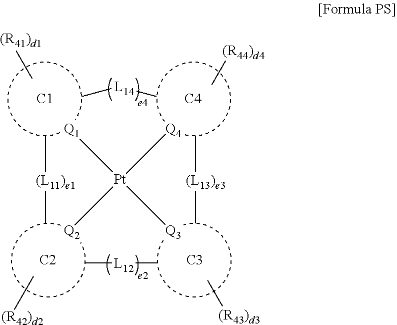

In Formula PS, Q₁ to Q₄ may each independently be C or N; C1 to C4 may each independently be a substituted or unsubstituted hydrocarbon ring having 5 to 30 ring-forming carbon atoms, or a substituted or unsubstituted heterocycle having 2 to 30 ring-forming carbon atoms; L₁₁ to L₁₄ may each independently be a direct linkage, *—O—*, *—S—*,

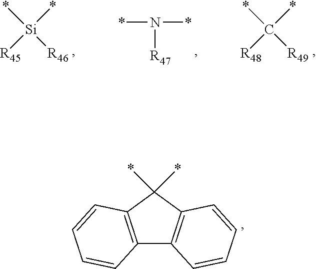

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; in L₁₁ to L₁₄, —* each represents a bonding site to one of C1 to C4; e1 to e4 may each independently be 0 or 1; R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and d1 to d4 may each independently be an integer from 0 to 4.

In an embodiment, the first compound represented by Formula 1 may be represented by Formula 1-1a or Formula 1-1b:

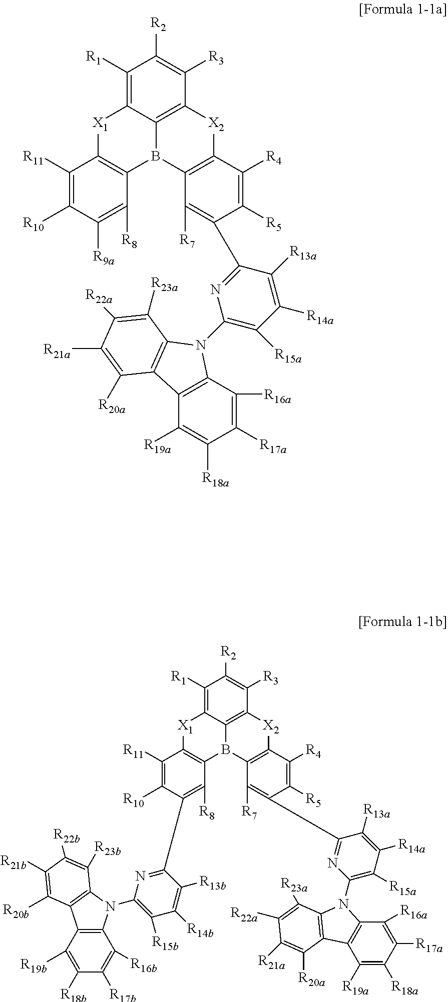

In Formula 1-1a and Formula 1-1b, R₉ₐ, R₁₃ₐ to R₂₃ₐ, and R_{13b} to R_{23b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and X₁, X₂, R₁ to R₅, R₇, R₈, R₁₀, and R₁₁ are each the same as defined in Formula 1.

In an embodiment, in Formula 1-1a and Formula 1-1b, R₁ to R₅, R₇, R₈, R₉ₐ, R₁₀, and R₁₁ may each independently be a hydrogen atom, a deuterium atom, a substituted or unsubstituted t-butyl group, a substituted or unsubstituted phenyl group, or a substituted or unsubstituted carbazole group.

In an embodiment, in Formula 1, R₁₂ may be a substituted or unsubstituted phenyl group, a substituted or unsubstituted biphenyl group, or a substituted or unsubstituted terphenyl group.

In an embodiment, the first compound represented by Formula 1 may be represented by any one of Formula 1-2a to Formula 1-2c:

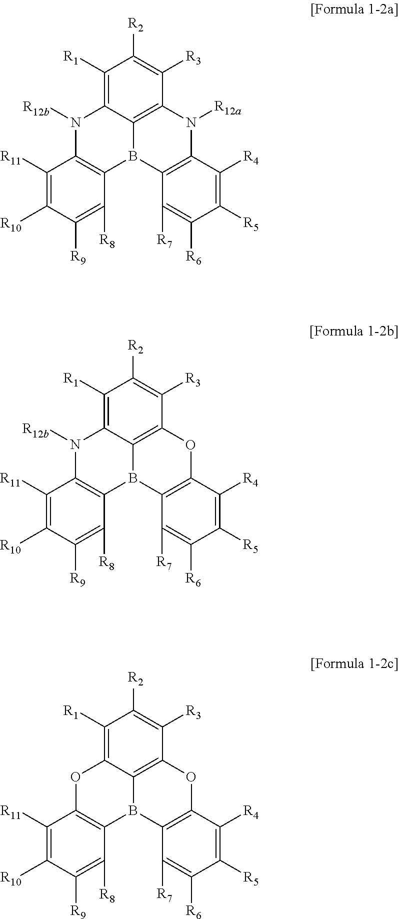

In Formula 1-2a to Formula 1-2c, R₁₂ₐ and R_{12b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; and R₁ to R₁₁ are each the same as defined in Formula 1.

In an embodiment, the first compound represented by Formula 1-2a may be represented by Formula 1-3a, and the first compound represented by Formula 1-2b may be represented by Formula 1-3b:

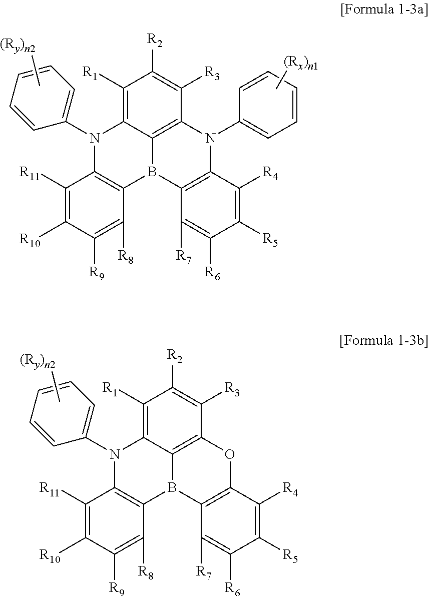

In Formula 1-3a to Formula 1-3b, Rₓ and R_{y} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; n1 and n2 may each independently be an integer from 0 to 5; and R₁ to R₁₁ are each the same as defined in Formula 1.

In an embodiment, Formula 2 may be represented by any one of Formula 2-1 to Formula 2-7:

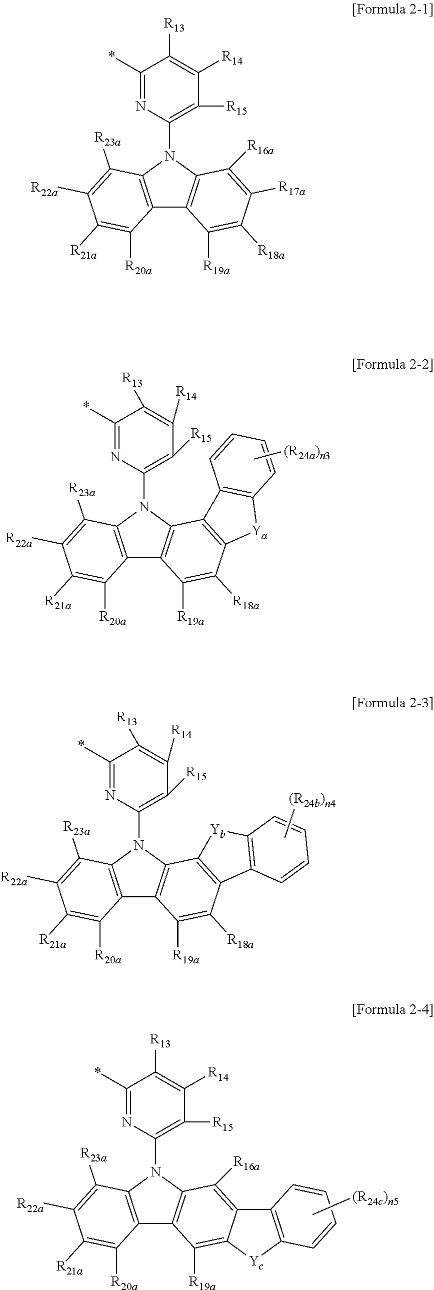

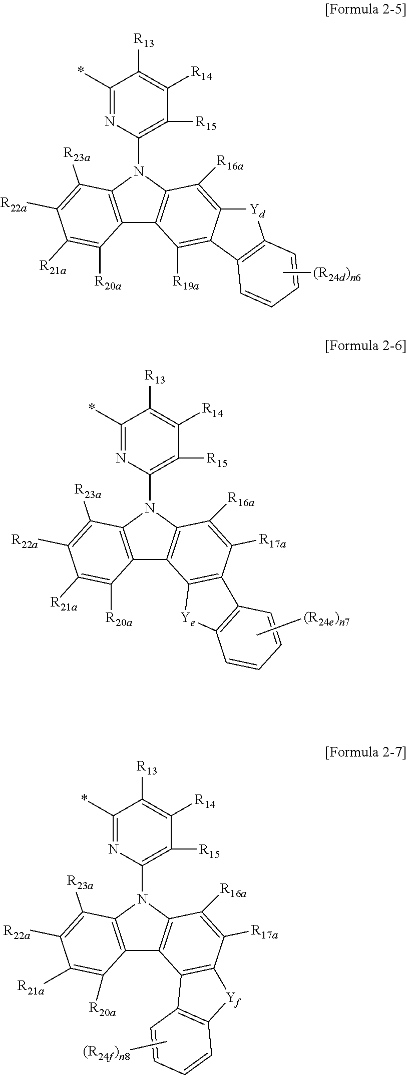

In Formula 2-1 to Formula 2-7, Yₐ to Y_{f} may each independently be O or S; R₁₆ₐ to R₂₃ₐ and R₂₄ₐ to R_{24f} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; n3 to n8 may each independently be an integer from 0 to 4; and R₁₃ to R₁₅, and —* are each the same as defined in Formula 2.

In an embodiment, in Formula 2-1 to Formula 2-7, R₁₃ to R₁₅, R₁₆ₐ to R₂₃ₐ, and R₂₄ₐ to R_{24f} may each independently be a hydrogen atom, a deuterium atom, a cyano group, a substituted or unsubstituted t-butyl group, a substituted or unsubstituted phenyl group, or a substituted or unsubstituted carbazole group.

In an embodiment, the first compound represented by Formula 1 may include at least one compound selected from Compound Group 1, which is explained below.

In an embodiment, the at least one functional layer may include an emission layer, a hole transport region disposed between the first electrode and the emission layer, and an electron transport a region between the emission layer and the second electrode; and
the emission layer may include: the first compound; and at least one of the second compound or the third compound.

In an embodiment, the emission layer may emit delayed fluorescence.

In an embodiment, the at least one functional layer may include the first compound, the second compound, and the third compound.

In an embodiment, the at least one functional layer may include the first compound, the second compound, the third compound, and the fourth compound.

An embodiment provides a light emitting device which may include a first electrode, a second electrode facing the first electrode, and an emission layer disposed between the first electrode and the second electrode, wherein the emission layer may include a compound represented by Formula 1:

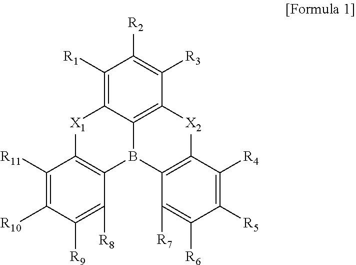

In Formula 1, X₁ and X₂ may each independently be N(R₁₂) or O; R₁ to R₁₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and at least one of R₆ or R₉ may be a group represented by Formula 2:

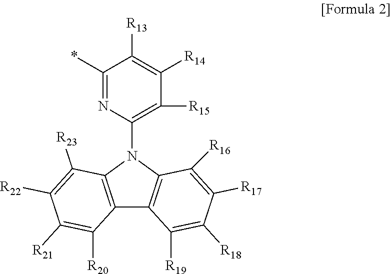

In Formula 2, R₁₃ to R₂₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and —* represents a bonding site to Formula 1.

In an embodiment, the compound represented by Formula 1 may be represented by Formula 1-1a or Formula 1-1b, which are explained herein.

In an embodiment, Formula 2 may be represented by any one of Formula 2-1 to Formula 2-7, which are explained herein.

An embodiment provides a polycyclic compound which may be represented by Formula 1:

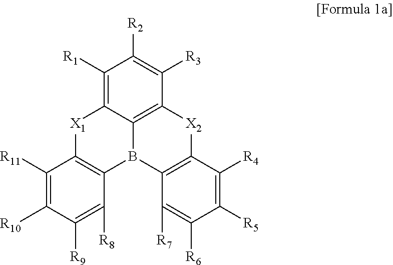

In Formula 1, X₁ and X₂ may each independently be N(R₁₂) or O; R₁ to R₁₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and at least one of R₆ or R₉ may be a group represented by Formula 2:

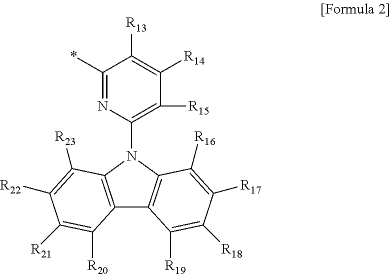

In Formula 2, R₁₃ to R₂₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring; and —* represents a bonding site to Formula 1.

In an embodiment, the polycyclic compound represented by Formula 1 may be represented by Formula 1-1a or Formula 1-1b, which are explained herein.

In an embodiment, in Formula 1-1a and Formula 1-1b, R₁ to R₅, R₇, R₈, R₉ₐ, R₁₀, and R₁₁ may each independently be a hydrogen atom, a deuterium atom, a substituted or unsubstituted t-butyl group, a substituted or unsubstituted phenyl group, or a substituted or unsubstituted carbazole group; and R₁₂ may be a substituted or unsubstituted phenyl group, a substituted or unsubstituted biphenyl group, or a substituted or unsubstituted terphenyl group.

In an embodiment, the polycyclic compound represented by Formula 1 may be represented by any one of Formula 1-2a to Formula 1-2c, which are explained herein.

In an embodiment, Formula 2 may be represented by any one of Formula 2-1 to Formula 2-7, which are explained herein.

In an embodiment, in Formula 2-1 to Formula 2-7, R₁₃ to R₁₅, R₁₆ₐ to R₂₃ₐ, and R₂₄ₐ to R_{24f} may each independently be a hydrogen atom, a deuterium atom, a cyano group, a substituted or unsubstituted t-butyl group, a substituted or unsubstituted phenyl group, or a substituted or unsubstituted carbazole group.

In an embodiment, the polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a display apparatus according to an embodiment;

FIG. 8 is a schematic cross-sectional view of a display apparatus according to an embodiment;

FIG. 9 is a schematic cross-sectional view of a display apparatus according to an embodiment; and

FIG. 10 is a schematic cross-sectional view of a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device.

Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent substituted for an atom which is substituted with a corresponding substituent, or as a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. for example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not specifically limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not specifically limited, but may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group are as follows. However, embodiments are not limited thereto.

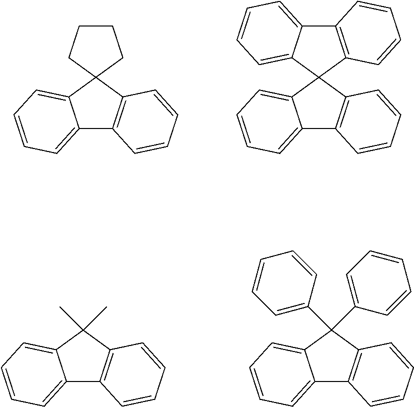

In the specification, a heterocyclic group may be any functional group or substituent derived from a ring that includes at least one of B, O, N, P, Si, S, or Se as a heteroatom. A heterocyclic group may be an aliphatic heterocyclic group or an aromatic heterocyclic group.

An aromatic heterocyclic group may be a heteroaryl group. The aliphatic heterocycle and the aromatic heterocycle may each independently be monocyclic or polycyclic. If a heterocyclic group includes two or more heteroatoms, the two or more heteroatoms may be the same as or different from each other.

In the specification, an aliphatic heterocyclic group may include at least one of B, O, N, P, Si, S, or Se as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

In the specification, a heteroaryl group may include at least one of B, O, N, P, Si, S, or Se as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of the aryl group may be applied to an arylene group, except that the arylene group is a divalent group. The above description of the heteroaryl group may be applied to a heteroarylene group, except that the heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in an amino group is not specifically limited, but may be 1 to 30. An amino group may be an alkyl amino group, an aryl amino group, or a heteroaryl amino group. Examples of an amino group may include a methylamino group, a dimethylamino group, a phenylamino group, a diphenylamino group, a naphthylamino group, a 9-methyl-anthracenylamino group, a triphenylamino group, etc., but embodiments are not limited thereto.

In the specification, the number of ring-forming carbon atoms in a carbonyl group is not specifically limited, but may be 1 to 40, 1 to 30, or 1 to 20. For example, a carbonyl group may have one of the following structures, but embodiments are not limited thereto:

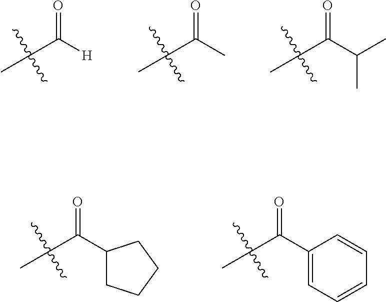

In the specification, the number of carbon atoms in a sulfinyl group or in a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not specifically limited, but may be, for example, 1 to 20 or 1 to 10. Examples of an oxy group may include methoxy, ethoxy, n-propoxy, isopropoxy, butoxy, pentyloxy, hexyloxy, octyloxy, nonyloxy, decyloxy, benzyloxy, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the specification, an alkyl group in an alkylthio group, an alkylsulfoxy group, an alkylaryl group, an alkylamino group, an alkyl boron group, an alkyl silyl group, or an alkyl amine group may be the same as an example of the alkyl group as described above.

In the specification, an aryl group in an aryloxy group, an arylthio group, an arylsulfoxy group, an arylamino group, an arylboron group, an arylsilyl group, or an arylamine group may be the same as an example of the aryl group as described above.

In the specification, a direct linkage may be a single bond.

In the specification, the symbols

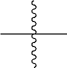

and —* each represent a bonding site to a neighboring atom.

Hereinafter, embodiments will be described with reference to the accompanying drawings.

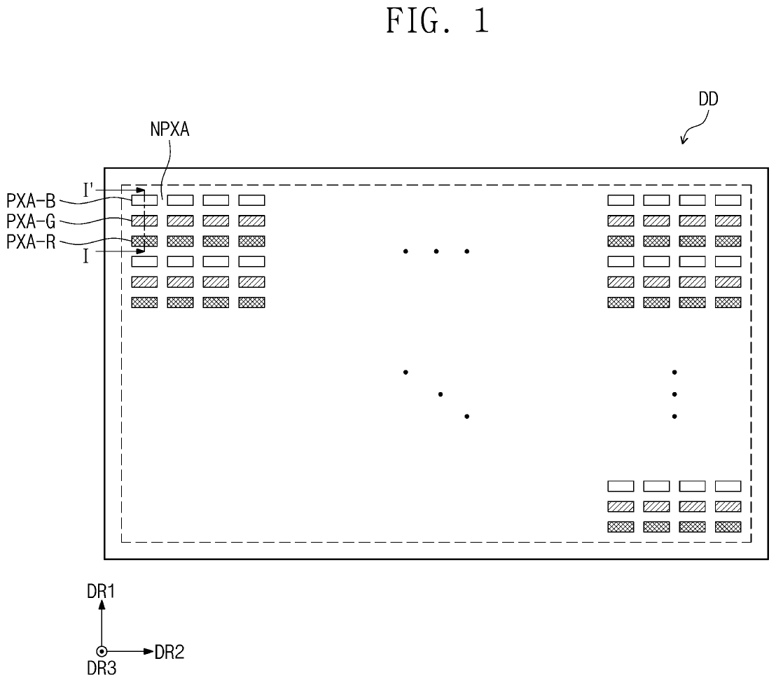

FIG. 1 is a schematic plan view illustrating an embodiment of a display apparatus DD.

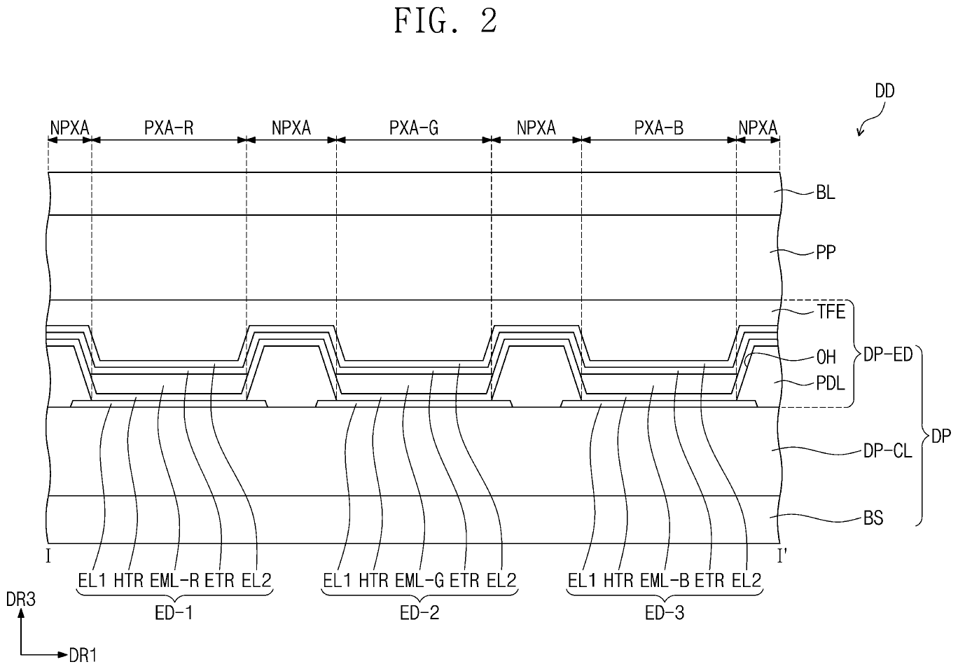

FIG. 2 is a schematic cross-sectional view of the display apparatus DD according to an embodiment. FIG. 2 is a schematic cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include multiples of each of the light emitting devices ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawing, in an embodiment, the optical layer PP may be omitted from the display apparatus DD.

A base substrate BL may be disposed on the optical layer PP. The base substrate BL may provide abase surface on which the optical layer PP disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, light emitting devices ED-1, ED-2, and ED-3 disposed between portions of the pixel defining film PDL, and an encapsulation layer TFE disposed on the light emitting devices ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting devices ED-1, ED-2, and ED-3 of the display device layer DP-ED.

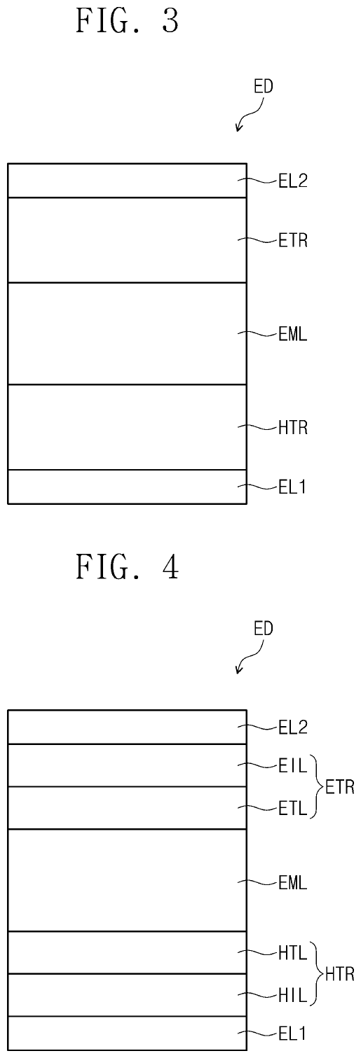

The light emitting devices ED-1, ED-2, and ED-3 may each have a structure of a light emitting device ED of an embodiment according to any of FIGS. 3 to 6, which will be described later. The light emitting devices ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and a hole transport region HTR, an electron transport region ETR, and a second electrode EL2 are each provided as a common layer for all of the light emitting devices ED-1, ED-2, and ED-3. However, embodiments are not limited thereto. Although not shown in FIG. 2, the hole transport region HTR and the electron transport region ETR may each be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 may each be provided by being patterned through an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display device layer DP-ED from moisture and/or oxygen, and the encapsulation-organic film may protect the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display apparatus DD may include non-light emitting regions NPXA and light emitting regions PXA-R, PXA-G, and PXA-B. The light emitting regions PXA-R, PXA-G, and PXA-B may each be a region which emits light generated by the respective light emitting devices ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting regions NPXA may be areas between neighboring light emitting areas PXA-R, PXA-G, and PXA-B, and may correspond to the pixel defining film PDL. For example, in an embodiment, the light emitting regions PXA-R, PXA-G, and PXA-B may each respectively correspond to a pixel. The pixel defining film PDL may separate the light emitting devices ED-1, ED-2, and ED-3. The emission layers EML-R, EML-G, and EML-B of the light emitting devices ED-1, ED-2, and ED-3 may be disposed in the openings OH defined in the pixel defining film PDL and separated from each other.

The light emitting regions PXA-R, PXA-G, and PXA-B may be arranged into groups according to the color of light generated from the light emitting devices ED-1, ED-2, and ED-3. In the display apparatus DD according to an embodiment illustrated in FIGS. 1 and 2, three light emitting regions PXA-R, PXA-G, and PXA-B, which respectively emit red light, green light, and blue light are illustrated. For example, the display apparatus DD may include the red light emitting region PXA-R, the green light emitting region PXA-G, and the blue light emitting region PXA-B that are separated from each other.

In the display apparatus DD according to an embodiment, the light emitting devices ED-1, ED-2 and ED-3 may emit light having wavelengths that are different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may respectively correspond to the first light emitting device ED-1, the second light emitting device ED-2, and the third light emitting device ED-3.

However, embodiments are not limited thereto, and the first to third light emitting devices ED-1, ED-2, and ED-3 may each emit light in a same wavelength range, or at least one light emitting device may emit light in a wavelength range that is different from the others.

For example, the first to third light emitting devices ED-1, ED-2, and ED-3 may each emit blue light.

The light emitting regions PXA-R, PXA-G, and PXA-B in the display apparatus DD according to an embodiment may be arranged in a stripe configuration. Referring to FIG. 1, the red light emitting regions PXA-R, the green light emitting regions PXA-G, and the blue light emitting regions PXA-B may each be arranged along a second direction DR2. In another embodiment, the red light emitting region PXA-R, the green light emitting region PXA-G, and the blue light emitting region PXA-B may be alternately arranged in this order along a first direction DR1.

FIGS. 1 and 2 illustrate that the light emitting regions PXA-R, PXA-G, and PXA-B each have a similar area, but embodiments are not limited thereto. The light emitting regions PXA-R, PXA-G, and PXA-B may have different areas from each other according to a wavelength range of emitted light. For example, the areas of the light emitting regions PXA-R, PXA-G, and PXA-B may be areas in a plan view that are defined by the first direction DR1 and the second direction DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics which are required for the display apparatus DD. For example, the light emitting regions PXA-R, PXA-G, and PXA-B may be arranged in a pentile configuration (such as a PENTILE™ configuration) or in a diamond configuration (such as a Diamond Pixel™ configuration).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

In the display apparatus DD according to an embodiment illustrated in FIG. 2, at least one of the first to third light emitting devices ED-1, ED-2, and ED-3 may include a polycyclic compound according to an embodiment, which will be described below.

FIGS. 3 to 6 are each a schematic cross-sectional view illustrating a light emitting device according to an embodiment. The light emitting devices ED according to embodiments may each include a first electrode EL1, a second electrode EL2 facing the first electrode EL1, and at least one functional layer disposed between the first electrode EL1 and the second electrode EL2. The light emitting device ED may include a polycyclic compound according to an embodiment, which will be described below, in at least one functional layer. In the specification, the polycyclic compound according to an embodiment may be referred to as a first compound.

Each of the light emitting devices ED may include, as the at least one functional layer, a hole transport region HTR, an emission layer EML, and an electron transport region ETR that are stacked in that order.

Referring to FIG. 3, a light emitting device ED according to an embodiment may include a first electrode EL1, a hole transport region HTR, an emission layer EML, an electron transport region ETR, and a second electrode EL2 that are stacked in that order. In the light emitting device ED, the emission layer EML may include a polycyclic compound according to an embodiment, which will be described below.

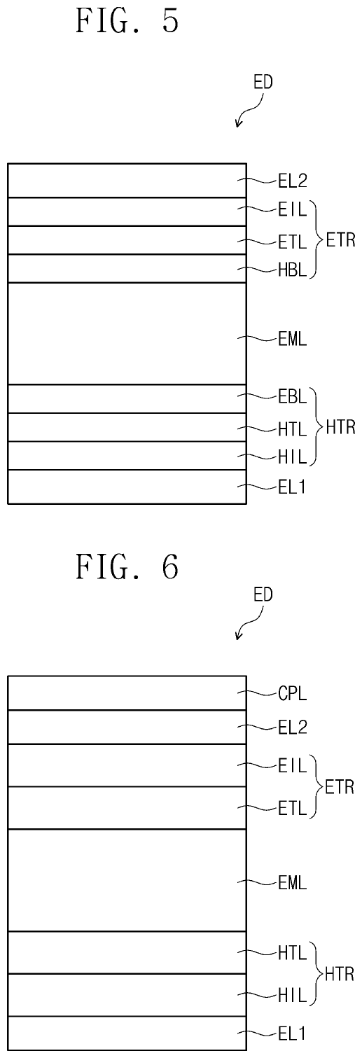

In comparison to FIG. 3, FIG. 4 illustrates a schematic cross-sectional view of a light emitting device ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting device ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting device ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), an emission-auxiliary layer (not shown), or an electron blocking layer EBL. A thickness of the hole transport region HTR may be, for example, in a range of about 50 Å to about 15,000 Å.

The hole transport region HTR may be a layer formed of a single material, a layer formed of different materials, or a structure including multiple layers formed of different materials.

For example, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stater order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

A hole transport region HTR may include a compound represented by Formula H-1:

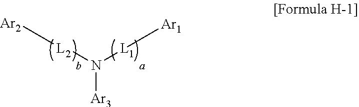

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple groups of L₁ or multiple groups of L₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, a compound represented by Formula H-1 may be a monoamine compound. In another embodiment, a compound represented by Formula H-1 may be a diamine compound in which at least one of Ar₁ to Ar₃ includes an amine group as a substituent.

In still other embodiments, a compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H-1. However, the compounds listed in Compound Group H-1 are only examples, and the compound represented by Formula H-1 is not limited to Compound Group H-1:

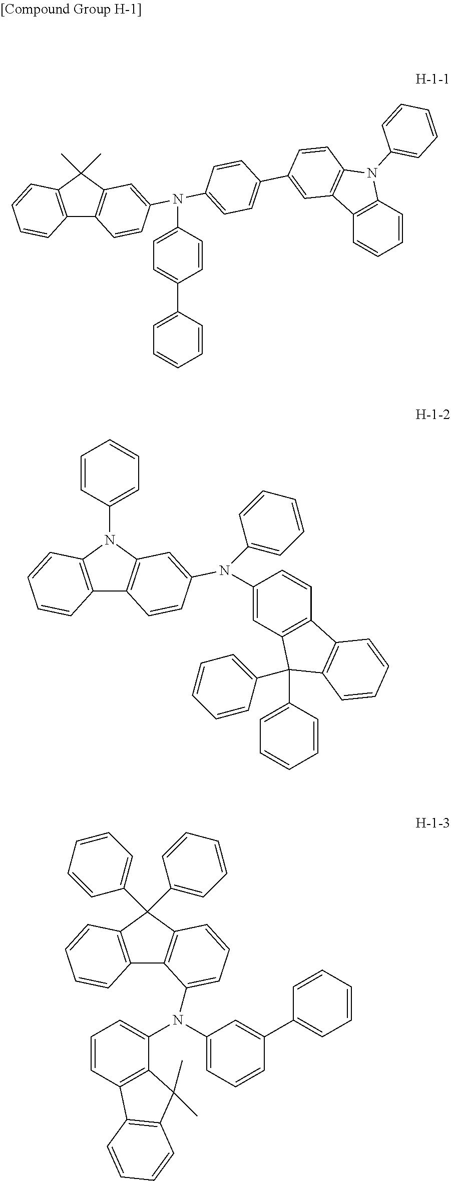 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

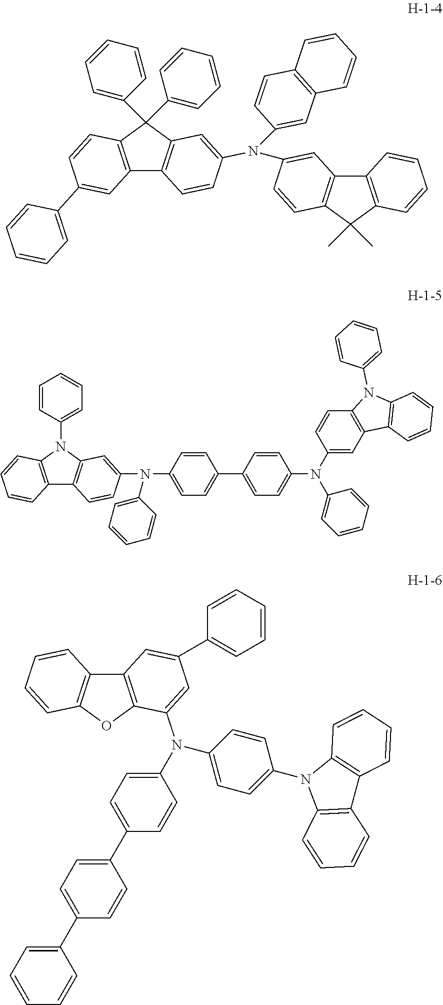 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

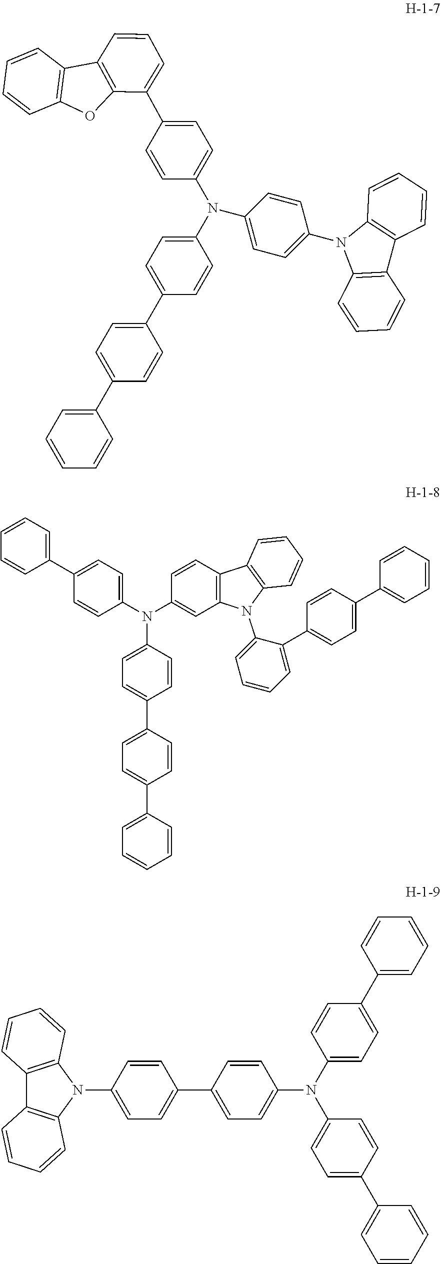 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

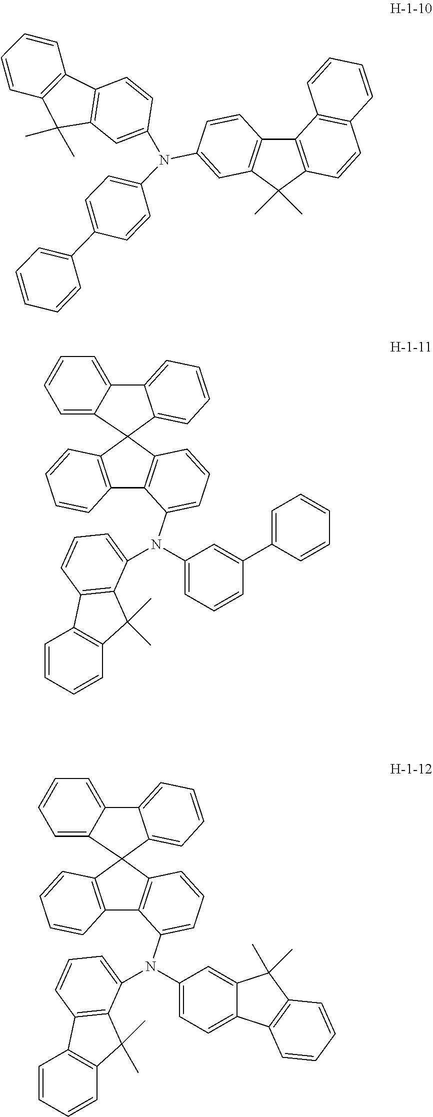

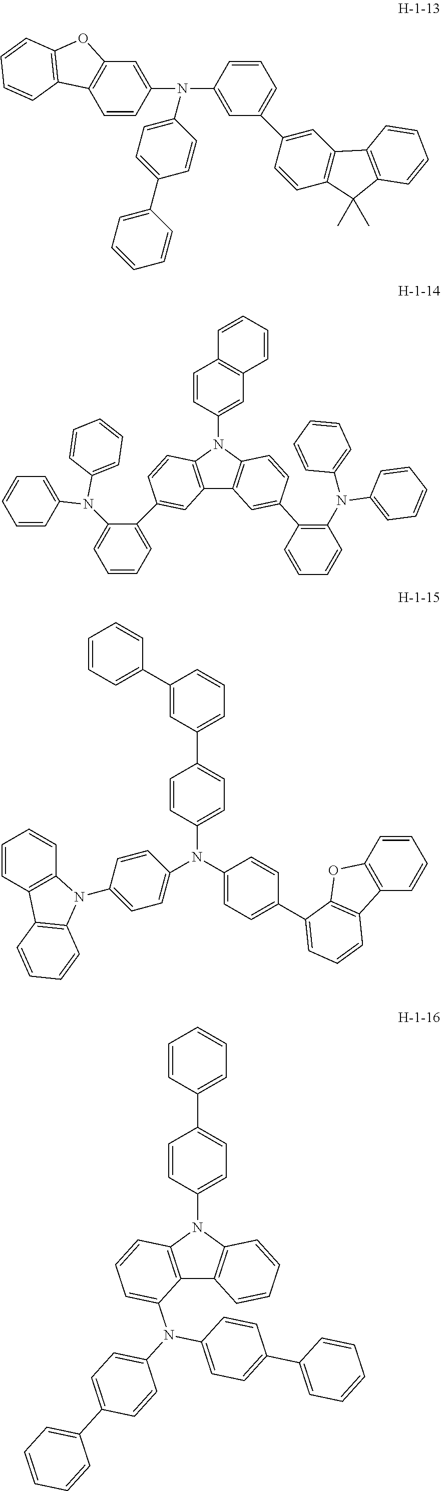 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

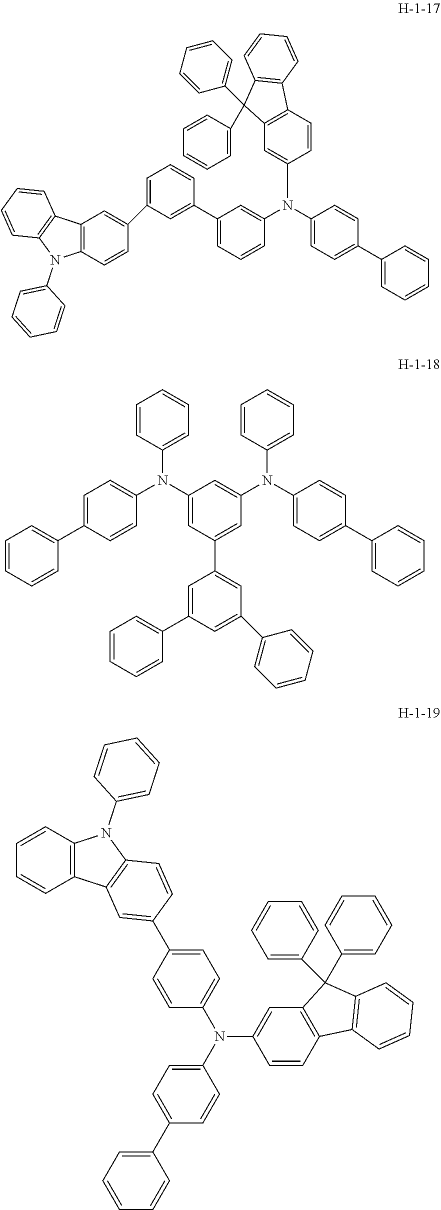 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material included in the buffer layer (not shown). The electron blocking layer EBL may prevent electron injection from an electron transport region ETR to a hole transport region HTR.

The emission layer EML is provided on the hole transport region HTR. The emission layer EML may have a thickness, for example, in a range of about 100 Å to about 1,000 Å. For example, the emission layer EML may have a thickness in a range of about 100 Å to about 300 Å. The emission layer EML may be a layer formed of a single material, a layer formed of different materials, or a structure including multiple layers formed of different materials.

In the light emitting device ED, the emission layer EML may include a polycyclic compound according to an embodiment. In an embodiment, the emission layer EML may include the polycyclic compound as a dopant. The polycyclic compound may be a dopant material for the emission layer EML.

The polycyclic compound according to an embodiment may include a core moiety in which multiple aromatic rings are fused via a boron atom and two heteroatoms. The polycyclic compound may include a structure in which first to third aromatic rings are fused via a boron atom, a first heteroatom, and a second heteroatom. For example, the first heteroatom and the second heteroatom may each independently be a nitrogen atom, or an oxygen atom. The first to third aromatic rings may be substituted or unsubstituted benzene rings.

The polycyclic compound may include a pyridine group that is bonded to at least one of the first aromatic ring or the second aromatic ring. The pyridine group may be bonded at a meta-position to the boron atom of the core moiety as described above. The pyridine group may be bonded to the core moiety at an ortho-position to a nitrogen atom of the ring of the pyridine group. The pyridine group may include a substituent bonded at another ortho-position to a nitrogen atom of the ring of the pyridine group. The substituent may be a substituted or unsubstituted carbazole group, a substituted or unsubstituted benzofurocarbazole group, or a substituted or unsubstituted benzothienocarbazole group.

In an embodiment, the emission layer EML may include a first compound represented by Formula 1. The first compound corresponds to a polycyclic compound according to an embodiment:

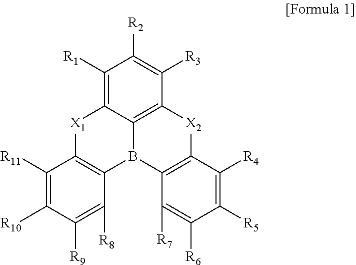

In Formula 1, X₁ and X₂ may each independently be N(R₁₂) or O. X₁ and X₂ may be the same as or different from each other. For example, X₁ and X₂ may each be N(R₁₂) or may each be O. For example, X₁ may be N(R₁₂) and X₂ may be O. For example, X₁ may be O and X₂ may be N(R₁₂). In Formula 1, X₁ and X₂ may respectively correspond to the first heteroatom and the second heteroatom, as described above.

In Formula 1, R₁ to R₁₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

For example, R₁ to R₅, R₇, R₈, R₁₀ and R₁₁ may each independently be a hydrogen atom, a deuterium atom, a substituted or unsubstituted t-butyl group, a substituted or unsubstituted phenyl group, or a substituted or unsubstituted carbazole group. For example, when R₁ to R₅, R₇, R₈, R₁₀ and R₁₁ are each a substituted phenyl group, R₁ to R₅, R₇, R₈, R₁₀ and R₁₁ may each independently be a phenyl group substituted with deuterium, or a phenyl group substituted with a t-butyl group. For example, when R₁ to R₅, R₇, R₈, R₁₀ and R₁₁ are each a substituted carbazole group, R₁ to R₅, R₇, R₈, R₁₀ and R₁₁ may each independently be a carbazole group substituted with deuterium, or a carbazole group substituted with a t-butyl group.

In an embodiment, R₁₂ may be a substituted or unsubstituted phenyl group, a substituted or unsubstituted biphenyl group, or a substituted or unsubstituted terphenyl group. For example, when R₁₂ is a substituted phenyl group, R₁₂ may be a phenyl group substituted with at least one of a t-butyl group or a substituted or unsubstituted phenyl group. For example, when R₁₂ is a substituted biphenyl group, R₁₂ may be a biphenyl group substituted with deuterium, a biphenyl group substituted with a t-butyl group, or a biphenyl group substituted with a substituted or unsubstituted phenyl group.

In Formula 1, at least one of R₆ or R₉ may be a group represented by Formula 2. For example, either R₆ or R₉ may be a group represented by Formula 2, or R₆ and R₉ may each independently be a group represented by Formula 2. When R₆ and R₉ are each independently a group represented by Formula 2, R₆ and R₉ may be the same as or different from each other.

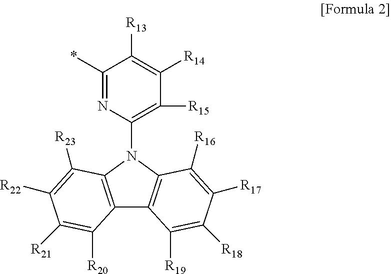

In Formula 2, R₁₃ to R₂₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

For example, R₁₃ to R₂₃ may each independently be a hydrogen atom, a deuterium atom, a cyano group, a t-butyl group, a substituted or unsubstituted phenyl group, or a substituted or unsubstituted carbazole group. For example, when R₁₃ to R₂₃ are each a substituted phenyl group, R₁₃ to R₂₃ may each independently be a phenyl group substituted with deuterium, a phenyl group substituted with a t-butyl group, or a phenyl group substituted with an isopropyl group. For example, when R₁₃ to R₂₃ are each a carbazole group, R₁₃ to R₂₃ may each independently be a carbazole group substituted with deuterium, or a carbazole group substituted with a t-butyl group.

For example, at least one of R₁₆ and R₁₇, R₁₇ and R₁₈, R₁₈ and R₁₉, R₂₀ and R₂₁, R₂₁ and R₂₂, or R₂₂ and R₂₃ may be bonded to each other to form a ring. For example, at least one of R₁₆ and R₁₇, R₁₇ and R₁₈, R₁₈ and R₁₉, R₂₀ and R₂₁, R₂₁ and R₂₂, or R₂₂ and R₂₃ may be bonded to each other to form a bicyclic heterocycle containing S or O. For example, a substituent represented by Formula 2 may be a pyridine group that is bonded to a substituted or unsubstituted benzofurocarbazole group, or a substituted or unsubstituted benzothienocarbazole group. However, embodiments are not limited thereto.

In Formula 2, —* represents a bonding site to Formula 1.

In an embodiment, the polycyclic compound represented by Formula 1 may be represented by Formula 1-1a or Formula 1-1b:

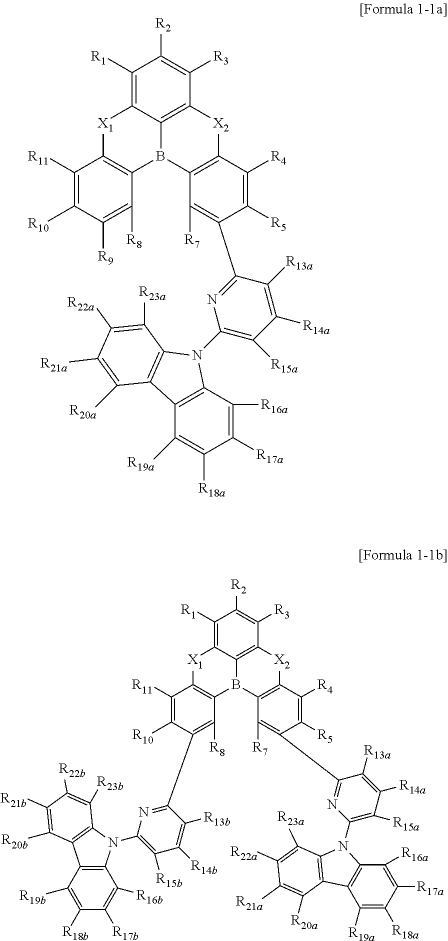

Formula 1-1a represents a case where only R₆ in Formula 1 is a group represented by Formula 2, and Formula 1-1b represents a case where R₆ and R₉ in Formula 1 are each independently a group represented by Formula 2.

In Formula 1-1a and Formula 1-1b, R₉ₐ, R₁₃ₐ to R₂₃ₐ, and R_{13b} to R_{23b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

For example, R₉ₐ may be a hydrogen atom, a deuterium atom, a substituted or unsubstituted t-butyl group, a substituted or unsubstituted phenyl group, or a substituted or unsubstituted carbazole group. For example, when R₉ₐ is a substituted phenyl group, R₉ₐ may be a phenyl group substituted with deuterium, or a phenyl group substituted with a t-butyl group.

For example, when R₉ₐ is a substituted carbazole group, R₉ₐ may be a carbazole group substituted with deuterium, or a carbazole group substituted with a t-butyl group.

For example, R₁₃ₐ to R₂₃ₐ and R_{13b} to R_{23b} may each independently be a hydrogen atom, a deuterium atom, a cyano group, a t-butyl group, a substituted or unsubstituted phenyl group, or a substituted or unsubstituted carbazole group. For example, when R₁₃ₐ to R₂₃ₐ and R_{13b} to R_{23b} are each a substituted phenyl group, R₁₃ₐ to R₂₃ₐ and R_{13b} to R_{23b} may each independently be a phenyl group substituted with deuterium, a phenyl group substituted with a t-butyl group, or a phenyl group substituted with an isopropyl group. For example, when R₁₃ₐ to R₂₃ₐ and R_{13b} to R_{23b} are each a substituted carbazole group, R₁₃ₐ to R₂₃ₐ and R_{13b} to R_{23b} may each independently be a carbazole group substituted with deuterium, or a carbazole group substituted with a t-butyl group.

For example, at least one of R₁₆ₐ and R₁₇ₐ, R₁₇ₐ and R₁₈ₐ, R₁₈ₐ and R₁₉ₐ, R₂₀ₐ and R₂₁ₐ, R₂₁ₐ and R₂₂ₐ, or R₂₂ₐ and R₂₃ₐ may be bonded to each other to form a ring. For example, at least one of R₁₆ₐ and R₁₇ₐ, R₁₇ₐ and R₁₈ₐ, R₁₈ₐ and R₁₉ₐ, R₂₀ₐ and R₂₁ₐ, R₂₁ₐ and R₂₂ₐ, or R₂₂ₐ and R₂₃ₐ may be bonded to each other to form a bicyclic heterocycle containing S or O. For example, a polycyclic compound represented by Formula 1-1a may include a pyridine group that is bonded to a substituted or unsubstituted benzofurocarbazole group, or a substituted or unsubstituted benzothienocarbazole group. However, embodiments are not limited thereto.

For example, at least one of R_{16b} and R_{17b}, R_{17b} and R₁₈ₐ, R_{18b} and R_{19b}, R_{20b} and R_{21b}, R_{21b} and R_{22b}, or R_{22b} and R_{23b} may be bonded to each other to form a ring, at least one of R_{16b} and R_{17b}, R_{17b} and R₁₈ₐ, R_{18b} and R_{19b}, R_{20b} and R_{21b}, R_{21b} and R_{22b}, or R_{22b} and R_{23b} may be bonded to each other to form a bicyclic heterocycle containing S or O. For example, a polycyclic compound represented by Formula 1-1b may include a pyridine group that is bonded to a substituted or unsubstituted benzofurocarbazole group, or a substituted or unsubstituted benzothienocarbazole group. However, embodiments are not limited thereto.

In Formula 1-1a and Formula 1-1b, X₁, X₂, R₁ to R₅, R₇, R₈, R₁₀ and R₁₁ are each the same as defined in Formula 1.

In an embodiment, in Formula 1-1a and Formula 1-1b, R₁ to R₅, R₇, R₈, R₉ₐ, R₁₀, and R₁₁ may each independently be a hydrogen atom, a deuterium atom, a substituted or unsubstituted t-butyl group, a substituted or unsubstituted phenyl group, or a substituted or unsubstituted carbazole group; and R₁₂ may be a substituted or unsubstituted phenyl group, a substituted or unsubstituted biphenyl group, or a substituted or unsubstituted terphenyl group.

In an embodiment, the polycyclic compound represented by Formula 1 may be represented by any one of Formula 1-2a to Formula 1-2c:

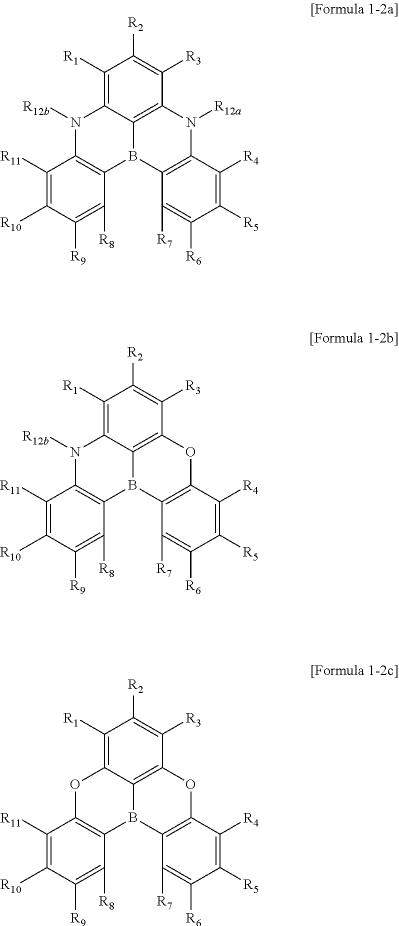

Formula 1-2a to Formula 1-2c each represent a case where X₁ and X₂ in Formula 1 are specified as N and N, N and O, and O and O, respectively.

In Formula 1-2a to Formula 1-2c, R₁₂ₐ and R_{12b} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

For example, R₁₂ₐ and R_{12b} may each independently be a substituted or unsubstituted phenyl group, a substituted or unsubstituted biphenyl group, or a substituted or unsubstituted terphenyl group. For example, when R₁₂ₐ and R_{12b} are each a substituted phenyl group, R₁₂ₐ and R_{12b} may each independently be a phenyl group substituted with at least one of a t-butyl group or a substituted or unsubstituted phenyl group. For example, when R₁₂ₐ and R_{12b} are each a substituted biphenyl group, R₁₂ₐ and R_{12b} may each independently be a biphenyl group substituted with deuterium, a biphenyl group substituted with a t-butyl group, or a biphenyl group substituted with a substituted or unsubstituted phenyl group.

In Formula 1-2a to Formula 1-2c, R₁ to R₁₁ are each the same as defined in Formula 1.

In an embodiment, the polycyclic compound represented by Formula 1-2a may be represented by Formula 1-3a, and the polycyclic compound represented by Formula 1-2b may be represented by Formula 1-3b:

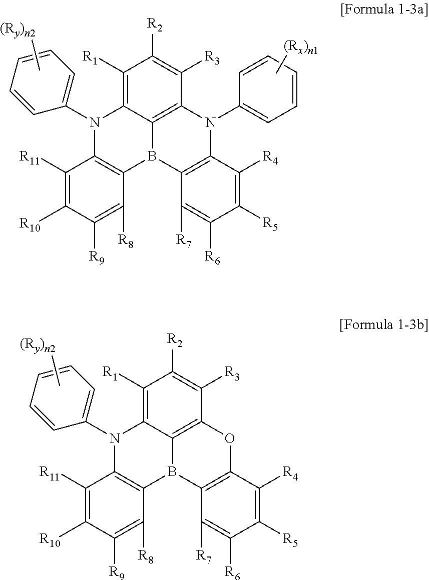

Formula 1-3a and Formula 1-3b respectively represent a case where in Formula 1-2a and Formula 1-2b, R₁₂ₐ and R_{12b} are specified as a substituted or unsubstituted phenyl group.

In Formula 1-3a and Formula 1-3b, Rₓ and R_{y} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring.

For example, Rₓ and R_{y} may each independently be a hydrogen atom, a deuterium atom, a t-butyl group, or a substituted or unsubstituted phenyl group. For example, when Rₓ and R_{y} are each a substituted phenyl group, Rₓ and R_{y} may each independently be a phenyl group substituted with deuterium.

In Formula 1-3a and Formula 1-3b, n1 and n2 may each independently be an integer from 0 to 5. For example, n1 and n2 may each independently be 1 or 2. However, embodiments are not limited thereto. A case where n1 is 0 may be the same as a case where n1 is 5 and Rₓ groups are all hydrogen atoms. It may be understood that when n1 is 0, Rₓ is not substituted at the polycyclic compound represented by Formula 1-3a. A case where n2 is 0 may be the same as a case where n2 is 5 and R_{y} groups are all hydrogen atoms. It may be understood that when n2 is 0, R_{y} is not substituted at the polycyclic compound represented by Formula 1-3a or Formula 1-3b. When n1 and n2 are each 2 or more, multiple groups of each of Rₓ and R_{y} may be the same as or different from each other.

In Formula 1-3a and Formula 1-3b, R₁ to R₁₁ are each the same as defined in Formula 1.

In an embodiment, Formula 2 may be represented by any one of Formula 2-1 to Formula 2-7:

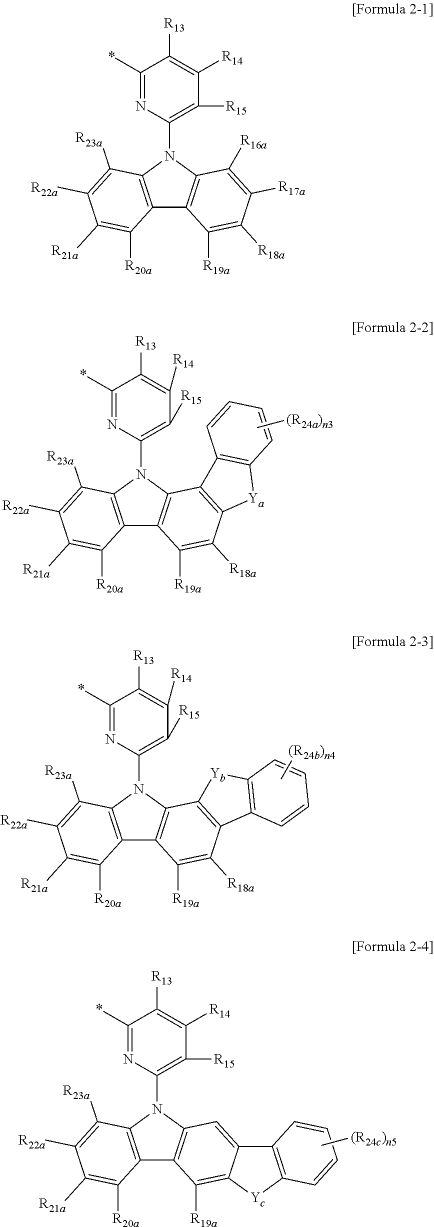

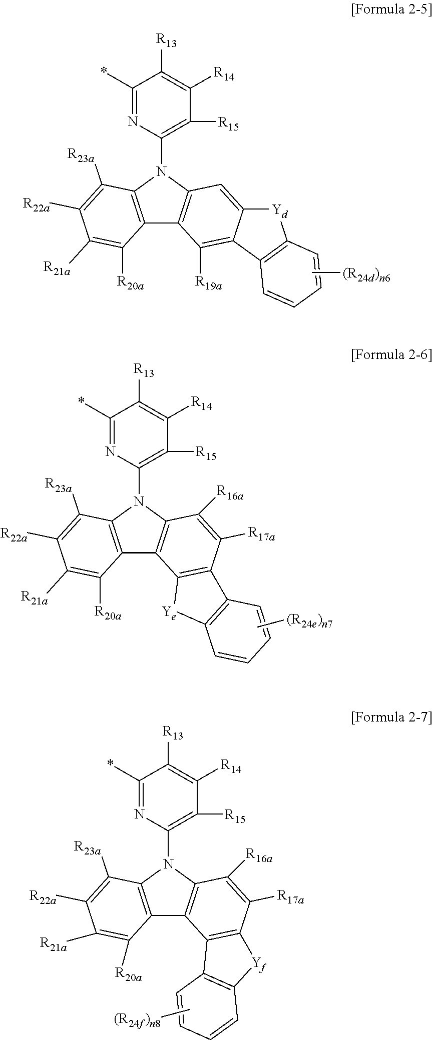

Formula 2-1 and Formula 2-7 each represent a case where R₁₆ to R₂₃ in Formula 2 are specified.

In Formula 2-1 to Formula 2-7, Yₐ to Y_{f} may each independently be O or S. For example, Yₐ may be O or S. For example, Y_{b} may be O or S. For example, Y_{c} may be O or S. For example, Y_{d} may be O or S. For example, Yₑ may be O or S. For example, Y_{f} may be 0 or S.

In Formula 2-1 to Formula 2-7, R₁₆ₐ to R₂₃ₐ and R₂₄ₐ to R_{24f} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

For example, R₁₆ₐ to R₂₃ₐ and R₂₄ₐ to R_{24f} may each independently be a hydrogen atom, a deuterium atom, a cyano group, or a t-butyl group.

In Formula 2-1 to Formula 2-7, n3 to n8 may each independently be an integer from 0 to 4. For example, n3 to n8 may each independently be 0 or 1. A case where n3 is 0 may be the same as a case where n3 is 4 and R₂₄ₐ groups are all hydrogen atoms. It may be understood that when n3 is 0, R₂₄ₐ is not substituted at the group represented by Formula 2-2. A case where n4 is 0 may be the same as a case where n4 is 4 and R_{24b} groups are all hydrogen atoms. It may be understood that when n4 is 0, R_{24b} is not substituted at the group represented by Formula 2-3. A case where n5 is 0 may be the same as a case where n5 is 4 and R_{24c} groups are all hydrogen atoms. It may be understood that when n5 is 0, R_{24c} is not substituted at the group represented by Formula 2-4. A case where n6 is 0 may be the same as a case where n6 is 4 and R_{24d} groups are all hydrogen atoms. It may be understood that when n6 is 0, R_{24d} is not substituted at the group represented by Formula 2-5. A case where n7 is 0 may be the same as a case where n7 is 4 and R₂₄ₑ groups are all hydrogen atoms. It may be understood that when n7 is 0, R₂₄ₑ is not substituted at the group represented by Formula 2-6. A case where n8 is 0 may be the same as a case where n8 is 4 and R_{24f} groups are all hydrogen atoms.

It may be understood that when n8 is 0, R_{24f} is not substituted at the group represented by Formula 2-7. When n3 to n8 are each 2 or more, multiple groups of each of R₂₄ₐ to R_{24f} may be the same as or different from each other.

In Formula 2-1 to Formula 2-7, R₁₃ to R₁₅ and —* are each the same as defined in Formula 2.

As described above, the polycyclic compound represented by Formula 1 may have a core moiety in which multiple aromatic rings are fused via a boron atom and two heteroatoms.

The polycyclic compound may include at least one pyridine group (hereinafter, a pyridine unit) substituted with a carbazole group which is bonded at a meta-position to the boron atom of the core moiety.

At a meta-position to the boron atom of the core, electron density is high. By introducing the pyridine unit having electron-withdrawing properties at a meta-position to the boron atom, highest occupied molecular orbital (HOMO)-lowest unoccupied molecular orbital (LUMO) sequential separation between atoms may occur and multiple resonance effects may be enhanced. Thus, delayed fluorescence characteristics may be improved, and high photoluminescence quantum yield (PLQY) may be exhibited.

The pyridine unit includes a substituted or unsubstituted carbazole group bonded at an ortho-position to the nitrogen atom of the ring of the pyridine unit. The substituted or unsubstituted carbazole group is bonded at an ortho-position to the nitrogen atom of the ring of the pyridine unit having strong electron activity, and may improve the molecular stability of the pyridine unit. The substituted or unsubstituted carbazole group is a bulky substituent, and may impart steric hindrance to the pyridine unit, and may effectively suppress Dexter energy transfer between molecules.

For example, the polycyclic compound has a fused ring core moiety containing a boron atom and two heteroatoms, and a structure in which a pyridine group substituted with at least one carbazole group is bonded at a specified position, and thus multiple resonance effects may be enhanced and Dexter energy transfer between molecules may be effectively suppressed.

Thus, the polycyclic compound may be applied to a light emitting device, thereby contributing to improving luminous efficiency and service life of the light emitting device.

In an embodiment, the polycyclic compound represented by Formula 1 may be selected from Compound Group 1. In an embodiment, in the light emitting device, the polycyclic compound represented by Formula 1 may include at least one compound selected from Compound Group 1. In Compound Group 1, D represents a deuterium atom, and Ph represents a substituted or unsubstituted phenyl group.

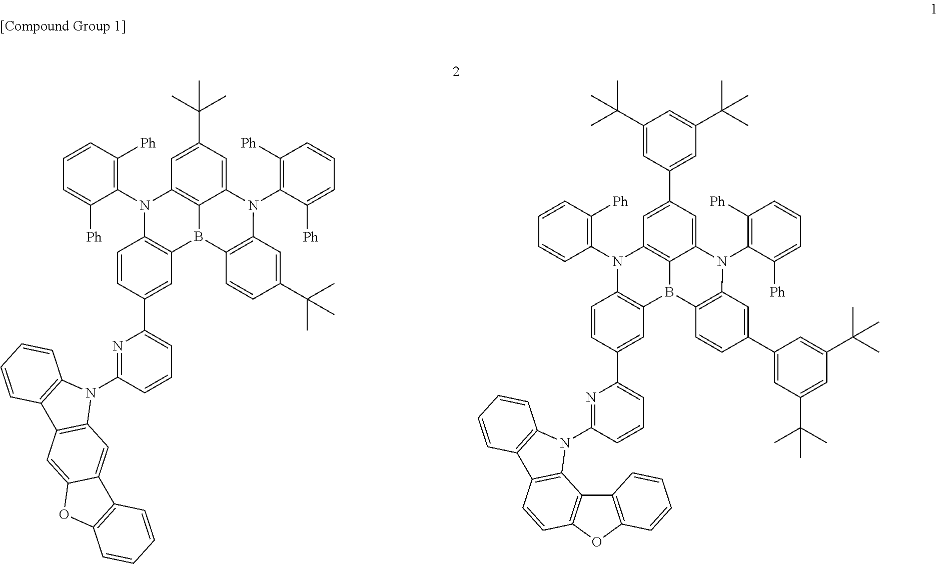 [SMILES: CC(C)(C)c1ccc2c(c1)N(c1c(-c3ccccc3)cccc1-c1ccccc1)c1cc(C(C)(C)C)cc3c1B2c1cc(-c2cccc(-n4c5ccccc5c5cc6oc7ccccc7c6cc54)n2)ccc1N3c1c(-c2ccccc2)cccc1-c1ccccc1 ; CC(C)(C)c1cc(-c2ccc3c(c2)N(c2c(-c4ccccc4)cccc2-c2ccccc2)c2cc(-c4cc(C(C)(C)C)cc(C(C)(C)C)c4)cc4c2B3c2cc(-c3cccc(-n5c6ccccc6c6ccc7oc8ccccc8c7c65)n3)ccc2N4c2ccccc2-c2ccccc2)cc(C(C)(C)C)c1]

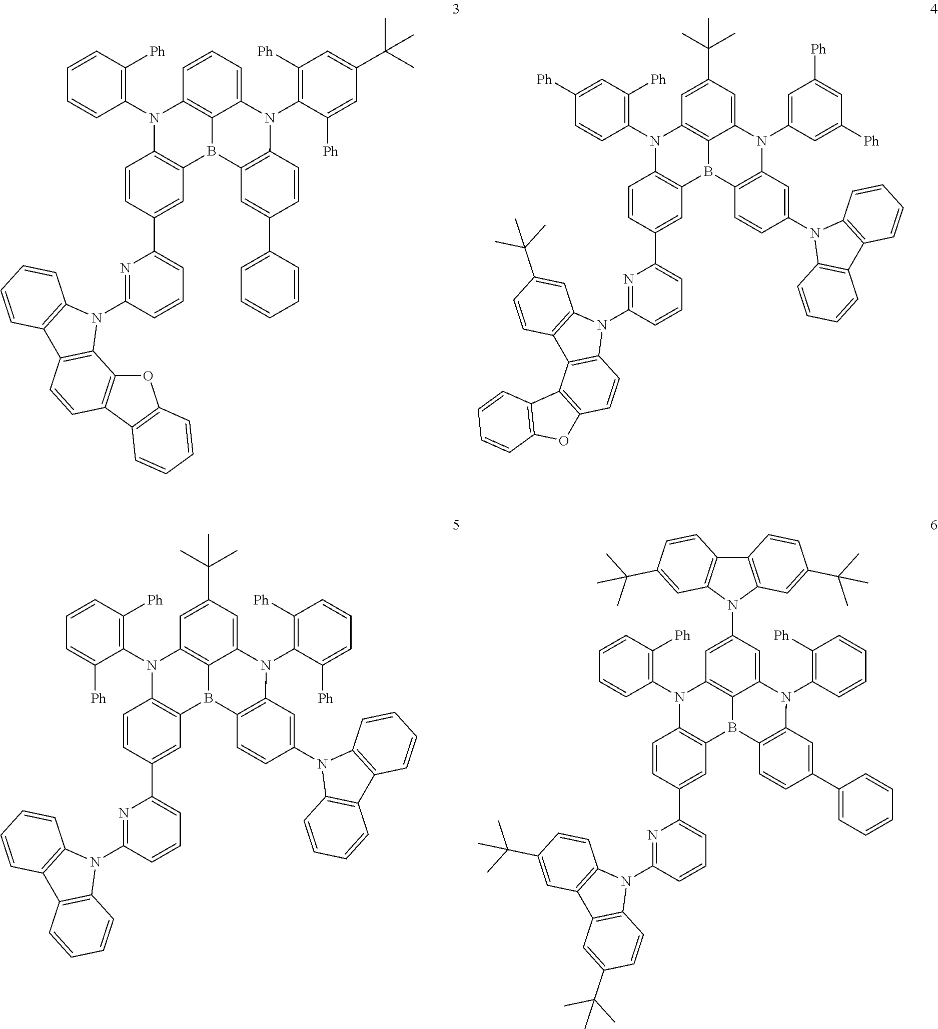

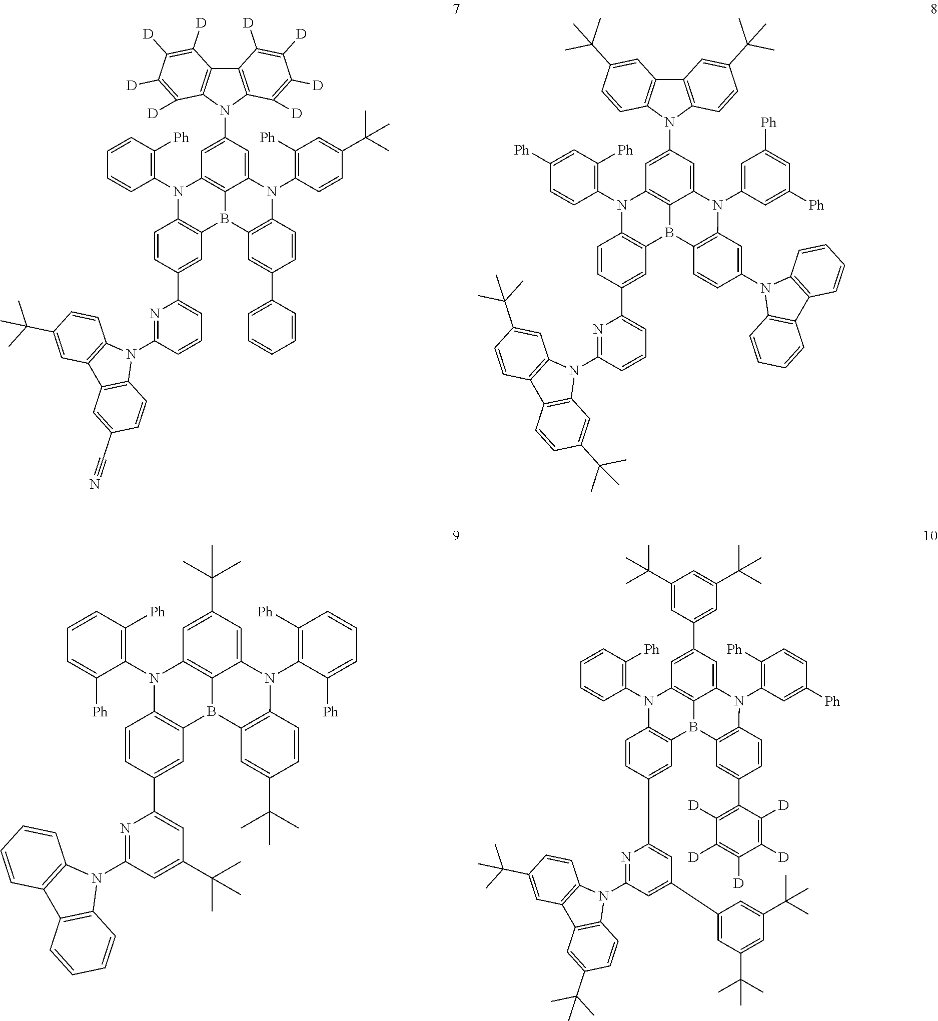

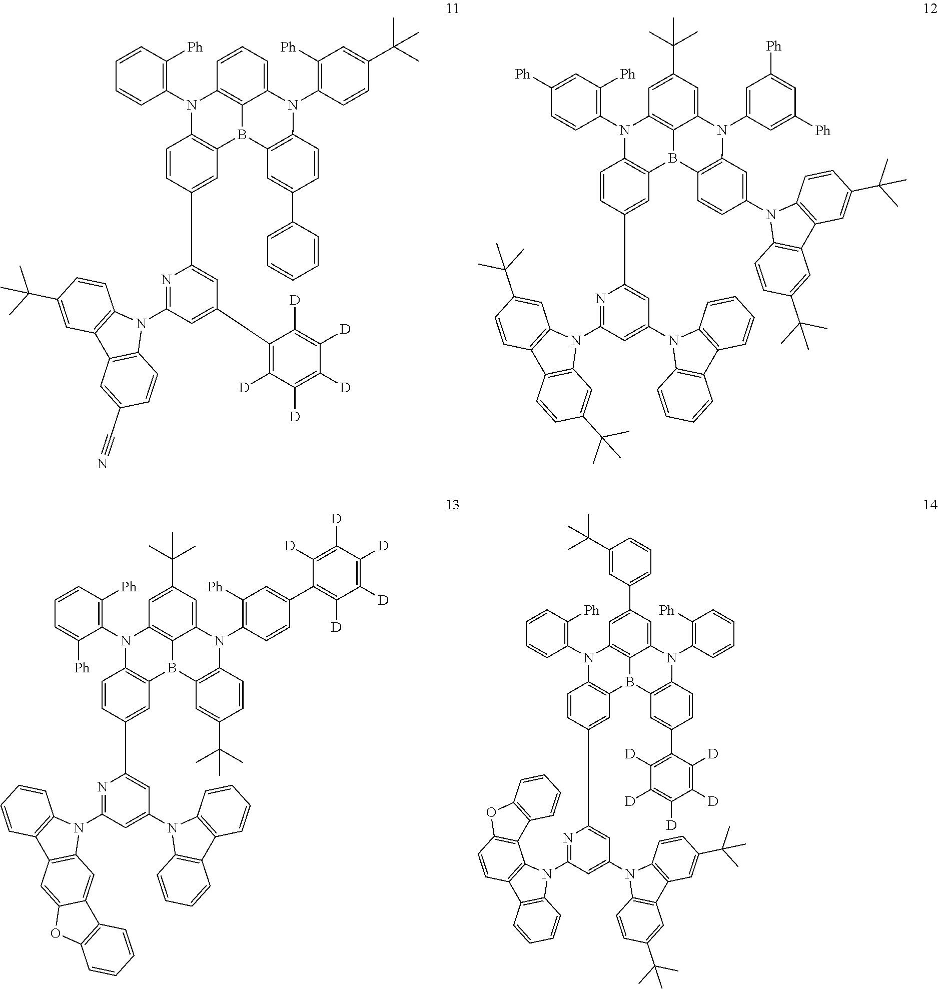

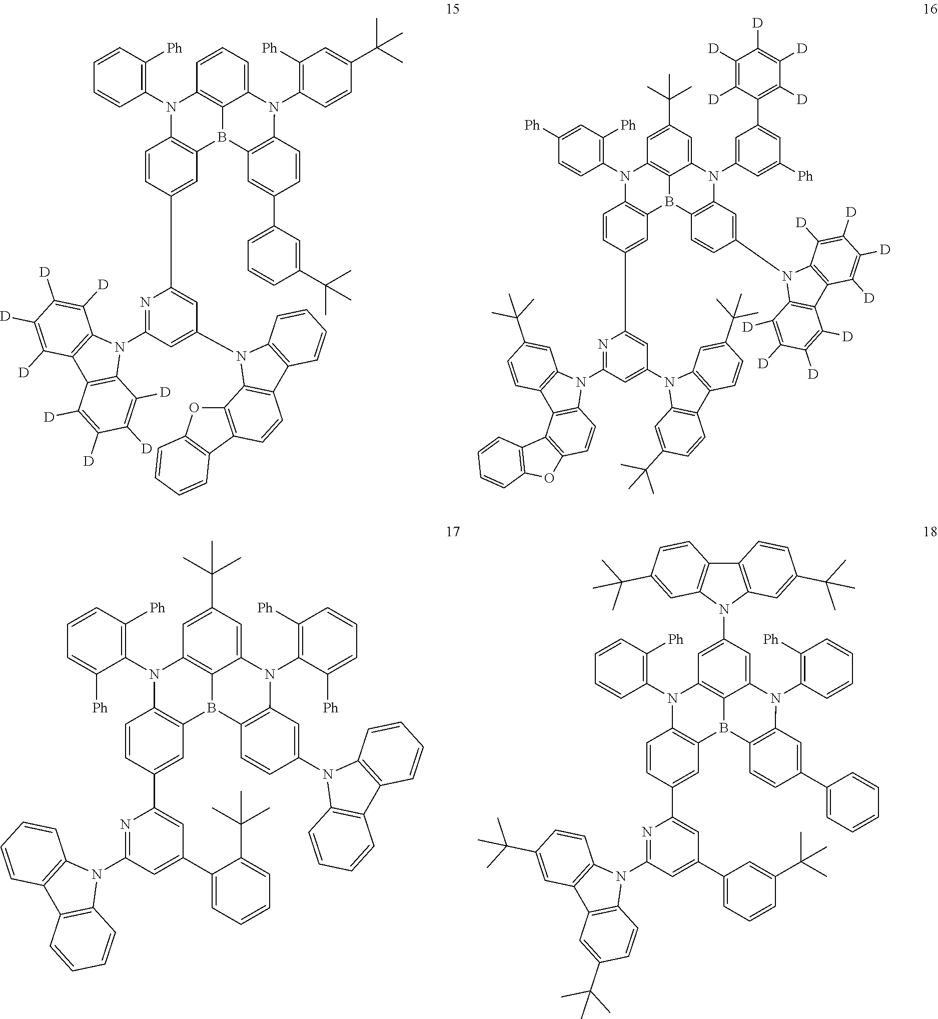

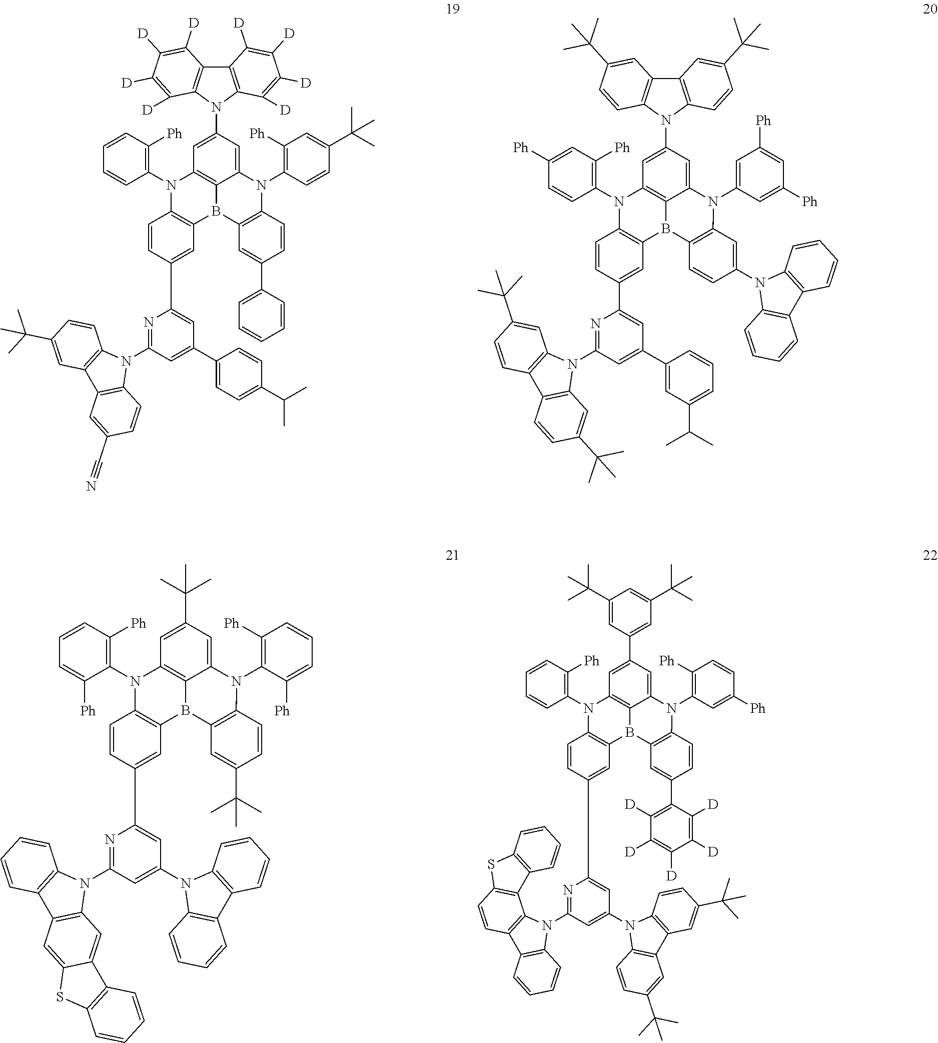

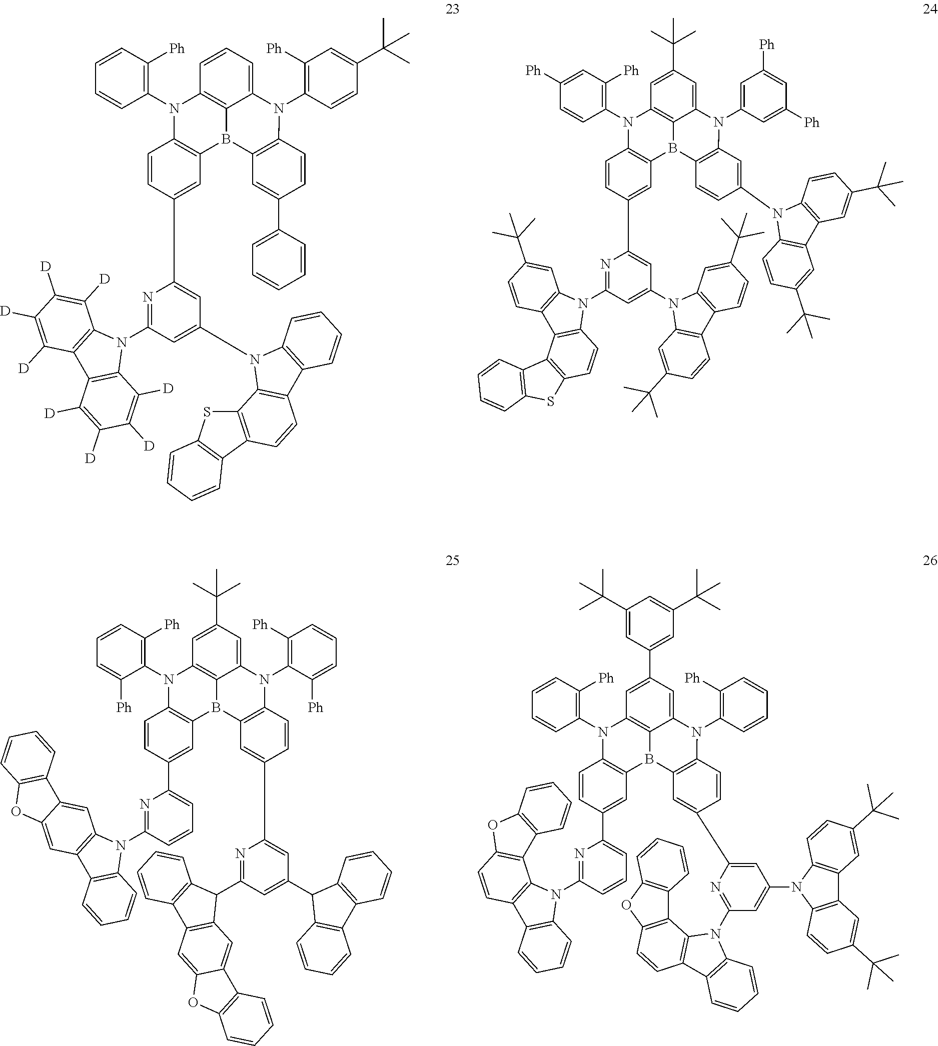

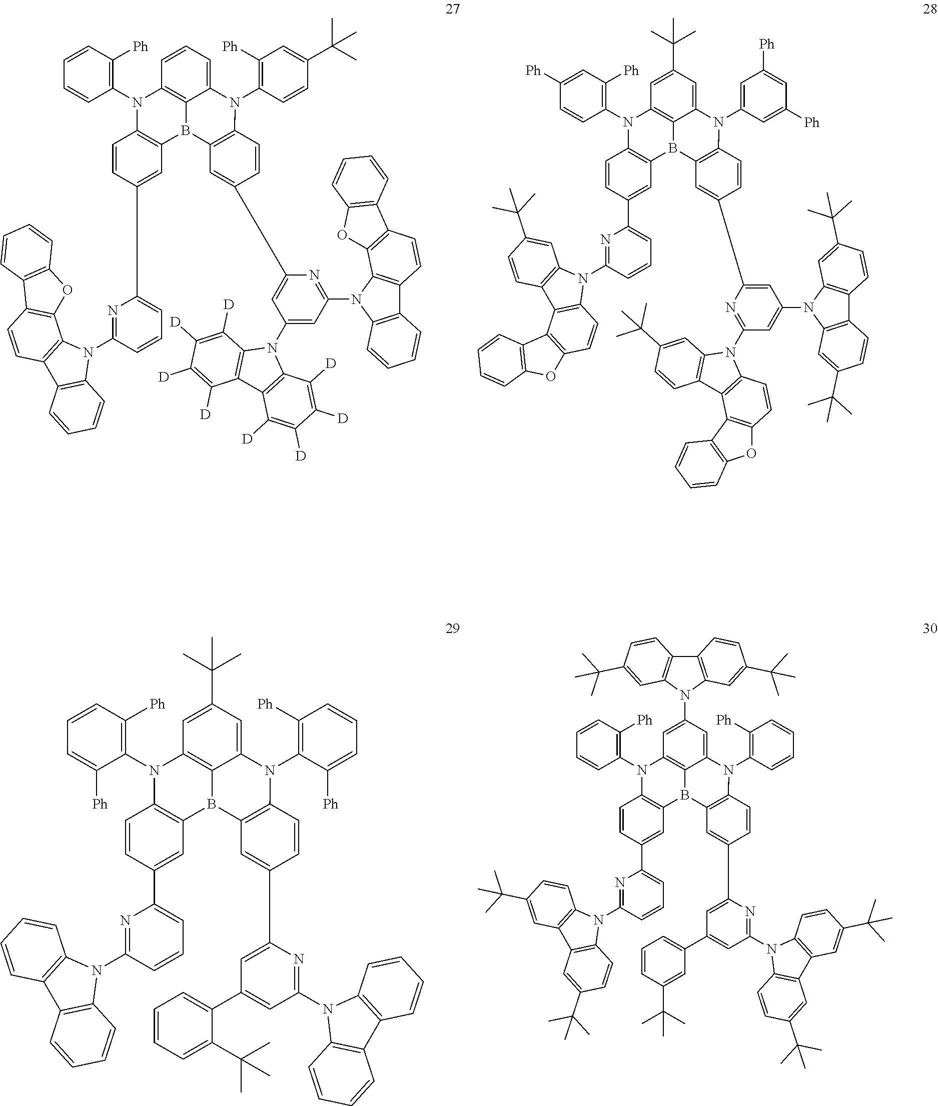

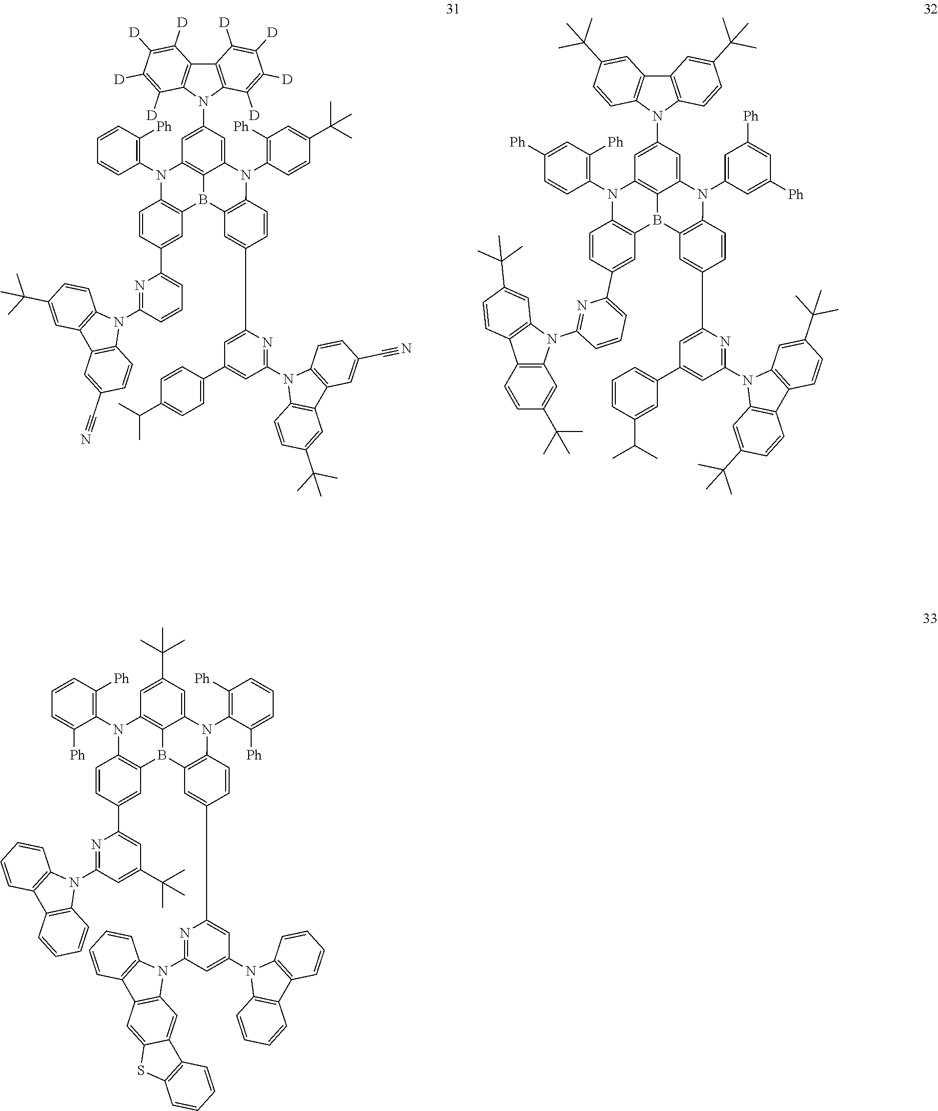

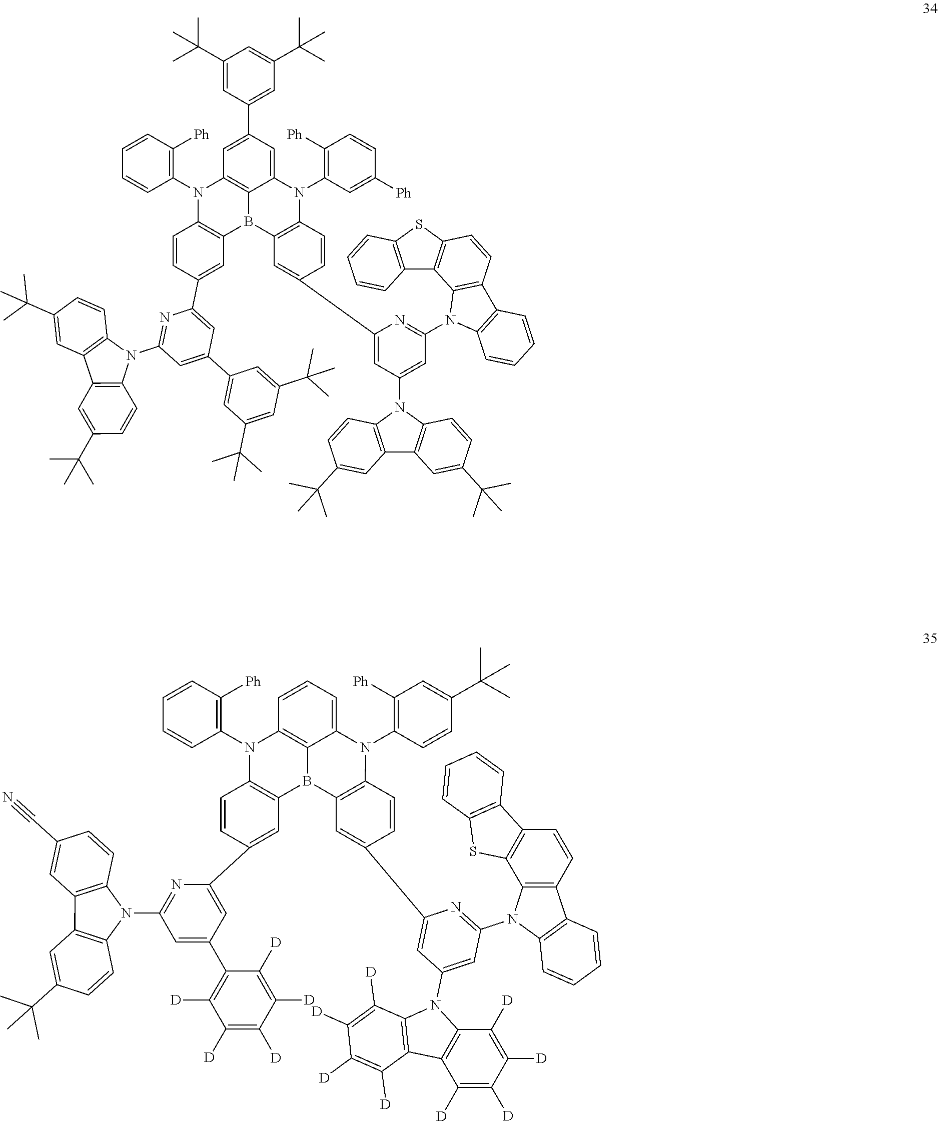

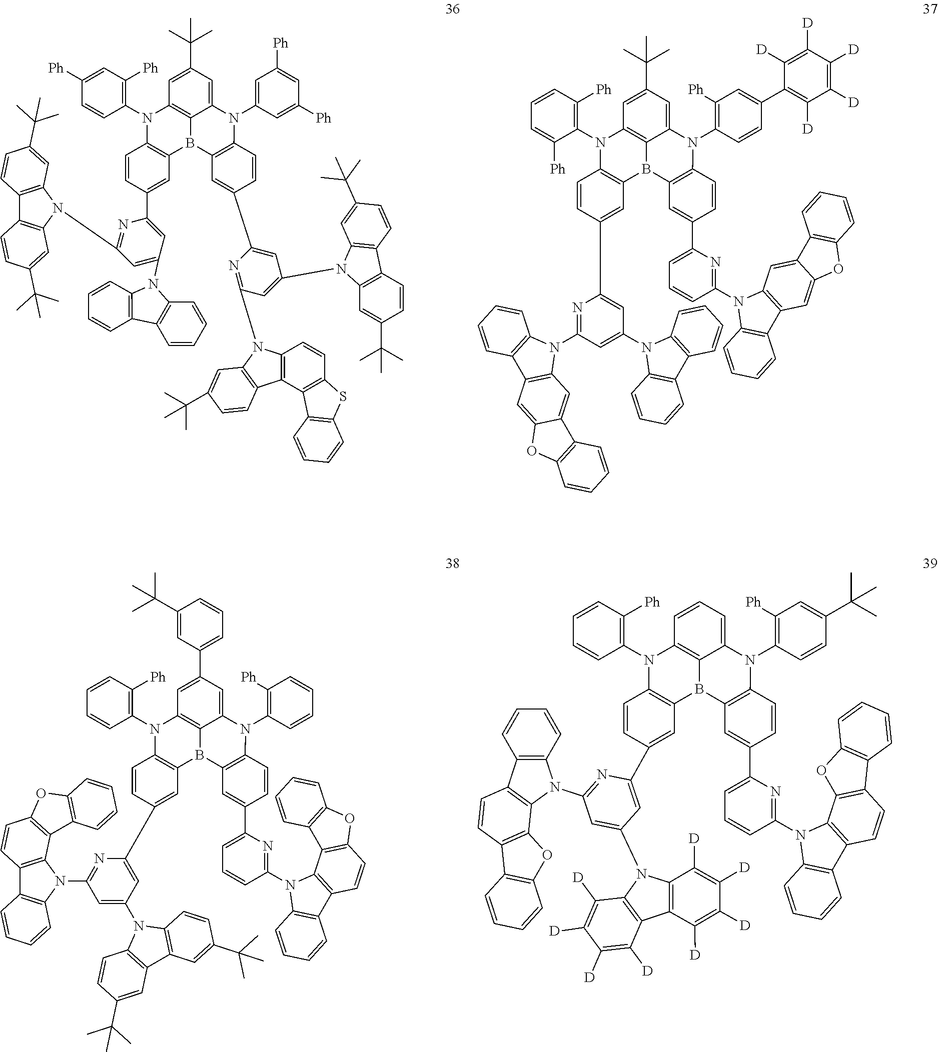

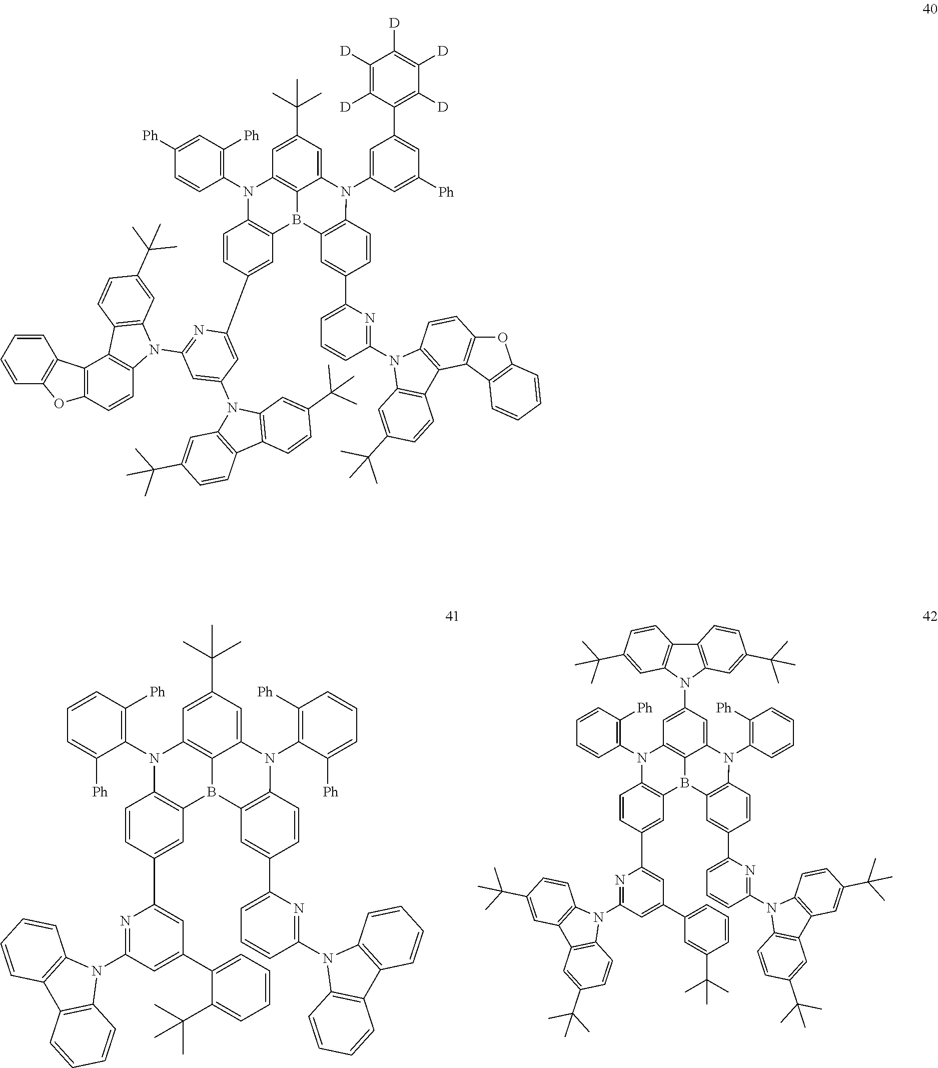

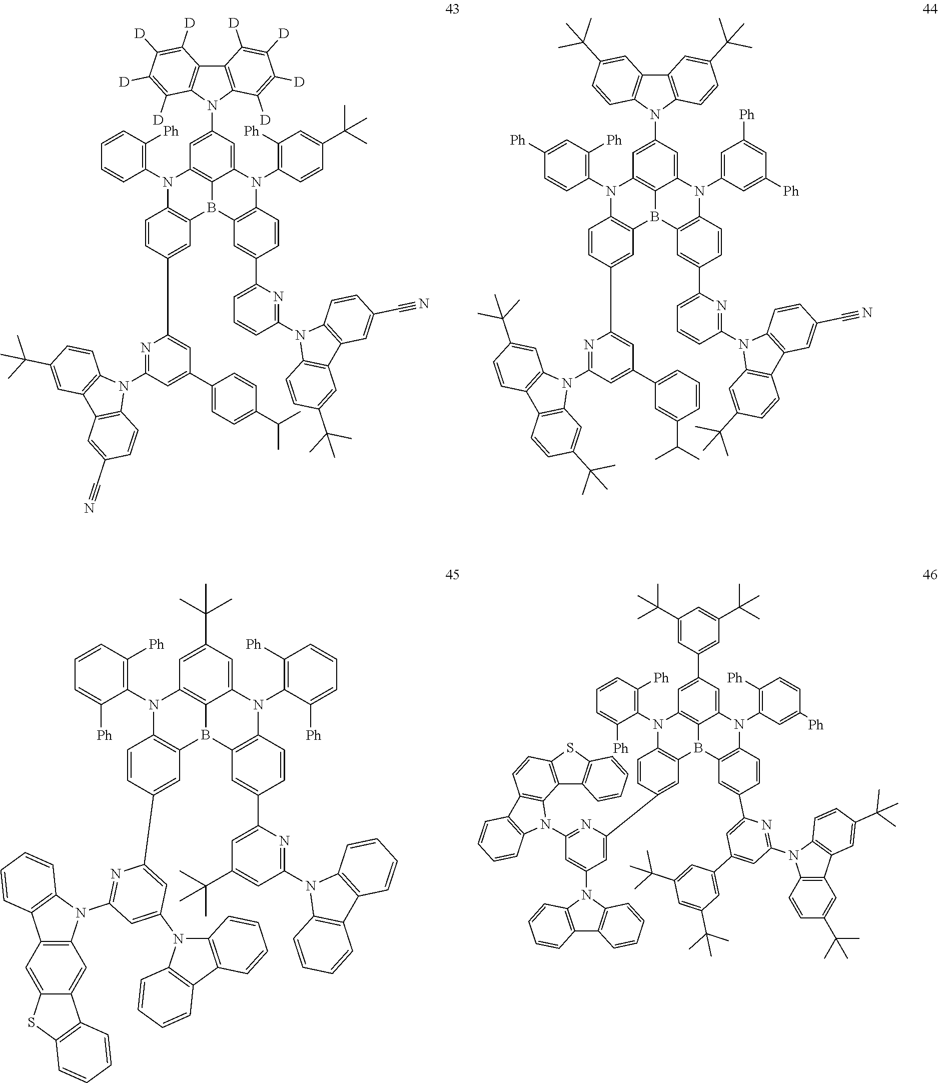

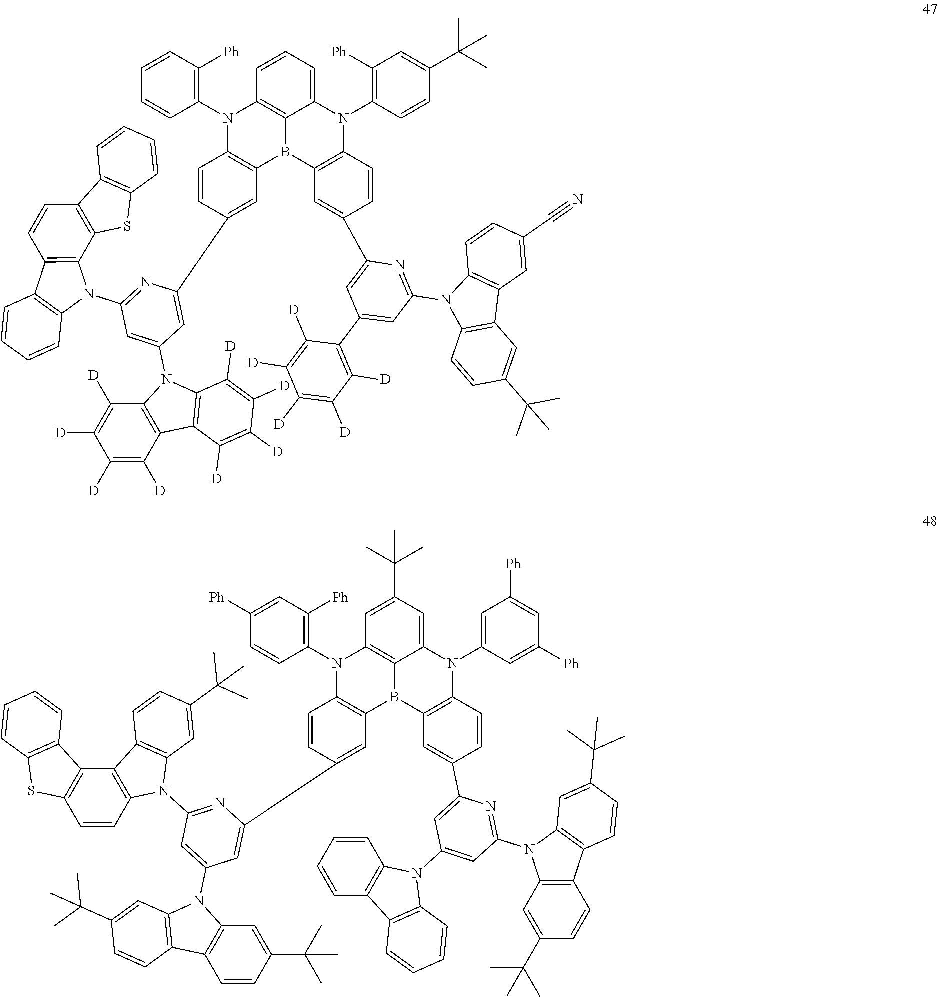

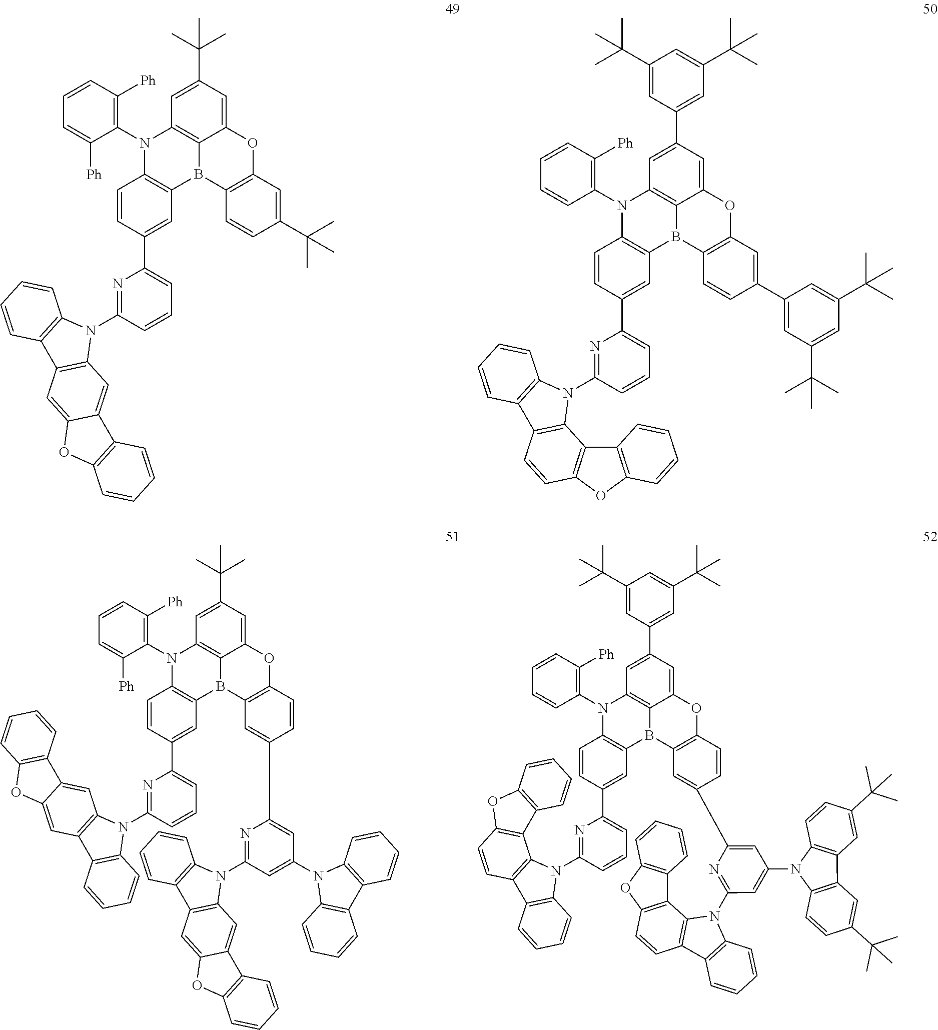

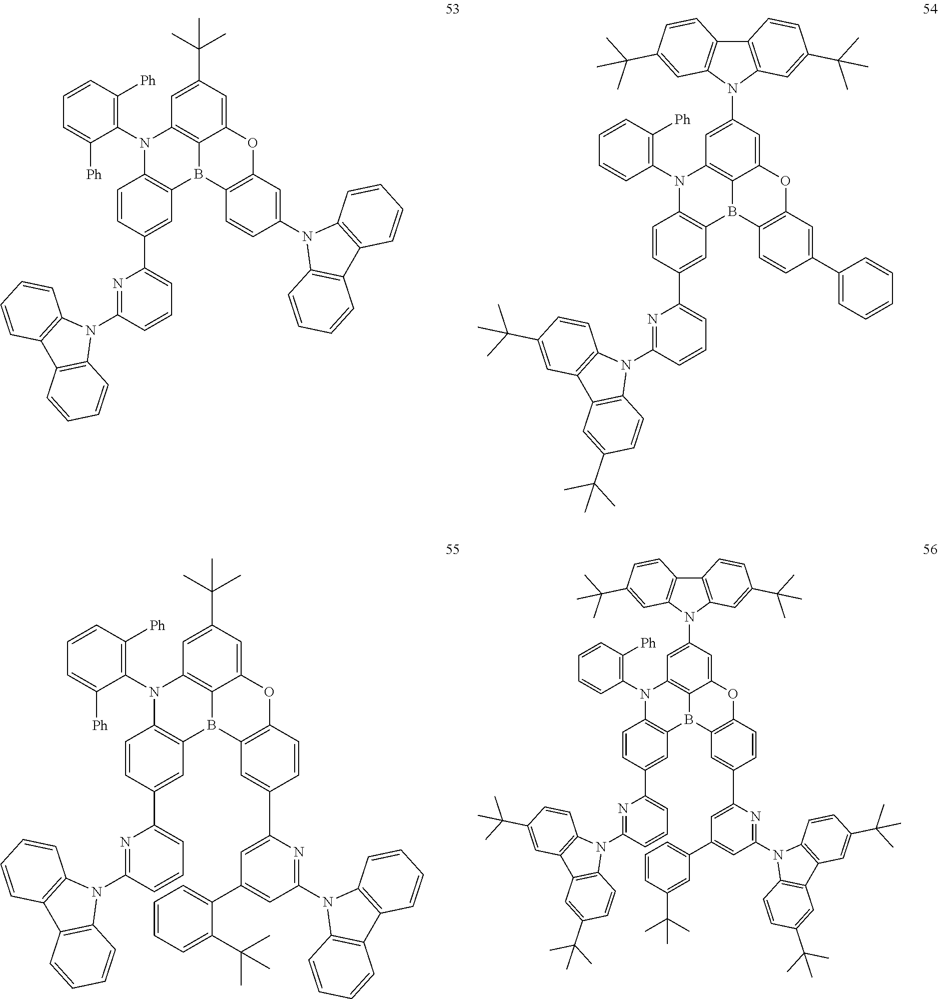

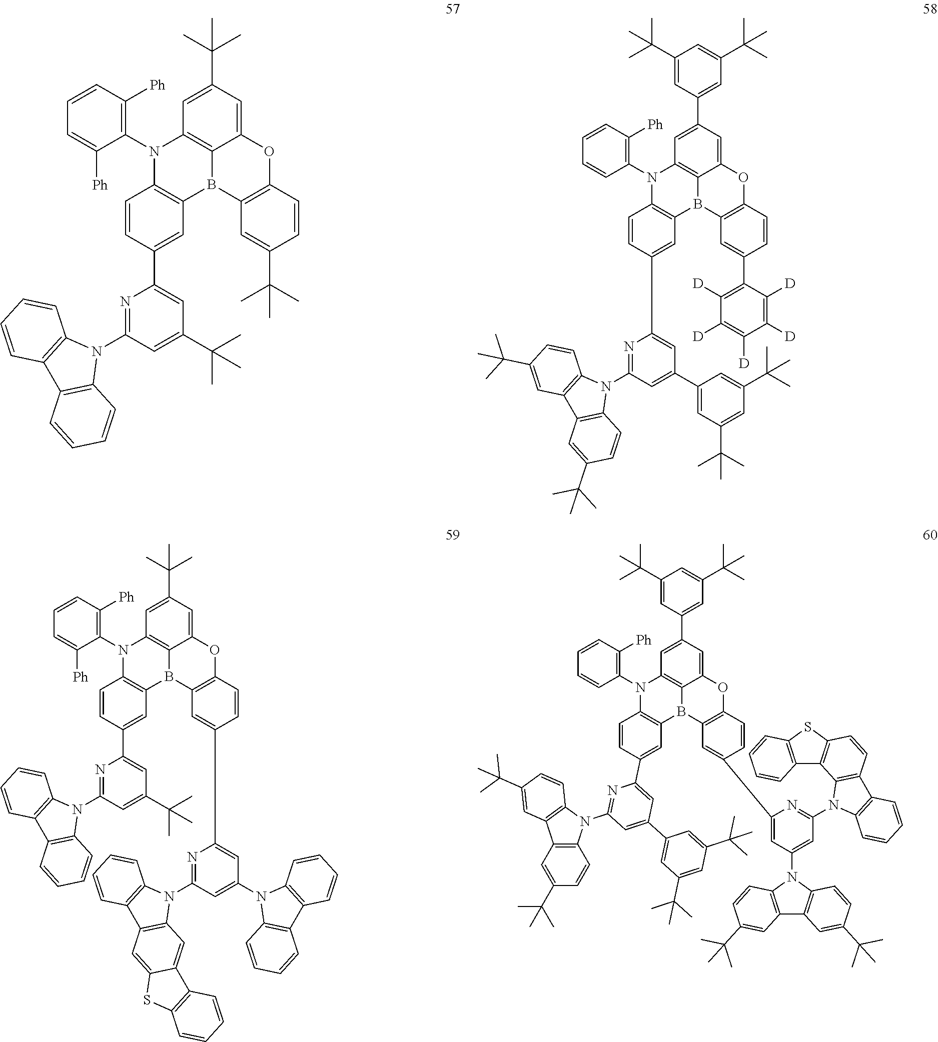

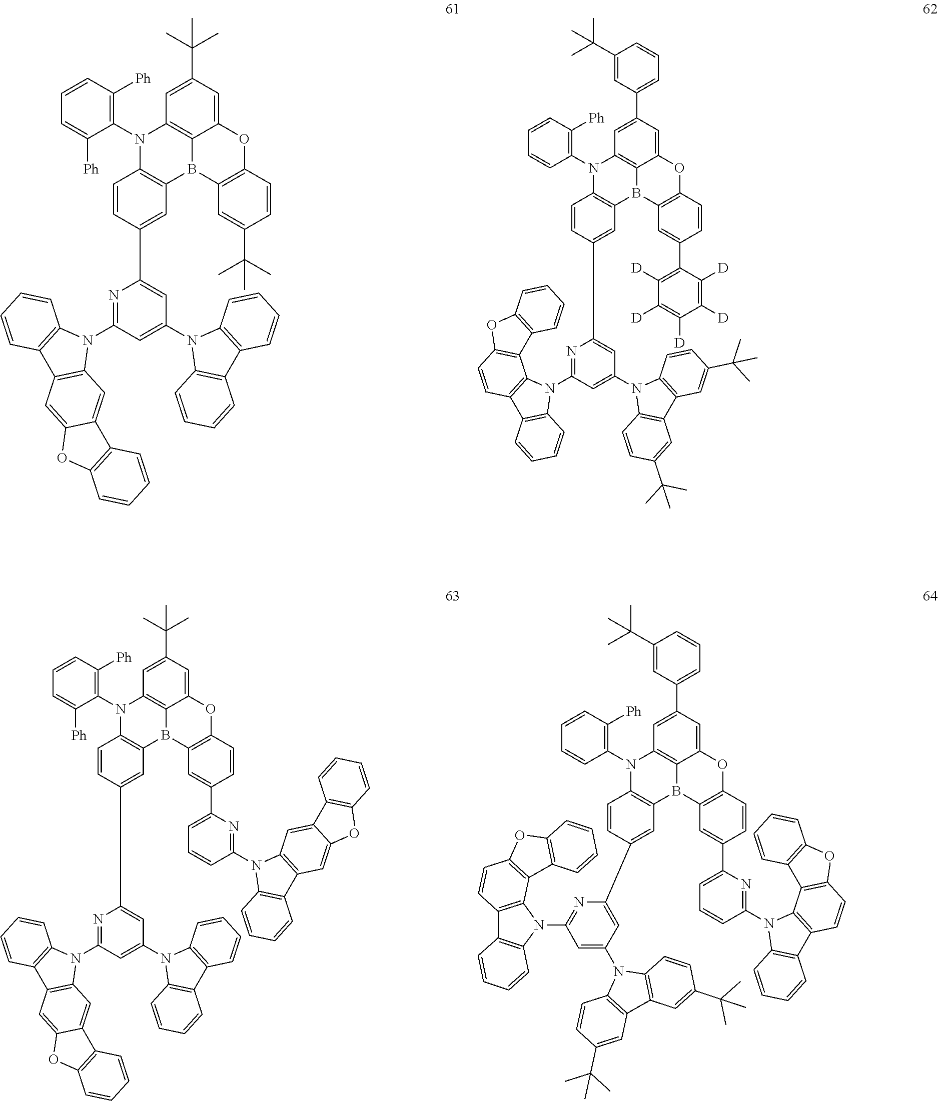

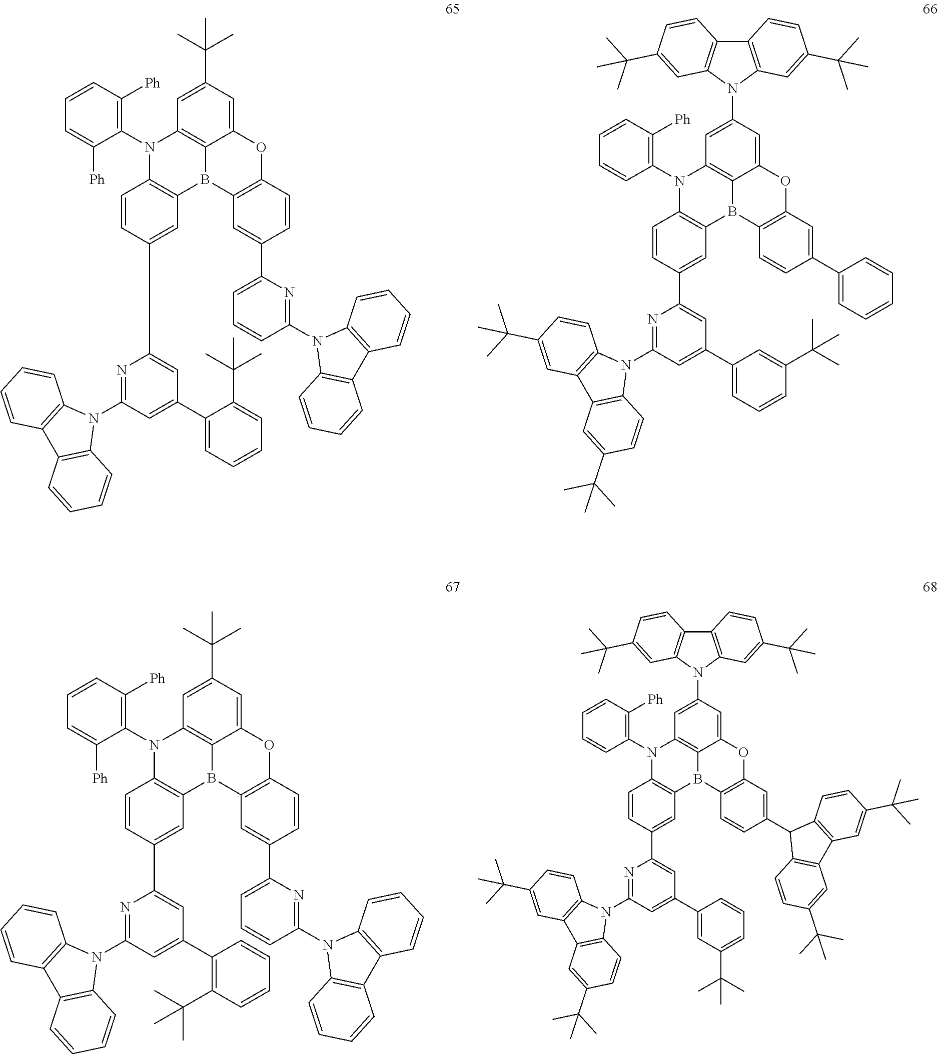

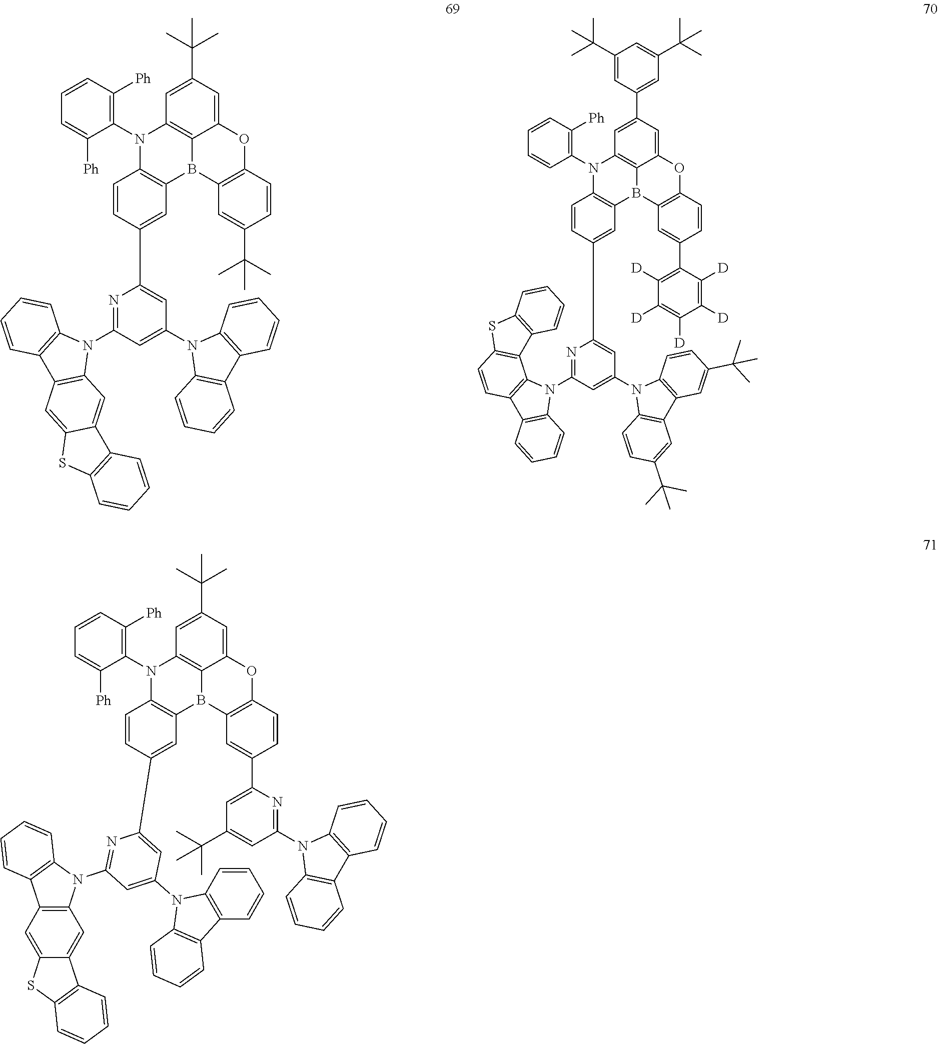

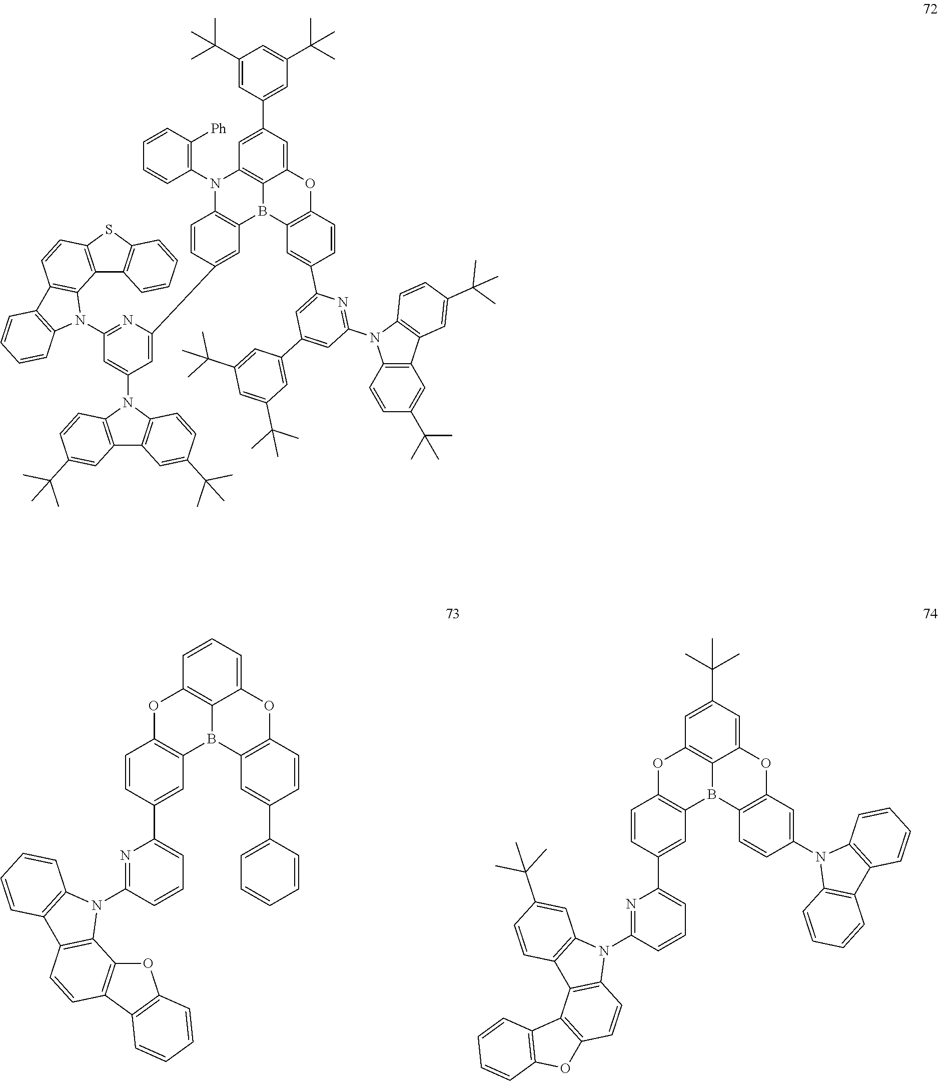 [SMILES: CC(C)(C)c1cc(-c2cc(-c3ccc4c(c3)B3c5cc(-c6cc(-n7c8ccc(C(C)(C)C)cc8c8cc(C(C)(C)C)ccc87)cc(-n7c8ccccc8c8ccc9sc%10ccccc%10c9c87)n6)ccc5N(c5ccccc5-c5ccccc5)c5cc(-c6cc(C(C)(C)C)cc(C(C)(C)C)c6)cc(c53)O4)nc(-n3c4ccc(C(C)(C)C)cc4c4cc(C(C)(C)C)ccc43)c2)cc(C(C)(C)C)c1 ; c1ccc(-c2ccc3c(c2)B2c4cc(-c5cccc(-n6c7ccccc7c7ccc8c9ccccc9oc8c76)n5)ccc4Oc4cccc(c42)O3)cc1 ; CC(C)(C)c1cc2c3c(c1)Oc1ccc(-c4cccc(-n5c6cc(C(C)(C)C)ccc6c6c7c(ccc65)oc5ccccc57)n4)cc1B3c1ccc(-n3c4ccccc4c4ccccc43)cc1O2]

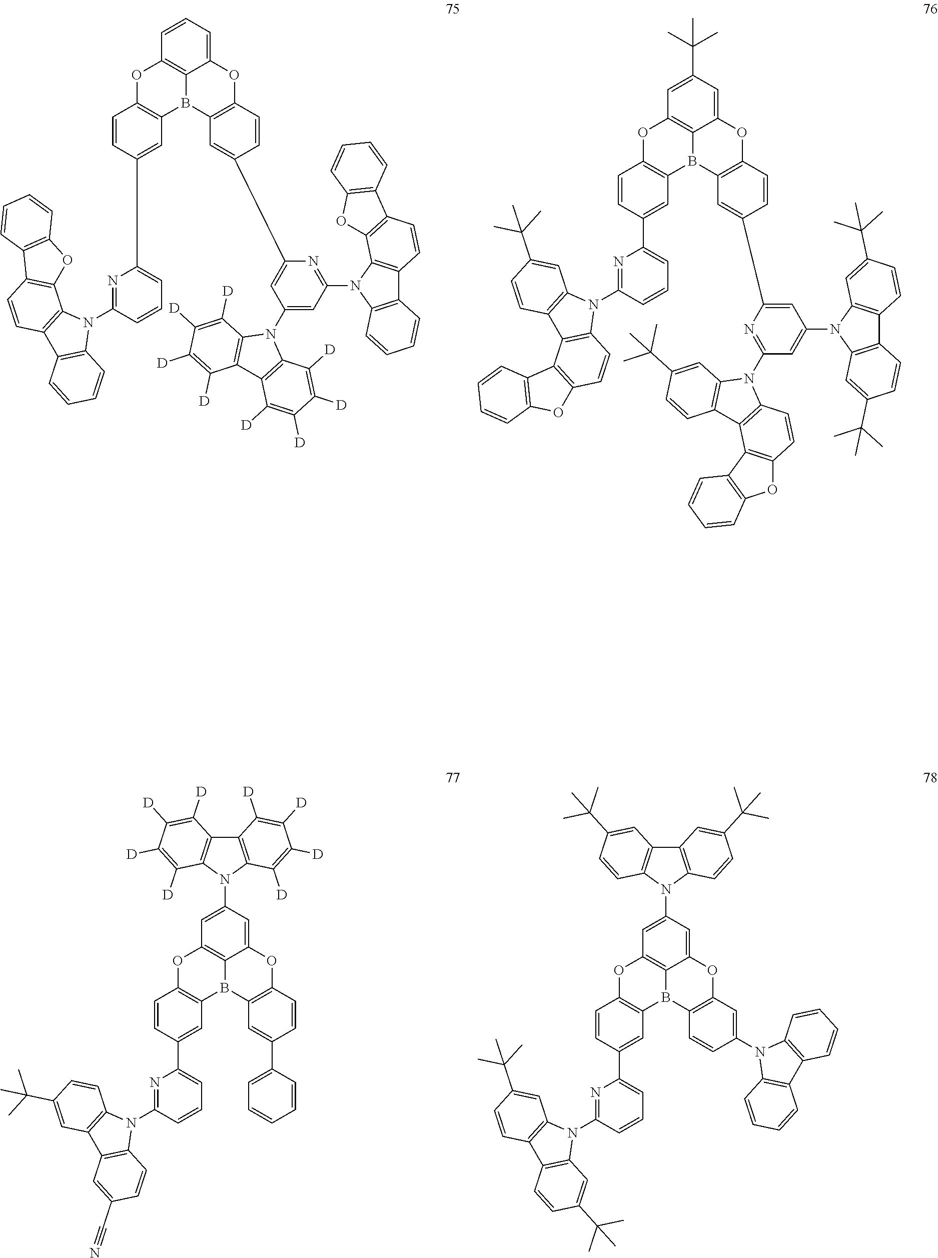

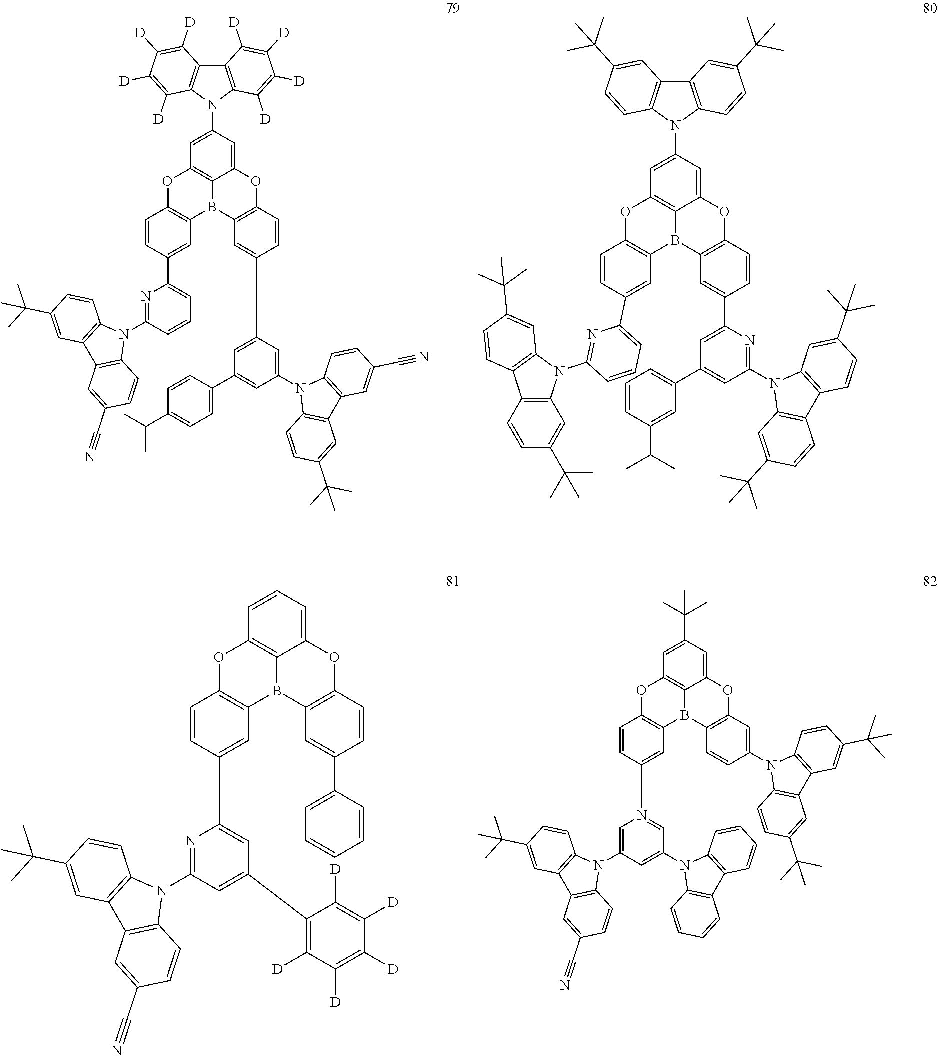

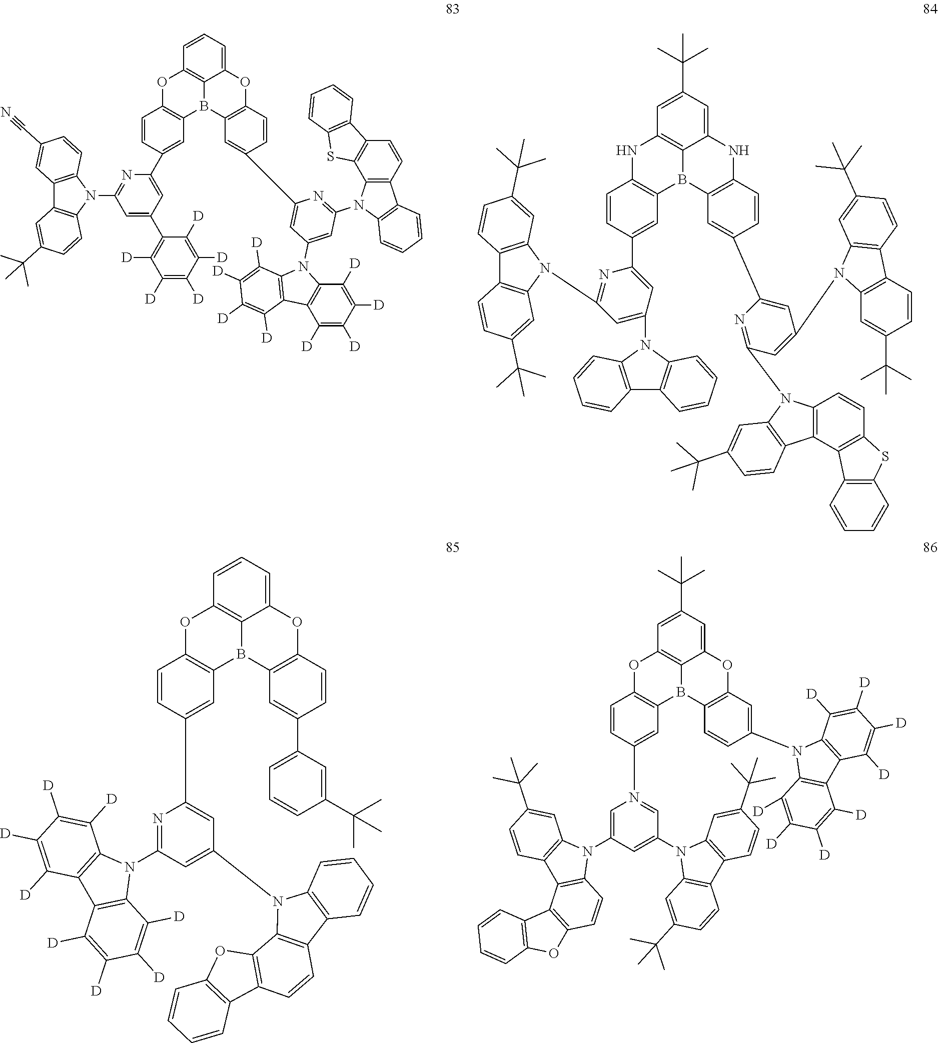

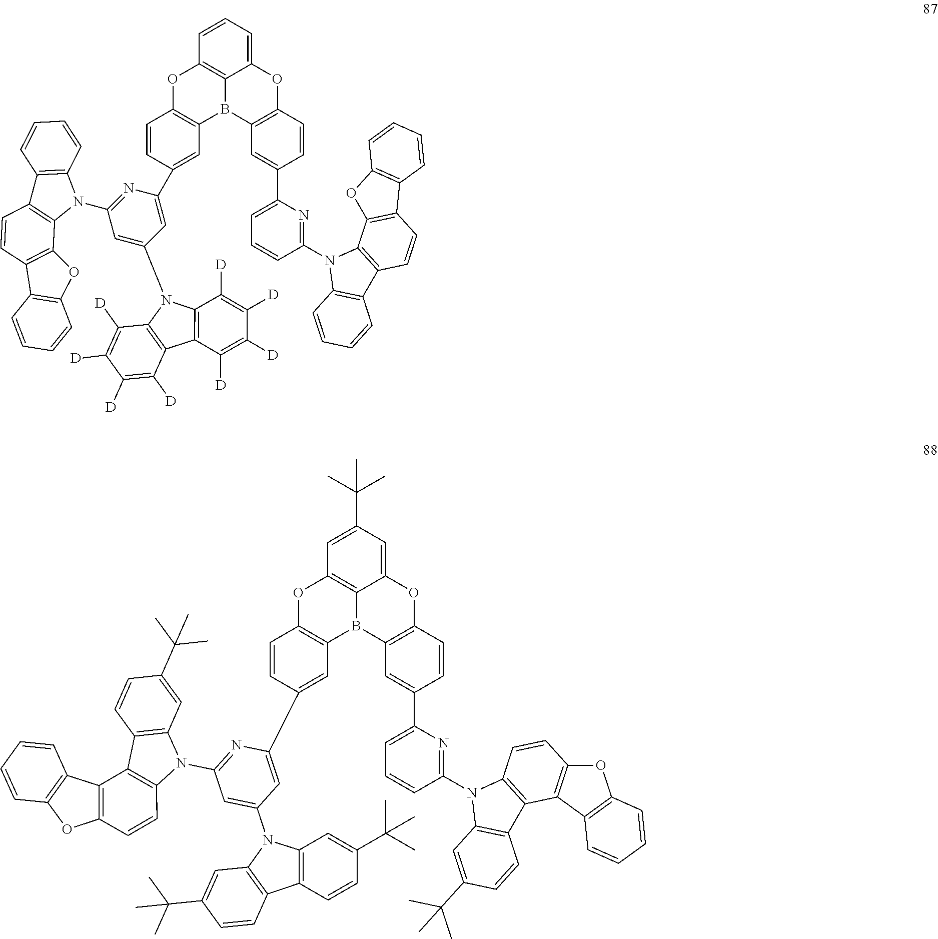 [SMILES: [2H]c1c([2H])c([2H])c2c(c1[2H])c1c([2H])c([2H])c([2H])c([2H])c1n2-c1cc(-c2ccc3c(c2)B2c4cc(-c5cccc(-n6c7ccccc7c7ccc8c9ccccc9oc8c76)n5)ccc4Oc4cccc(c42)O3)nc(-n2c3ccccc3c3ccc4c5ccccc5oc4c32)c1 ; CC(C)(C)c1cc2c3c(c1)Oc1ccc(-c4cc(-n5c6cc(C(C)(C)C)ccc6c6ccc(C(C)(C)C)cc65)cc(-n5c6cc(C(C)(C)C)ccc6c6c7c(ccc65)oc5ccccc57)n4)cc1B3c1cc(-c3cccc(-n4c5cc(C(C)(C)C)ccc5c5c6c(ccc54)oc4ccccc46)n3)ccc1O2]

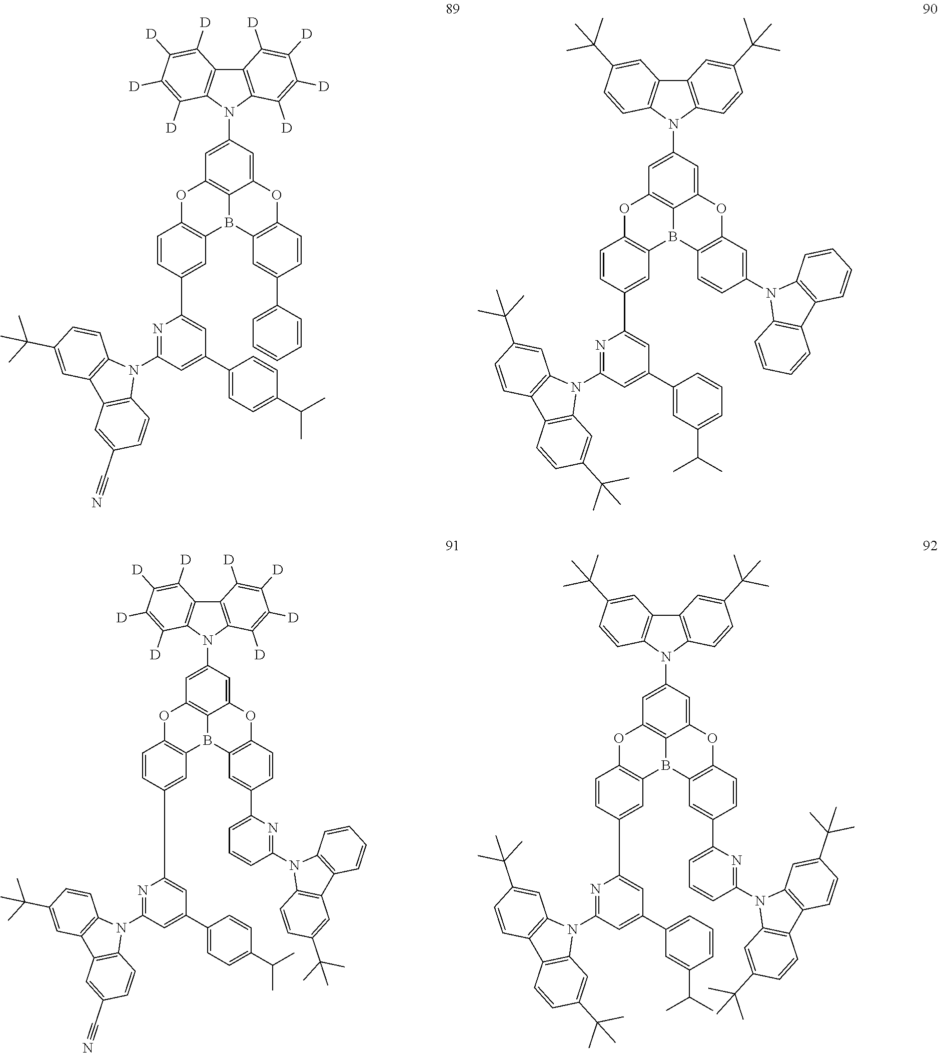

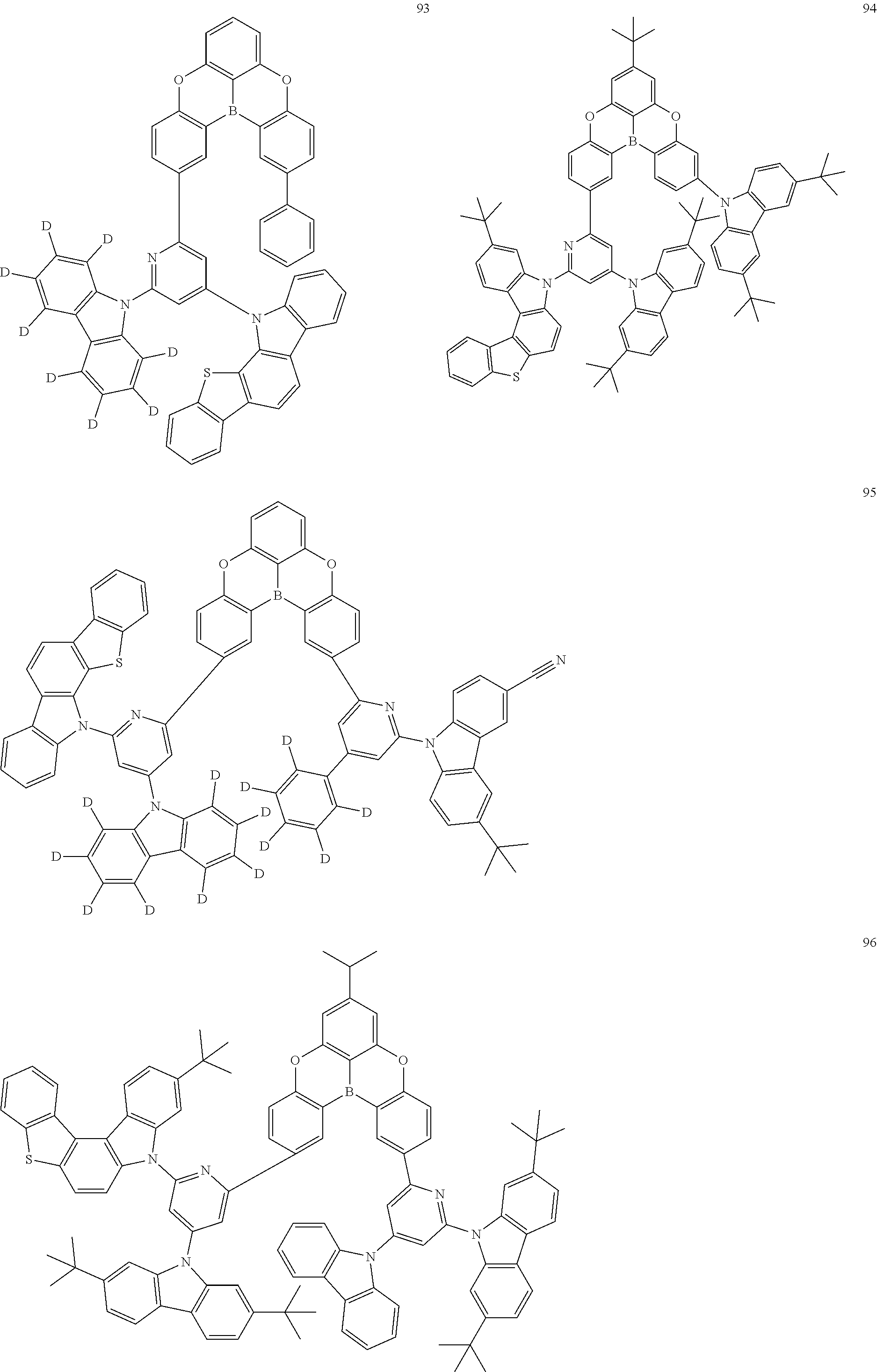

In a light emitting device, the emission layer EML may include the polycyclic compound. The emission layer EML may include the polycyclic compound as a dopant material. The polycyclic compound may be a thermally activated delayed fluorescence (TADF) material. The polycyclic compound may be used as a thermally activated delayed fluorescence dopant. For example, in the light emitting device ED, the emission layer EML may include, as a thermally activated delayed fluorescence dopant, at least one compound selected from Compound Group 1 as described above. However, a use of the polycyclic compound is not limited thereto.

The polycyclic compound may emit blue light. The polycyclic compound may have a maximum emission wavelength in a range of about 450 nm to about 480 nm. For example, the polycyclic compound may have a maximum emission wavelength in a range of about 455 nm to about 465 nm.

In an embodiment, the emission layer EML may include: a first compound represented by Formula 1; and at least one of a second compound represented by Formula HT or a third compound represented by Formula ET.

In an embodiment, the second compound represented by Formula HT may be used as a hole transport host material of the emission layer EML.

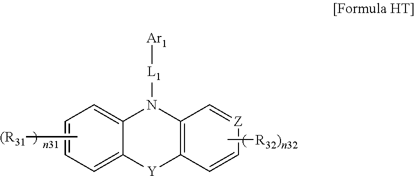

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT, Y may be a direct linkage, C(R_{y1})(R_{y2}), or Si(R_{y3})(R_{y4}). For example, the two benzene rings that are bonded to the nitrogen atom in Formula HT may be linked via a direct linkage,

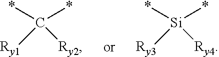

For example, when Y is a direct linkage, the second compound represented by Formula HT may include a carbazole moiety.

In Formula HT, Z may be C(R_{z}) or N.

In Formula HT, R_{y1} to R_{y4}, R₃₁, R₃₂, and R_{z} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R_{y1} to R_{y4} may each independently be a methyl group or a phenyl group. For example, R₃₁ and R₃₂ may each independently be a hydrogen atom or a deuterium atom.

In Formula HT, n31 may be an integer from 0 to 4. If n31 is 0, the fused polycyclic compound may not be substituted with R₃₁. A case where n31 is 4 and R₃₁ groups are all hydrogen atoms may be the same as a case where n31 is 0. When n31 is 2 or more, at least two R₃₁ groups may be the same as or different from each other.

In Formula HT, n32 may be an integer from 0 to 3. If n32 is 0, the fused polycyclic compound may not be substituted with R₃₂. A case where n32 is 3 and R₃₂ groups are all hydrogen atoms may be the same as a case where n32 is 0. When n32 is 2 or more, at least two R₃₂ groups may be the same as or different from each other.

In an embodiment, the emission layer EML may include a third compound represented by Formula ET. In an embodiment, the third compound represented by Formula ET may be used as an electron transport host material for the emission layer EML.

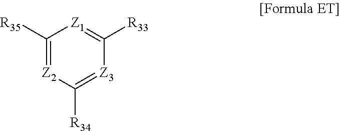

In Formula ET, Z₁ to Z₃ may each independently N or C(R₃₆), and at least one of Z₁ to Z₃ may each be N. For example, Z₁ to Z₃ may each be N. For example, Z₁ and Z₂ may each be N and Z₃ may be C(R₃₆), Z₁ may be C(R₃₆) and Z₂ and Z₃ may each be N, or Z₁ and Z₃ may each be N and Z₂ may be C(R₃₆). For example, Z₁ may be N and Z₂ and Z₃ may each independently be C(R₃₆), Z₂ may be N and Z₂ and Z₃ may each independently be C(R₃₆), or Z₃ may be N and Z₁ and Z₂ may each independently be C(R₃₆).

In Formula ET, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₃₃ to R₃₆ may each independently be a substituted or unsubstituted phenyl group, a substituted or unsubstituted carbazole group, etc., but embodiments are not limited thereto.

In an embodiment, the emission layer EML may include the second compound and the third compound, and the second compound and the third compound may form an exciplex.

In the emission layer EML, an exciplex may be formed by the hole transport host and the electron transport host. A triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, an absolute value of the triplet energy (T1) of the exciplex formed by the hole transporting host and the electron transporting host may be in a range of about 2.4 eV to about 3.0 eV. The triplet energy of the exciplex may be a value that is smaller than an energy gap of each host material. The exciplex may have a triplet energy equal to or less than about 3.0 eV which is an energy gap between the hole transporting host and the electron transporting host.

In an embodiment, the emission layer EML may further include a fourth compound, in addition to the first compound to the third compound as described above. The fourth compound may be used as a phosphorescent sensitizer in the emission layer EML. Energy may be transferred from the fourth compound to the first compound, thereby emitting light.

In an embodiment, the emission layer EML may include, as the fourth compound, an organometallic complex that includes platinum (Pt) as a central metal atom and ligands bonded to the central metal atom. In an embodiment, an emission layer EML of the light emitting device ED may include, as the fourth compound, a compound represented by Formula PS:

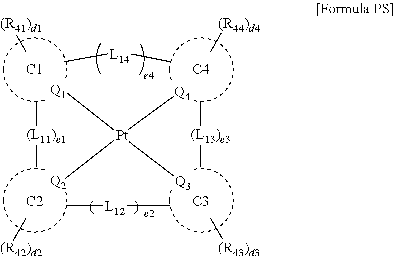

In Formula PS, Q₁ to Q₄ may each independently be C or N.

In Formula PS, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula PS, L₁₁ to L₁₄ may each independently be a direct linkage, *—O—*, *—S—*,

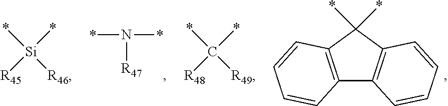

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula PS, e1 to e4 may each independently be 0 or 1. If e1 is 0, C1 and C2 may not be directly linked to each other. If e2 is 0, C2 and C3 may not be directly linked to each other. If e3 is 0, C3 and C4 may not be directly linked to each other. If e4 is 0, C1 and C4 may not be directly linked to each other.

In Formula PS, R₄₁ to R₄₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₄₁ to R₄₉ may each independently be a substituted or unsubstituted methyl group, or a substituted or unsubstituted t-butyl group.

In Formula PS, d1 to d4 may each independently be an integer from 0 to 4. If each of d1 to d4 is 0, the fourth compound may not be substituted with each of R₄₁ to R₄₄. A case where each of d1 to d4 is 4 and multiple groups of each of R₄₁ to R₄₄ are each hydrogen atoms may be the same as a case where each of d1 to d4 is 0. When each of d1 to d4 is 2 or more, multiple groups of each of R₄₁ to R₄₄ may be the same as or different from each other.

In an embodiment, C1 to C4 may each independently be a substituted or unsubstituted hydrocarbon ring or a substituted or unsubstituted heterocycle represented by any one of Formula C-1 to Formula C-4:

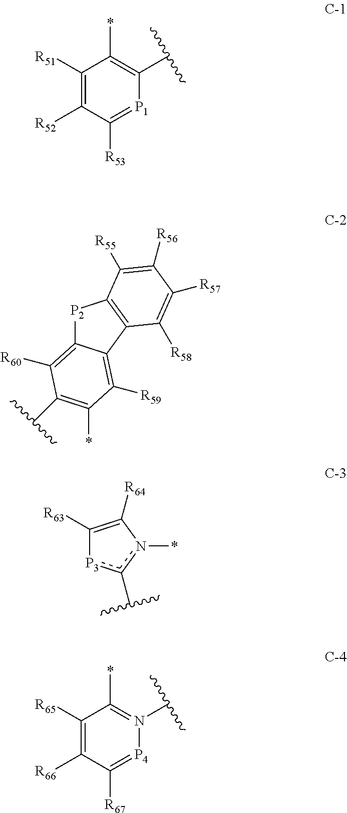

In Formula C-1 to Formula C-4, P₁ may be C—* or C(R₅₄), P₂ may be N—* or N(R₆₁), P₃ may be N—* or N(R₆₂), and P₄ may be C—* or C(R₆₈). In Formula C-1 to Formula C-4, R₅₁ to R₆₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula C-1 to Formula C-4,

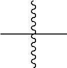

represents a bonding site to Pt that is a central metal atom, and —* represents a bonding site to a neighboring cyclic group (C1 to C4) or to a linking group (L₁₁ to L₁₄).

The emission layer EML may include the first compound, and at least one of the second to fourth compounds. In an embodiment, the emission layer EML may include the first compound, the second compound, and the third compound. In the emission layer EML, the second compound and the third compound may form an exciplex, and energy may be transferred from the exciplex to the first compound, thereby emitting light.

In another embodiment, the emission layer EML may include the first compound, the second compound, the third compound, and the fourth compound. In the emission layer EML, the second compound and the third compound may form an exciplex, and energy may be transferred from the exciplex to the fourth compound and the first compound, thereby emitting light. In an embodiment, the fourth compound may be a sensitizer (for example, a phosphorescent sensitizer). The fourth compound included in the emission layer EML in the light emitting device ED may serve as a sensitizer that transfers energy from the host to the first compound, which may be a light emitting dopant. The fourth compound serving as an auxiliary dopant may accelerate energy transfer to the first compound, which is a light emitting dopant, thereby increasing the emission ratio of the first compound. Therefore, the emission layer EML may have improved luminous efficiency. When energy transfer to the first compound is increased, an exciton formed in the emission layer EML may not accumulate in the emission layer EML and may rapidly emit light, and thus deterioration of the device may be reduced. Therefore, the service life of the light emitting device ED may increase.

The light emitting device ED may include the first compound, the second compound, the third compound, and the fourth compound, and the emission layer EML may include a combination of two host materials and two dopant materials. In the light emitting device ED, the emission layer EML may include two different hosts, a first compound that emits delayed fluorescence, and a fourth compound including an organometallic complex, thereby exhibiting excellent luminous efficiency characteristics.

In an embodiment, the second compound represented by Formula HT may be any compound selected from Compound Group HT. The emission layer EML may include at least one compound selected from Compound Group HT as a hole transporting host material. In Compound Group HT, D represents a deuterium atom, and Ph represents a substituted or unsubstituted phenyl group.

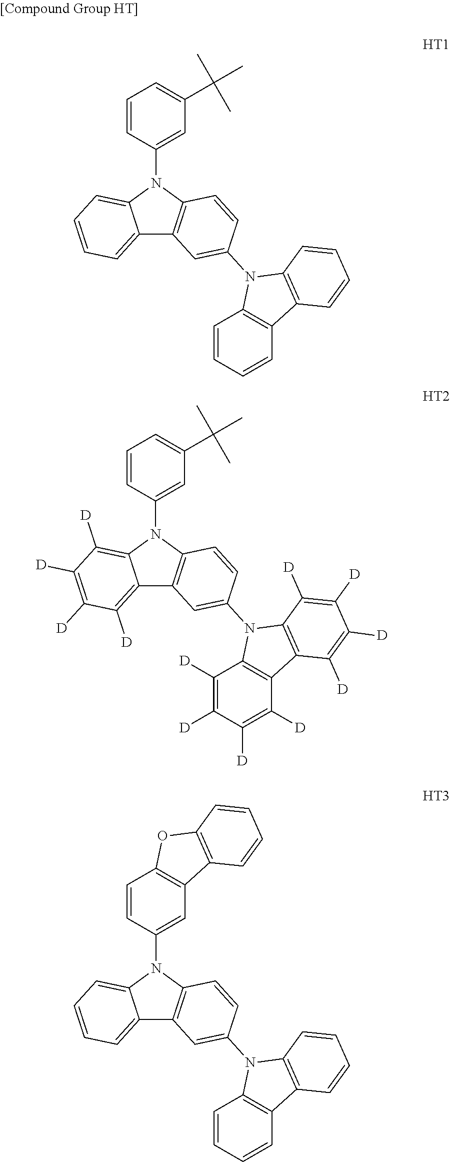

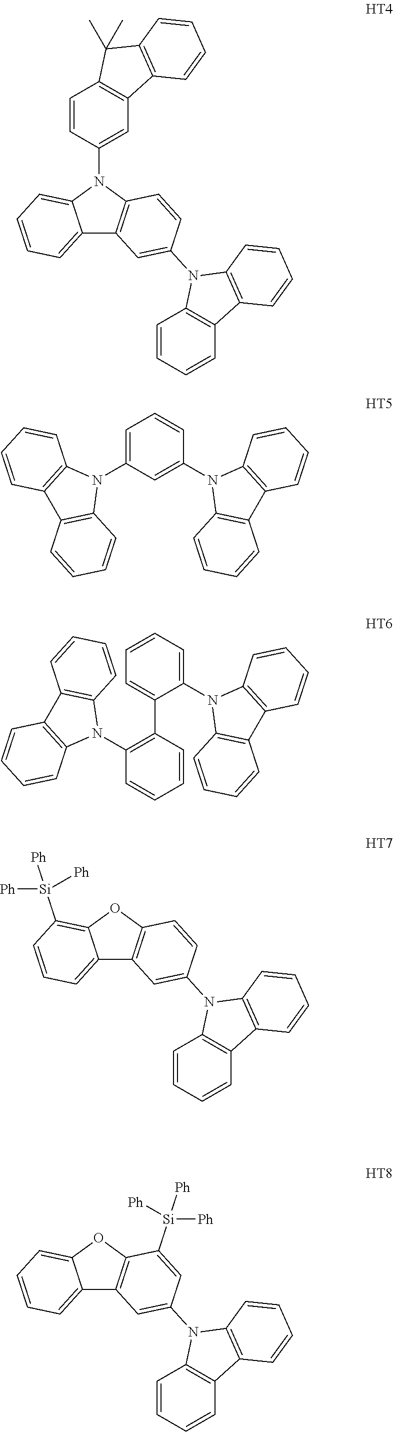 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

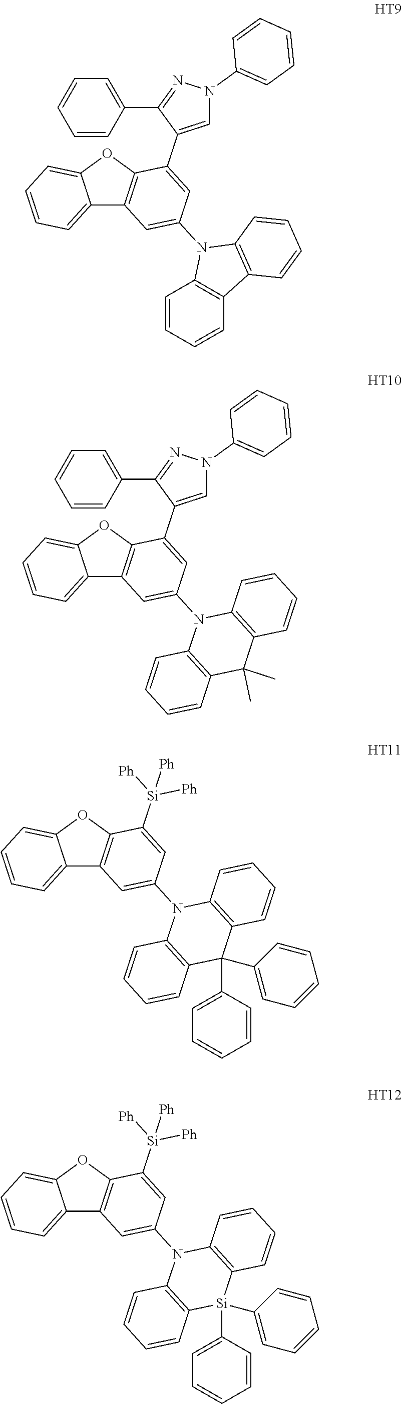 [SMILES: c1ccc(-c2nn(-c3ccccc3)cc2-c2cc(-n3c4ccccc4c4ccccc43)cc3c2oc2ccccc23)cc1 ; CC1(C)c2ccccc2N(c2cc(-c3cn(-c4ccccc4)nc3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

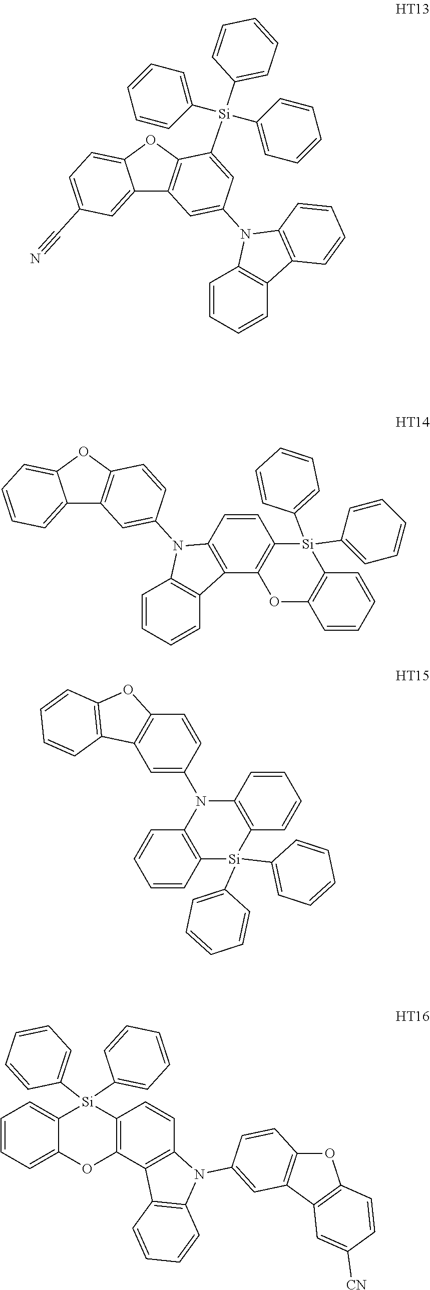 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

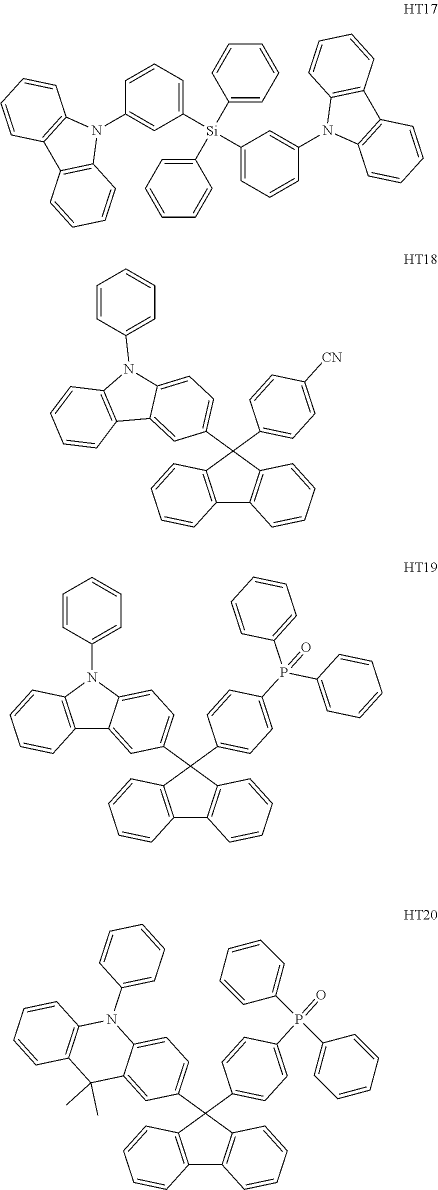 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

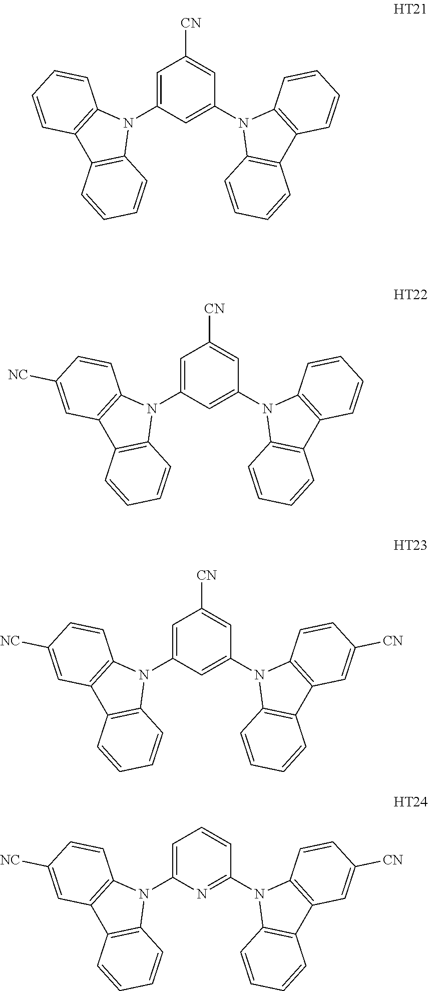 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

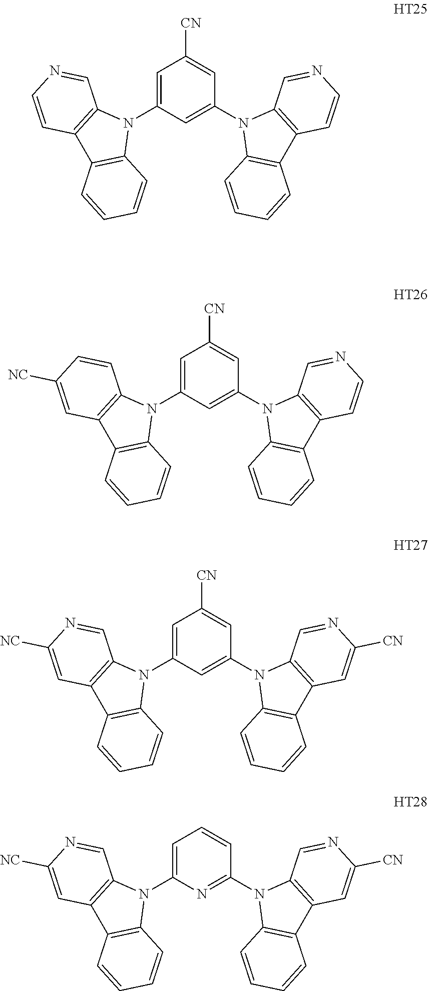 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

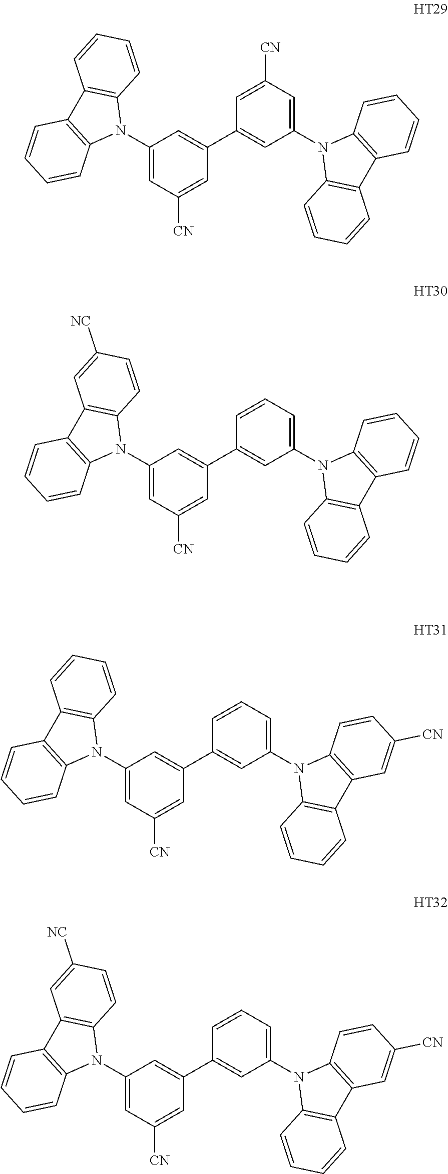 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

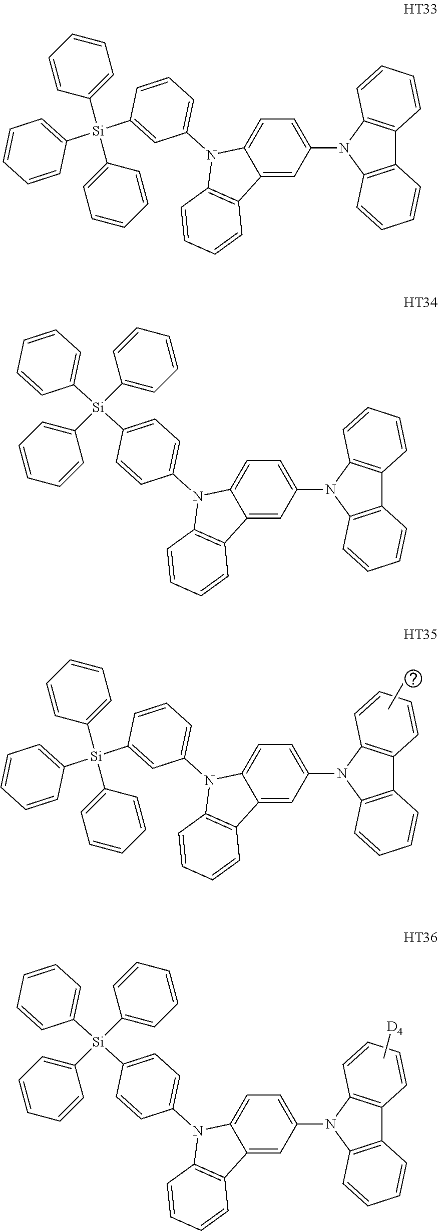

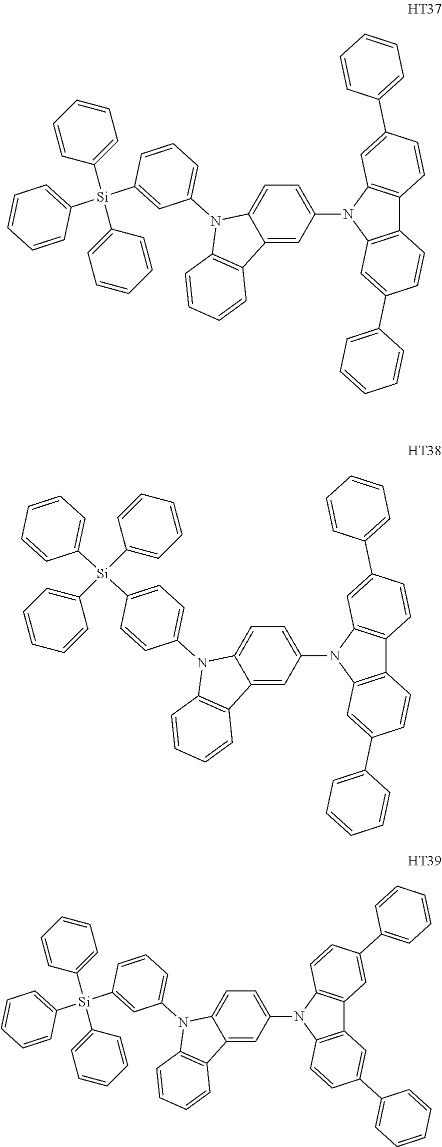 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1]

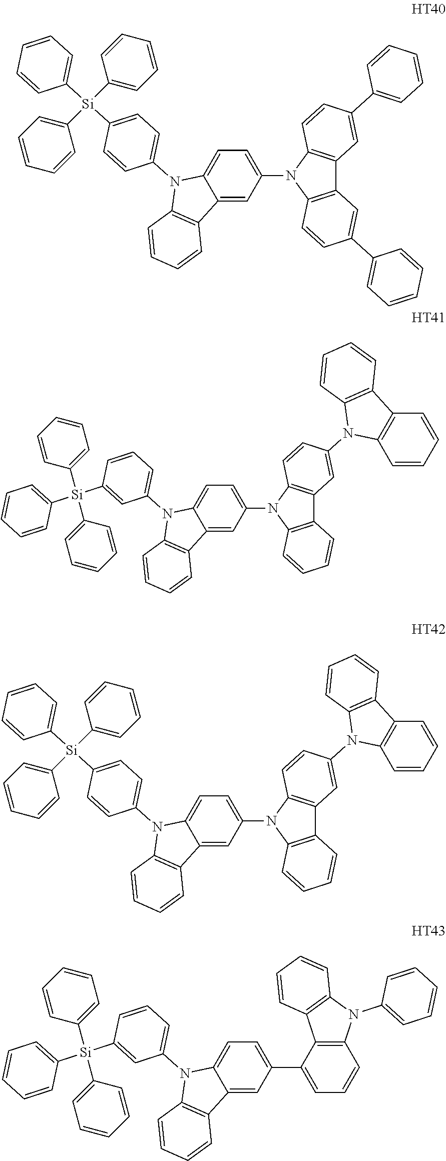 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1]

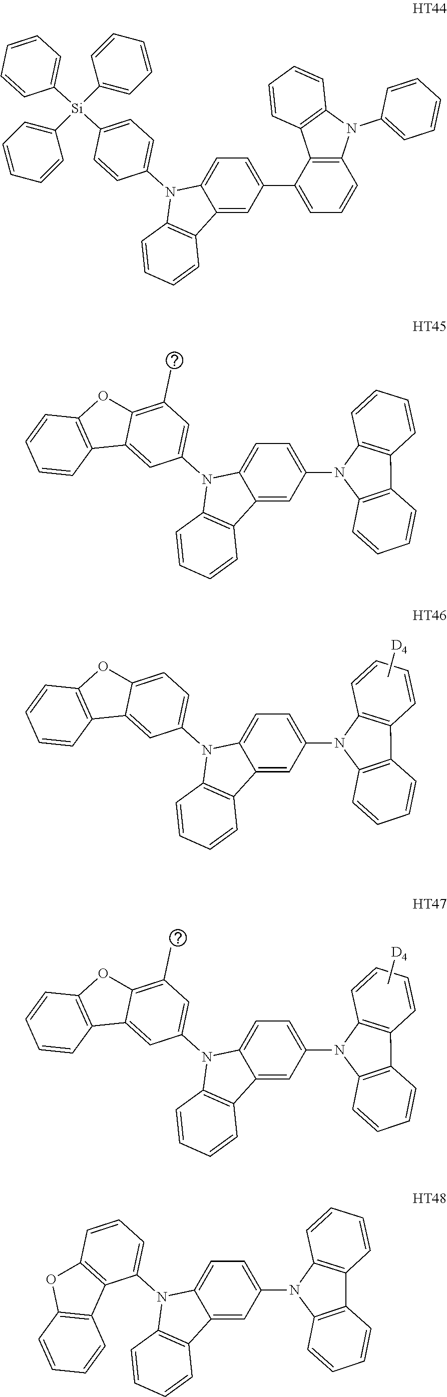

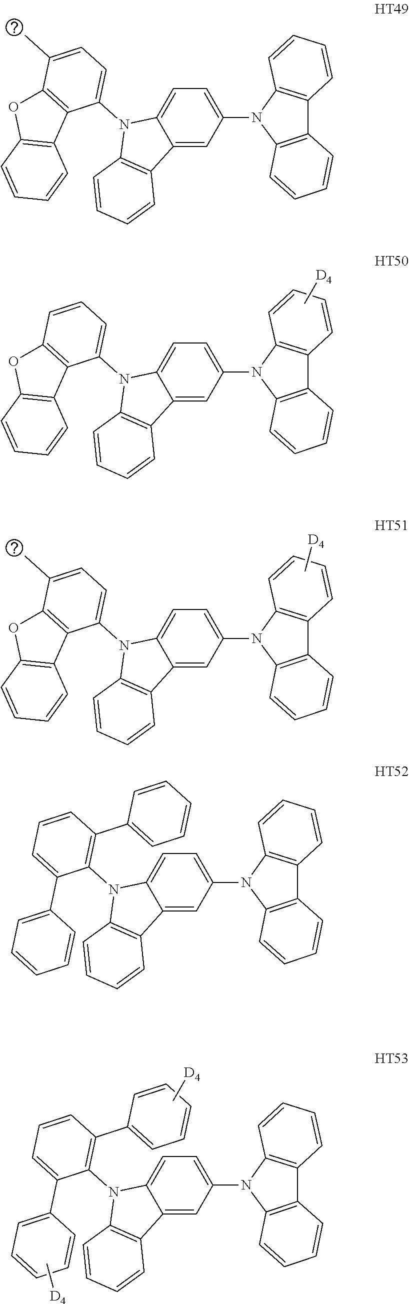

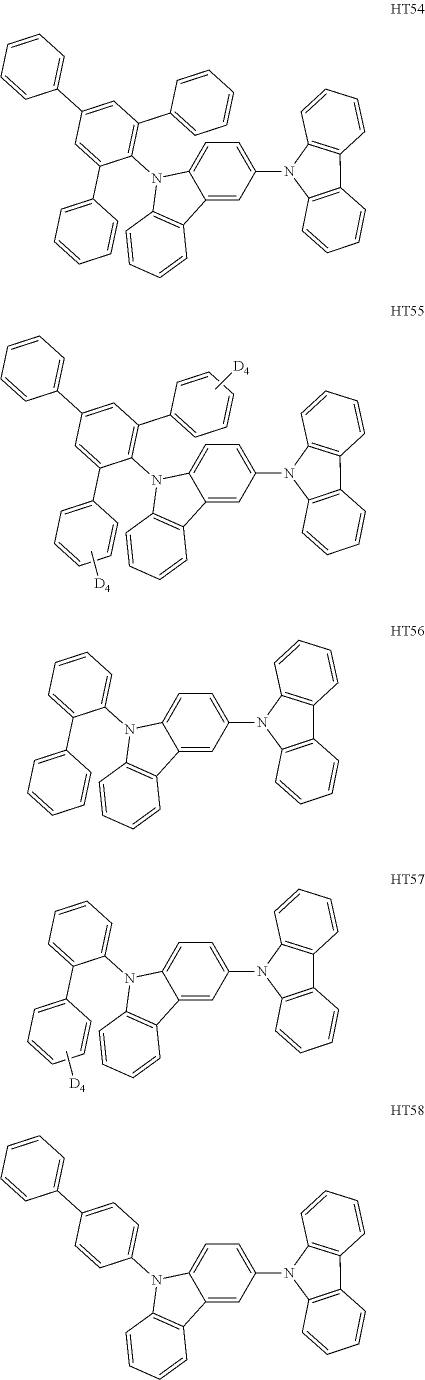

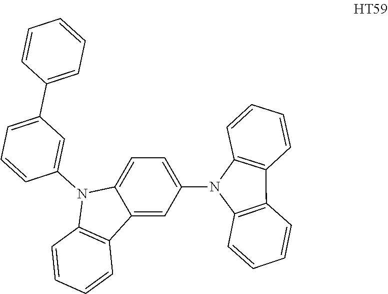 [SMILES: c1ccc(-c2cccc(-n3c4ccccc4c4cc(-n5c6ccccc6c6ccccc65)ccc43)c2)cc1]

In an embodiment, the third compound represented by Formula ET may be compound selected from Compound Group ET. The emission layer EML may include at least one compound selected from Compound Group ET as an electron transporting host material. In Compound Group ET, D represents a deuterium atom.

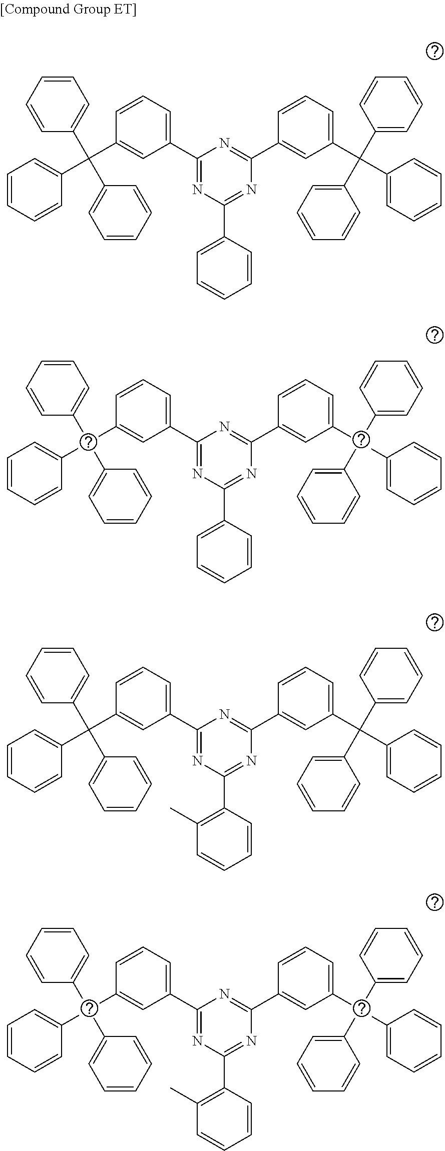 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1]

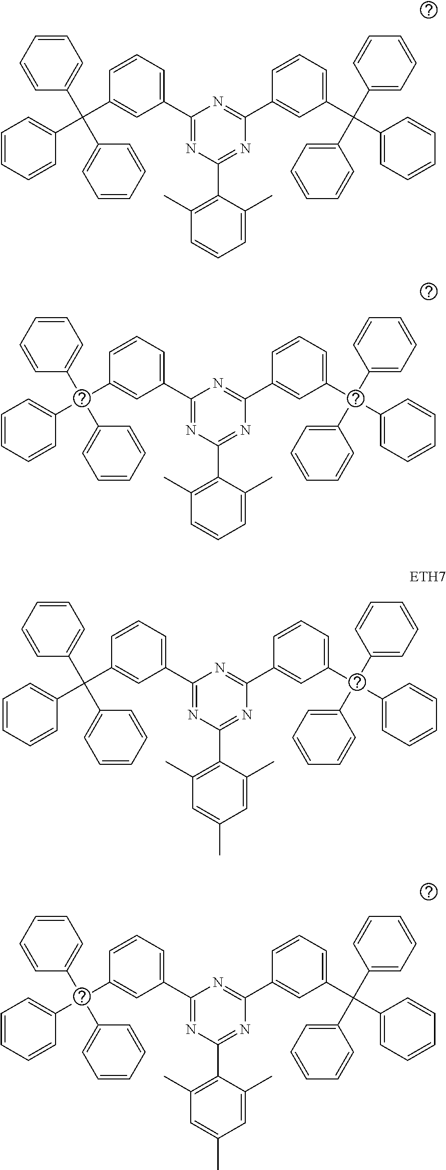 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1]

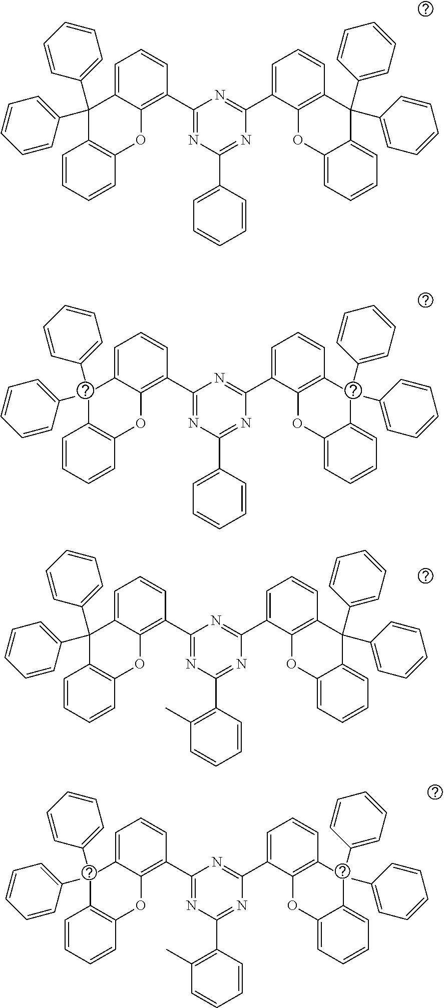 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1]

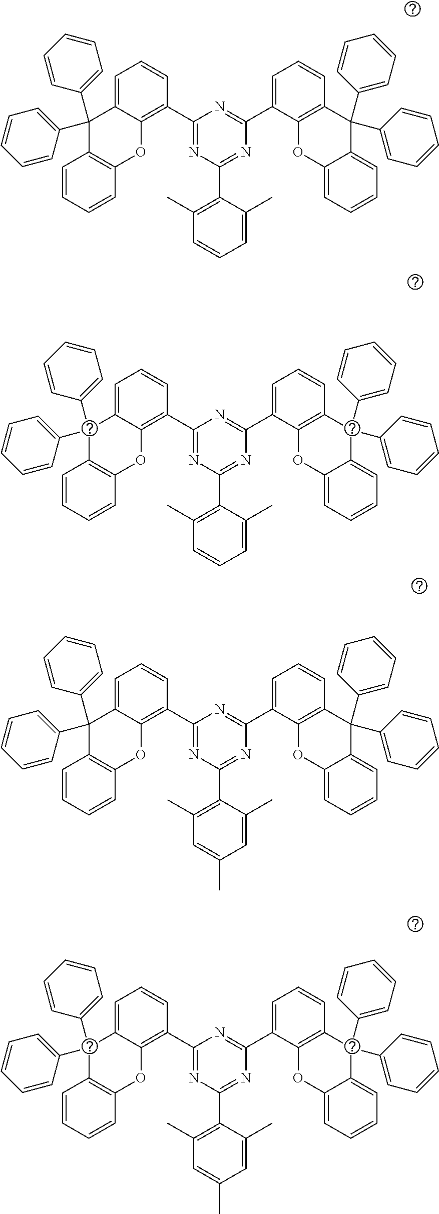 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1]

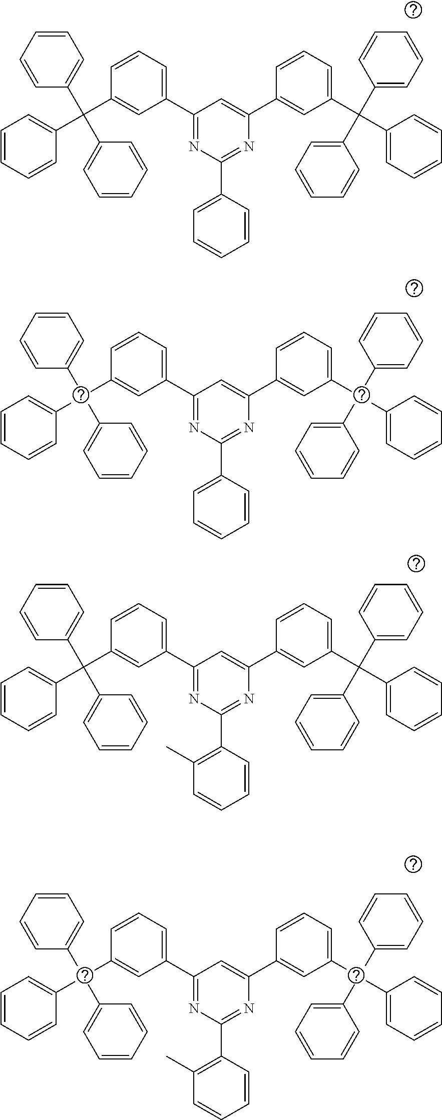 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1]

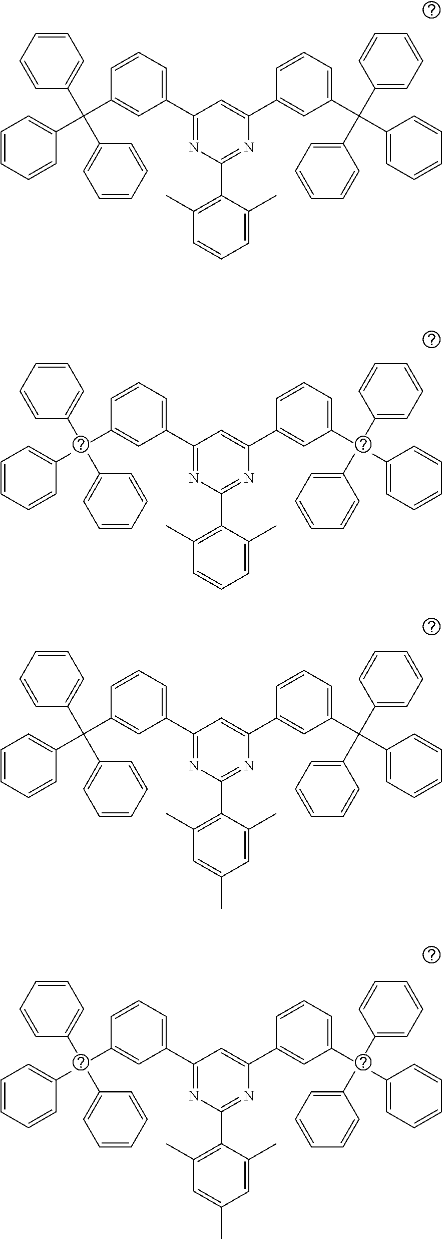 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1]

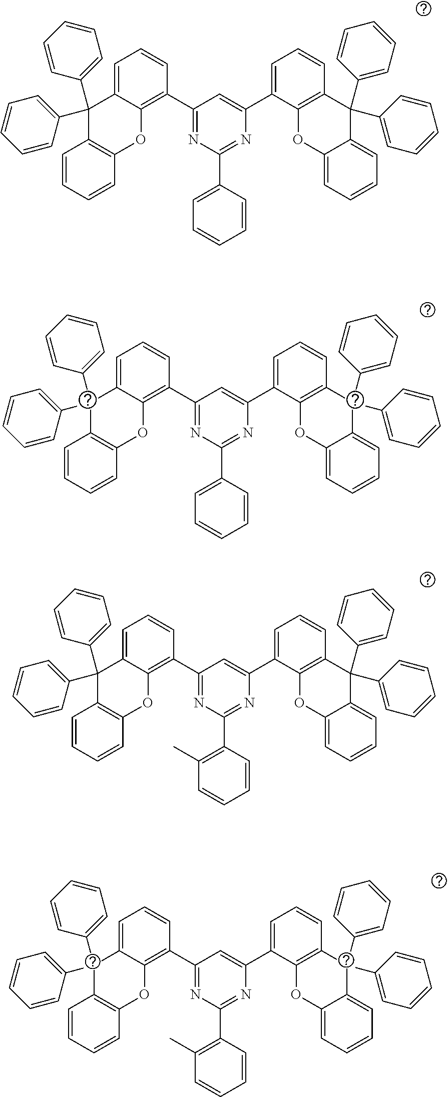 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1]

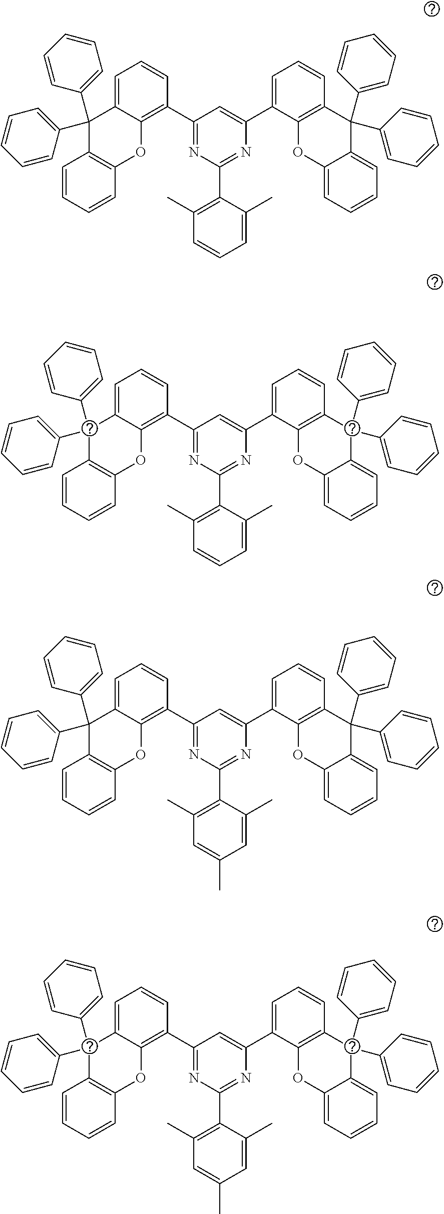 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1]

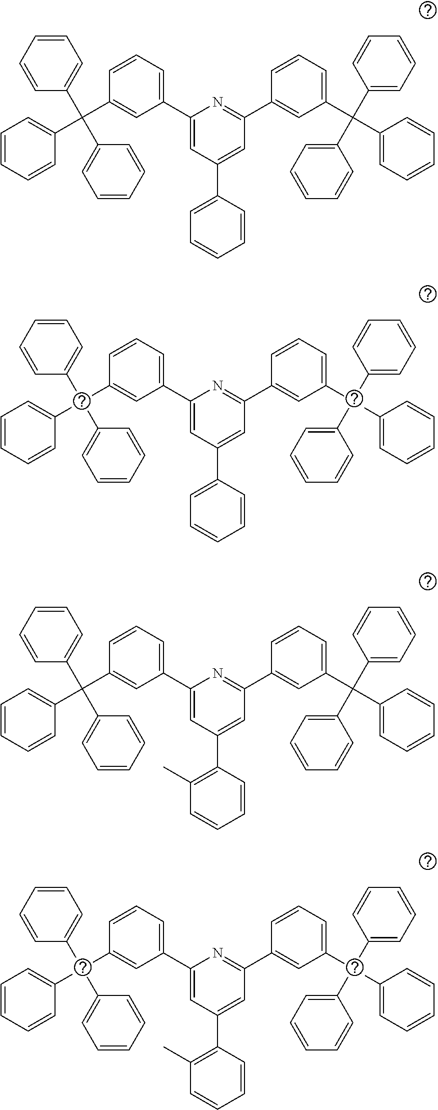 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1]

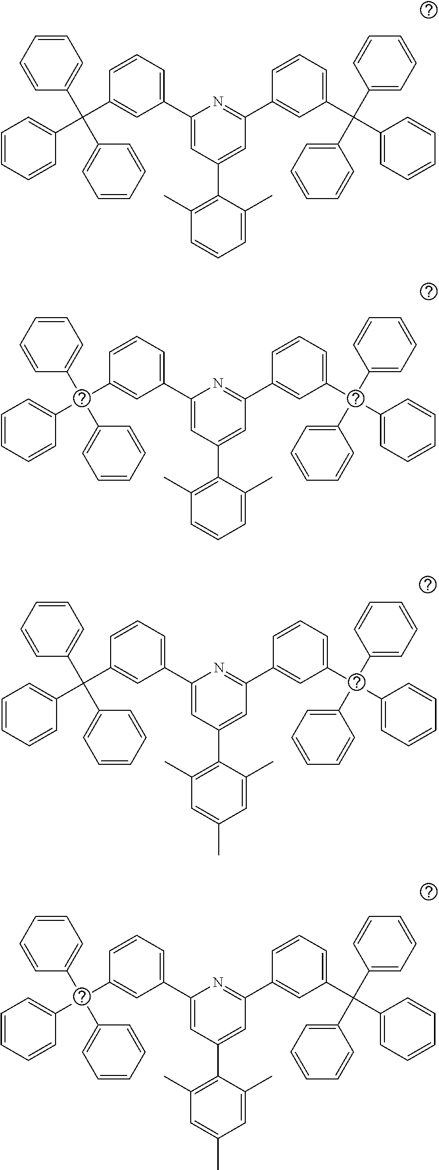 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1]

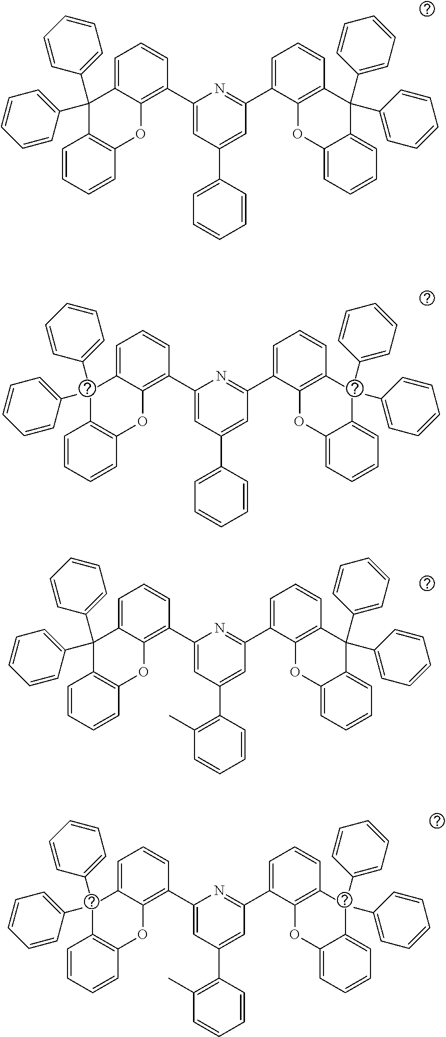 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1]

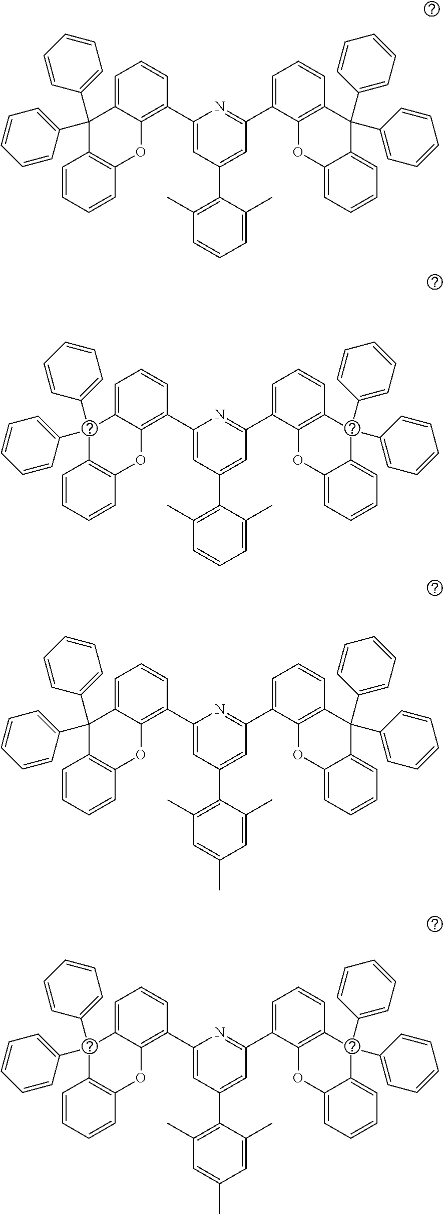 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1]

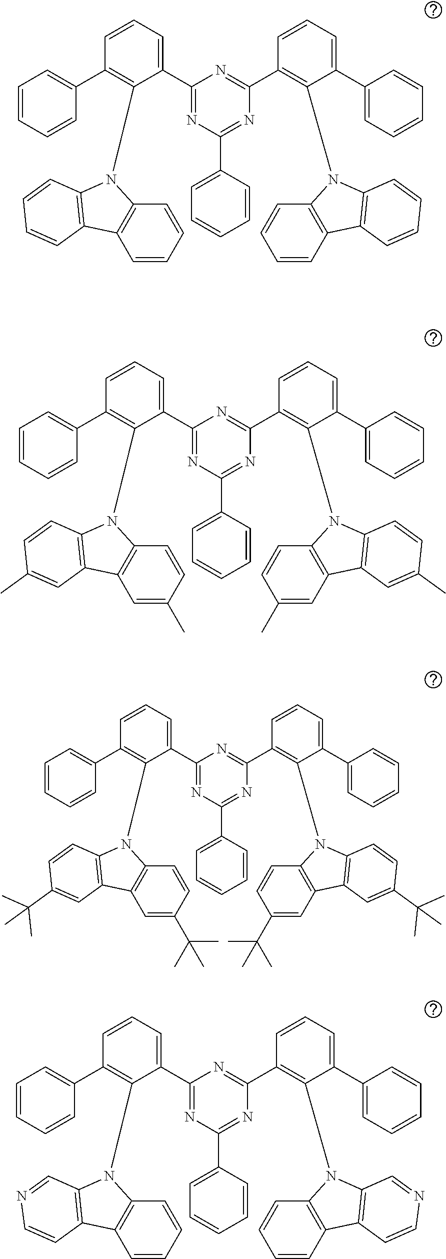

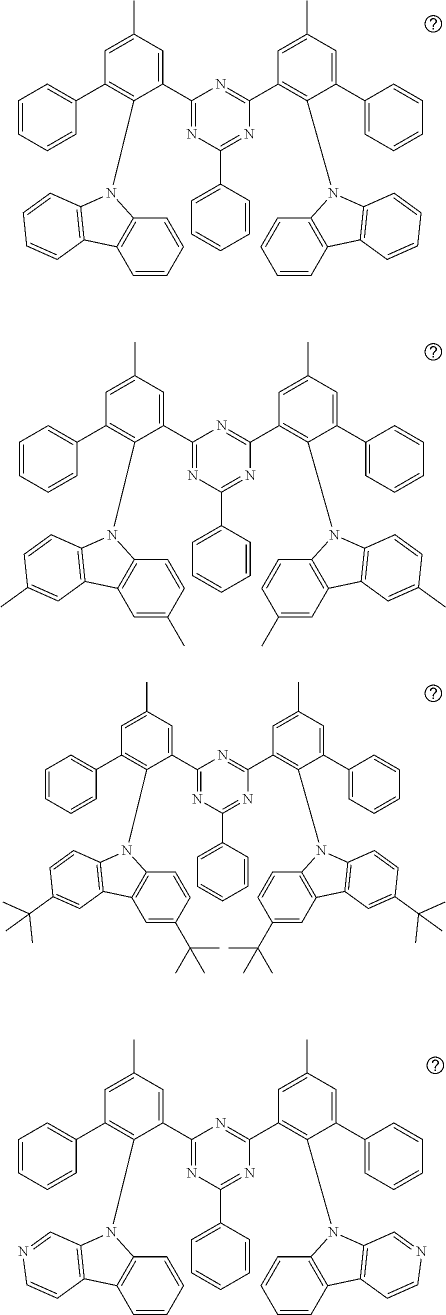

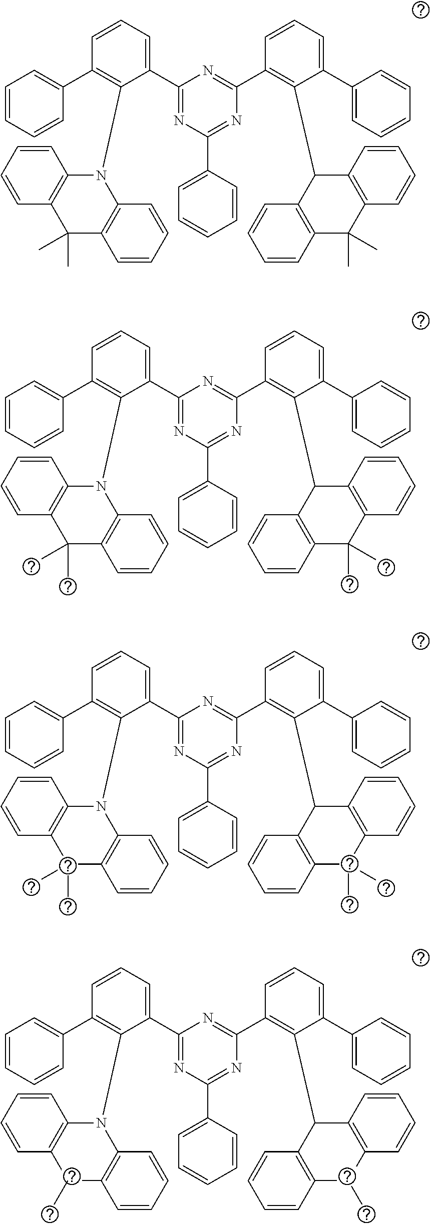 [SMILES: CC1(C)c2ccccc2C(c2c(-c3ccccc3)cccc2-c2nc(-c3ccccc3)nc(-c3cccc(-c4ccccc4)c3N3c4ccccc4C(C)(C)c4ccccc43)n2)c2ccccc21 ; CC1(C)c2ccccc2C(c2c(-c3ccccc3)cccc2-c2nc(-c3ccccc3)nc(-c3cccc(-c4ccccc4)c3N3c4ccccc4C(C)(C)c4ccccc43)n2)c2ccccc21 ; CC1(C)c2ccccc2C(c2c(-c3ccccc3)cccc2-c2nc(-c3ccccc3)nc(-c3cccc(-c4ccccc4)c3N3c4ccccc4C(C)(C)c4ccccc43)n2)c2ccccc21 ; CC1c2ccccc2C(c2c(-c3ccccc3)cccc2-c2nc(-c3ccccc3)nc(-c3cccc(-c4ccccc4)c3N3c4ccccc4C(C)c4ccccc43)n2)c2ccccc21]

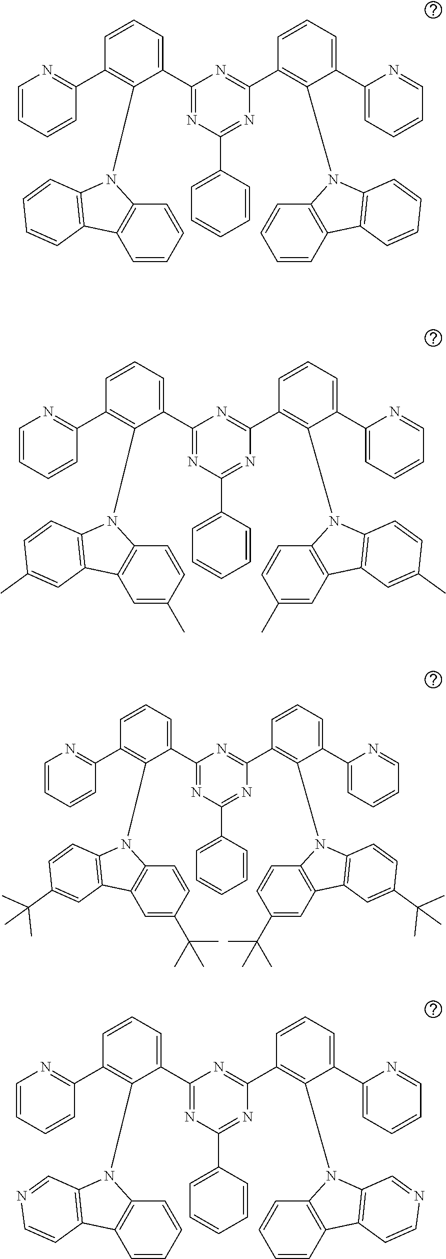

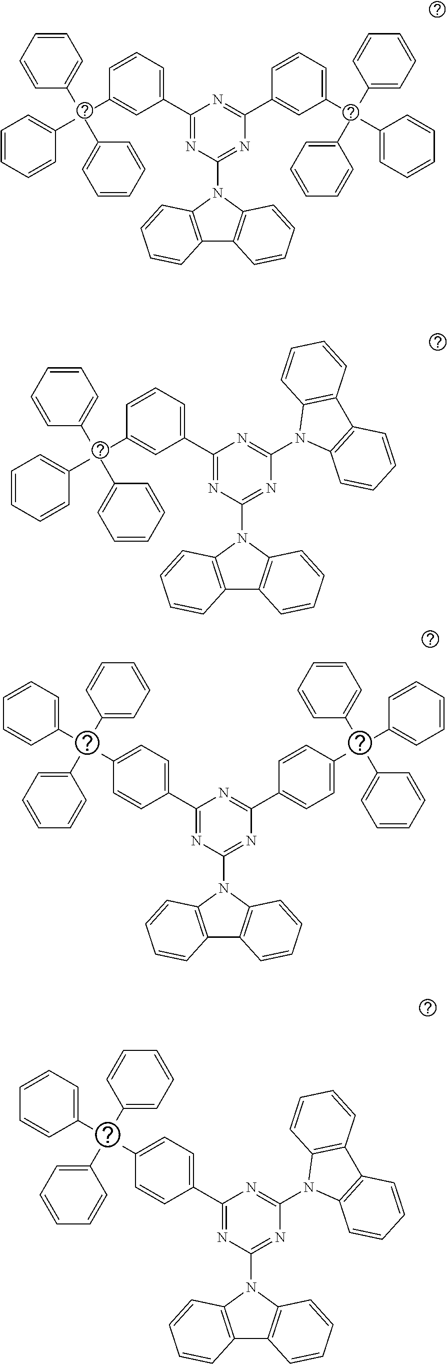 [SMILES: c1ccc(C(c2ccccc2)(c2ccccc2)c2cccc(-c3nc(-c4cccc(C(c5ccccc5)(c5ccccc5)c5ccccc5)c4)nc(-n4c5ccccc5c5ccccc54)n3)c2)cc1 ; c1ccc(C(c2ccccc2)(c2ccccc2)c2cccc(-c3nc(-n4c5ccccc5c5ccccc54)nc(-n4c5ccccc5c5ccccc54)n3)c2)cc1 ; c1ccc(C(c2ccccc2)(c2ccccc2)c2ccc(-c3nc(-c4ccc(C(c5ccccc5)(c5ccccc5)c5ccccc5)cc4)nc(-n4c5ccccc5c5ccccc54)n3)cc2)cc1 ; c1ccc(C(c2ccccc2)(c2ccccc2)c2ccc(-c3nc(-n4c5ccccc5c5ccccc54)nc(-n4c5ccccc5c5ccccc54)n3)cc2)cc1]

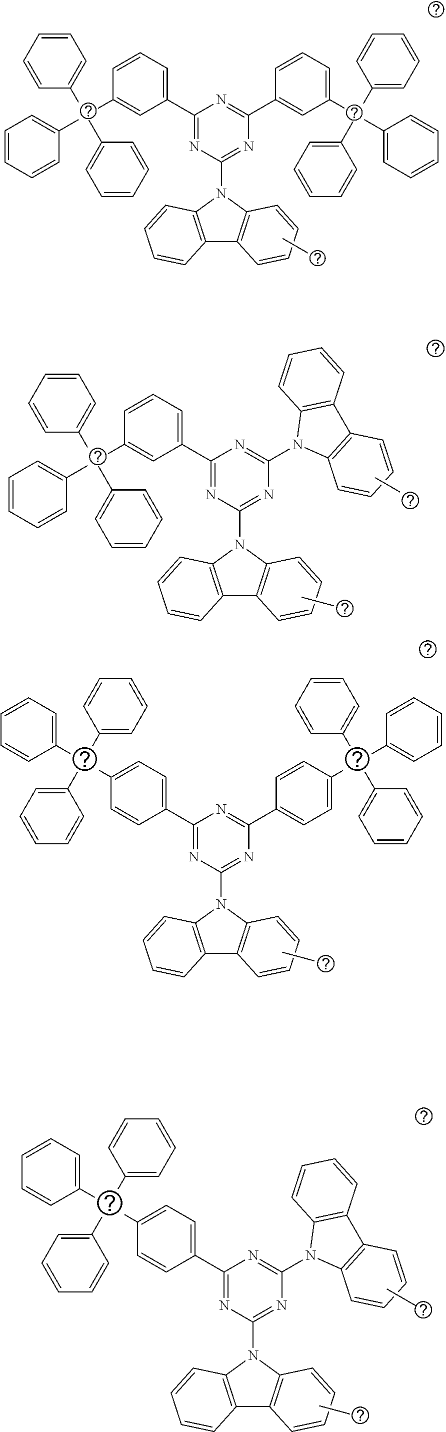

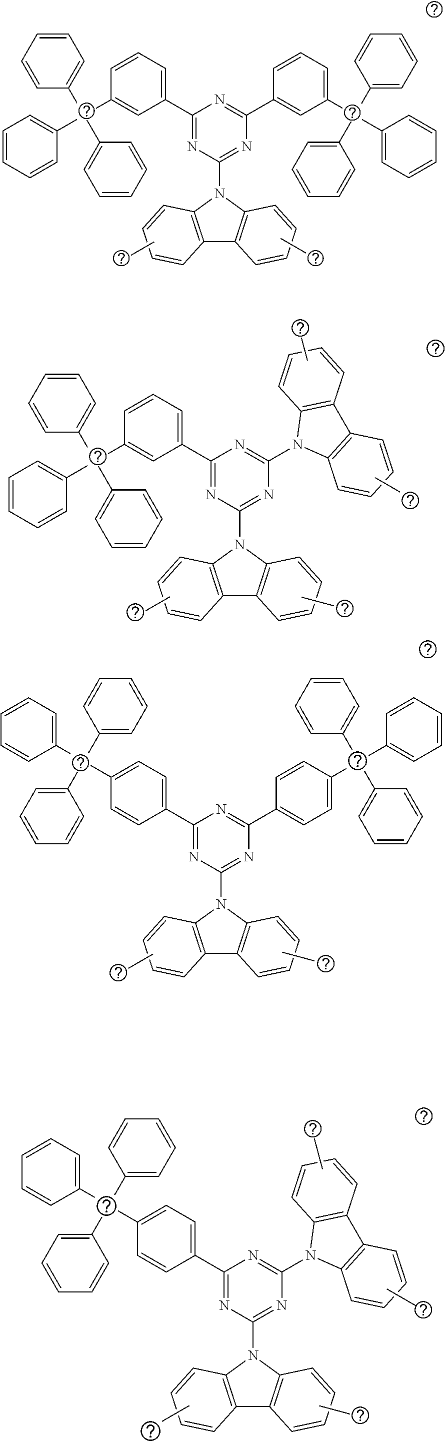

In an embodiment, the fourth compound represented by Formula PS may be any compound selected from Compound Group AD. The emission layer EML may include at least one compound selected from Compound Group AD as a sensitizer material.

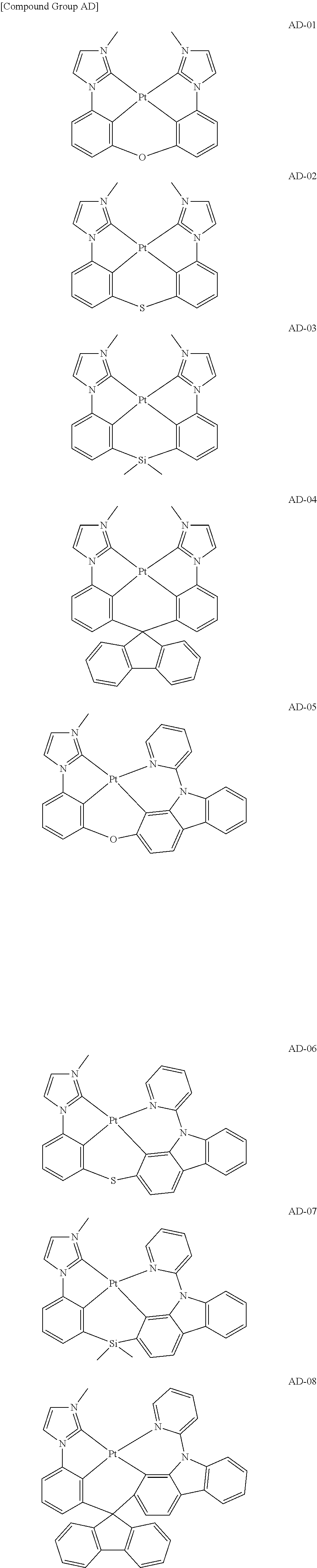

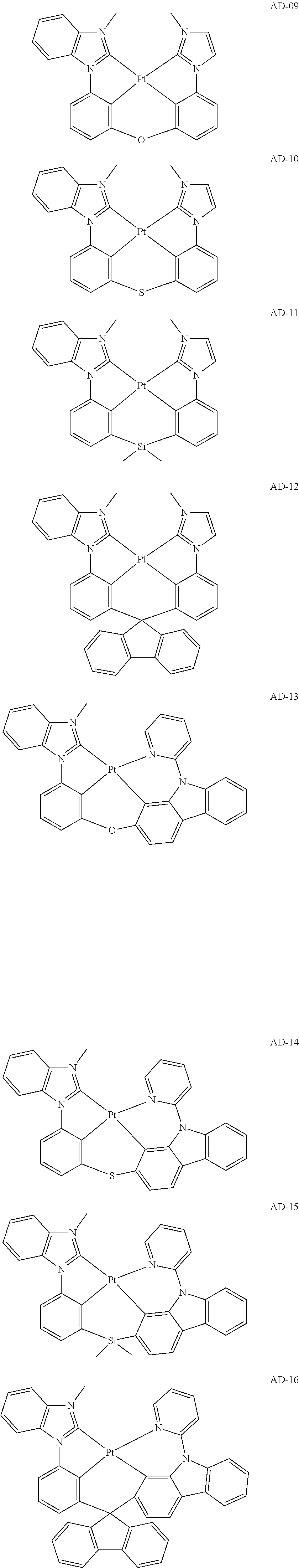

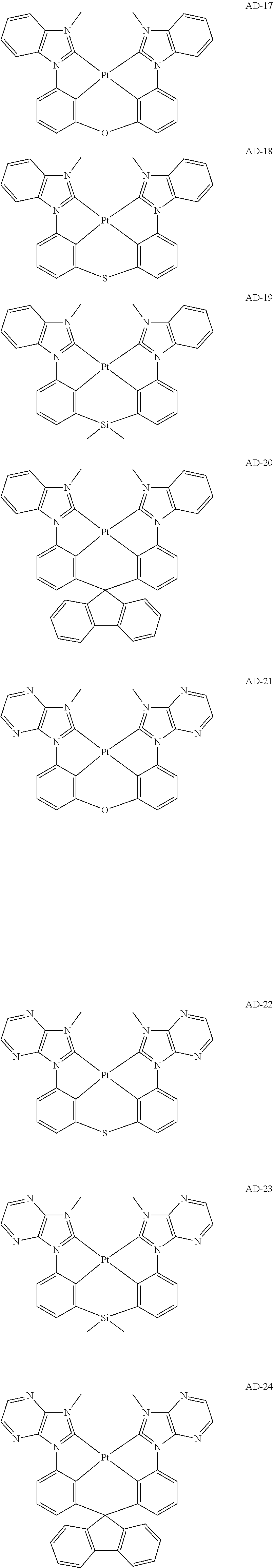

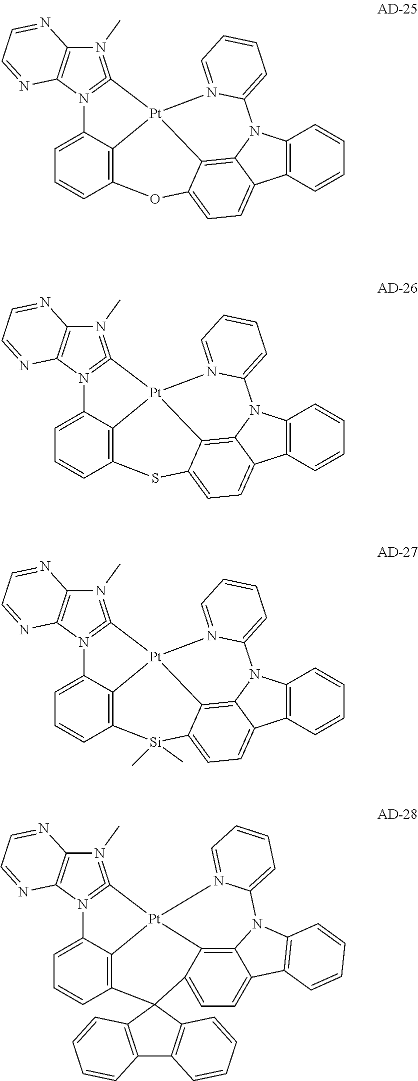

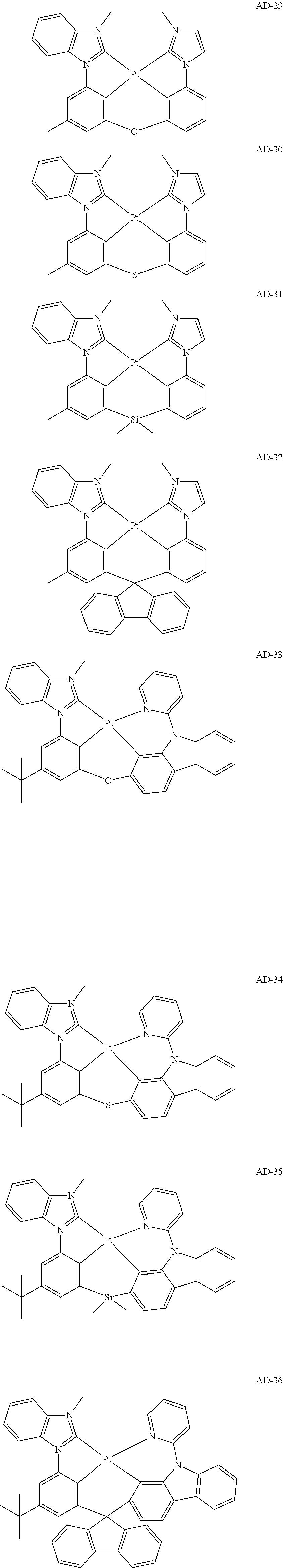

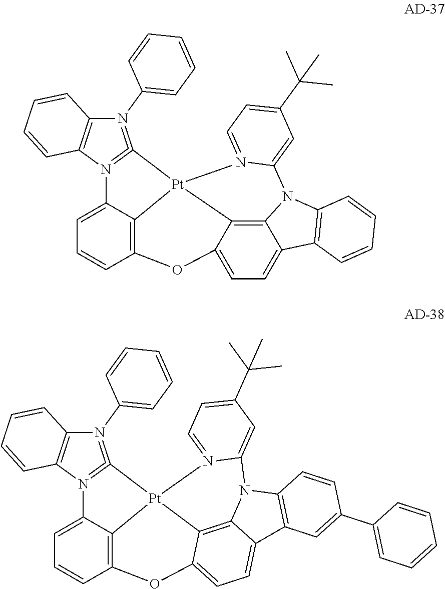

Although not shown in FIGS. 1 to 6, the light emitting device ED may include multiple emission layers. The emission layers may be stacked and provided. For example, the light emitting device ED including multiple emission layers may emit white light. The light emitting device including multiple emission layers may be a light emitting device having a tandem structure. When the light emitting device ED includes multiple emission layers, at least one emission layer EML may include the first compound, the second compound, the third compound, and the fourth compound as described above.

In the light emitting device ED according to an embodiment, the emission layer EML may further include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting device ED according to embodiments illustrated in each of FIGS. 3 to 6, the emission layer EML may further include a host and a dopant of the related art, in addition to the above-described host and dopant, and the emission layer EML may include a compound represented by Formula E-1. The compound represented by Formula E-1 may be used as a fluorescent host material.

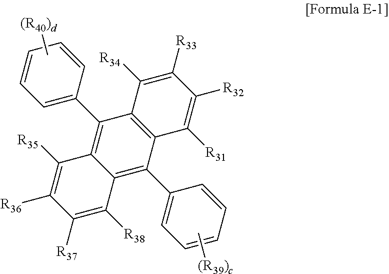

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, in Formula E-1, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

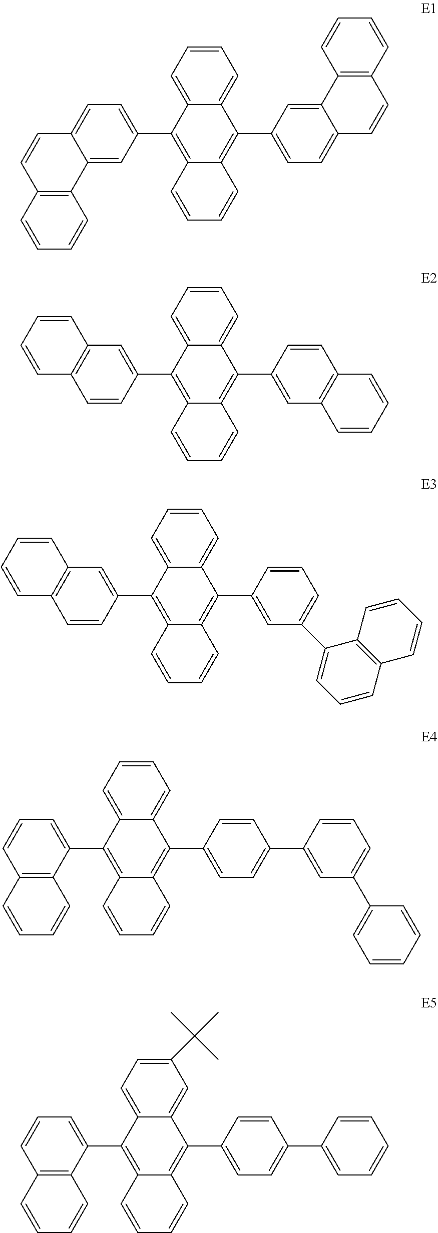

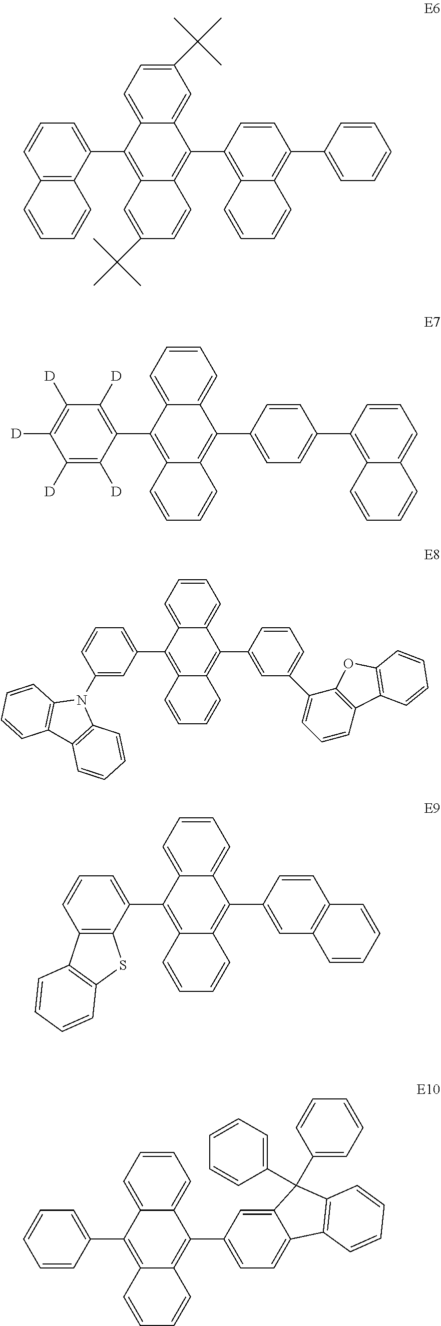

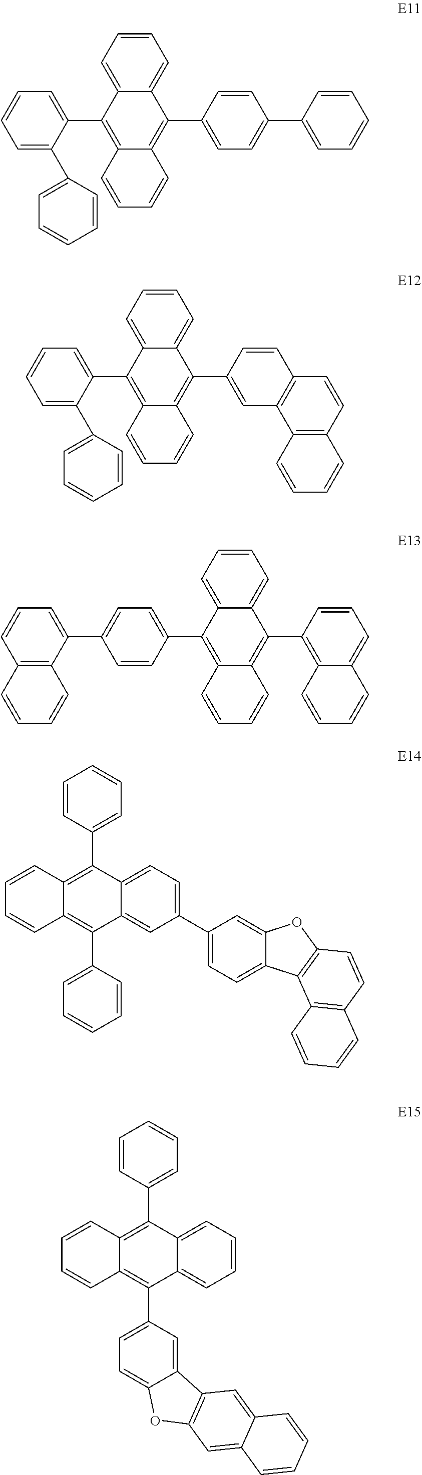

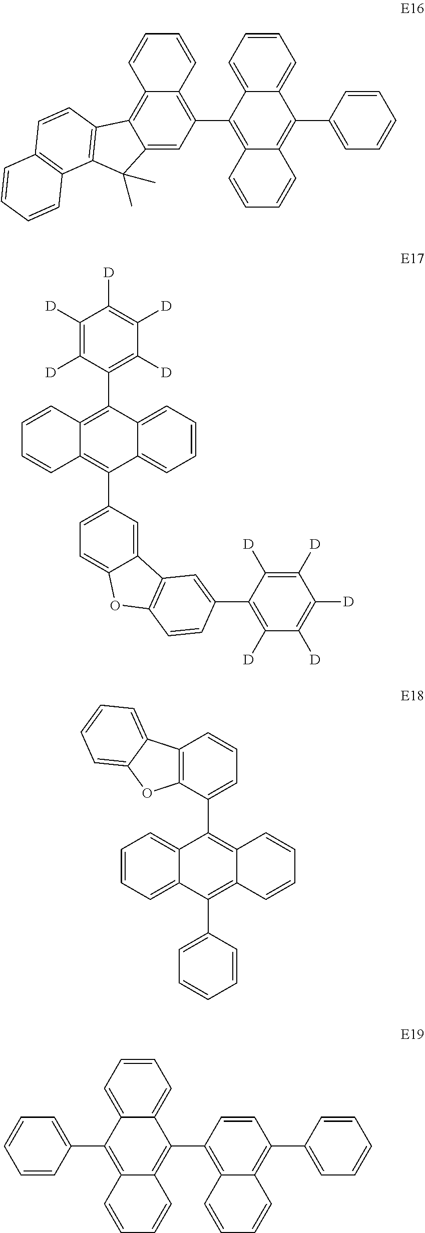

In an embodiment, the emission layer EML may include a compound represented by Formula E-2a or Formula E-2b. The compound represented by Formula E-2a or Formula E-2b may be used as a phosphorescent host material.

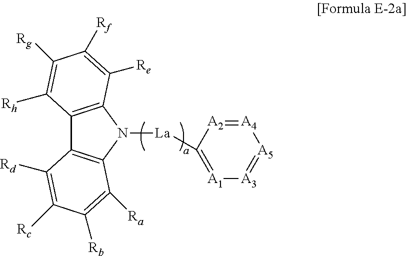

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms.

When a is 2 or more, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

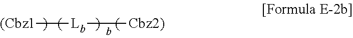

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

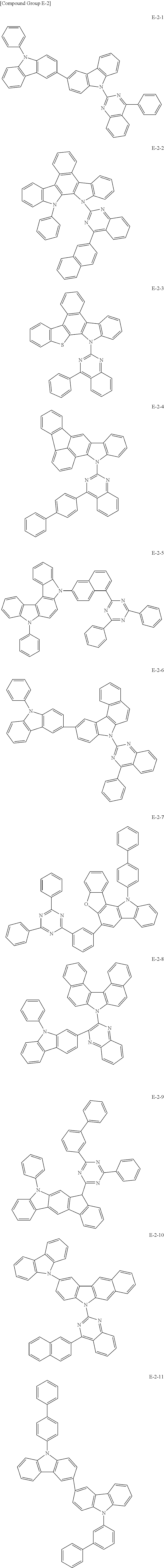

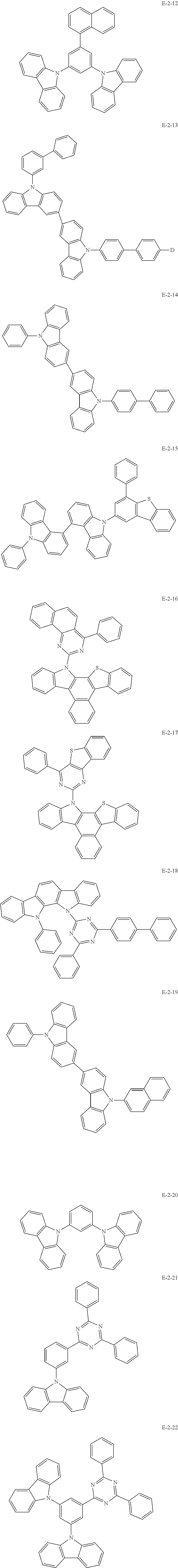

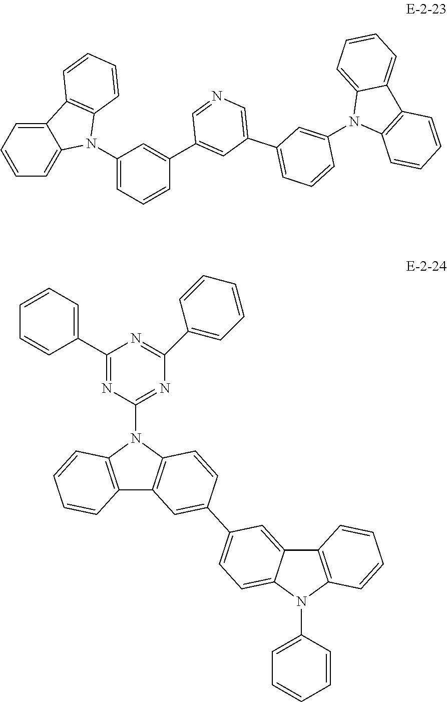 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include a compound represented by Formula M-a. The compound represented by Formula M-a may be used as a phosphorescent dopant material.

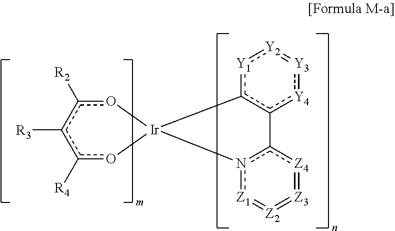

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

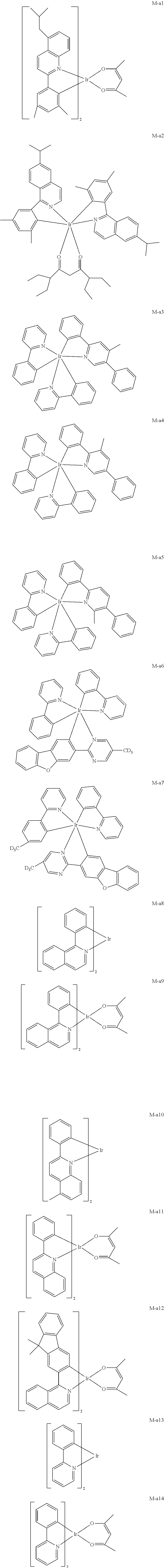

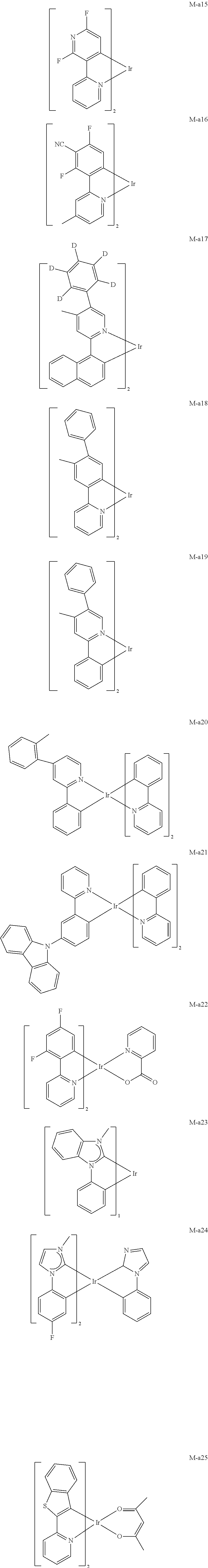

The emission layer EML may include a compound represented by any one of Formula F-a to Formula F-c. The compound represented by one of Formula F-a to Formula F-c may be used as a fluorescence dopant material.

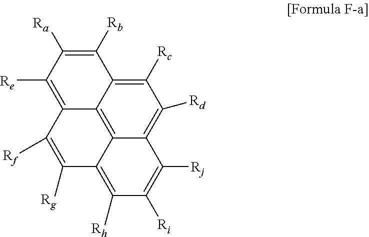

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂, may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

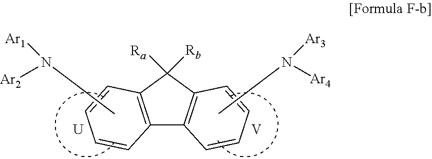

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

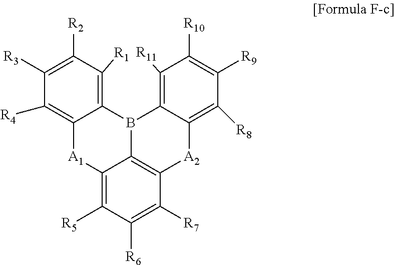

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-c, A₁ and A₂ may each independently be bonded to substituents of an adjacent ring to form a condensed ring. For example, when A₁ and A₂ are each independently N(Rₘ), A₁ may be bonded to R₄ or R₅ to form a ring. For example, A₂ may be bonded to R₇ or R₈ to form a ring.

In an embodiment, the emission layer EML may include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may include a phosphorescent dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, an emission layer EML may include a quantum dot. The quantum dot may be a Group II-VI compound, a Group III-VI compound, a Group I-III-IV compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and any mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any mixture thereof; or any combination thereof.

The Group III-VI compound may include: a binary compound such as In₂S₃ or In₂Se₃; a ternary compound such as InGaS₃ or InGaSe₃; or any combination thereof.

The Group 1-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and any mixture thereof; a quaternary compound such as AgInGaS₂ or CuInGaS₂; or any combination thereof.

The Group III-V compound may include: a binary compound selected from the group consisting of GaN, GaP, GaAs, GaSb, AlN, AlP, AlAs, AlSb, InN, InP, InAs, InSb, and any mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof; or any combination thereof. In an embodiment, the Group III-V compound may further include a Group II metal. For example, InZnP, etc., may be selected as a Group III-II-V compound.

The Group IV-VI compound may include: a binary compound selected from the group consisting of SnS, SnSe, SnTe, PbS, PbSe, PbTe, and any mixture thereof; a ternary compound selected from the group consisting of SnSeS, SnSeTe, SnSTe, PbSeS, PbSeTe, PbSTe, SnPbS, SnPbSe, SnPbTe, and any mixture thereof; a quaternary compound selected from the group consisting of SnPbSSe, SnPbSeTe, SnPbSTe, and any mixture thereof; or any combination thereof. The Group IV element may be Si, Ge, or any mixture thereof. The Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which one quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent the chemical deformation of the core to maintain semiconductor properties, and/or may serve as a charging layer to impart electrophoretic properties to the quantum dot. The shell may be a single layer or a multilayer.

Examples of the shell of the quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in the above ranges. Light emitted through a quantum dot may be emitted in all directions, so that a wide viewing angle may be improved.

The form of a quantum dot may be any form that is used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoparticles, etc.

The quantum dot may control the color of emitted light according to a particle size thereof. Accordingly, the quantum dot may have various light emission colors such as blue, red, and green.

In the light emitting device ED according to an embodiment illustrated in each of FIGS. 3 to 6, the electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure including multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure including different materials, or may have a structure in which an electron transport layer ETL/electron injection layer EIL, or a hole blocking layer HBL/electron transport layer ETL/electron injection layer EIL are stacked in its respective stated order from an emission layer EML, but embodiments are not limited thereto. The electron transport region ETR may have a thickness, for example, in a range of about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

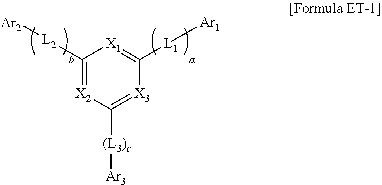

In Formula ET-1, at least one of X₁ to X₃ may each be N; and the remainder of X₁ to X₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each independently 2 or more, multiple groups of each of L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N 1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-Bis[3,5-di(pyridin-3-yl)phenyl]benzene (BmPyPhB), or any mixture thereof.

In an embodiment, the electron transport region ETR may include at least one compound selected from Compound ET1 to Compound ET36:

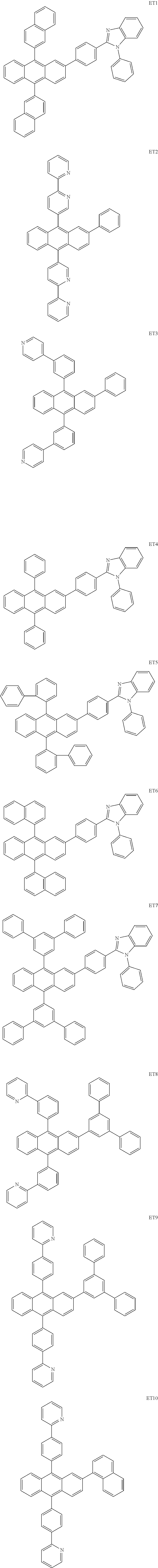

[chemical structure]

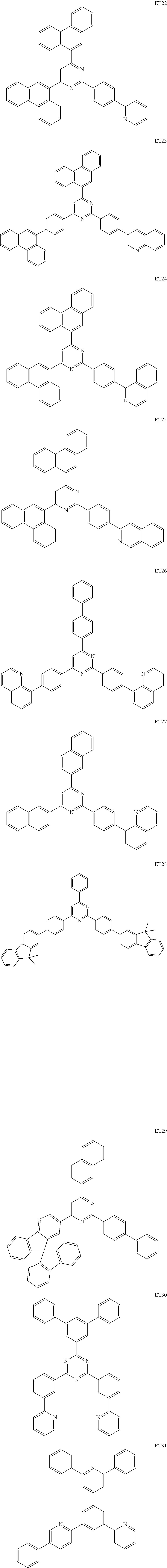

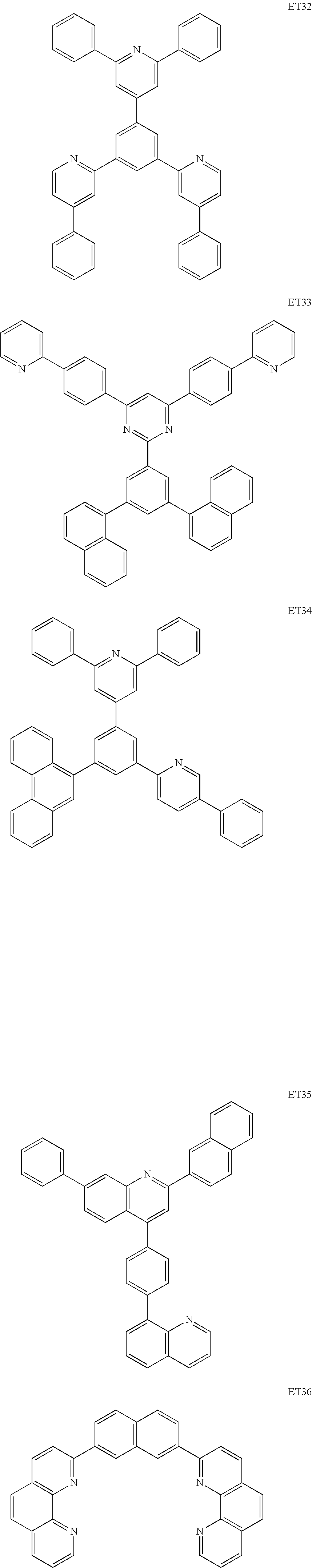 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

The electron transport regions ETR may include: a metal halide such as LiF, NaCl, CsF, RbCl, RbI, CuI, or KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may be formed of a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto.

The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In another embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting device ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or an epoxy resin, or an acrylate such as methacrylate.

However, embodiments are not limited thereto. In an embodiment, the capping layer CPL may include at least one of Compounds P1 to P5:

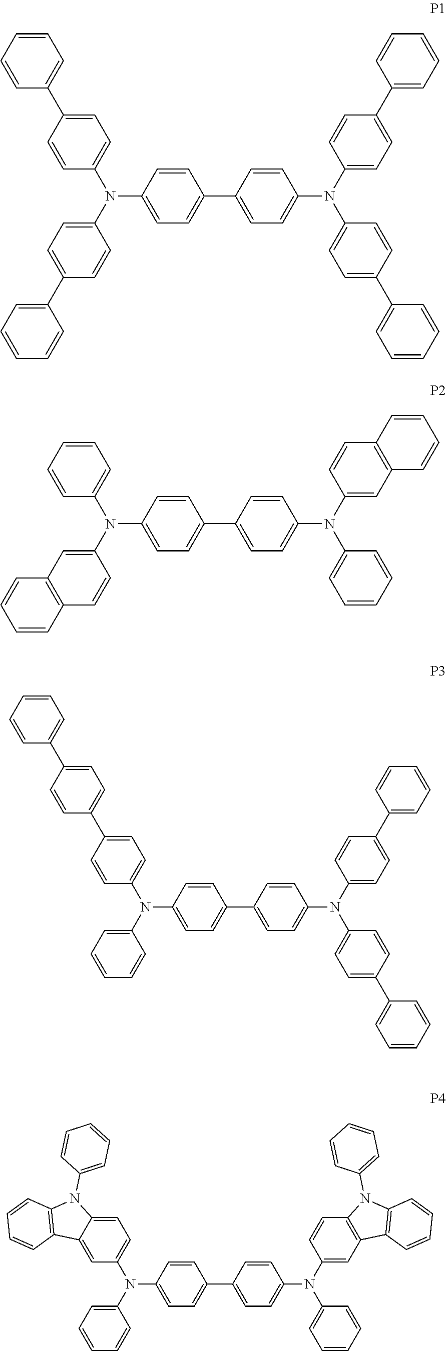 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

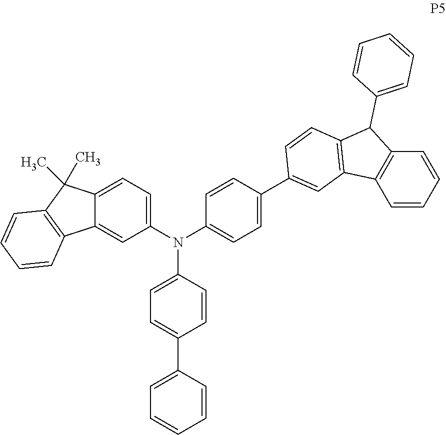 [SMILES: CC1(C)c2ccccc2-c2cc(N(c3ccc(-c4ccccc4)cc3)c3ccc(-c4ccc5c(c4)-c4ccccc4C5c4ccccc4)cc3)ccc21]

A refractive index of the capping layer CPL may be equal to or greater than about 1.6. For example, a refractive index of the capping layer CPL may be equal to or greater than about 1.6 with respect to light in a wavelength range of about 550 nm to about 660 nm.

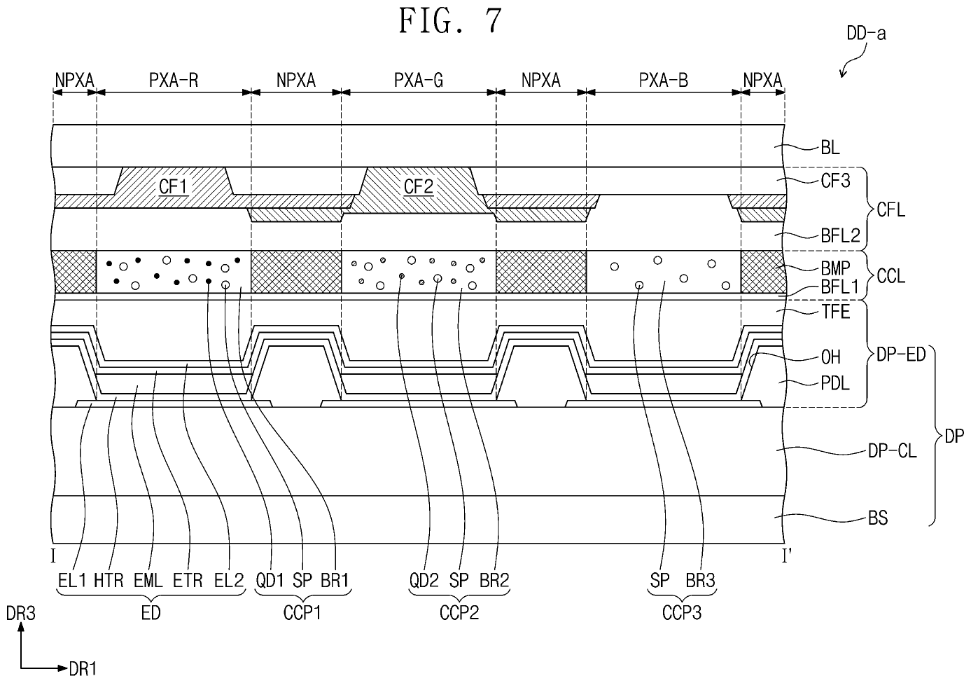

FIG. 7 to FIG. 10 are each a schematic cross-sectional view of a display apparatus according to an embodiment. In the explanation on the display apparatuses according to embodiments with reference to FIGS. 7 to 10, the features which have been described above with respect to FIGS. 1 to 6 will not be explained again, and the differing features will be described.

Referring to FIG. 7, a display apparatus DD-a according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting device according to one of FIGS. 3 to 6 as described herein.

In the display apparatus DD-a, the emission layer EML of the light emitting device ED may include the polycyclic compound as described herein.

Referring to FIG. 7, the emission layer EML may be disposed in an opening OH defined in a pixel defining film PDL. For example, the emission layer EML, which is separated by the pixel defining film PDL and provided corresponding to each of the light emitting regions PXA-R, PXA-G, and PXA-B, may each emit light in a same wavelength range. In the display apparatus DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. In FIG. 7, it is shown that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 including a first quantum dot QD1 that converts first color light provided from the light emitting device ED into second color light, a second light control part CCP2 including a second quantum dot QD2 that converts the first color light into third color light, and a third light control part CCP3 that transmits the first color light.

In an embodiment, the first light control part CCP1 may provide red light, which may be the second color light, and the second light control part CCP2 may provide green light, which may be the third color light. The third light control part CCP3 may provide blue light by transmitting a blue light which may be the first color light provided from the light emitting device ED. For example, the first quantum dot QD1 may be a red quantum dot, and the second quantum dot QD2 may be a green quantum dot. The quantum dots QD1 and QD2 may each be the same as a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, and hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and filters CF1, CF2, and CF3, which will be explained below.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film which secures a transmittance, etc. The barrier layers BFL1 and BFL2 may each independently further include an organic film. The barrier layers BFL1 and BFL2 may each independently be formed of a single layer or of multiple layers.

In the display apparatus DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a light shielding part (not shown) and filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter. The first to third filters CF1, CF2, and CF3 may be disposed to respectively correspond to the red light emitting region PXA-R, the green light emitting region PXA-G, and the blue light emitting region PXA-B.

Although not shown in the drawings, the color filter layer CFL may include a light shielding part (not shown). The color filter layer CFL may include a light shielding part (not shown) that is disposed to overlap the boundaries between neighboring filters CF1, CF2, and CF3. The light shielding part (not shown) may be a black matrix. The light shielding part (not shown) may include an organic light shielding material or an inorganic light shielding material that includes a black pigment or a black dye. The light shielding part (not shown) may separate boundaries between adjacent filters CF1, CF2, and CF3. In an embodiment, the light shielding part (not shown) may be formed of a blue filter.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

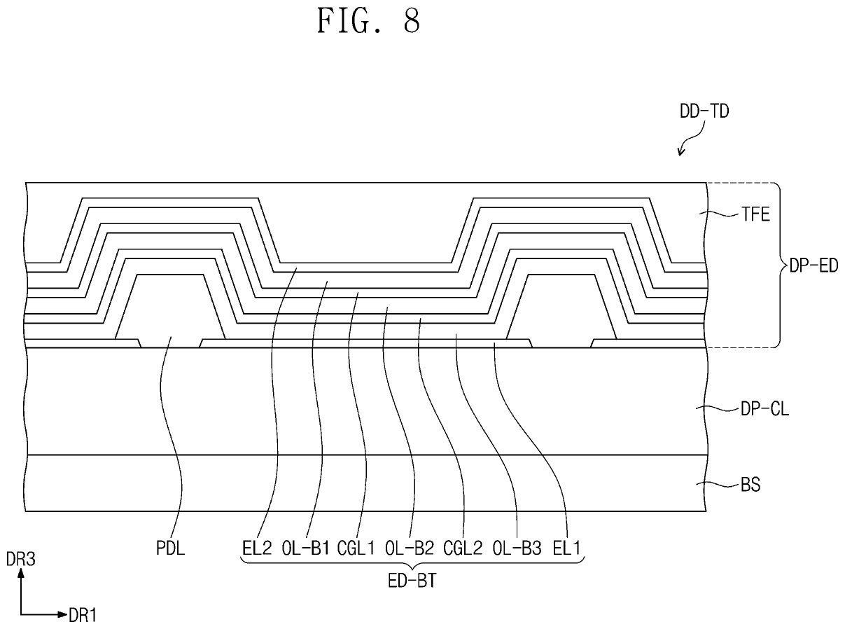

FIG. 8 is a schematic cross-sectional view illustrating a portion of a display apparatus DD-a according to an embodiment. FIG. 8 illustrates a schematic cross-sectional view of a portion corresponding to the display panel DP of FIG. 7. In the display apparatus DD-TD according to an embodiment, the light emitting device ED-BT may include light emitting structures OL-B1, OL-B2, and OL-B3. The light emitting device ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) therebetween.

For example, the light emitting device ED-BT included in the display apparatus DD-TD may be a light emitting device having a tandem structure and including multiple emission layers.

In an embodiment illustrated in FIG. 8, light respectively emitted from each of the light emitting structures OL-B1, OL-B2, and OL-B3 may all be blue light. However, embodiments are not limited thereto, and the light respectively emitted from the light emitting structures OL-B1, OL-B2, and OL-B3 may have wavelength ranges that are different from each other. For example, the light emitting device ED-BT, which includes the light emitting structures OL-B1, OL-B2, and OL-B3 that emit light having different wavelength ranges from each other, may emit white light.

Charge generation layers CGL1 and CGL2 may be disposed between neighboring light emitting structures OL-B1, OL-B2, and OL-B3. Charge generation layers CGL1 and CGL2 may each independently include a p-type charge generation layer and/or an n-type charge generation layer.

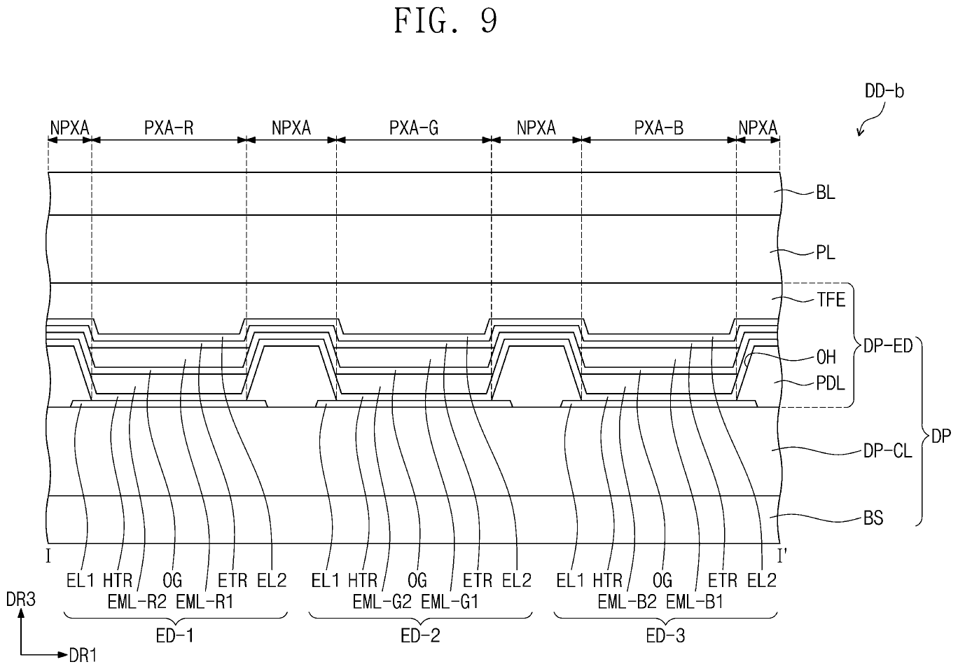

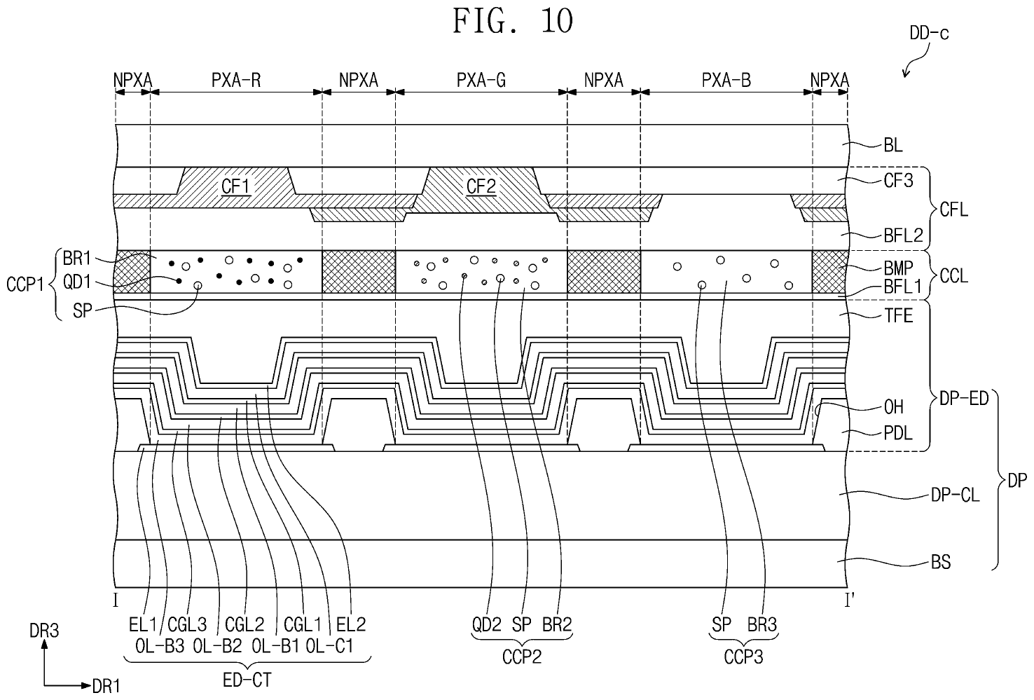

Referring to FIG. 9, a display apparatus DD-b according to an embodiment may include light emitting devices ED-1, ED-2, and ED-3, which may each include two emission layers that are stacked. In comparison to the display apparatus DD illustrated in FIG. 2, the embodiment illustrated in FIG. 9 is different at least in that the first to third light emitting devices ED-1, ED-2, and ED-3 each include two emission layers that are stacked in a thickness direction. In each of the first to third light emitting devices ED-1, ED-2, and ED-3, the two emission layers may emit light in a same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. The third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region, which are stacked in that order. The emission auxiliary part OG may be provided as a common layer for all of the first to third light emitting devices ED-1, ED-2, and ED-3.

However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

The first light emitting device ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2, which are stacked in that order.

An optical auxiliary layer PL may be disposed on the display device layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display apparatus DD-b.

At least one emission layer included in the display apparatus DD-b illustrated in FIG. 9 may include the polycyclic compound as described herein. For example, in an embodiment, at least one of the first blue emission layer EML-B1 or the second blue emission layer EML-B2 may include the polycyclic compound according to an embodiment.

In contrast to FIGS. 8 and 9, FIG. 10 illustrates a display apparatus DD-c that is different at least in that it includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2.

Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength regions from each other.

The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

In the display apparatus DD-c, at least one of the light emitting structures OL-B1, OL-B2, OL-B3, and OL-C1 may include the polycyclic compound as described herein. For example, in an embodiment, at least one of the first to third light emitting structures OL-B1, OL-B2, and OL-B3 may include the polycyclic compound as described herein.

The light emitting device ED according to an embodiment may include the polycyclic compound in at least one functional layer disposed between the first electrode EL1 and the second electrode EL2, thereby exhibiting excellent luminous efficiency and improved service life characteristics. For example, the polycyclic compound according to an embodiment may be included in the emission layer EML of the light emitting device ED, and the light emitting device ED may exhibit high efficiency and long service life characteristics.

Hereinafter, a polycyclic compound according to an embodiment and a light emitting device according to an embodiment will be described in detail with reference to the Examples and the Comparative Examples. The Examples described below are only provided as illustrations to assist in understanding the disclosure, and the scope thereof is not limited thereto.

### EXAMPLES

1. Synthesis of Polycyclic Compound

A synthesis method of a polycyclic compound according to an embodiment will be described in detail by illustrating a synthesis method for Compounds 12, 42, 58, 61, 91, and 93.

The synthesis methods of the polycyclic compounds are provided as examples, but synthesis methods according to embodiments are not limited to the Examples below.

(1) Synthesis of Compound 12

Compound 12 according to an example may be synthesized by, for example, Reaction Scheme 1:

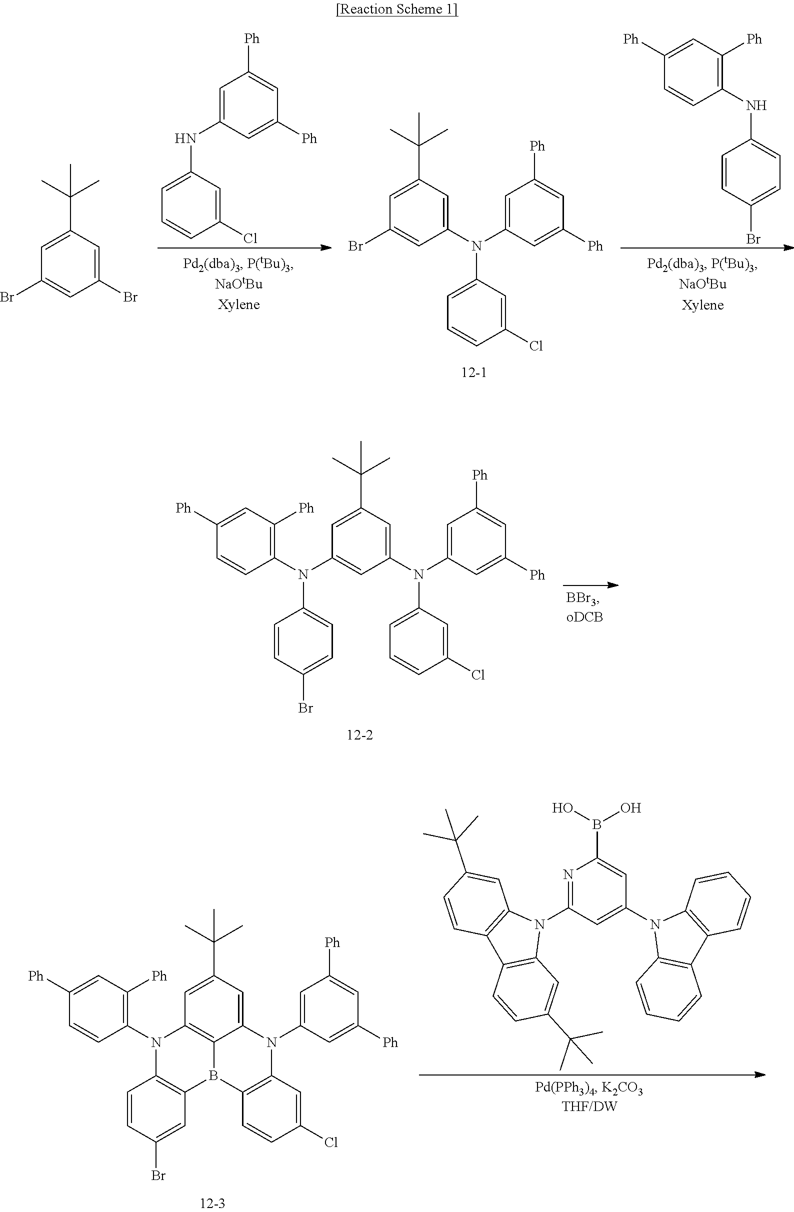

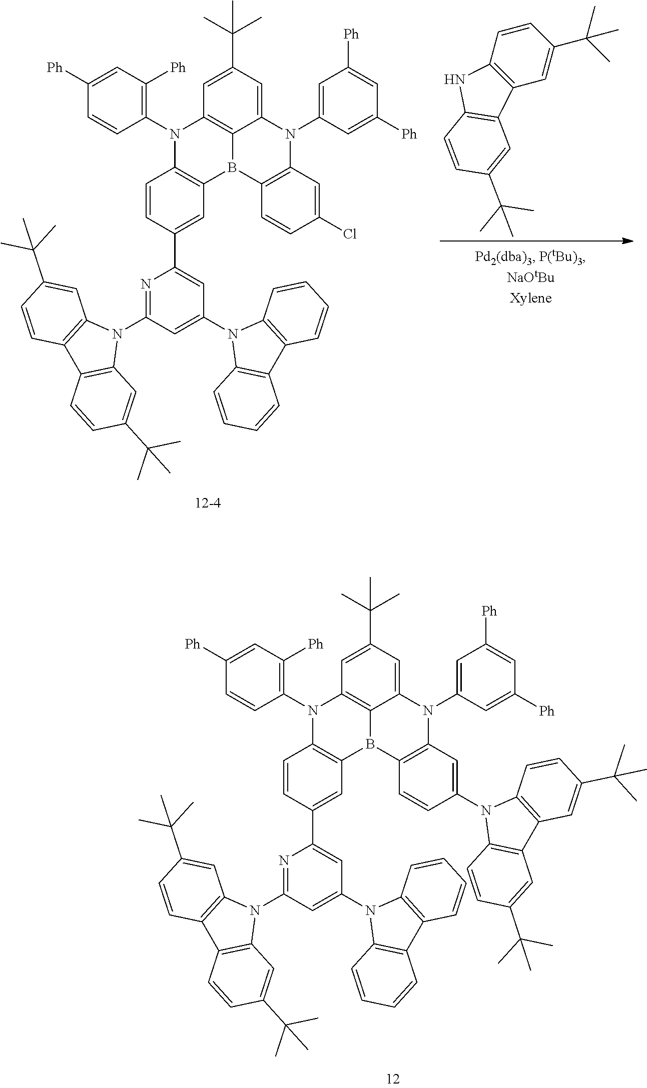

1) Synthesis of Intermediate 12-1

1,3-dibromo-5-(tert-butyl)benzene (1 eq), N-(3-chlorophenyl)-[1,1′:3′,1″-terphenyl]-5′-amine (1 eq), tris(dibenzylideneacetone)dipalladium(0) (0.05 eq), tri-tert-butylphosphine (0.10 eq), and sodium tert-butoxide (1.5 eq) were dissolved in xylene, and the resultant mixture was stirred in a nitrogen atmosphere at about 90° C. for about 24 hours. After cooling, the resultant mixture was dried under reduced pressure and the xylene was removed. The resulting product was washed three times with ethyl acetate and water to obtain organic layers.

The obtained organic layers were dried over MgSO₄, and dried under reduced pressure. The resulting product was purified and recrystallized by column chromatography (dichloromethane:n-hexane) to obtain Intermediate 12-1 (yield: 58%).

2) Synthesis of Intermediate 12-2

Intermediate 12-1 (1 eq), N-(4-bromophenyl)-[1,1′:3′,1″-terphenyl]-4′-amine (1 eq), tris(dibenzylideneacetone)dipalladium(0) (0.05 eq), tri-tert-butylphosphine (0.10 eq), and sodium tert-butoxide (1.5 eq) were dissolved in xylene, and the resultant mixture was stirred in a nitrogen atmosphere at about 90° C. for about 24 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 12-2 (yield: 61%).

3) Synthesis of Intermediate 12-3

Intermediate 12-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 12-3. Thereafter, Intermediate 12-3 was finally purified by column chromatography (dichloromethane:n-hexane) (yield: 9%).

4) Synthesis of Intermediate 12-4

Intermediate 12-3 (1 eq), (4-(9H-carbazol-9-yl)-6-(2,7-di-tert-butyl-9H-carbazol-9-yl)pyridin-2-yl)boronic acid (1.2 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Intermediate 12-4 (yield: 56%).

5) Synthesis of Compound 12

Intermediate 12-4 (1 eq), 3,6-di-tert-butyl-9H-carbazole (1.3 eq), tris(dibenzylideneacetone)dipalladium(0) (0.05 eq), tri-tert-butylphosphine (0.10 eq), and sodium tert-butoxide (3 eq) were dissolved in xylene, and the resultant mixture was stirred in a nitrogen atmosphere at about 140° C. for about 24 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 12 (yield: 67%). The resulting product was further purified by sublimation purification to obtain final purity. The obtained compound was identified as Compound 12 through ESI-LCMS (ESI-LCMS: [M]⁺: C₁₁₅H₁₀₁BN₆, 1576.82).

(2) Synthesis of Compound 42

Compound 42 according to an example may be synthesized by, for example, Reaction Scheme 2 below:

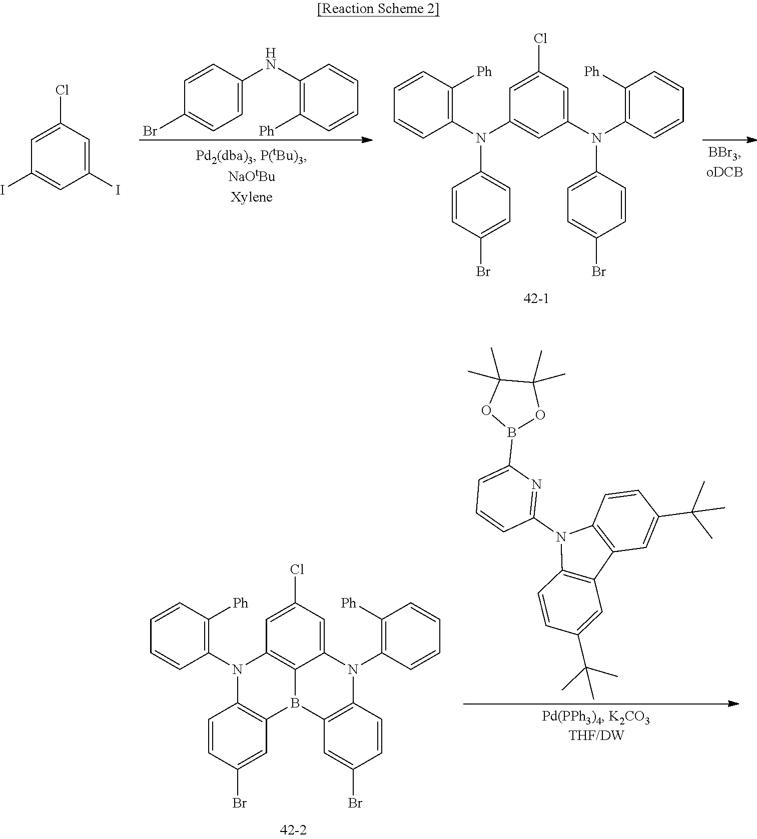

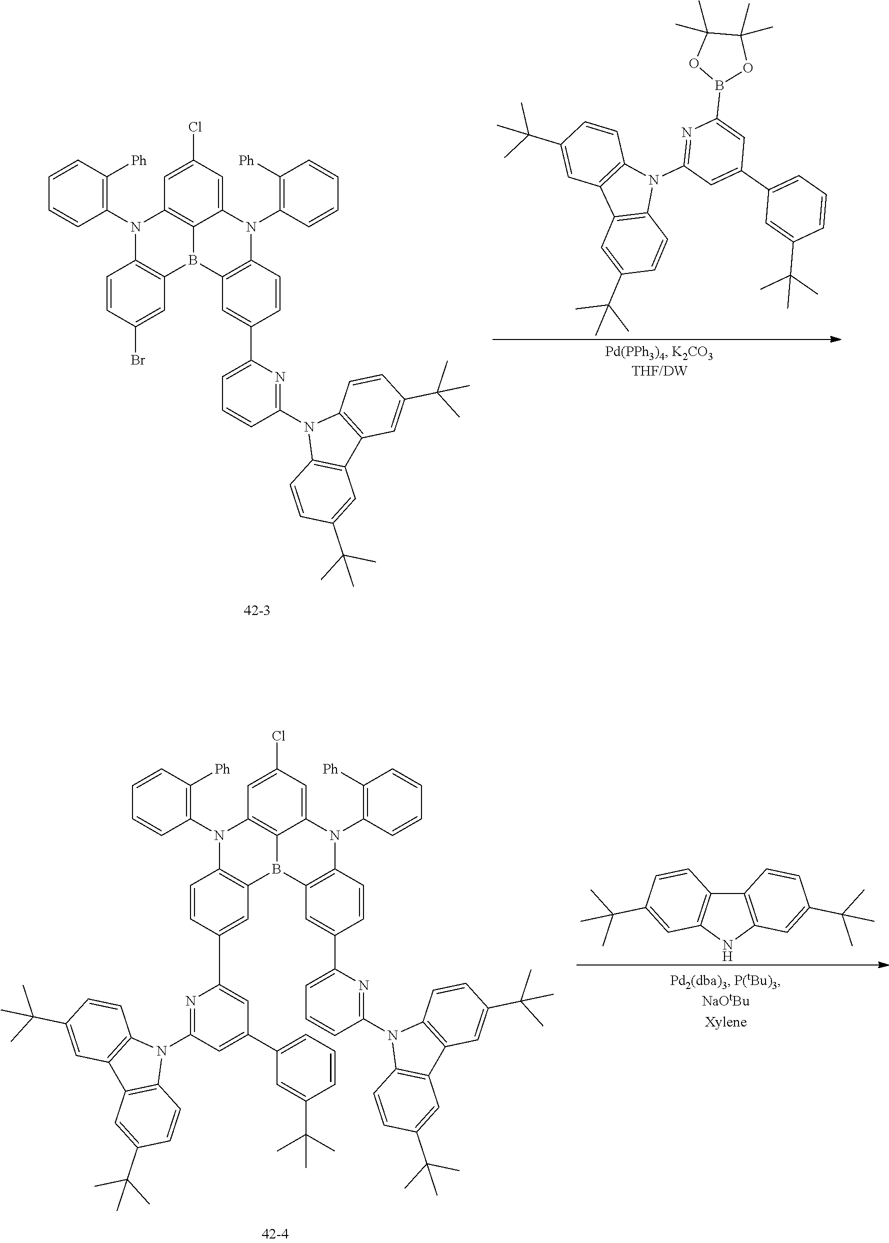 [SMILES: CC(C)(C)c1ccc2c(c1)c1cc(C(C)(C)C)ccc1n2-c1cccc(-c2ccc3c(c2)B2c4cc(Br)ccc4N(c4ccccc4-c4ccccc4)c4cc(Cl)cc(c42)N3c2ccccc2-c2ccccc2)n1 ; CC(C)(C)c1cccc(-c2cc(B3OC(C)(C)C(C)(C)O3)nc(-n3c4ccc(C(C)(C)C)cc4c4cc(C(C)(C)C)ccc43)c2)c1 ; CC(C)(C)c1cccc(-c2cc(-c3ccc4c(c3)B3c5cc(-c6cccc(-n7c8ccc(C(C)(C)C)cc8c8cc(C(C)(C)C)ccc87)n6)ccc5N(c5ccccc5-c5ccccc5)c5cc(Cl)cc(c53)N4c3ccccc3-c3ccccc3)nc(-n3c4ccc(C(C)(C)C)cc4c4cc(C(C)(C)C)ccc43)c2)c1 ; CC(C)(C)c1ccc2c(c1)[nH]c1cc(C(C)(C)C)ccc12]

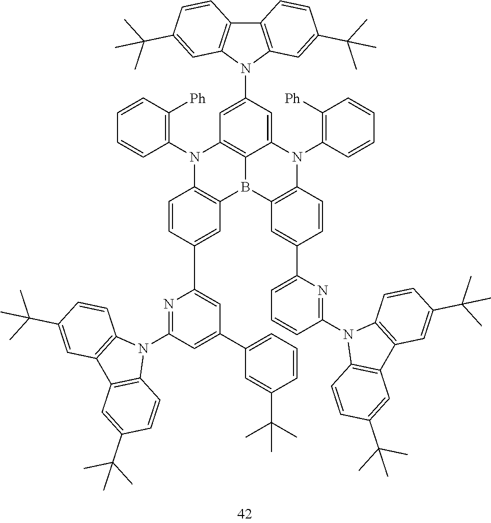 [SMILES: CC(C)(C)c1cccc(-c2cc(-c3ccc4c(c3)B3c5cc(-c6cccc(-n7c8ccc(C(C)(C)C)cc8c8cc(C(C)(C)C)ccc87)n6)ccc5N(c5ccccc5-c5ccccc5)c5cc(-n6c7cc(C(C)(C)C)ccc7c7ccc(C(C)(C)C)cc76)cc(c53)N4c3ccccc3-c3ccccc3)nc(-n3c4ccc(C(C)(C)C)cc4c4cc(C(C)(C)C)ccc43)c2)c1]

1) Synthesis of Intermediate 42-1

1-chloro-3,5-diiodobenzene (1 eq), N-(4-bromophenyl)-[1,1′-biphenyl]-2-amine (2 eq), tris(dibenzylideneacetone)dipalladium(0) (0.10 eq), tri-tert-butylphosphine (0.20 eq), and sodium tert-butoxide (3 eq) were dissolved in xylene, and the resultant mixture was stirred in a nitrogen atmosphere at about 100° C. for about 10 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 42-1 (yield: 53%).

2) Synthesis of Intermediate 42-2

Intermediate 42-1 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 42-2. Thereafter, Compound 34 was finally purified by column chromatography (dichloromethane:n-hexane) (yield: 8%).

3) Synthesis of Intermediate 42-3

Intermediate 42-2 (1 eq), 3,6-di-tert-butyl-9-(6-(4,4,5,5-tetramethyl-1,3,2-dioxaborolan-2-yl)pyridin-2-yl)-9H-carbazole (1 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Intermediate 42-3 (yield: 48%).

4) Synthesis of Intermediate 42-4

Intermediate 42-3 (1 eq), 3,6-di-tert-butyl-9-(4-(3-(tert-butyl)phenyl)-6-(4,4,5,5-tetramethyl-1,3,2-dioxaborolan-2-yl)pyridin-2-yl)-9H-carbazole (1 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Intermediate 42-4 (yield: 67%).

5) Synthesis of Compound 42

1-chloro-3,5-diiodobenzene (1 eq), N-(4-bromophenyl)-[1,1′-biphenyl]-2-amine (2 eq), tris(dibenzylideneacetone)dipalladium(0) (0.10 eq), tri-tert-butylphosphine (0.20 eq), and sodium tert-butoxide (3 eq) were dissolved in xylene, and the resultant mixture was stirred in a nitrogen atmosphere at about 150° C. for about 20 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 42 (yield: 53%). The resulting product was further purified by sublimation purification to obtain final purity. The obtained compound was identified as Compound 42 through ESI-LCMS (ESI-LCMS: [M]⁺: C₁₂₂H₁₁₆BN₇, 1689.94).

(3) Synthesis of Compound 58

Compound 58 according to an example may be synthesized by, for example, Reaction Scheme 3 below:

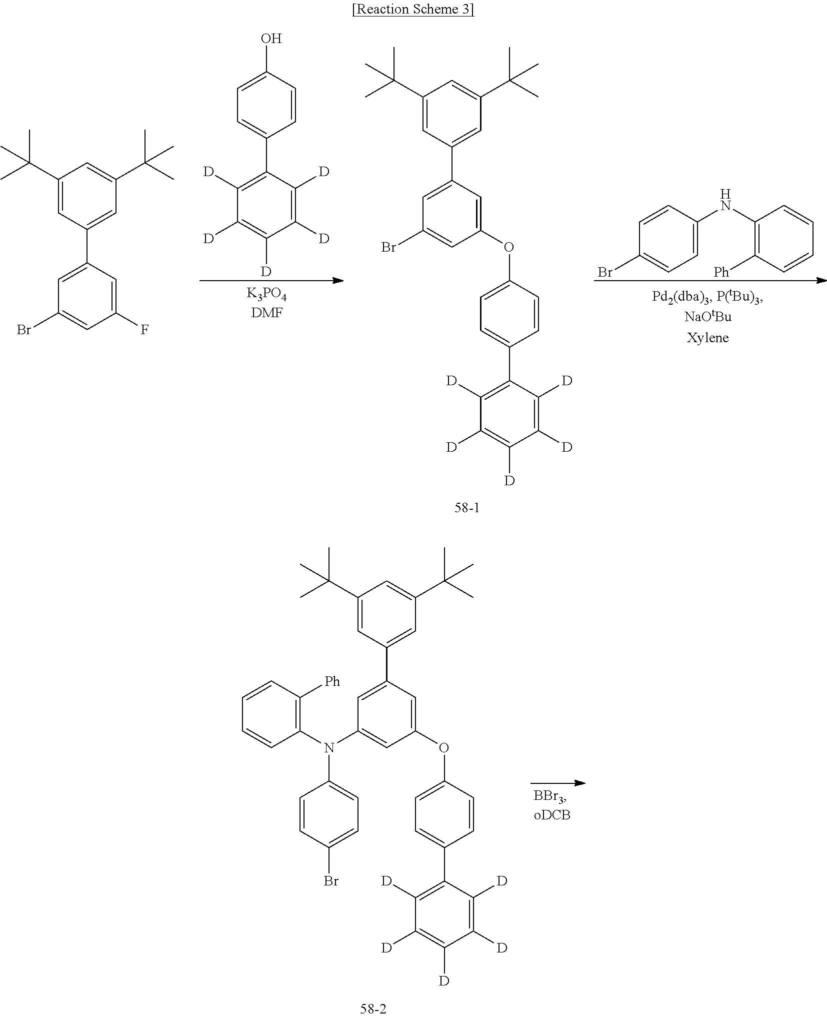

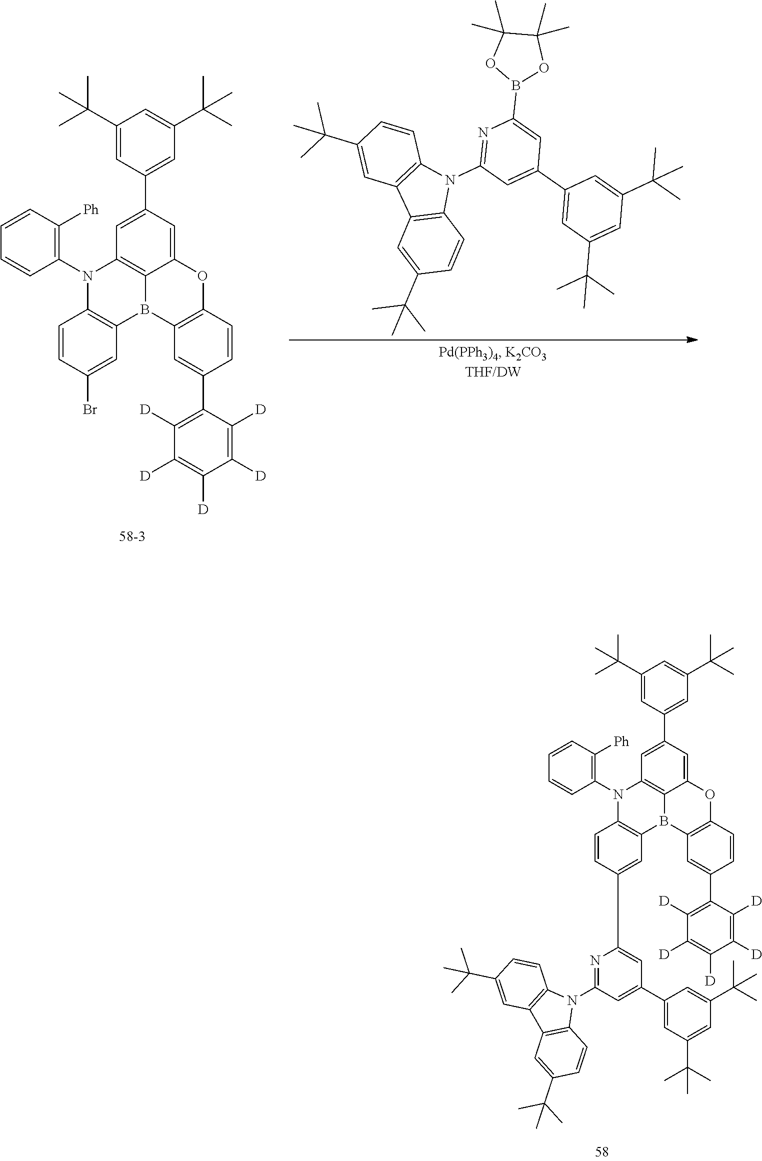 [SMILES: [2H]c1c([2H])c([2H])c(-c2ccc3c(c2)B2c4cc(Br)ccc4N(c4ccccc4-c4ccccc4)c4cc(-c5cc(C(C)(C)C)cc(C(C)(C)C)c5)cc(c42)O3)c([2H])c1[2H] ; CC(C)(C)c1cc(-c2cc(B3OC(C)(C)C(C)(C)O3)nc(-n3c4ccc(C(C)(C)C)cc4c4cc(C(C)(C)C)ccc43)c2)cc(C(C)(C)C)c1 ; [2H]c1c([2H])c([2H])c(-c2ccc3c(c2)B2c4cc(-c5cc(-c6cc(C(C)(C)C)cc(C(C)(C)C)c6)cc(-n6c7ccc(C(C)(C)C)cc7c7cc(C(C)(C)C)ccc76)n5)ccc4N(c4ccccc4-c4ccccc4)c4cc(-c5cc(C(C)(C)C)cc(C(C)(C)C)c5)cc(c42)O3)c([2H])c1[2H]]

1) Synthesis of Intermediate 58-1

3-bromo-3′, 5′-di-tert-butyl-5-fluoro-1,1′-biphenyl (1 eq), [1,1′-biphenyl]-2′, 3′, 4′, 5′, 6′-d5-4-ol (1.5 eq), and potassium phosphate (3 eq) were dissolved in dimethylformamide, and the resultant mixture was stirred at about 150° C. for about 24 hours. After cooling, the resultant mixture was dried under reduced pressure and the dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 58-1. (yield: 57%)

2) Synthesis of Intermediate 58-2

Intermediate 58-1 (1 eq), N-(4-bromophenyl)-[1,1′-biphenyl]-2-amine (1 eq), tris(dibenzylideneacetone)dipalladium(0) (0.05 eq), tri-tert-butylphosphine (0.10 eq), and sodium tert-butoxide (1.5 eq) were dissolved in xylene, and the resultant mixture was stirred in a nitrogen atmosphere at about 100° C. for about 10 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 58-2. (yield: 43%)

3) Synthesis of Intermediate 58-3

Intermediate 58-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 58-3. Thereafter, Intermediate 58-3 was finally purified by column chromatography (dichloromethane:n-hexane) (yield: 7%).

4) Synthesis of Compound 58

Intermediate 58-3 (1 eq), 3,6-di-tert-butyl-9-(4-(3,5-di-tert-butylphenyl)-6-(4,4,5,5-tetramethyl-1,3,2-dioxaborolan-2-yl)pyridin-2-yl)-9H-carbazole (1.2 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 58 (yield: 56%). The resulting product was further purified by sublimation purification to obtain final purity. The obtained compound was identified as Compound 58 through ESI-LCMS (ESI-LCMS: [M]⁺: C₈₉H₈₅D₅BN₃O, 1232.75).

(4) Synthesis of Compound 61

Compound 61 according to an example may be synthesized by Reaction Scheme 4 below:

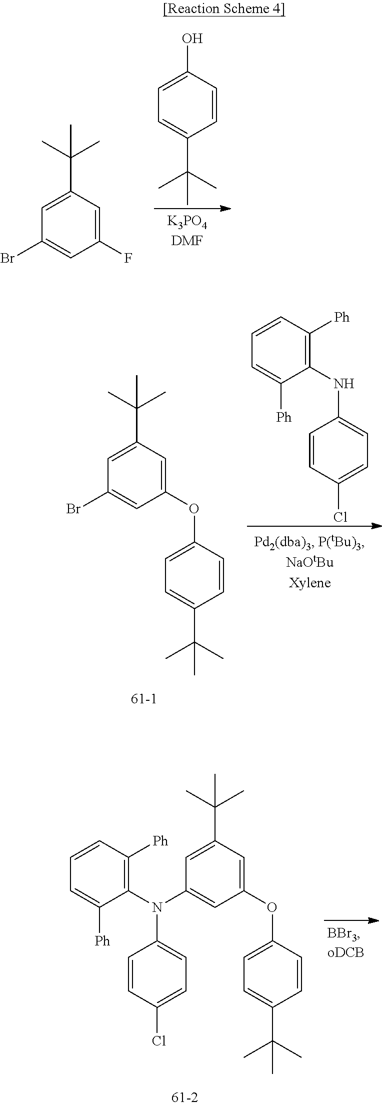 [SMILES: CC(C)(C)c1cc(F)cc(Br)c1 ; CC(C)(C)c1ccc(O)cc1 ; CC(C)(C)c1ccc(Oc2cc(Br)cc(C(C)(C)C)c2)cc1 ; Clc1ccc(Nc2c(-c3ccccc3)cccc2-c2ccccc2)cc1 ; CC(C)(C)c1ccc(Oc2cc(N(c3ccc(Cl)cc3)c3c(-c4ccccc4)cccc3-c3ccccc3)cc(C(C)(C)C)c2)cc1]

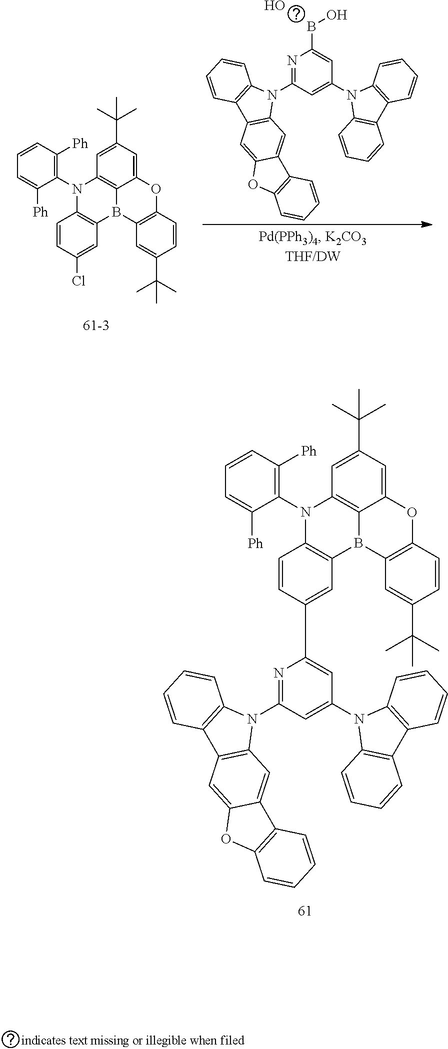

1) Synthesis of Intermediate 61-1

1-bromo-3-(tert-butyl)-5-fluorobenzene (1 eq), 4-(tert-butyl)phenol (1.5 eq), and potassium phosphate (3 eq) were dissolved in dimethylformamide, and the resultant mixture was stirred at about 150° C. for about 24 hours. After cooling, the resultant mixture was dried under reduced pressure and the dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 61-1. (yield: 54%)

2) Synthesis of Intermediate 61-2

Intermediate 61-1 (1 eq), N-(4-chlorophenyl)-[1,1′:3′,1″-terphenyl]-2′-amine (1 eq), tris(dibenzylideneacetone)dipalladium(0) (0.05 eq), tri-tert-butylphosphine (0.10 eq), and sodium tert-butoxide (1.5 eq) were dissolved in xylene, and the resultant mixture was stirred in a nitrogen atmosphere at about 140° C. for about 10 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 61-2 (yield: 57%).

3) Synthesis of Intermediate 61-3

Intermediate 61-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 61-3. Thereafter, Compound 34 was finally purified by column chromatography (dichloromethane:n-hexane) (yield: 11%).

4) Synthesis of Compound 61

Intermediate 61-3 (1 eq), (6-(11H-benzofuro[3,2-b]carbazol-11-yl)-4-(9H-carbazol-9-yl)pyridin-2-yl)boronic acid (1.2 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained.

The obtained organic layer was dried over MgSO₄, and dried under reduced pressure. The resulting product was purified and recrystallized by column chromatography (dichloromethane:n-hexane) to obtain Compound 61. (yield: 66%). The resulting product was further purified by sublimation purification to obtain final purity. The obtained compound was identified as Compound 61 through ESI-LCMS (ESI-LCMS: [M]⁺: C₇₉H₅₉BN₄O₂, 1106.47).

(5) Synthesis of Compound 91

Compound 91 according to an example may be synthesized by Reaction Scheme 5 below:

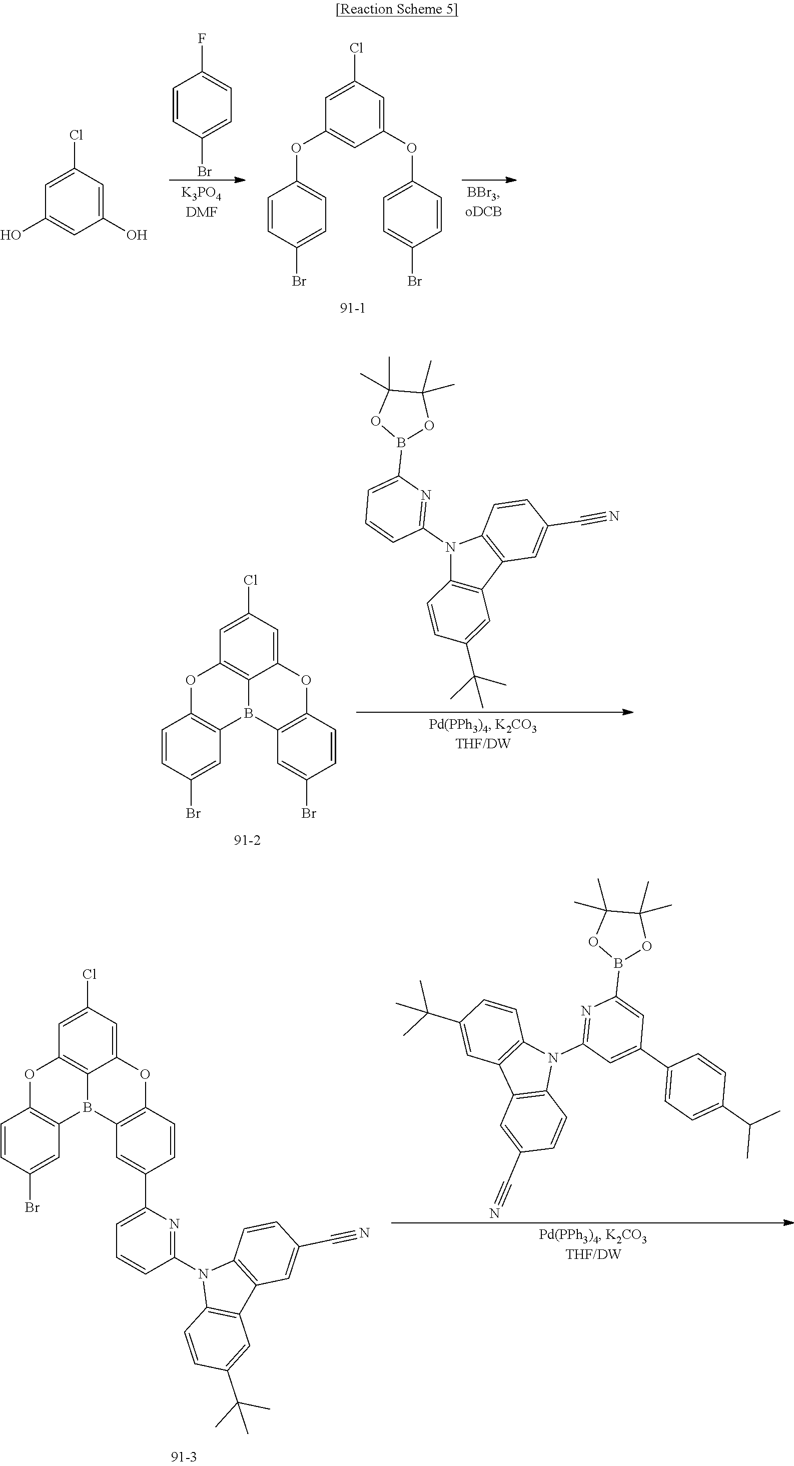

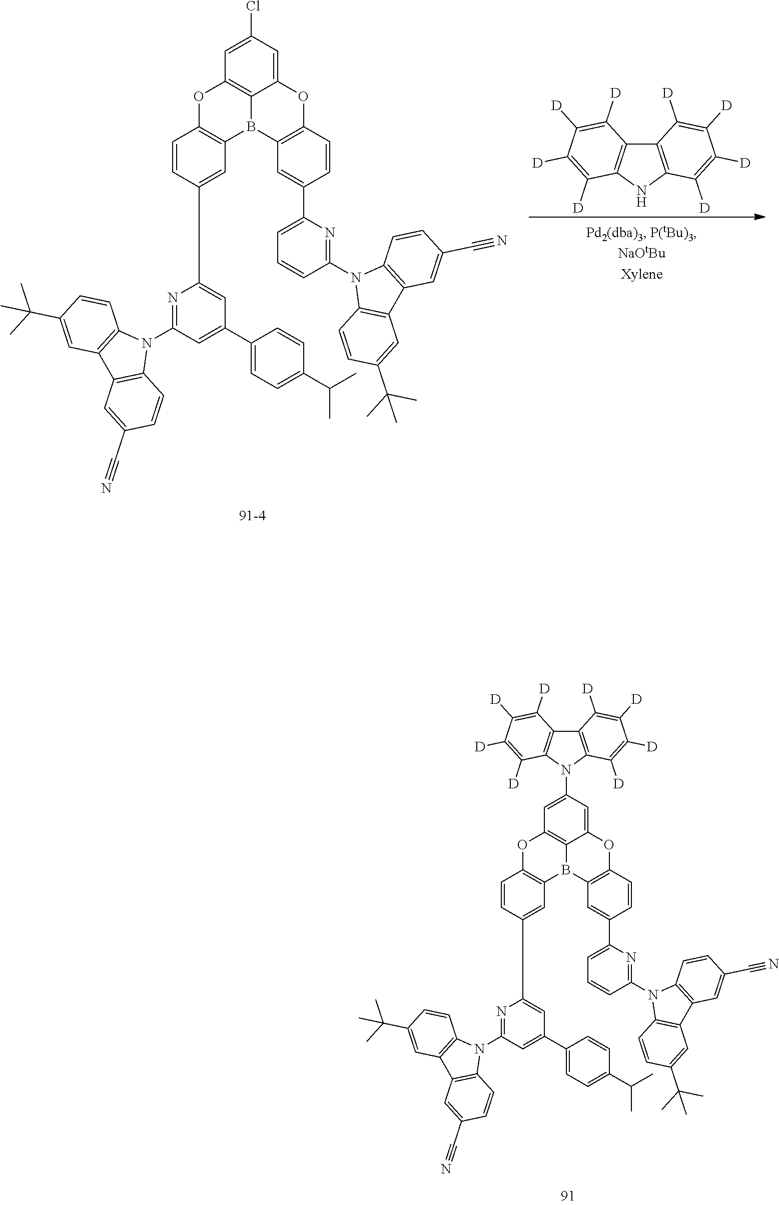 [SMILES: CC(C)c1ccc(-c2cc(-c3ccc4c(c3)B3c5cc(-c6cccc(-n7c8ccc(C#N)cc8c8cc(C(C)(C)C)ccc87)n6)ccc5Oc5cc(Cl)cc(c53)O4)nc(-n3c4ccc(C#N)cc4c4cc(C(C)(C)C)ccc43)c2)cc1 ; [2H]c1c([2H])c([2H])c2c([nH]c3c([2H])c([2H])c([2H])c([2H])c32)c1[2H] ; [2H]c1c([2H])c([2H])c2c(c1[2H])c1c([2H])c([2H])c([2H])c([2H])c1n2-c1cc2c3c(c1)Oc1ccc(-c4cc(-c5ccc(C(C)C)cc5)cc(-n5c6ccc(C#N)cc6c6cc(C(C)(C)C)ccc65)n4)cc1B3c1cc(-c3cccc(-n4c5ccc(C#N)cc5c5cc(C(C)(C)C)ccc54)n3)ccc1O2]

1) Synthesis of Intermediate 91-1

5-chlorobenzene-1,3-diol (1 eq), 1-bromo-4-fluorobenzene (1 eq), and potassium phosphate (3 eq) were dissolved in dimethylformamide, and the resultant mixture was stirred at about 150° C. for about 24 hours. After cooling, the resultant mixture was dried under reduced pressure and the dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 91-1 (yield: 45%).

2) Synthesis of Intermediate 91-2

Intermediate 91-1 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 91-2. Thereafter, Compound 34 was finally purified by column chromatography (dichloromethane:n-hexane) (yield: 7%).

3) Synthesis of Intermediate 91-3

Intermediate 91-2 (1 eq), 6-(tert-butyl)-9-(6-(4,4,5,5-tetramethyl-1,3,2-dioxaborolan-2-yl)pyridin-2-yl)-9H-carbazole-3-carbonitrile (1 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Intermediate 91-3 (yield: 43%).

4) Synthesis of Intermediate 91-4

Intermediate 91-3 (1 eq), 6-(tert-butyl)-9-(4-(4-isopropylphenyl)-6-(4,4,5,5-tetramethyl-1,3,2-dioxaborolan-2-yl)pyridin-2-yl)-9H-carbazole-3-carbonitrile (1.5 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Intermediate 91-4 (yield: 51%).

5) Synthesis of Compound 91

Intermediate 91-4 (1 eq), 9H-carbazole-1,2,3,4,5,6,7,8-d8 (1.2 eq), tris(dibenzylideneacetone)dipalladium(0) (0.10 eq), tri-tert-butylphosphine (0.20 eq), and sodium tert-butoxide (3 eq) were dissolved in xylene, and the resultant mixture was stirred in a nitrogen atmosphere at about 150° C. for about 20 hours. After cooling, the resultant mixture was dried under reduced pressure and the xylene was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Compound 91 (yield: 62%). The resulting product was further purified by sublimation purification to obtain final purity. The obtained compound was identified as Compound 91 through ESI-LCMS (ESI-LCMS: [M]⁺: C₈₃H₅₄D₈BN₇O₂, 1207.56).

(6) Synthesis of Compound 93

Compound 93 according to an example may be synthesized by Reaction Scheme 6 below:

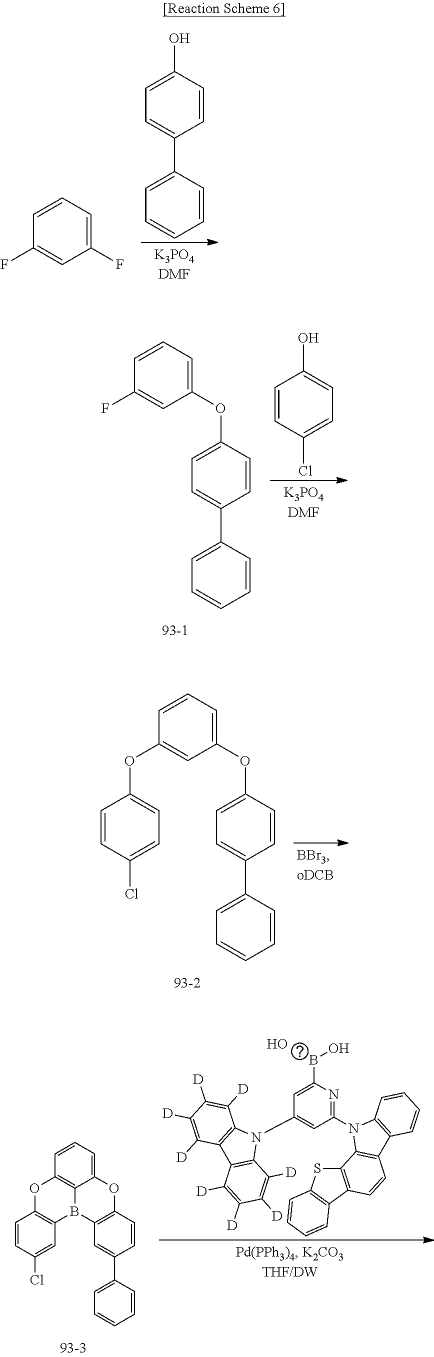

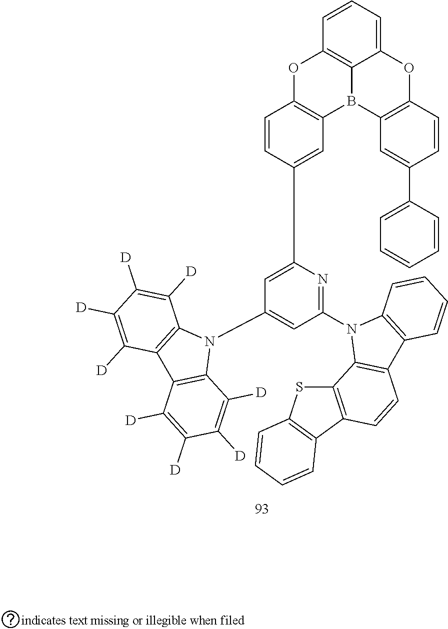 [SMILES: [2H]c1c([2H])c([2H])c2c(c1[2H])c1c([2H])c([2H])c([2H])c([2H])c1n2-c1cc(-c2ccc3c(c2)B2c4cc(-c5ccccc5)ccc4Oc4cccc(c42)O3)nc(-n2c3ccccc3c3ccc4c5ccccc5sc4c32)c1]

1) Synthesis of Intermediate 93-1

1,3-difluorobenzene (1 eq), [1,1′-biphenyl]-4-ol (1 eq), and potassium phosphate (3 eq) were dissolved in dimethylformamide, and the resultant mixture was stirred at about 150° C. for about 24 hours. After cooling, the resultant mixture was dried under reduced pressure and the dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 93-1 (yield: 61%).

2) Synthesis of Intermediate 93-2

Intermediate material 93-1 (1 eq), 4-chlorophenol (1 eq), and potassium phosphate (3 eq) were dissolved in dimethylformamide, and the resultant mixture was stirred at about 150° C. for about 24 hours. After cooling, the resultant mixture was dried under reduced pressure and the dimethylformamide was removed. The resulting product was washed three times with ethyl acetate and water to obtain organic layers. The obtained organic layers were dried over MgSO₄, and dried under reduced pressure. The resulting product was purified and recrystallized by column chromatography (dichloromethane:n-hexane) to obtain Intermediate 93-2 (yield: 59%).

3) Synthesis of Intermediate 93-3

Intermediate 93-2 (1 eq) was dissolved in ortho dichlorobenzene, and the flask was cooled to about 0° C. in a nitrogen atmosphere, and BBr₃ (2.5 eq) dissolved in ortho dichlorobenzene was slowly injected thereto. After dropping was completed, the temperature was elevated to about 180° C., and the mixture was stirred for about 24 hours. After the mixture was cooled to about 0° C., triethylamine was slowly dropped to the flask until heating stopped to terminate the reaction, and the mixture was dried under reduced pressure to remove the ortho dichlorobenzene. Hexane was added to the flask and extracted solids. The extracted solids were obtained by filtration. The obtained solids were purified with silica filtration, and purified again through recrystallization in methylene chloride/hexane to obtain Intermediate 93-3. Thereafter, Compound 34 was finally purified by column chromatography (dichloromethane:n-hexane) (yield: 9%).

4) Synthesis of Compound 93

Intermediate 93-3 (1 eq), (6-(12H-benzo[4,5]thieno[2,3-a]carbazol-12-yl)-4-(9H-carbazol-9-yl-d8)pyridin-2-yl)boronic acid (1.5 eq), tetrakis(triphenylphosphine)-palladium(0) (0.05 eq), and potassium carbonate (3 eq) were dissolved in tetrahydrofuran:distilled water (3:1), and the resultant mixture was stirred at about 80° C. for about 24 hours. After cooling, the resulting product was washed three times with ethyl acetate and water, and an organic layer was obtained. The obtained organic layer was dried over MgSO₄, and dried under reduced pressure. The resulting product was purified and recrystallized by column chromatography (dichloromethane:n-hexane) to obtain Compound 93 (yield: 47%). The resulting product was further purified by sublimation purification to obtain final purity. The obtained compound was identified as Compound 93 through ESI-LCMS (ESI-LCMS: [M]⁺: C₅₉H₂₆D₈BN₃O₂S, 867.30).

2. Manufacture and Evaluation of Light Emitting Device Including Polycyclic Compound

(1) Manufacture of Light Emitting Devices

The light emitting device of an example including the polycyclic compound of an example in the emission layer was manufactured as follows. Polycyclic compounds of Compounds 12, 42, 58, 61, 91 and 93, which are Example Compounds as described above, were used as dopant materials for the emission layers to manufacture the light emitting devices of Examples 1 to 12. Comparative Examples 1 to 12 correspond to the light emitting devices manufactured by using Comparative Example Compounds C1 to C6 as dopant materials for the emission layers.

### Example Compounds

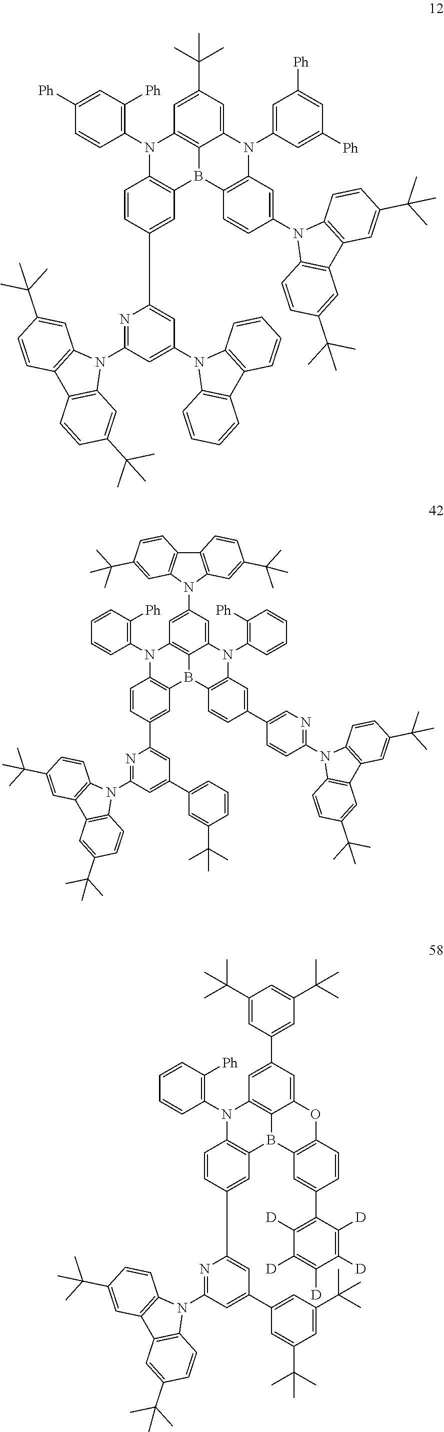

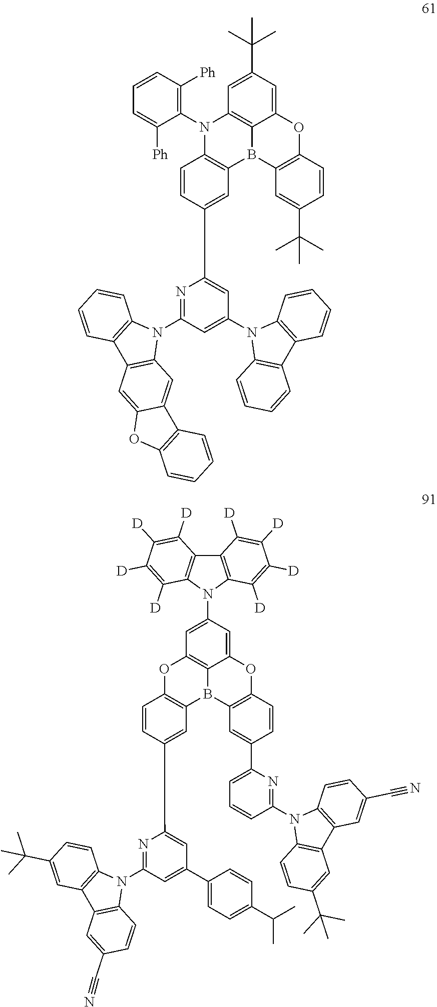

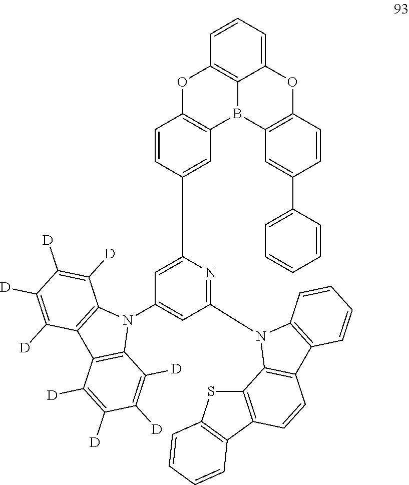 [SMILES: [2H]c1c([2H])c([2H])c2c(c1[2H])c1c([2H])c([2H])c([2H])c([2H])c1n2-c1cc(-c2ccc3c(c2)B2c4cc(-c5ccccc5)ccc4Oc4cccc(c42)O3)nc(-n2c3ccccc3c3ccc4c5ccccc5sc4c32)c1]

### 1) Manufacture Example 1 of Light Emitting Device

A glass substrate, on which an ITO electrode of about 15 Ω/cm² (about 1,200 k) is formed as a first electrode, was cut to a size of about 50 mm×50 mm×of 0.7 mm cleansed by ultrasonic waves using isopropyl alcohol and pure water for about five minutes each. The glass substrate was irradiated with ultraviolet rays for about 30 minutes and exposed to ozone and cleansed, and was installed on a vacuum deposition apparatus.

NPD was deposited to form a 300 Å-thick hole injection layer. Compound H-1-2 was deposited on the upper portion of the hole injection layer to form a 200 Å-thick hole transport layer. CzSi was deposited on the upper portion of the hole transport layer to form a 100 Å-thick emission-auxiliary layer.

A host material, which the second compound and the third compound were mixed in an amount of about 1:1, the fourth compound, and an Example Compound or a Comparative Example Compound were co-deposited in a weight ratio of about 85:14:1 to form a 200 Å-thick emission layer.

TSPO1 was deposited on the upper portion of the emission layer to form a 200 Å-thick hole blocking layer. TPBi was deposited on the upper portion of the hole blocking layer to form a 300 Å-thick electron transport layer. LiF was deposited on the upper portion of the electron transport layer to form a 10 Å-thick electron injection layer. Al was deposited on the upper portion of the electron injection layer to form a 3,000 Å-thick second electrode. Compound P4 was deposited on the upper portion of the second electrode to form a 700 Å-thick capping layer, thereby manufacturing a light emitting device.

### 2) Manufacture Example 2 of Light Emitting Device

In comparison to Manufacture Example 1 of Light Emitting Device, a host material in which the second compound and the third compound were mixed in an amount of about 1:1, and Example Compound or Comparative Example Compound were co-deposited on the upper portion of the emission auxiliary layer in a weight ratio of about 99:1 to form a 200 Å-thick emission layer. Other manufacturing methods are the same as in Manufacture Example 1 of Light Emitting Device.

Compounds used for manufacturing the light emitting devices of Examples and Comparative Examples are as follows. The materials below were used to manufacture the devices by subjecting commercial products to sublimation purification.

[chemical structure]

(2) Evaluation of Light Emitting Device Characteristics

The characteristics of the light emitting devices of Examples 1 to 6 and Comparative Examples 1 to 6 are evaluated and listed in Table 1. The light emitting devices of Examples 1 to 6 and Comparative Examples 1 to 6 were manufactured according to Manufacture Example 1 of Light Emitting Device, as described above.

The characteristics of the light emitting devices of Examples 7 to 12 and Comparative Examples 7 to 12 are evaluated and listed in Table 2. The light emitting devices of Examples 7 to 12 and Comparative Examples 7 to 12 were manufactured according to Manufacture Example 2 of Light Emitting Device, as described above.

In Tables 1 and 2, each of driving voltage (V), luminous efficiency (cd/A), and emission color at a luminance of 1,000 cd/m² was measured by using Keithley MU 236 and a luminance meter PR650. The time taken for the brightness to reduce to 95% relative to an initial brightness was measured as a service life (T₉₅), and a relative service life was calculated on the basis of the device of Comparative Example 1 and shown in Relative service life (%).

Materials used in Table 1 and Table 2 are as follows:

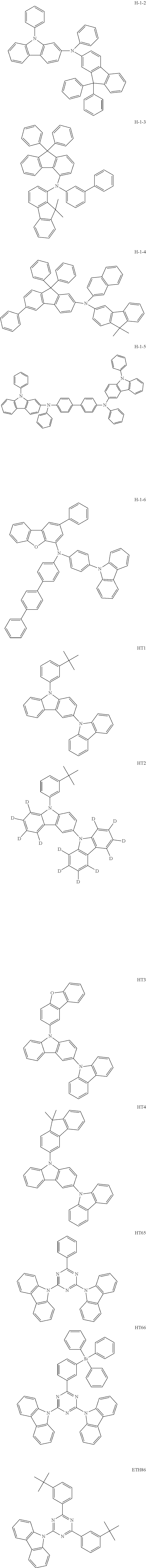

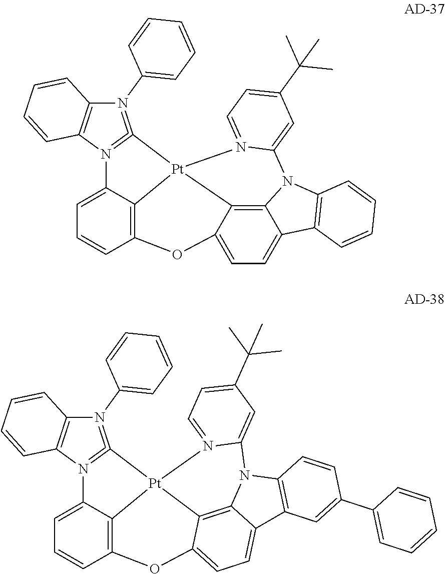

TABLE 1

| | | Second | | | | | Maximum | | |
|---|---|---|---|---|---|---|---|---|---|
| | | compound/ | | | | | external | Relative | |
| | Hole | third | | | Driving | | quantum | device | |
| | transport | compound | Fourth | First | voltage | Efficiency | efficiency | service | Emission |
| | layer | (HT:ET = 5:5) | compound | compound | (V) | (cd/A) | (%) | life (%) | color |
| Example 1 | H-1-2 | HT3/ETH66 | AD-37 | Compound | 4.3 | 26.8 | 25.9 | 245 | Blue |
| | | | | 12 | | | | | |
| Example 2 | H-1-6 | HT1/ETH86 | AD-38 | Compound | 4.2 | 25.9 | 25.2 | 270 | Blue |
| | | | | 42 | | | | | |
| Example 3 | H-1-4 | HT2/ETH86 | AD-37 | Compound | 4.4 | 23.2 | 22.8 | 205 | Blue |
| | | | | 58 | | | | | |
| Example 4 | H-1-2 | HT3/ETH86 | AD-38 | Compound | 4.3 | 23.5 | 22.7 | 180 | Blue |
| | | | | 61 | | | | | |
| Example 5 | H-1-3 | HT3/ETH66 | AD-38 | Compound | 4.5 | 22.4 | 21.8 | 175 | Blue |
| | | | | 91 | | | | | |
| Example 6 | H-1-5 | HT1/ETH86 | AD-37 | Compound | 4.6 | 21.3 | 20.5 | 160 | Blue |
| | | | | 93 | | | | | |
| Comparative | H-1-3 | HT1/ETH86 | AD-38 | Compound | 4.7 | 14.7 | 13.8 | 100 | Blue |
| Example 1 | | | | C1 | | | | | |
| Comparative | H-1-5 | HT3/ETH86 | AD-37 | Compound | 4.6 | 15.6 | 14.9 | 135 | Blue |
| Example 2 | | | | C2 | | | | | |
| Comparative | H-1-6 | HT2/ETH85 | AD-38 | Compound | 4.6 | 17.9 | 16.7 | 150 | Blue |
| Example 3 | | | | C3 | | | | | |
| Comparative | H-1-5 | HT3/ETH86 | AD-37 | Compound | 4.7 | 14.1 | 13.5 | 110 | Blue |
| Example 4 | | | | C4 | | | | | |
| Comparative | H-1-6 | HT1/ETH86 | AD-37 | Compound | 4.8 | 13.5 | 12.8 | 85 | Blue |
| Example 5 | | | | C5 | | | | | |
| Comparative | H-1-3 | HT2/ETH85 | AD-38 | Compound | 4.9 | 11.9 | 10.4 | 35 | Blue |
| Example 6 | | | | C6 | | | | | |

TABLE 2

| | Hole | Second compound/ | | | Maximum | |
|---|---|---|---|---|---|---|
| | transport | third compound | First | Efficiency | external quantum | Emission |
| | layer | (HT:ET = 5:5) | compound | (cd/A) | efficiency (%) | color |
| Example 7 | H-1-2 | HT3/ETH66 | Compound 12 | 8.7 | 8.4 | Blue |
| Example 8 | H-1-6 | HT1/ETH86 | Compound 42 | 8.4 | 8.2 | Blue |
| Example 9 | H-1-4 | HT2/ETH86 | Compound 58 | 7.5 | 7.4 | Blue |
| Example 10 | H-1-2 | HT3/ETH86 | Compound 61 | 7.6 | 7.4 | Blue |
| Example 11 | H-1-3 | HT3/ETH66 | Compound 91 | 7.3 | 7.1 | Blue |
| Example 12 | H-1-5 | HT1/ETH86 | Compound 93 | 6.9 | 6.6 | Blue |
| Comparative | H-1-3 | HT1/ETH86 | Compound C1 | 4.7 | 4.4 | Blue |
| Example 7 | | | | | | |
| Comparative | H-1-5 | HT3/ETH86 | Compound C2 | 5.0 | 4.8 | Blue |
| Example 8 | | | | | | |
| Comparative | H-1-6 | HT2/ETH85 | Compound C3 | 5.8 | 5.4 | Blue |
| Example 9 | | | | | | |
| Comparative | H-1-5 | HT3/ETH86 | Compound C4 | 4.5 | 4.3 | Blue |
| Example 10 | | | | | | |
| Comparative | H-1-6 | HT1/ETH86 | Compound C5 | 4.3 | 4.1 | Blue |
| Example 11 | | | | | | |
| Comparative | H-1-3 | HT2/ETH85 | Compound C6 | 3.8 | 3.3 | Blue |
| Example 12 | | | | | | |

Referring to Tables 1 and 2, Examples 1 to 6, which are light emitting devices that include the polycyclic compounds according to embodiments, exhibit device characteristics of low driving voltage, high luminous efficiency, high maximum external quantum efficiency, and long service life as compared with Comparative Examples 1 to 6. Referring again to Tables 1 and 2, Examples 7 to 12, which are light emitting devices that include the polycyclic compound according to embodiments as a single dopant, exhibit high luminous efficiency and high maximum external quantum efficiency as compared with Comparative Examples 7 to 12. As described above, the polycyclic compound represented by Formula 1 may have a core structure in which multiple aromatic rings are fused via one boron atom and two heteroatoms. The polycyclic compound may contain at least one pyridine group substituted with a carbazole group which is bonded at a meta-position to the boron atom of the fused ring core moiety.

In the case of the meta-position of the boron atom in the fused ring core moiety, the electron density is high. By introducing the pyridine group having electron-withdrawing properties at a meta-position to the boron atom, HOMO-LUMO sequential separation between atoms occurs and multiple resonance effects are further enhanced. Thus, delayed fluorescence characteristics may be improved, and high photoluminescence quantum yield (PLQY) may be exhibited.

The carbazole group is bonded to the pyridine group. The carbazole group is bonded at an ortho-position to the nitrogen atom of the pyridine. The ortho-position to the nitrogen atom of the pyridine is a position with strong activity, and the carbazole group is bonded thereto, and thus molecular stability may be improved. The polycyclic compound according to embodiments includes a bulky substituent like a pyridine group substituted with a carbazole group, and thus may exhibit steric hindrance characteristics, and may effectively suppress Dexter energy transfer between molecules.

Comparative Example Compound C1 is a compound that includes a pyridine group, but in which the pyridine group is introduced at a para-position rather than a meta-position to the boron atom. Thus, it is considered that the multiple resonance effects are low and thus the characteristics of the device are exhibited lower than the device in which the polycyclic compound according to an embodiment is applied.

Comparative Example Compound C2 is a compound in which a pyridine group is bonded at a meta-position to the boron atom. However, Comparative Example Compound C2 includes a pyridine group substituted with only hydrogen rather than a pyridine group substituted with a carbazole group, and thus molecular stability is low, and there are no steric hindrance characteristics so that it is difficult to suppress Dexter energy transfer between molecules. Thus, it is considered that the characteristics of the device are exhibited lower than the device in which the polycyclic compound according to an embodiment is applied.

Comparative Example Compound C3 is a compound which includes a pyridine group substituted with a carbazole group but in which the pyridine group is bonded at a meta-position to the nitrogen atom of the core moiety rather than at a meta-position to the boron atom of the core moiety. From such a configuration, a plate type state increases and a triplet energy decreases. Thus, it is considered that Dexter energy transfer is increased, and thus the characteristics of the device are exhibited lower than the device in which the polycyclic compound according to an embodiment is applied.

Comparative Example Compound C4 is a compound in which a pyridine group is bonded at a meta-position to the boron atom of the core, but the substituent substituted at the pyridine group is a methyl group rather than a carbazole group. There are no steric hindrance characteristics, and thus Dexter energy transfer increases between molecules. Thus, it is considered that the characteristics of the device are exhibited lower than the device in which the polycyclic compound according to an embodiment is applied.

Comparative Example Compound C5 is a compound in which a pyridine group is bonded at a meta-position to the boron atom of the core moiety but the position of the nitrogen atom of the pyridine group is different from the polycyclic compound according to an embodiment. The ortho-position of the nitrogen atom of the pyridine group with strong activity is not stabilized. Thus, it is considered that the characteristics of the devices are exhibited lower than the device in which the polycyclic compound according to an embodiment is applied.

Comparative Example Compound C6 is a compound in which a substituent is bonded at a meta-position to the boron atom of the core moiety, but a phenyl group is bonded rather than a pyridine group having electron-withdrawing properties. Thus, it is considered that the multiple resonance effects are low and thus the characteristics of the device are exhibited lower than the device in which the polycyclic compound according to an embodiment is applied.

The polycyclic compound of an embodiment has a fused ring core moiety containing one boron atom and two heteroatoms, and a structure in which at least one pyridine group substituted with a carbazole group is bonded to the fused ring core moiety, and thus multiple resonance effects may be further enhanced and Dexter energy transfer between molecules may be effectively suppressed. Thus, the polycyclic compound of an embodiment may be applied to the light emitting device, thereby contributing to improving luminous efficiency and service life of the light emitting device.

The light emitting device of an embodiment may exhibit improved device characteristics with high efficiency and a long service life.

The polycyclic compound of an embodiment may be included in the emission layer of the light emitting device, thereby contributing to improving luminous efficiency and service life of the light emitting device.

Embodiments have been disclosed herein, and although terms are employed, they are used and are to be interpreted in a generic and descriptive sense only and not for the purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting device comprising:
a first electrode;
a second electrode facing the first electrode; and
at least one functional layer disposed between the first electrode and the second electrode, wherein
the at least one functional layer comprises:
a first compound represented by Formula 1; and
at least one of a second compound represented by Formula HT or a third compound represented by Formula ET: 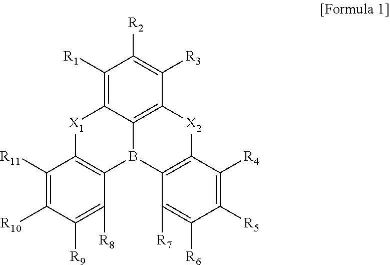
wherein in Formula 1,
X₁ and X₂ are each independently N(R₁₂) or O,
R₁ to R₁₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
at least one of R₆ or R₉ is a group represented by Formula 2: 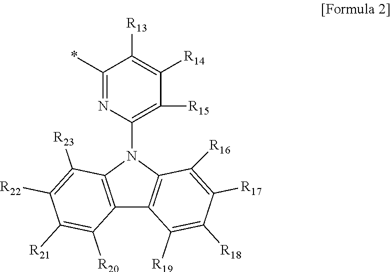
wherein in Formula 2,
R₁₃ to R₂₃ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
—* represents a bonding site to Formula 1, 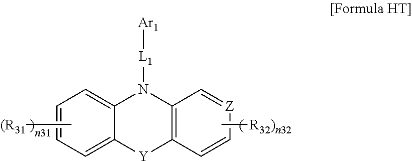
wherein in Formula HT,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
Y is a direct linkage, C(R_{y1})(R_{y2}), or Si(R_{y3})(R_{y4}),
Z is C(R_{z}) or N,
R_{y1} to R_{y4}, R₃₁, R₃₂, and R_{z} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n31 is an integer from 0 to 4, and
n32 is an integer from 0 to 3, 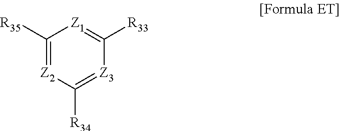
wherein in Formula ET,
Z₁ to Z₃ are each independently N or C(R₃₆),
at least one of Z₁ to Z₃ is each N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

2. The light emitting device of claim 1, wherein the at least one functional layer further comprises a fourth compound represented by Formula PS: 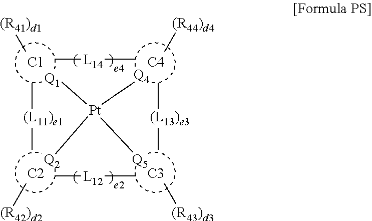
wherein in Formula PS,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₄ are each independently a direct linkage, *—O—*, *—S—*, 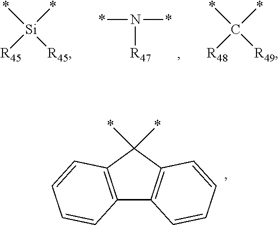
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
in L₁₁ to L₁₄, —* each represents a bonding site to one of C1 to C4,
e1 to e4 are each independently 0 or 1,
R₄₁ to R₄₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

3. The light emitting device of claim 1, wherein the first compound represented by Formula 1 is represented by Formula 1-1a or Formula 1-1b: 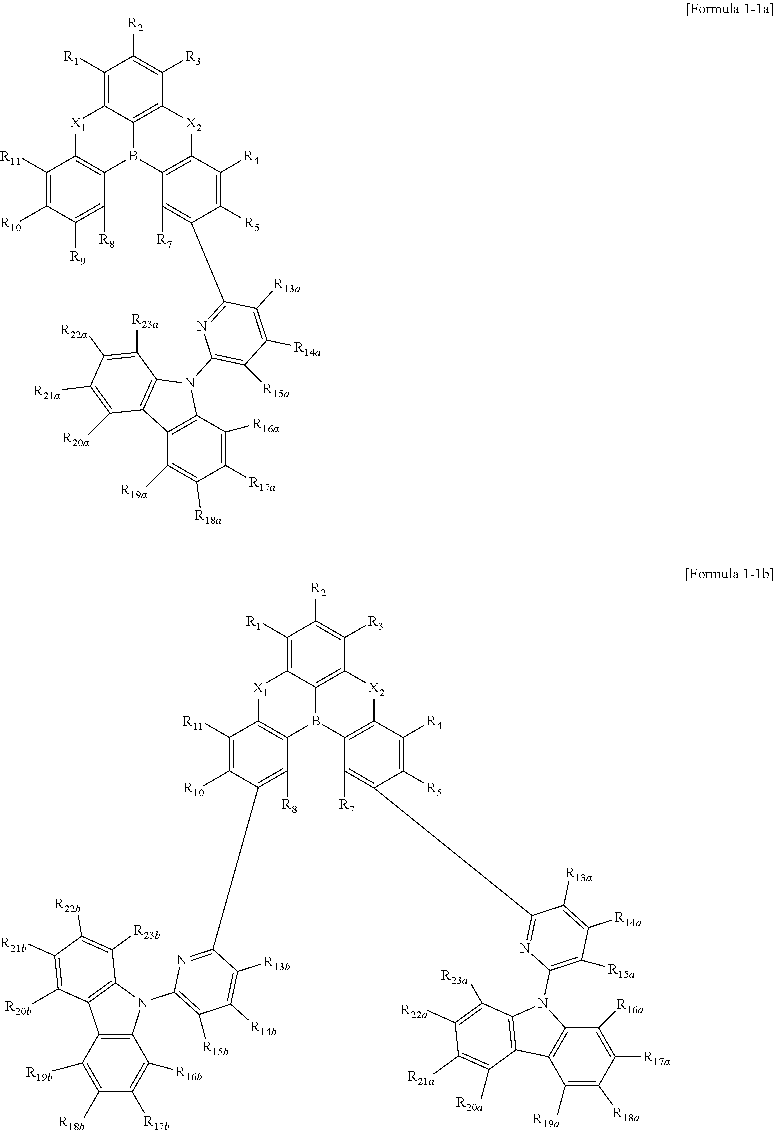
wherein in Formula 1-1a and Formula 1-1b,
R₉ₐ, R₁₃ₐ to R₂₃ₐ, and R_{13b} to R_{23b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
X₁, X₂, R₁ to R₅, R₇, R₈, R₁₀, and R₁₁ are each the same as defined in Formula 1.

4. The light emitting device of claim 3, wherein in Formula 1-1a and Formula 1-1b, R₁ to R₅, R₇, R₈, R₉ₐ, R₁₀, and R₁₁ are each independently a hydrogen atom, a deuterium atom, a substituted or unsubstituted t-butyl group, a substituted or unsubstituted phenyl group, or a substituted or unsubstituted carbazole group.

5. The light emitting device of claim 1, wherein in Formula 1, R₁₂ is a substituted or unsubstituted phenyl group, a substituted or unsubstituted biphenyl group, or a substituted or unsubstituted terphenyl group.

6. The light emitting device of claim 1, wherein the first compound represented by Formula 1 is represented by one of Formula 1-2a to Formula 1-2c: 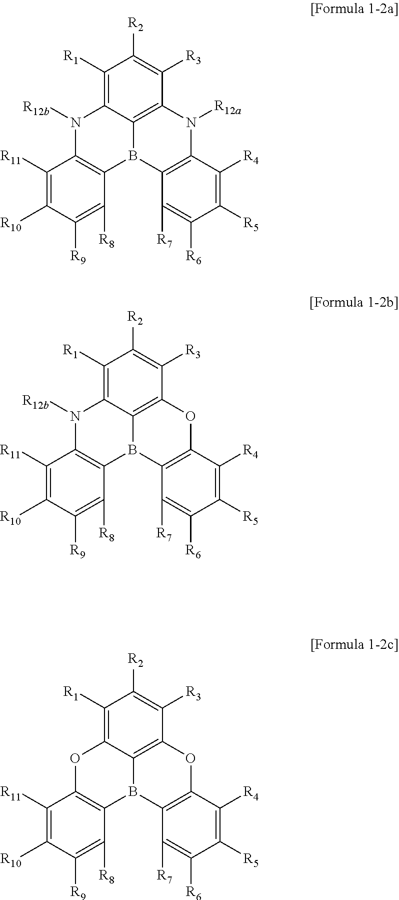
wherein in Formula 1-2a to Formula 1-2c,
R₁₂ₐ and R_{12b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and
R₁ to R₁₁ are each the same as defined in Formula 1.

7. The light emitting device of claim 6, wherein
the first compound represented by Formula 1-2a is represented by Formula 1-3a, and
the first compound represented by Formula 1-2b is represented by Formula 1-3b: 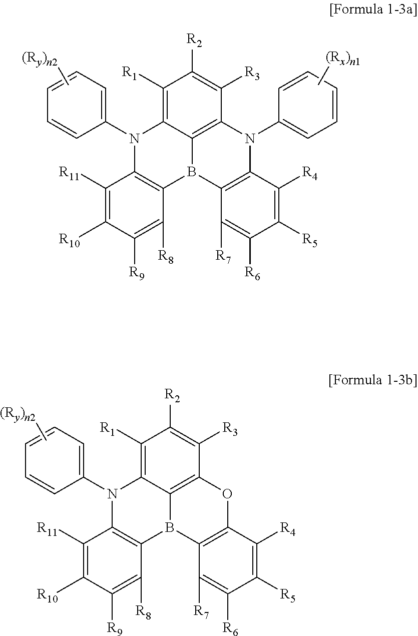
wherein in Formula 1-3a and Formula 1-3b,
Rₓ and R_{y} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
n1 and n2 are each independently an integer from 0 to 5, and
R₁ to R₁₁ are each the same as defined in Formula 1.

8. The light emitting device of claim 1, wherein Formula 2 is represented by one of Formula 2-1 to Formula 2-7: 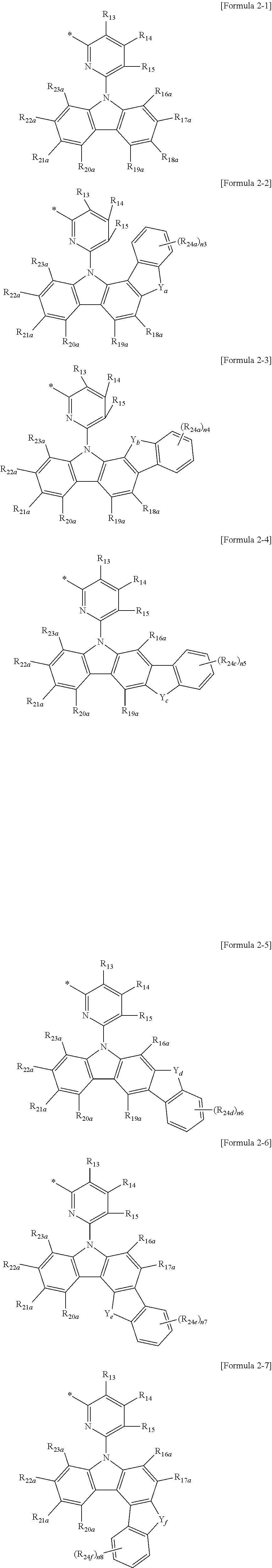
wherein in Formula 2-1 to Formula 2-7,
Yₐ to Y_{f} are each independently O or S,
R₁₆ₐ to R₂₃ₐ and R₂₄ₐ to R_{24f} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
n3 to n8 are each independently an integer from 0 to 4, and
R₁₃ to R₁₅ and —* are each the same as defined in Formula 2.

9. The light emitting device of claim 8, wherein in Formula 2-1 to Formula 2-7, R₁₃ to R₁₅, R₁₆ₐ to R₂₃ₐ, and R₂₄ₐ to R_{24f} are each independently a hydrogen atom, a deuterium atom, a cyano group, a substituted or unsubstituted t-butyl group, a substituted or unsubstituted phenyl group, or a substituted or unsubstituted carbazole group.

10. The light emitting device of claim 1, wherein the first compound represented by Formula 1 includes at least one compound selected from Compound Group 1: 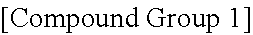 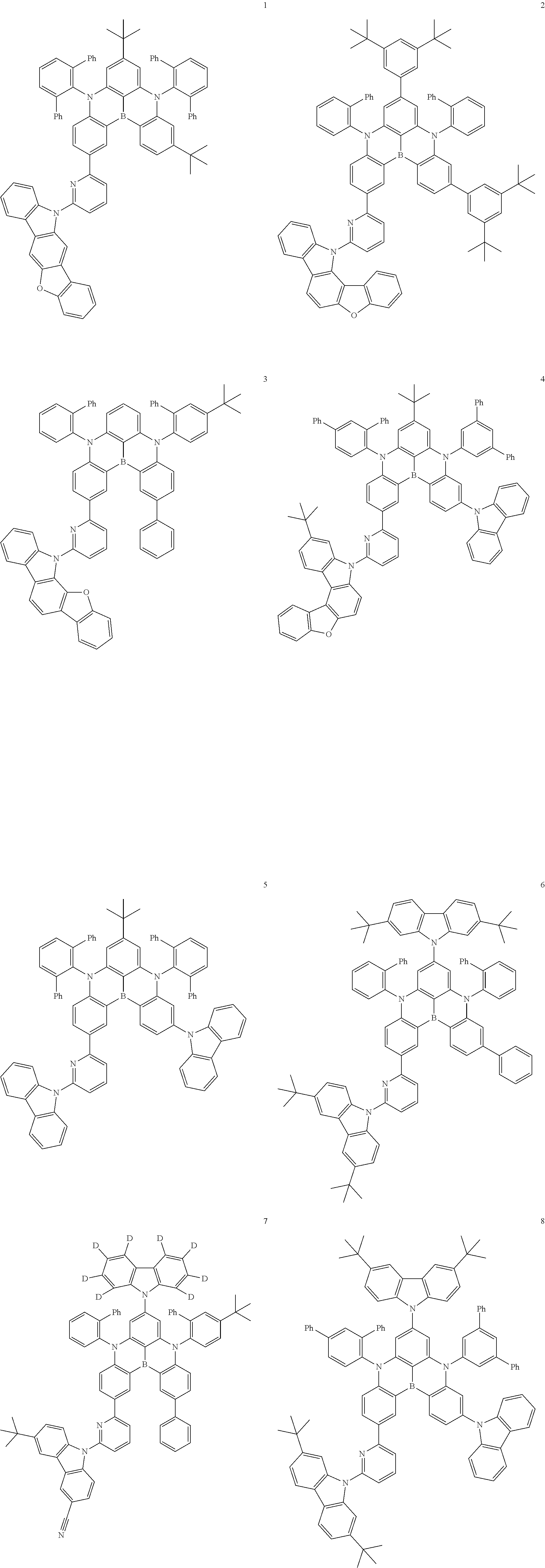 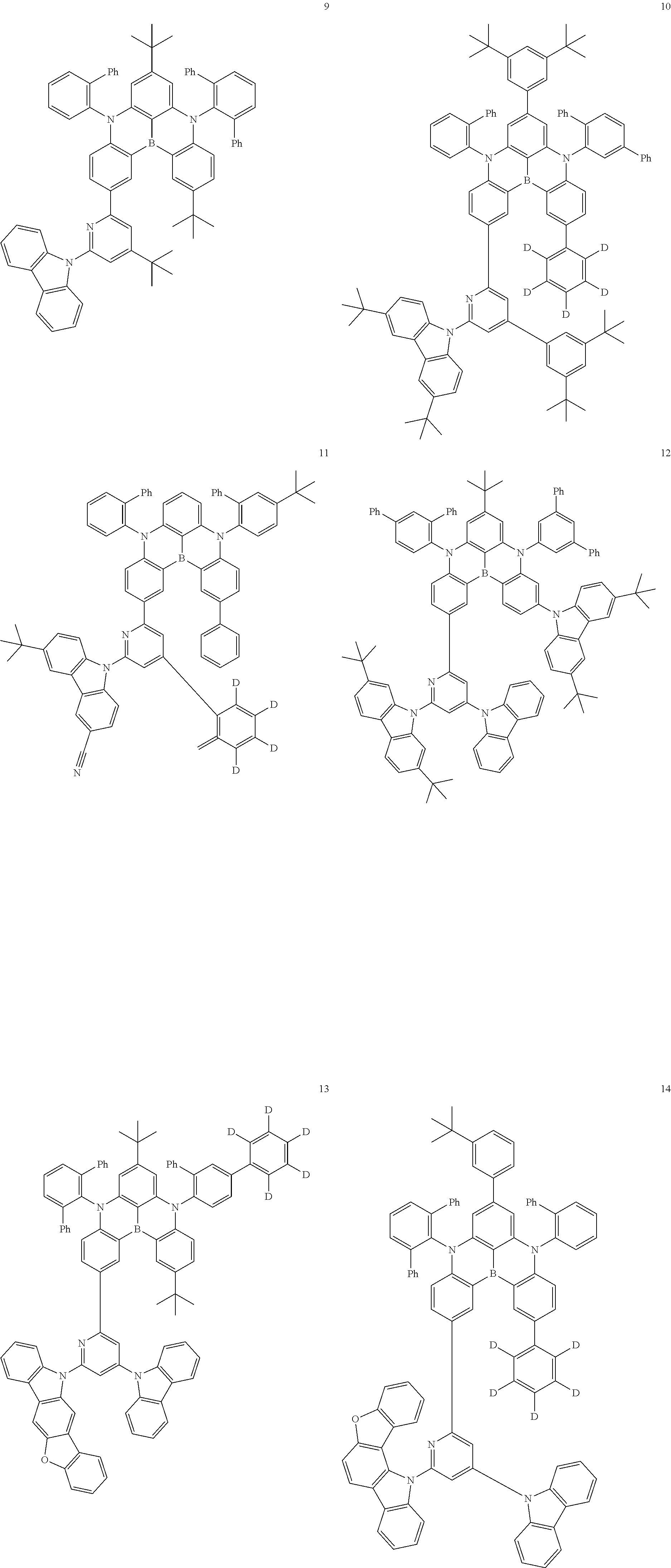 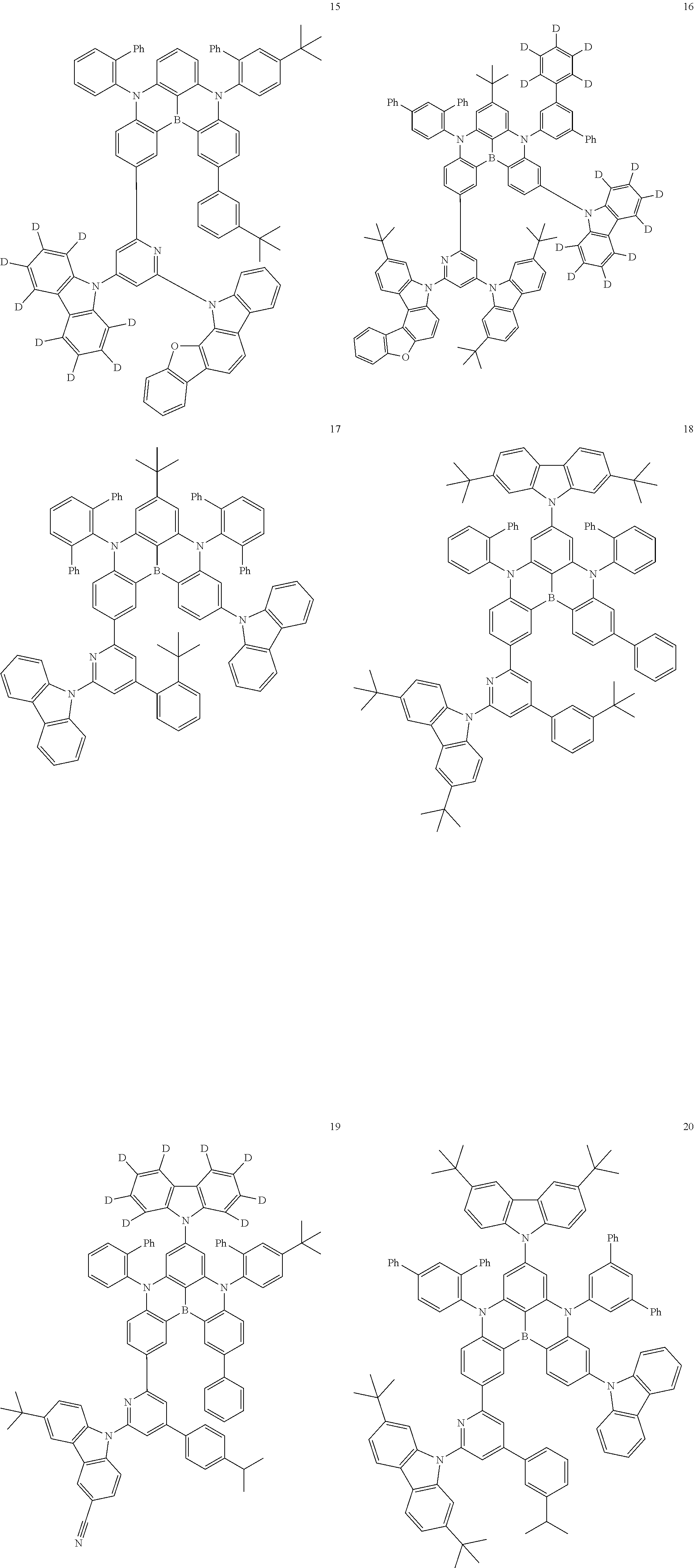 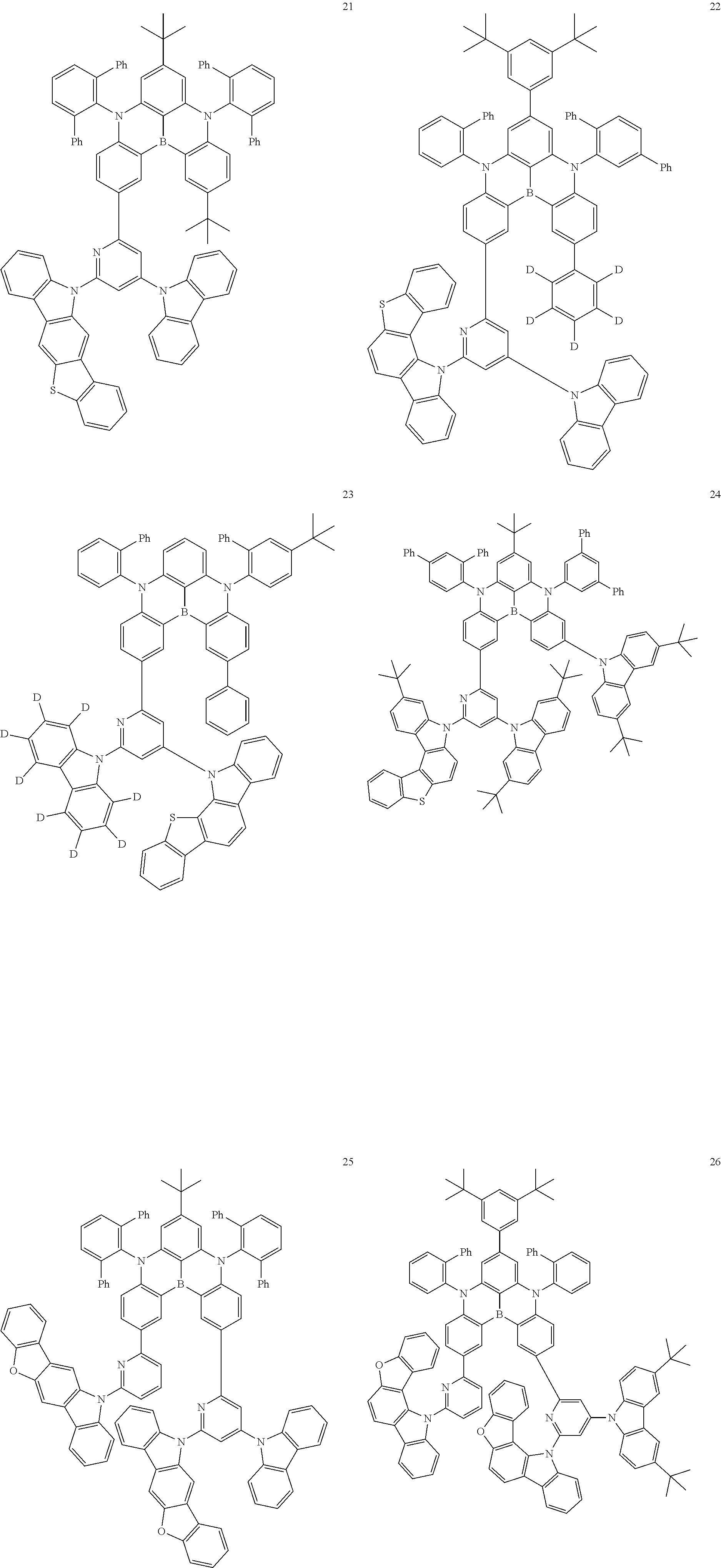 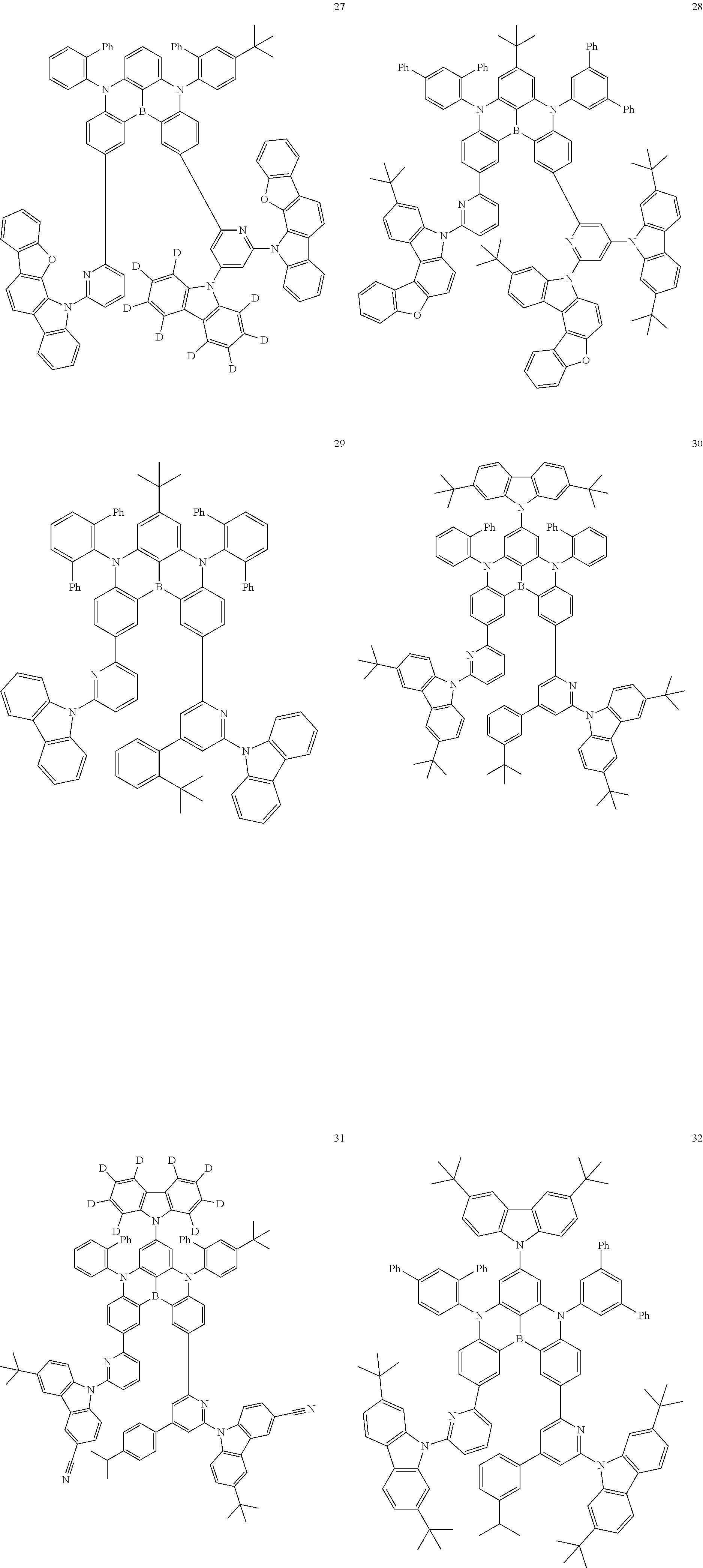 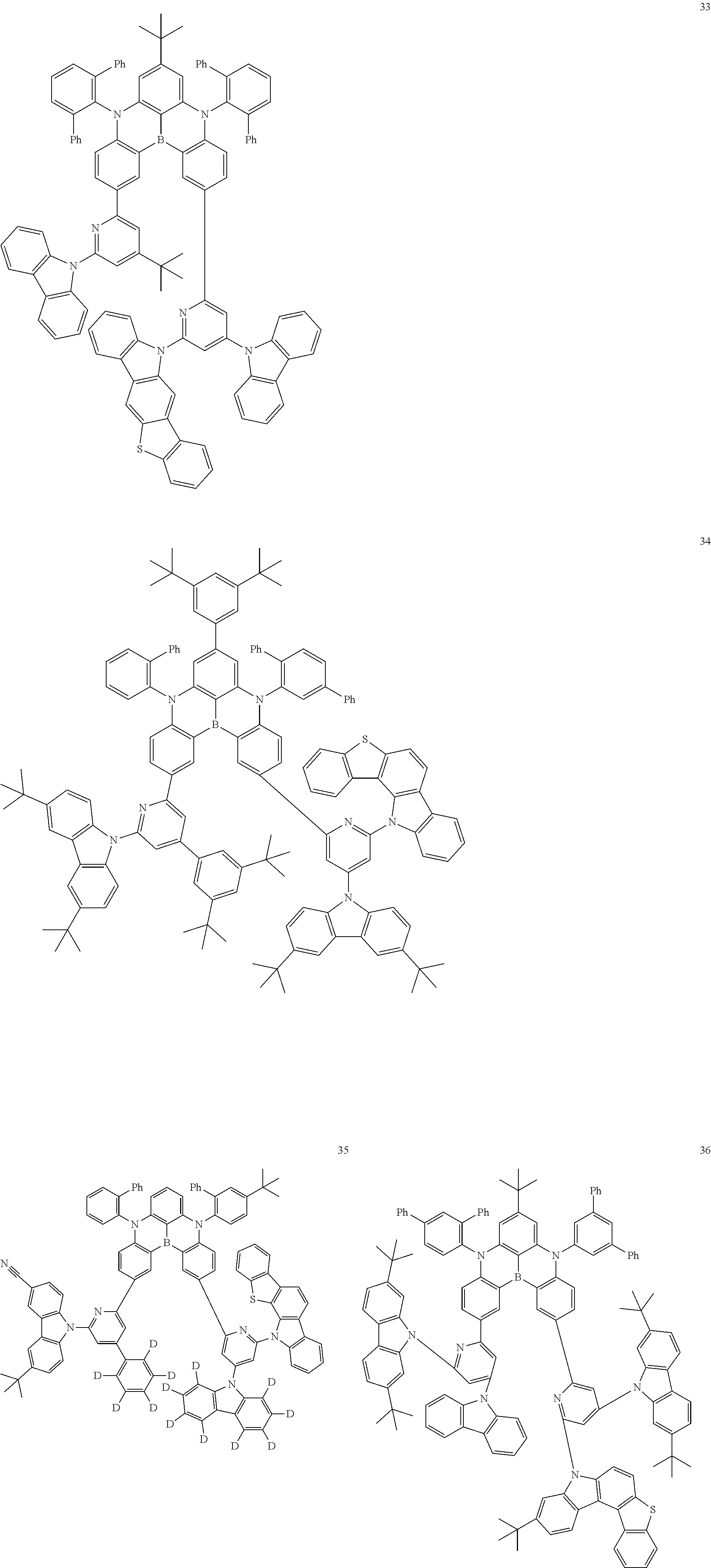 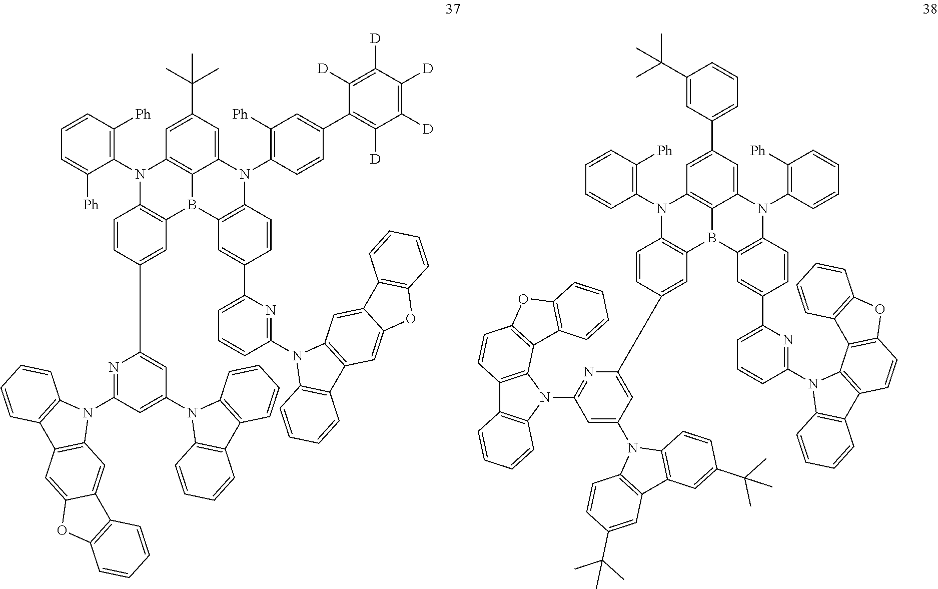 [SMILES: [2H]c1c([2H])c([2H])c(-c2ccc(N3c4ccc(-c5cccc(-n6c7ccccc7c7cc8oc9ccccc9c8cc76)n5)cc4B4c5cc(-c6cc(-n7c8ccccc8c8ccccc87)cc(-n7c8ccccc8c8cc9oc%10ccccc%10c9cc87)n6)ccc5N(c5c(-c6ccccc6)cccc5-c5ccccc5)c5cc(C(C)(C)C)cc3c54)c(-c3ccccc3)c2)c([2H])c1[2H] ; CC(C)(C)c1cccc(-c2cc3c4c(c2)N(c2ccccc2-c2ccccc2)c2ccc(-c5cc(-n6c7ccc(C(C)(C)C)cc7c7cc(C(C)(C)C)ccc76)cc(-n6c7ccccc7c7ccc8oc9ccccc9c8c76)n5)cc2B4c2cc(-c4cccc(-n5c6ccccc6c6ccc7oc8ccccc8c7c65)n4)ccc2N3c2ccccc2-c2ccccc2)c1] 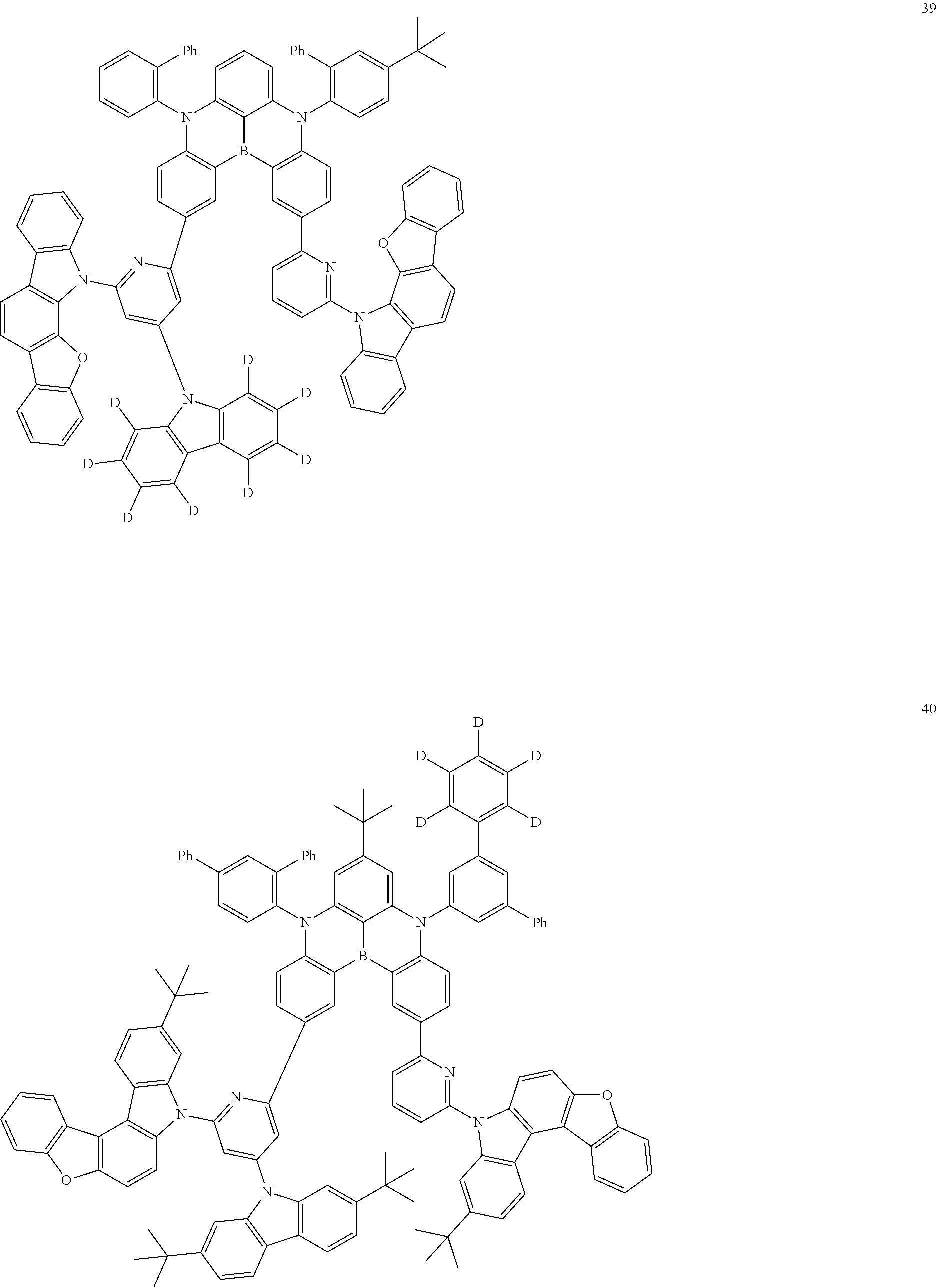 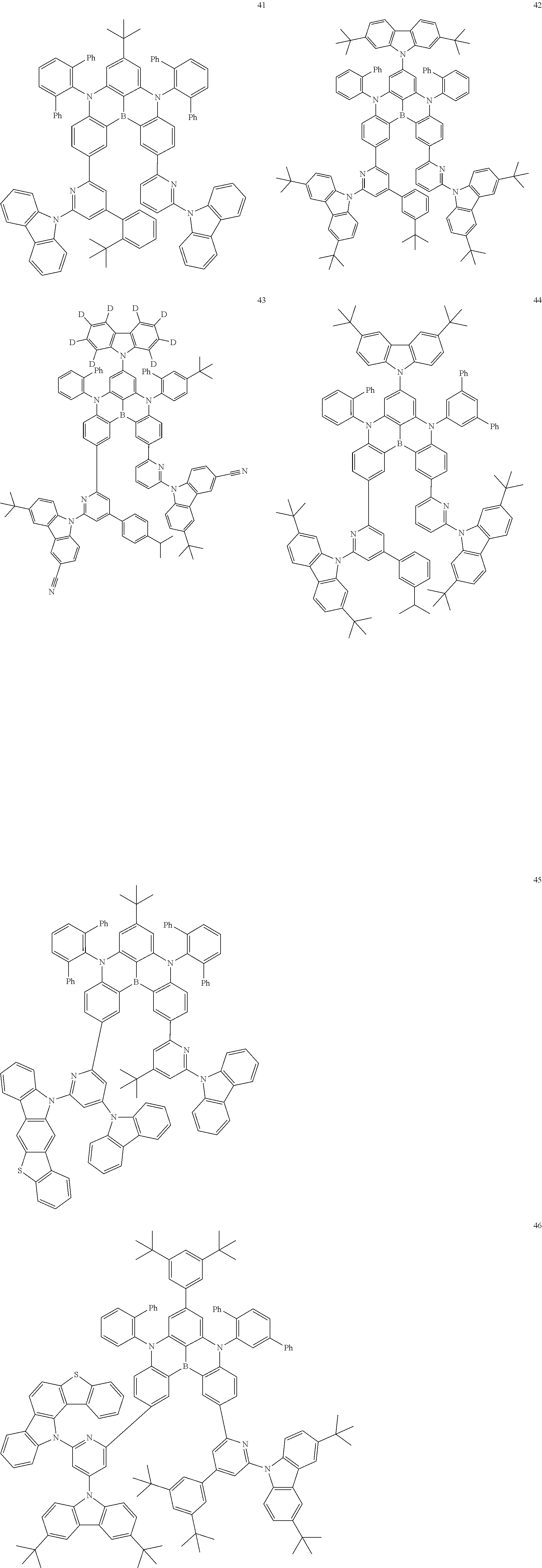 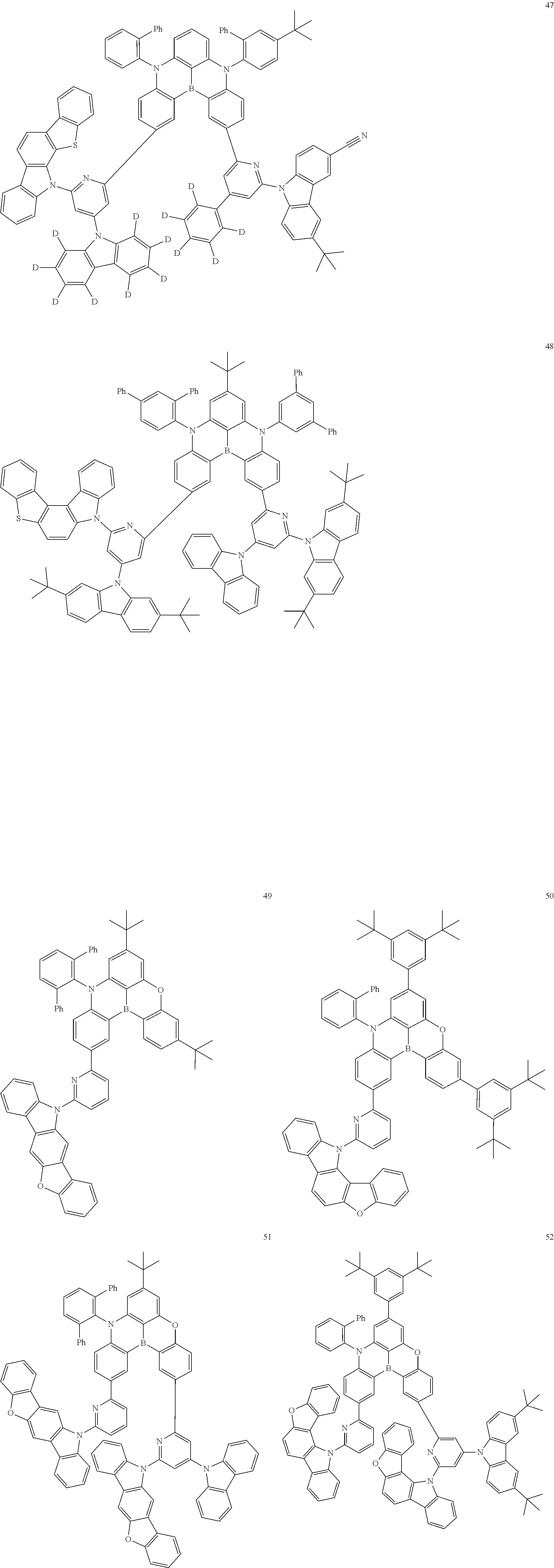 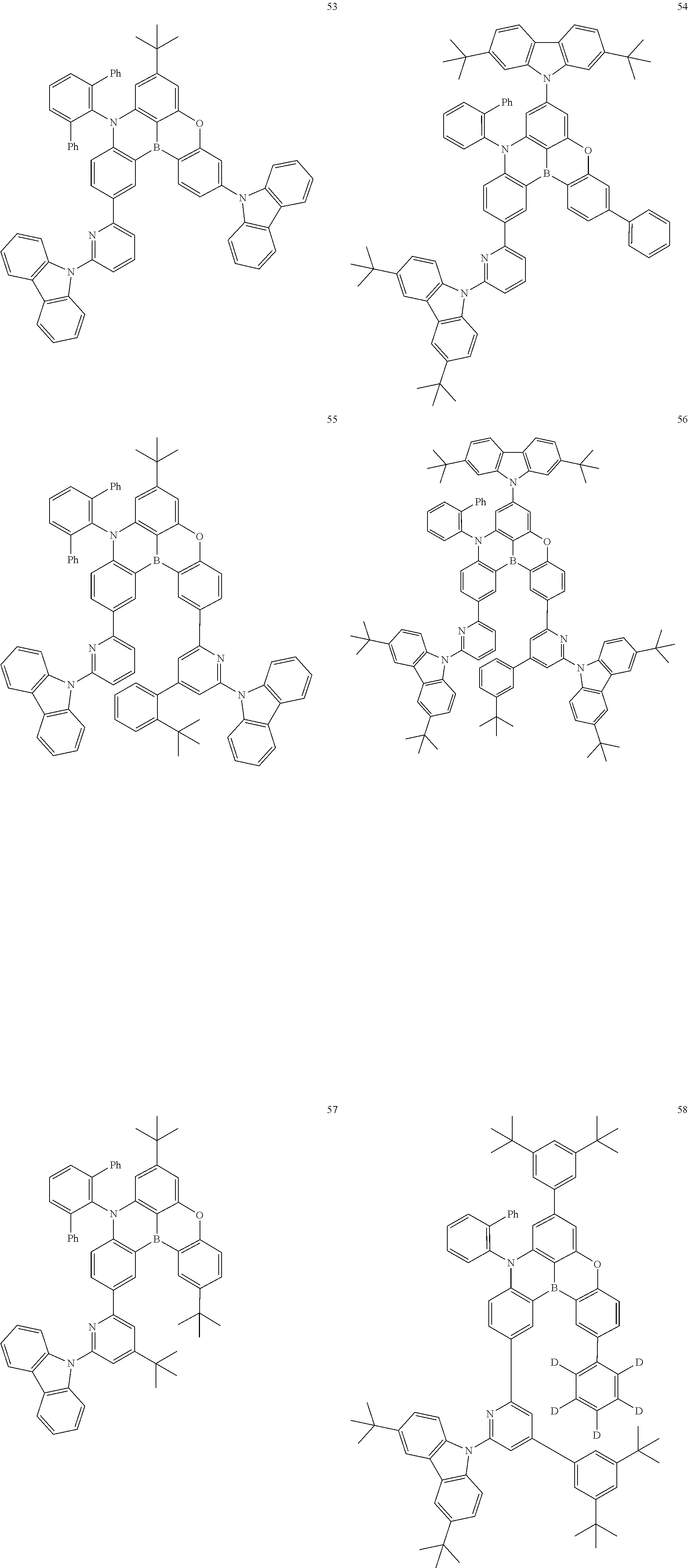 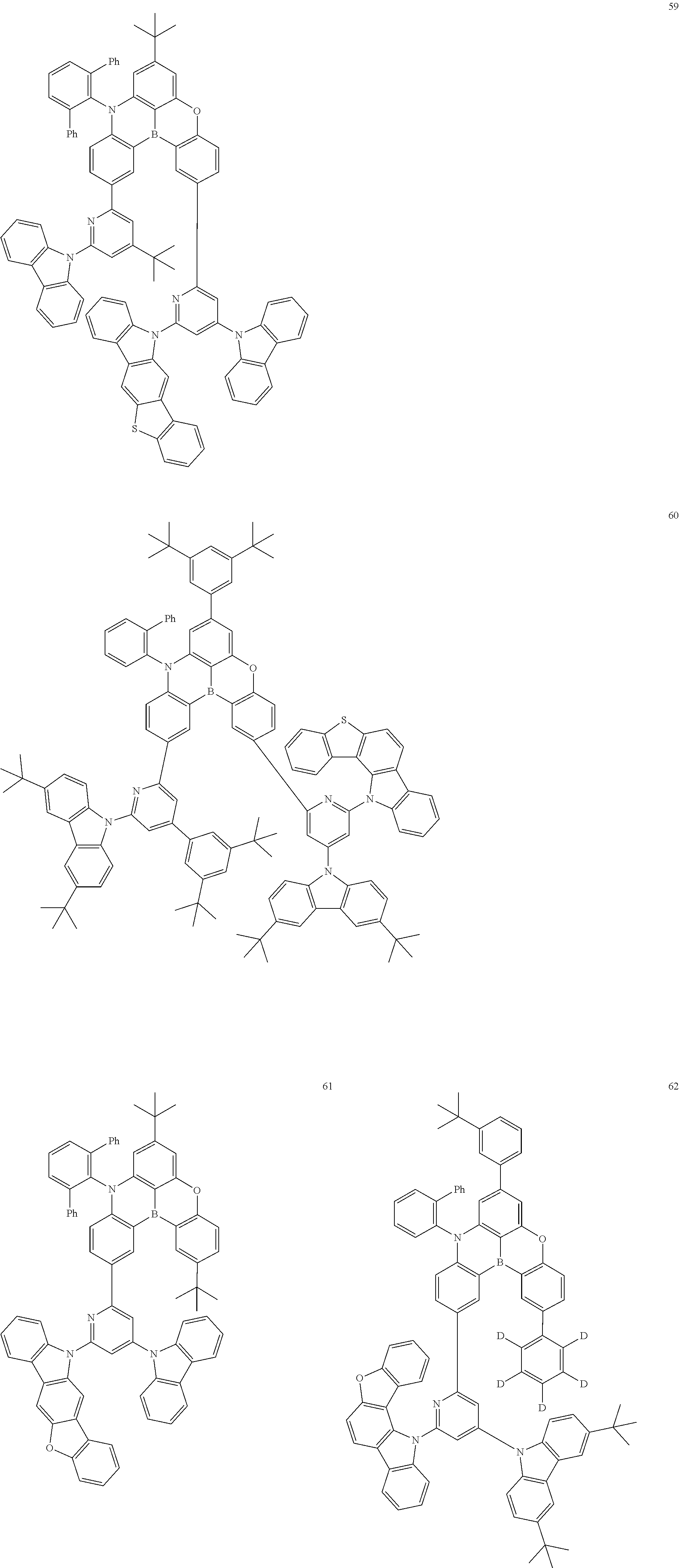 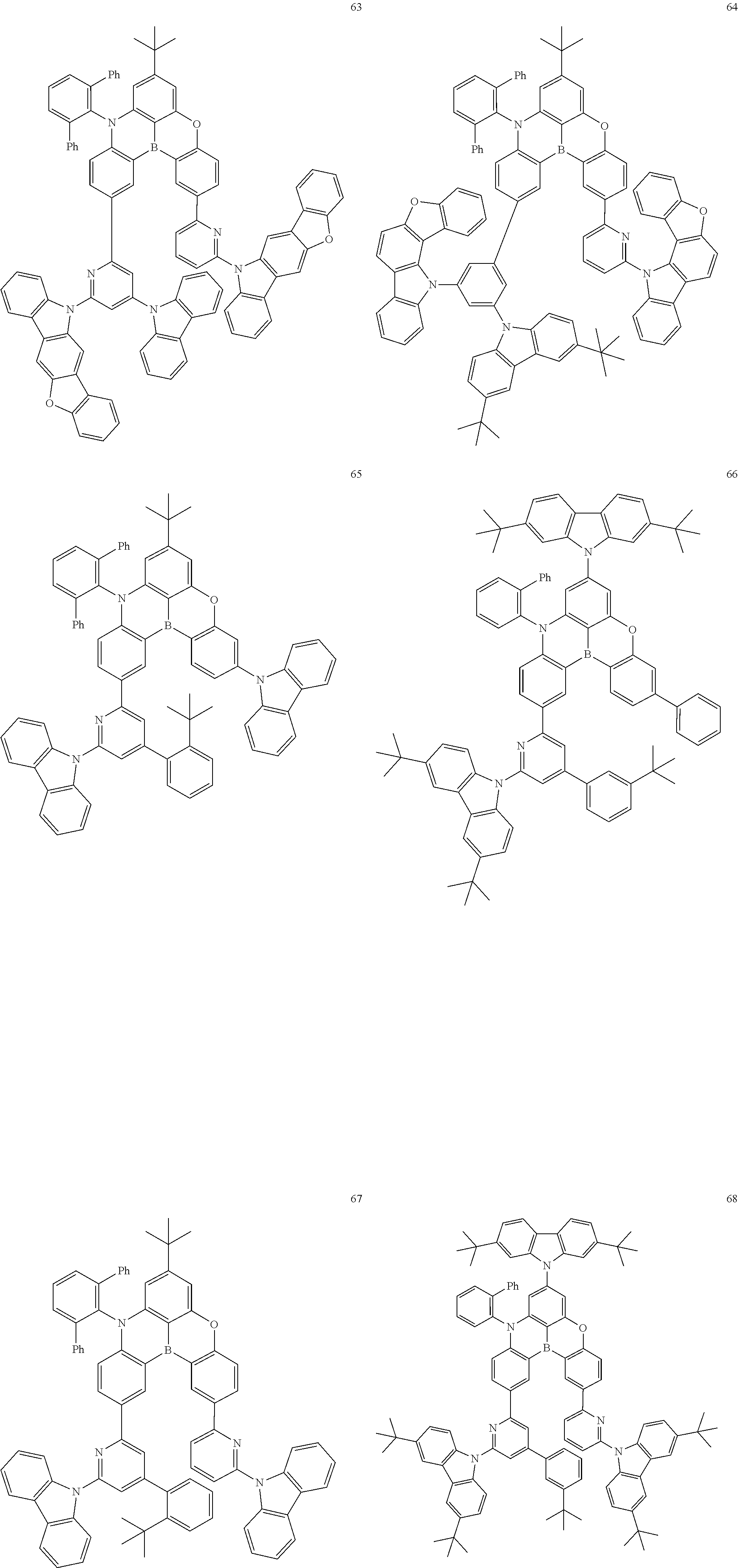 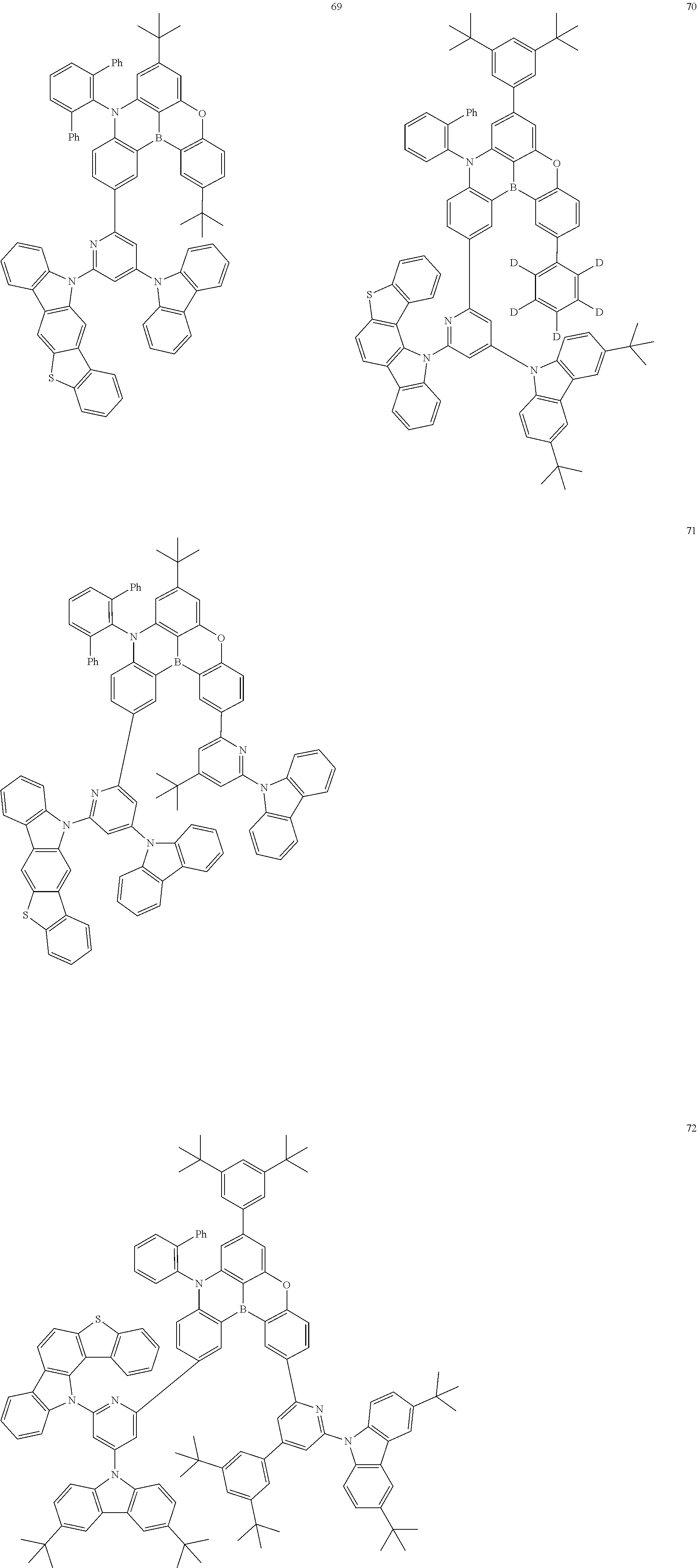 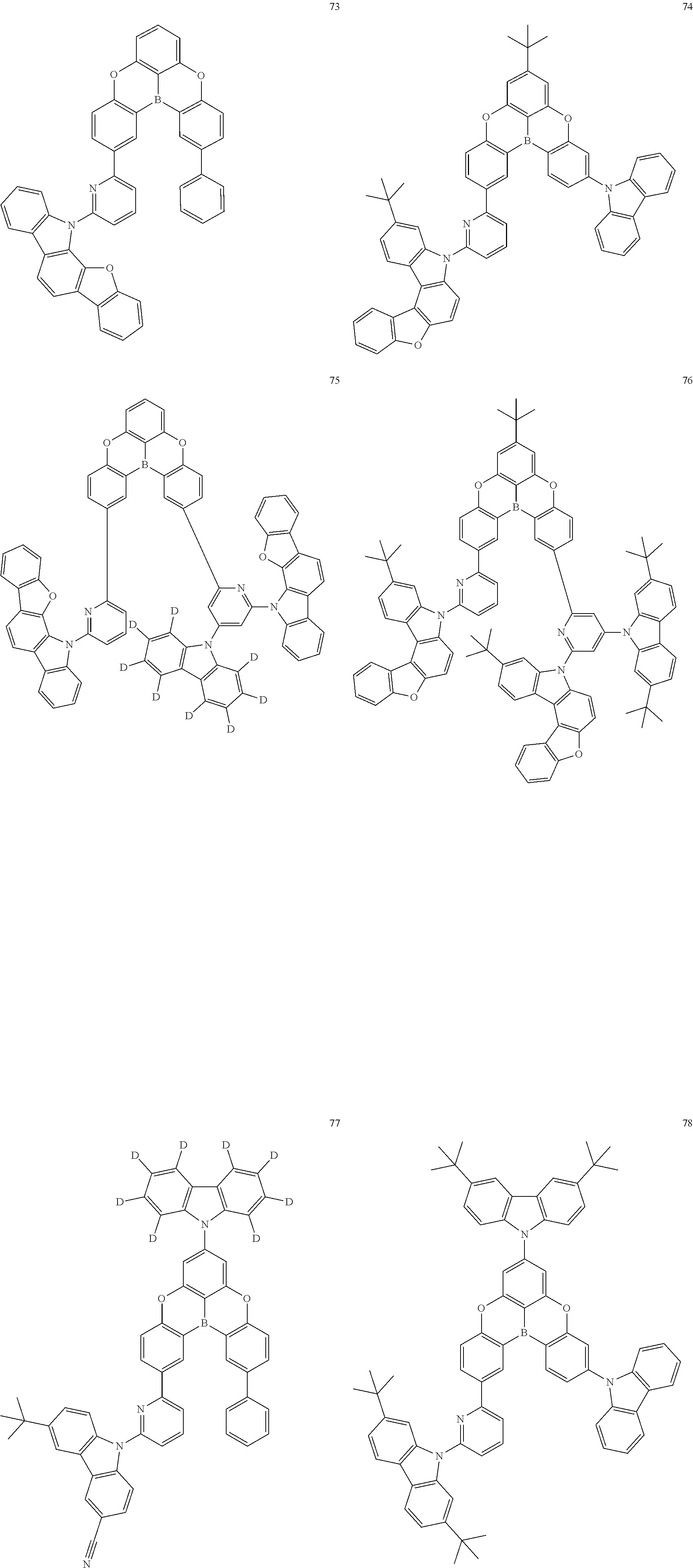 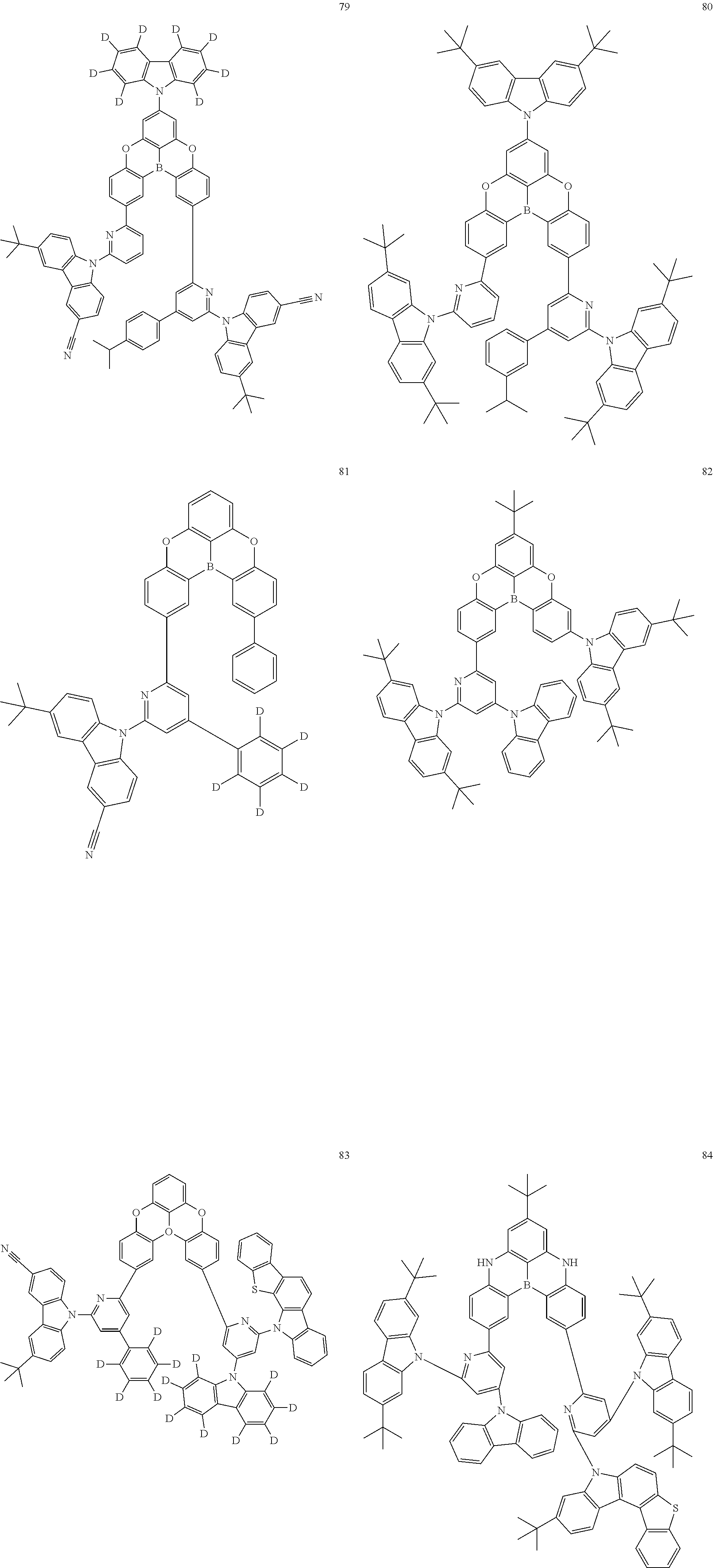 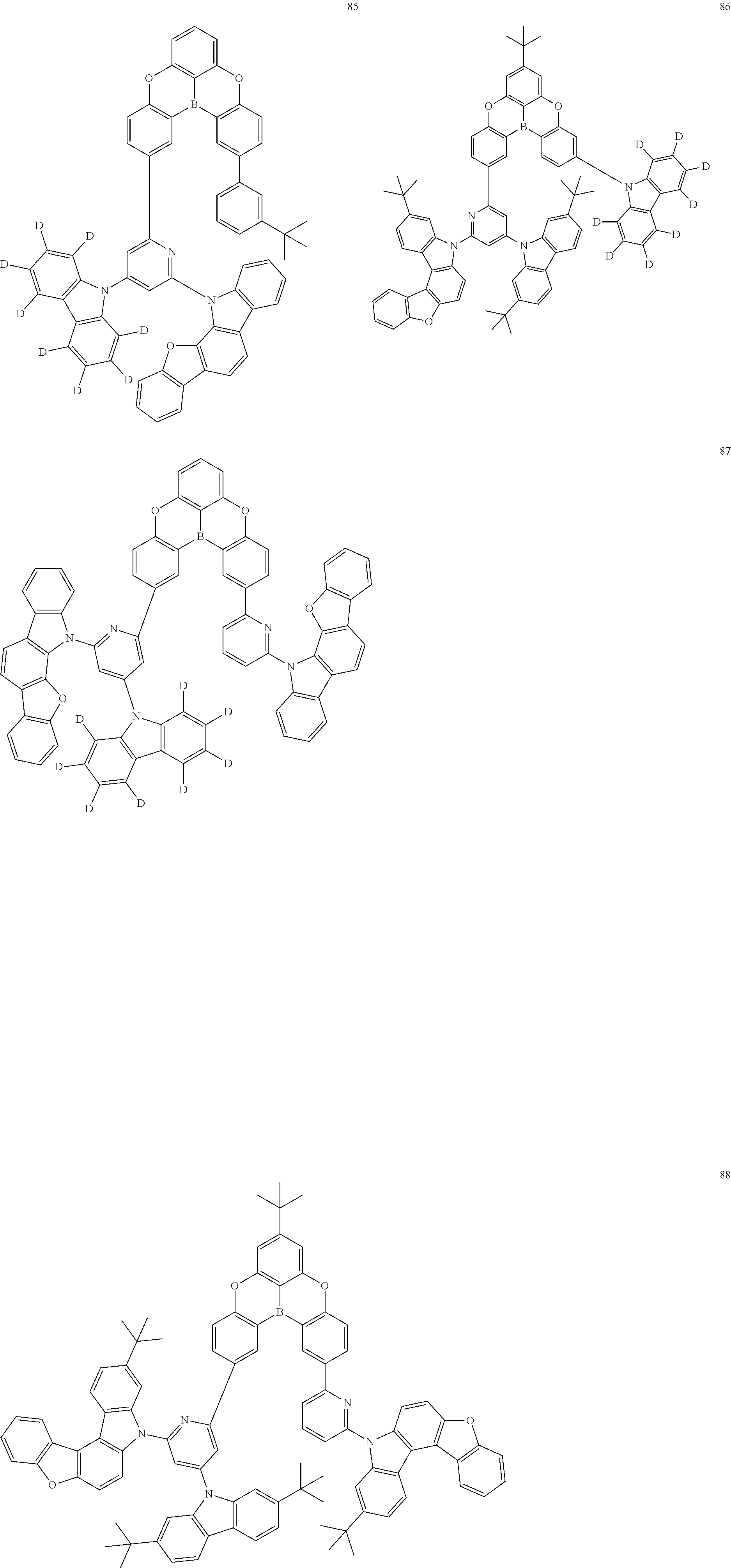 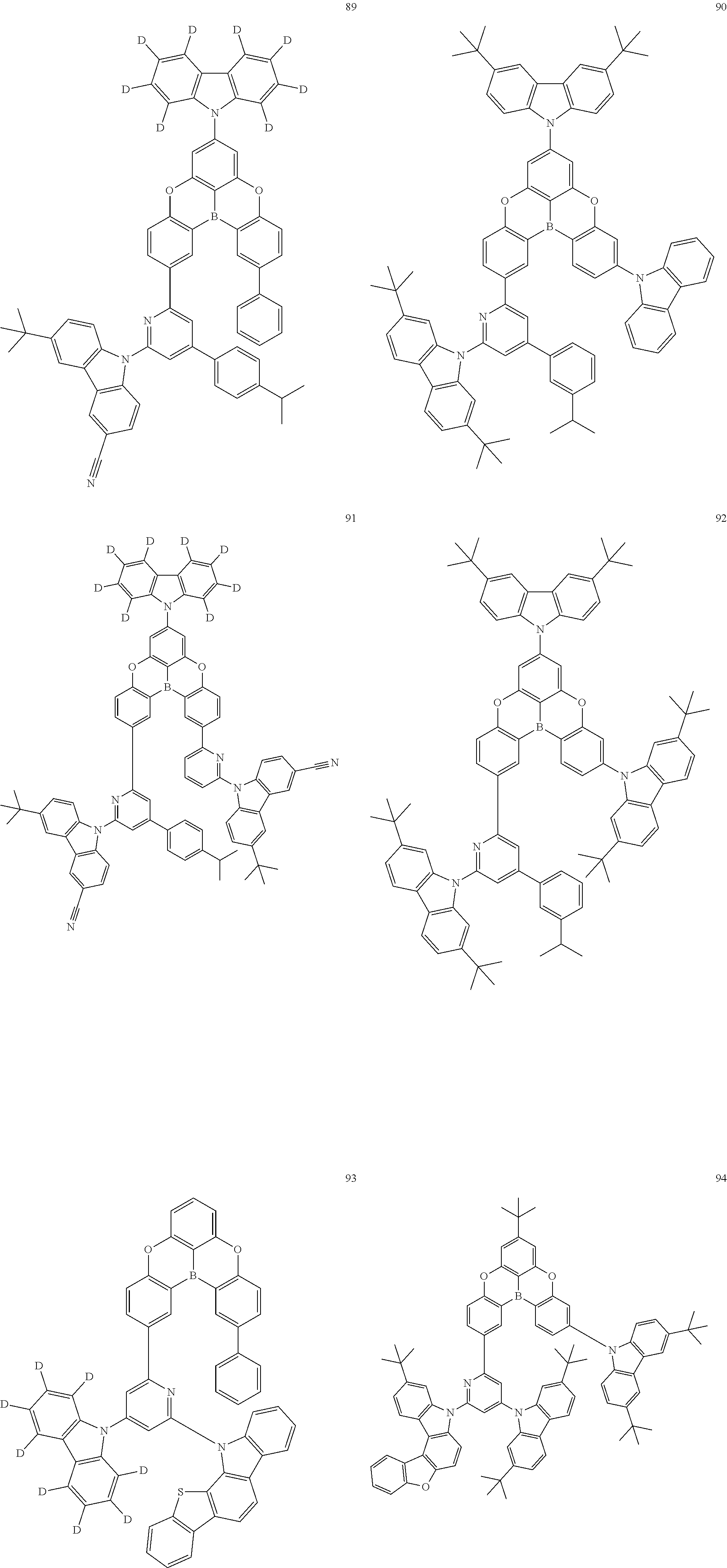 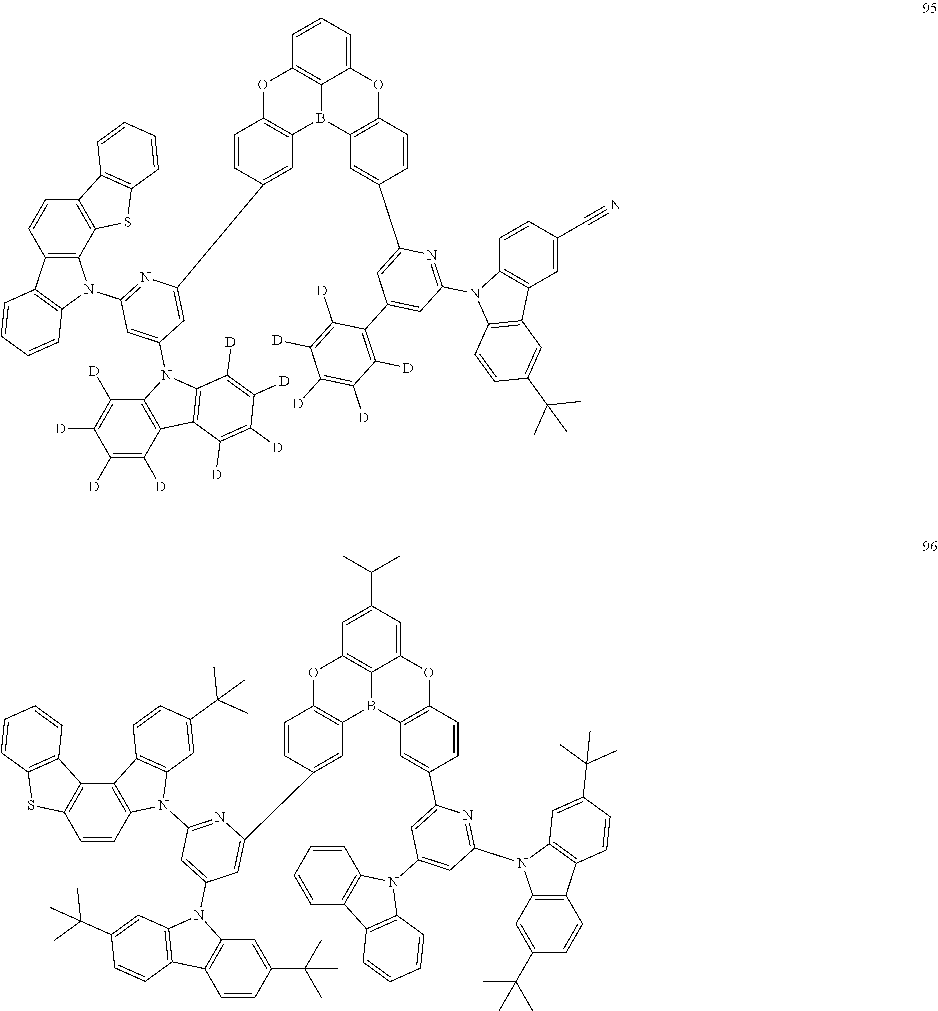 [SMILES: [2H]c1c([2H])c([2H])c(-c2cc(-c3ccc4c(c3)B3c5cc(-c6cc(-n7c8c([2H])c([2H])c([2H])c([2H])c8c8c([2H])c([2H])c([2H])c([2H])c87)cc(-n7c8ccccc8c8ccc9c%10ccccc%10sc9c87)n6)ccc5Oc5cccc(c53)O4)nc(-n3c4ccc(C#N)cc4c4cc(C(C)(C)C)ccc43)c2)c([2H])c1[2H] ; CC(C)c1cc2c3c(c1)Oc1ccc(-c4cc(-n5c6cc(C(C)(C)C)ccc6c6ccc(C(C)(C)C)cc65)cc(-n5c6cc(C(C)(C)C)ccc6c6c7c(ccc65)sc5ccccc57)n4)cc1B3c1cc(-c3cc(-n4c5ccccc5c5ccccc54)cc(-n4c5cc(C(C)(C)C)ccc5c5ccc(C(C)(C)C)cc54)n3)ccc1O2]
wherein in Compound Group 1,
D represents a deuterium atom, and
Ph represents a substituted or unsubstituted phenyl group.

11. The light emitting device of claim 1, wherein
the at least one functional layer comprises:
an emission layer;
a hole transport region disposed between the first electrode and the emission layer; and
an electron transport region disposed between the emission layer and the second electrode, and
the emission layer comprises:
the first compound; and
at least one of the second compound or the third compound.

12. The light emitting device of claim 11, wherein the emission layer emits delayed fluorescence.

13. The light emitting device of claim 1, wherein the at least one functional layer comprises the first compound, the second compound, and the third compound.

14. The light emitting device of claim 2, wherein the at least one functional layer comprises the first compound, the second compound, the third compound, and the fourth compound.

15. A light emitting device comprising:
a first electrode;
a second electrode facing the first electrode; and
an emission layer disposed between the first electrode and the second electrode, wherein
the emission layer comprises a compound represented by Formula 1: 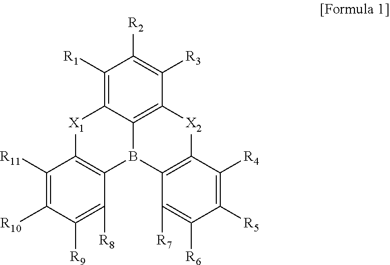
wherein in Formula 1,
X₁ and X₂ are each independently N(R₁₂) or O,
R₁ to R₁₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
at least one of R₆ or R₉ is a group represented by Formula 2: 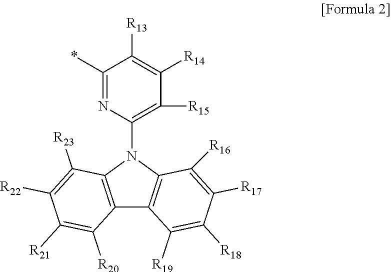
wherein in Formula 2,
R₁₃ to R₂₃ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
—* represents a bonding site to Formula 1.

16. The light emitting device of claim 15, wherein the compound represented by Formula 1 is represented by Formula 1-1a or Formula 1-1b: 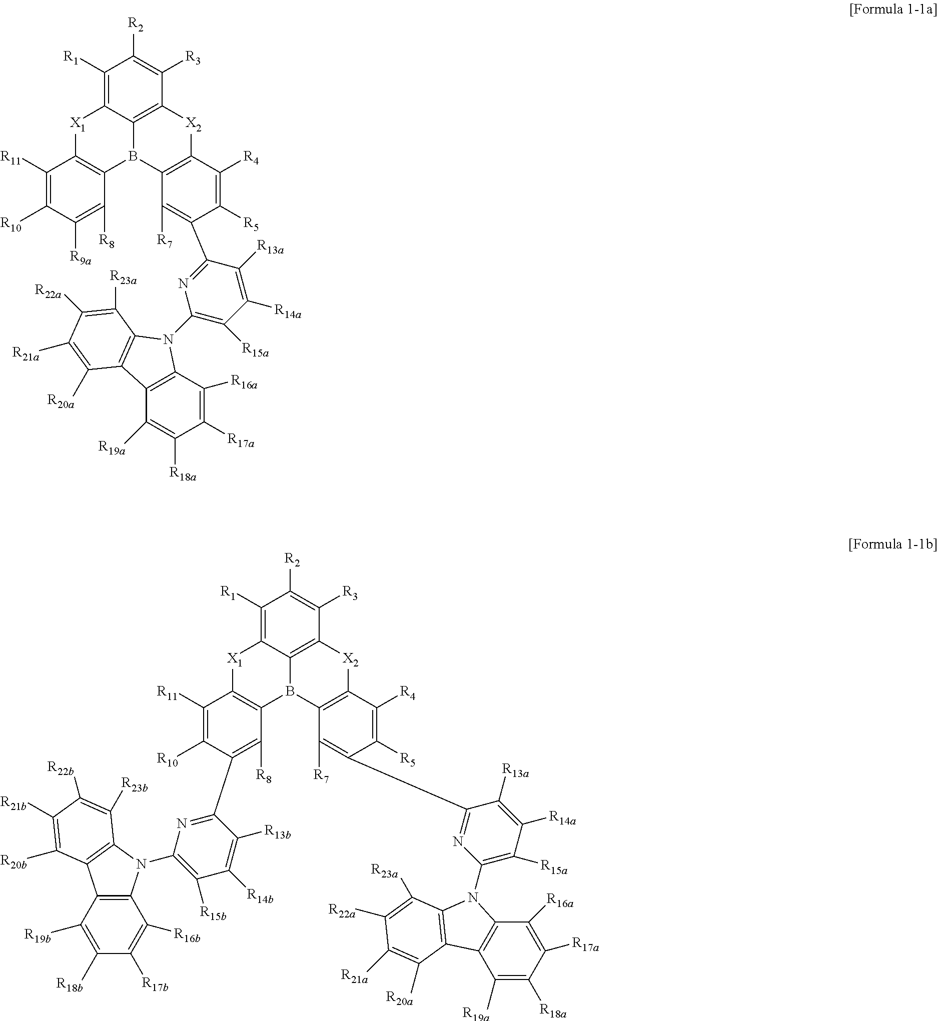
wherein in Formula 1-1a and Formula 1-1b,
R₉ₐ, R₁₃ₐ to R₂₃ₐ, and R_{13b} to R_{23b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
X₁, X₂, R₁ to R₅, R₇, R₈, R₁₀, and R₁₁ are each the same as defined in Formula 1.

17. The light emitting device of claim 15, wherein Formula 2 is represented by one of Formula 2-1 to Formula 2-7: 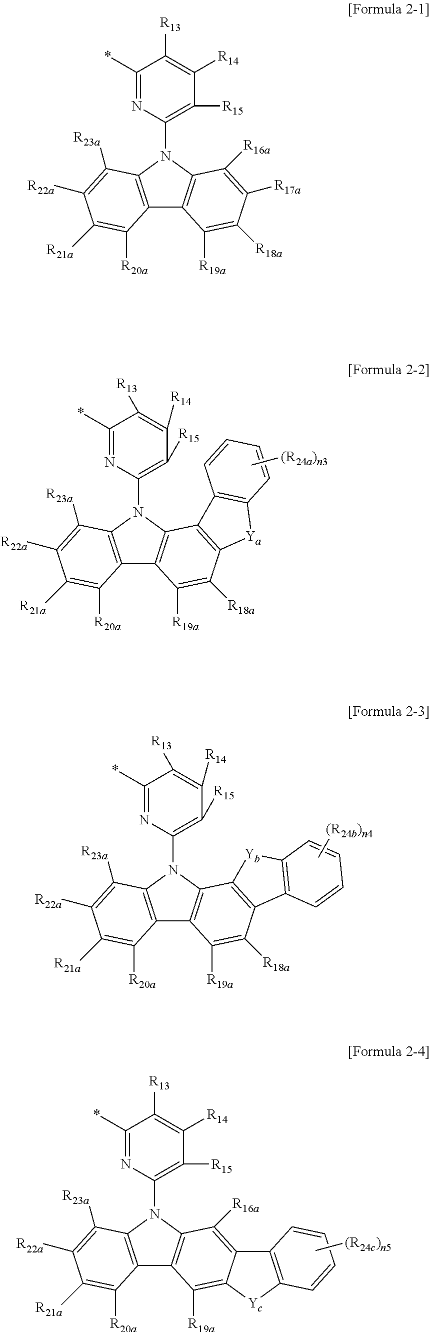 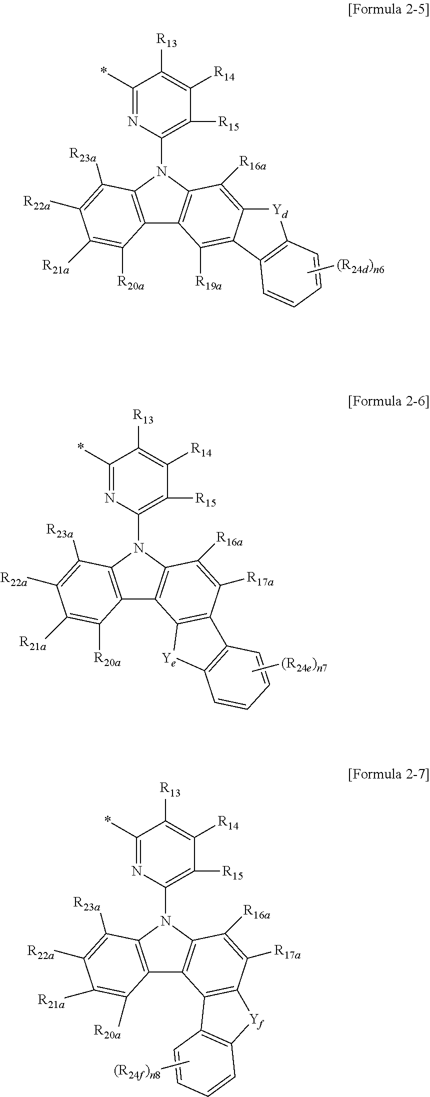
wherein in Formula 2-1 to Formula 2-7,
Yₐ to Y_{f} are each independently O or S,
R₁₆ₐ to R₂₃ₐ and R₂₄ₐ to R_{24f} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
n3 to n8 are each independently an integer from 0 to 4, and
R₁₃ to R₁₅ and —* are each the same as defined in Formula 2.

18. A polycyclic compound represented by Formula 1: 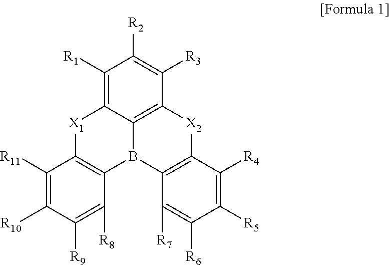
wherein in Formula 1,
X₁ and X₂ are each independently N(R₁₂) or O,
R₁ to R₁₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
at least one of R₆ or R₉ is a group represented by Formula 2: 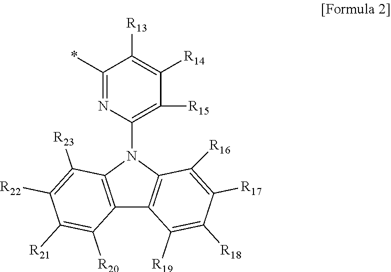
wherein in Formula 2,
R₁₃ to R₂₃ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
—* represents a bonding site to Formula 1.

19. The polycyclic compound of claim 18, wherein the polycyclic compound represented by Formula 1 is represented by Formula 1-1a or Formula 1-1b: 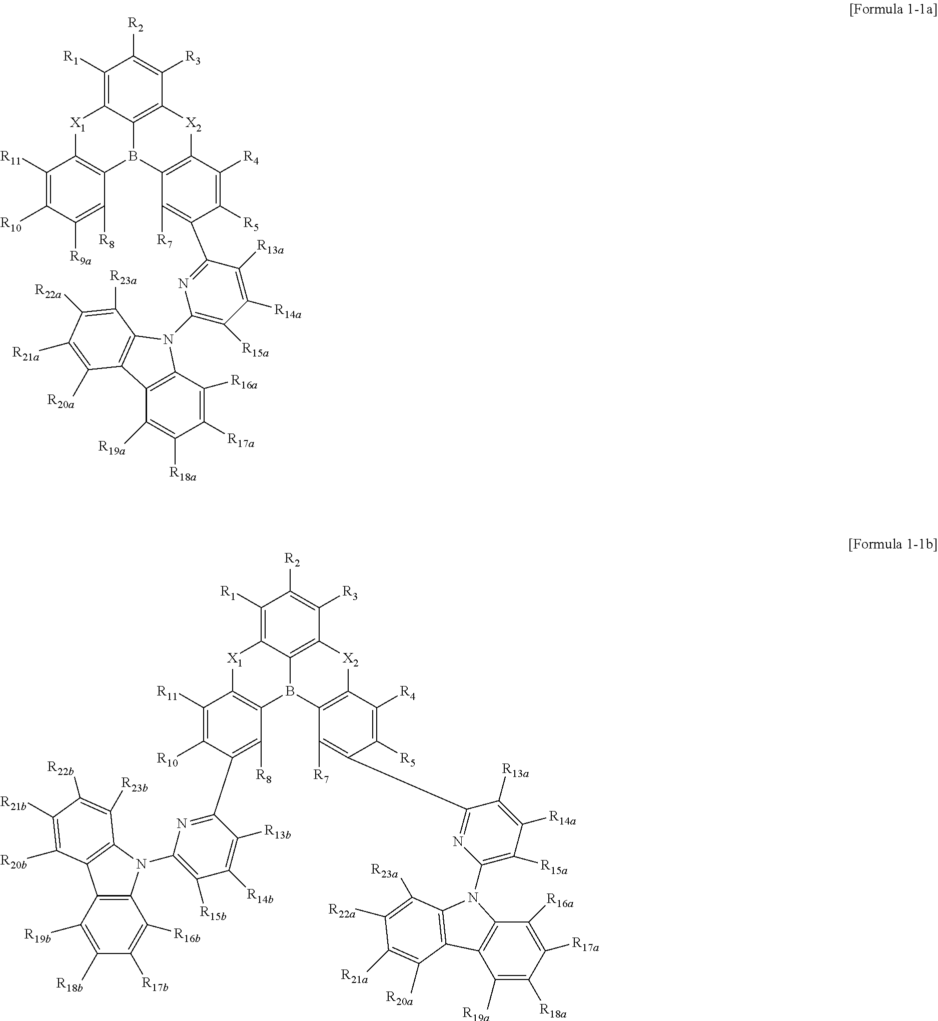
wherein in Formula 1-1a and Formula 1-1b,
R₉ₐ, R₁₃ₐ to R₂₃ₐ, and R_{13b} to R_{23b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
X₁, X₂, R₁ to R₅, R₇, R₈, R₁₀, and R₁₁ are each the same as defined in Formula 1.

20. The polycyclic compound of claim 19, wherein in Formula 1-1a and Formula 1-1b,
R₁ to R₅, R₇, R₈, R₉ₐ, R₁₀ and R₁₁ are each independently a hydrogen atom, a deuterium atom, a substituted or unsubstituted t-butyl group, a substituted or unsubstituted phenyl group, or a substituted or unsubstituted carbazole group, and
R₁₂ is a substituted or unsubstituted phenyl group, a substituted or unsubstituted biphenyl group, or a substituted or unsubstituted terphenyl group.

21. The polycyclic compound of claim 18, wherein the polycyclic compound represented by Formula 1 is represented by one of Formula 1-2a to Formula 1-2c: 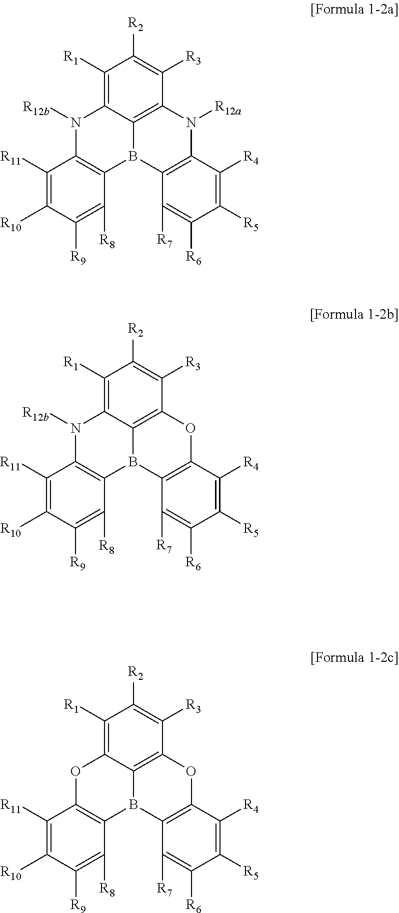
wherein in Formula 1-2a to Formula 1-2c,
R₁₂ₐ and R_{12b} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and
R₁ to R₁₁ are each the same as defined in Formula 1.

22. The polycyclic compound of claim 18, wherein Formula 2 is represented by one of Formula 2-1 to Formula 2-7: 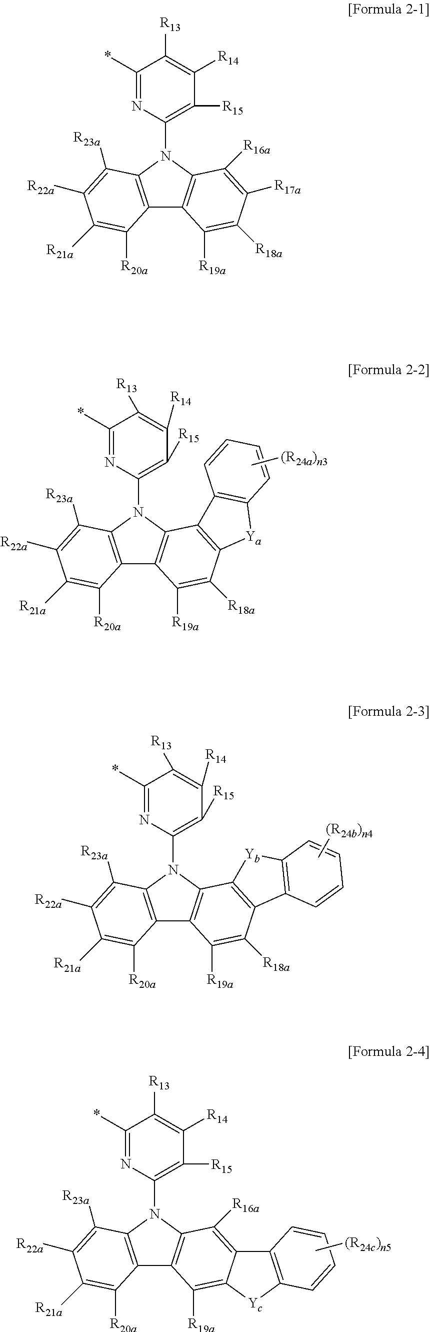 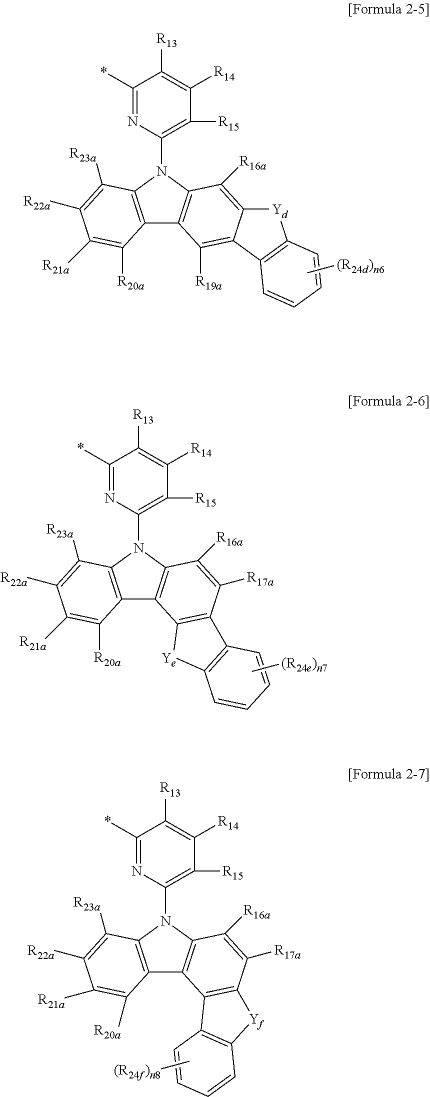
wherein in Formula 2-1 to Formula 2-7,
Yₐ to Y_{f} are each independently O or S,
R₁₆ₐ to R₂₃ₐ and R₂₄ₐ to R_{24f} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
n3 to n8 are each independently an integer from 0 to 4, and
R₁₃ to R₁₅ and —* are each the same as defined in Formula 2.

23. The polycyclic compound of claim 22, wherein in Formula 2-1 to Formula 2-7, R₁₃ to R₁₅, R₁₆ₐ to R₂₃ₐ, and R₂₄ₐ to R_{24f} are each independently a hydrogen atom, a deuterium atom, a cyano group, a substituted or unsubstituted t-butyl group, a substituted or unsubstituted phenyl group, or a substituted or unsubstituted carbazole group.

24. The polycyclic compound of claim 18, wherein the polycyclic compound represented by Formula 1 is selected from Compound Group 1: 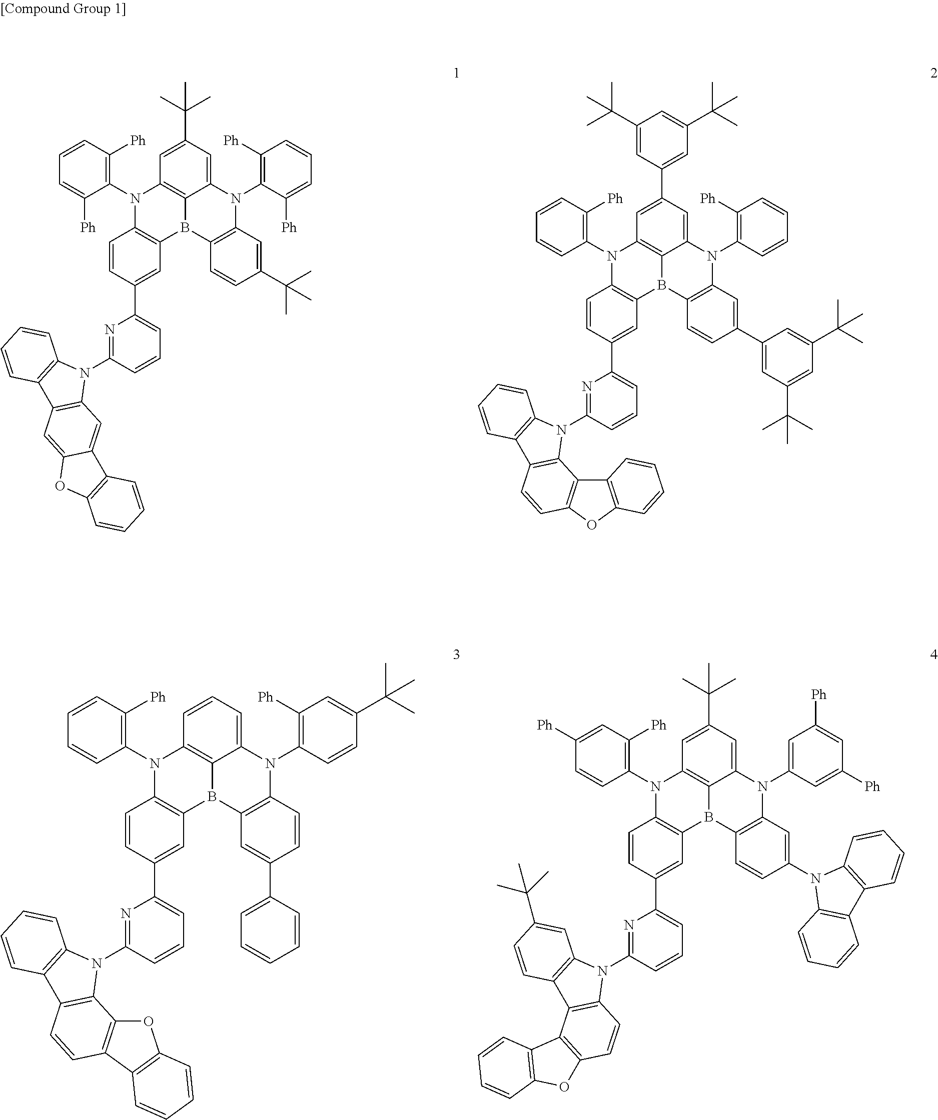 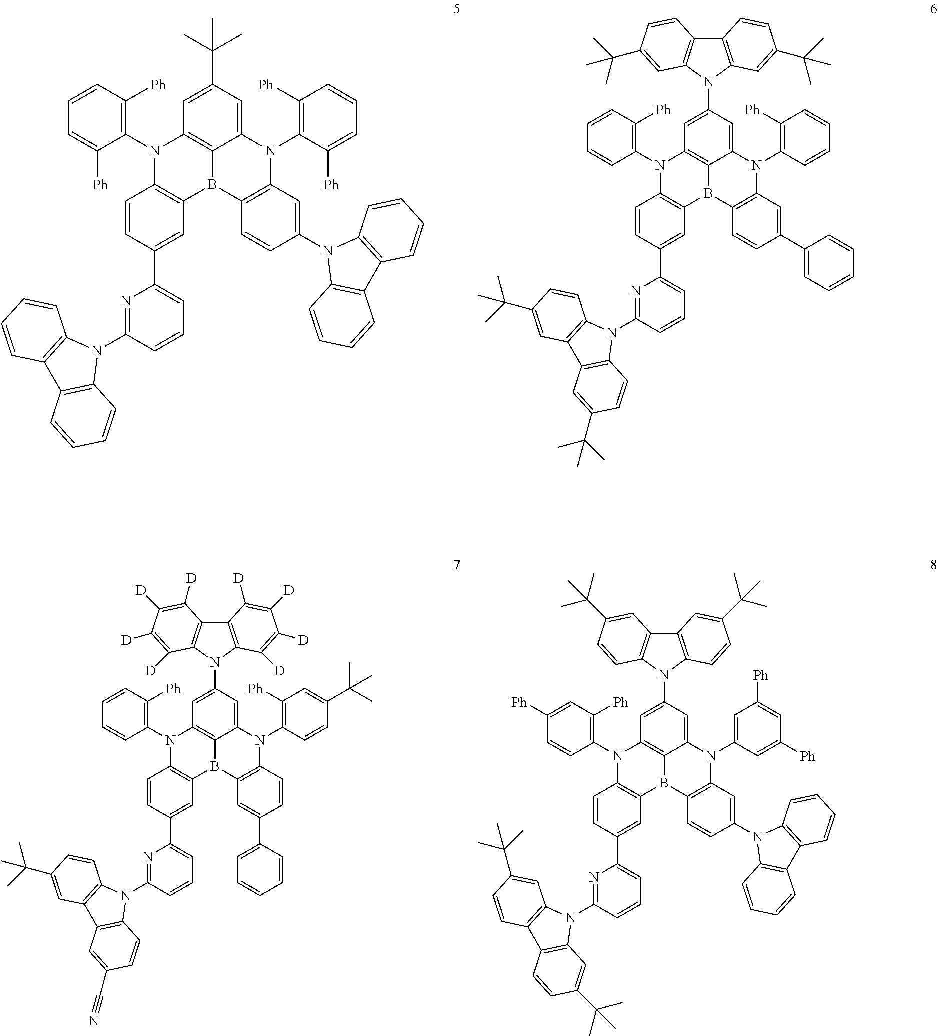 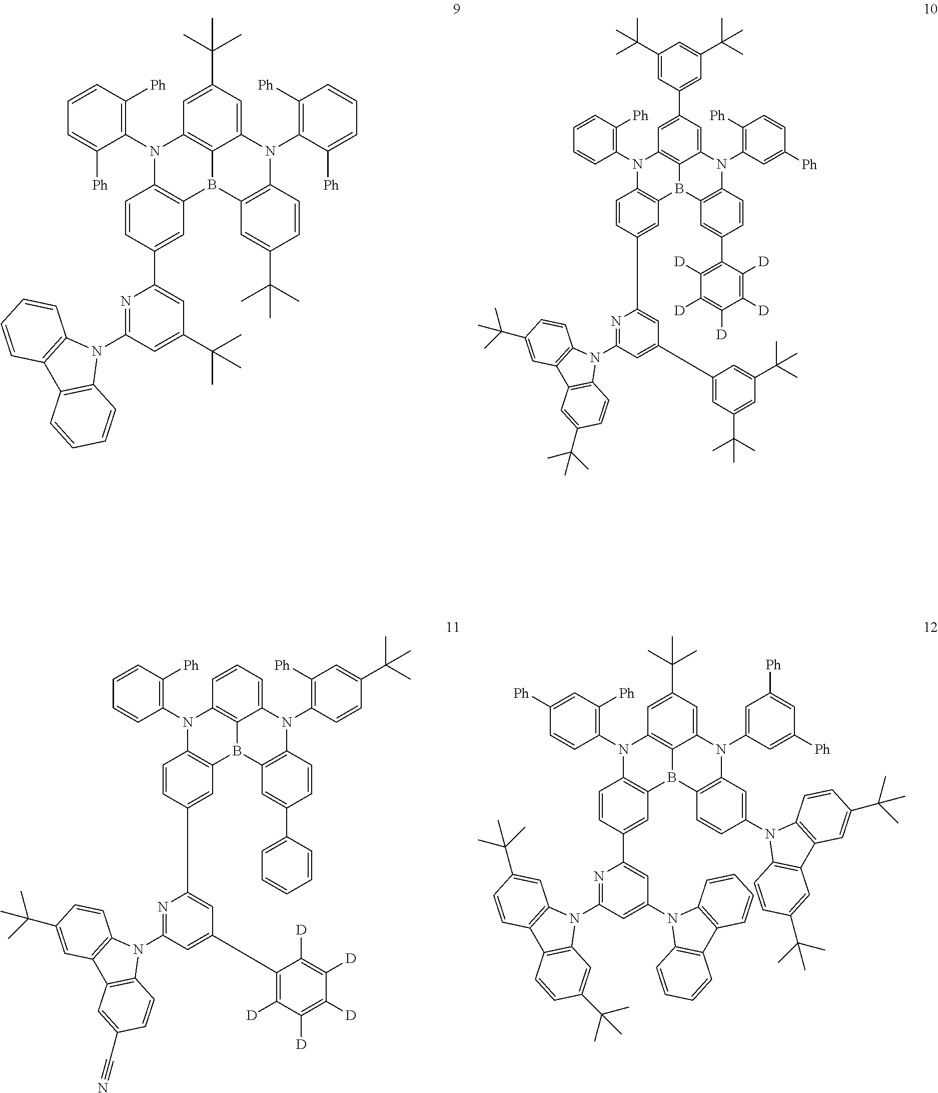 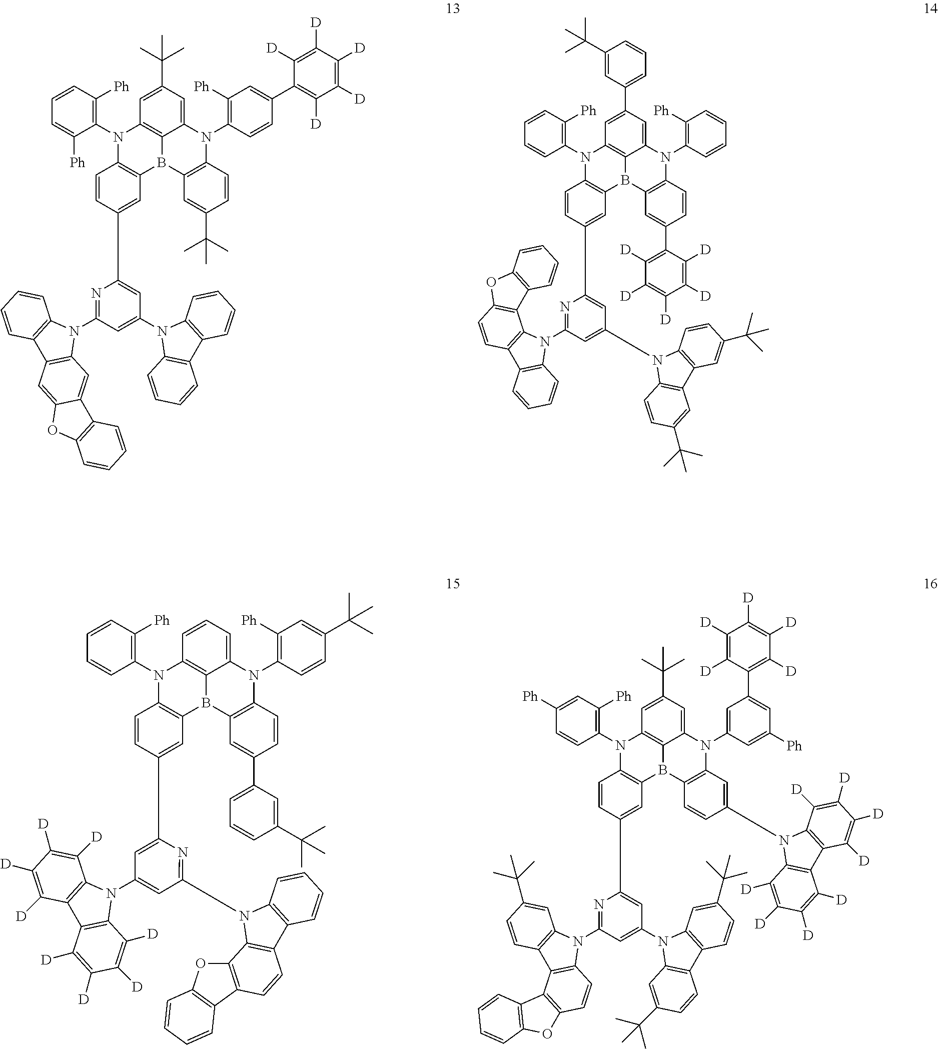 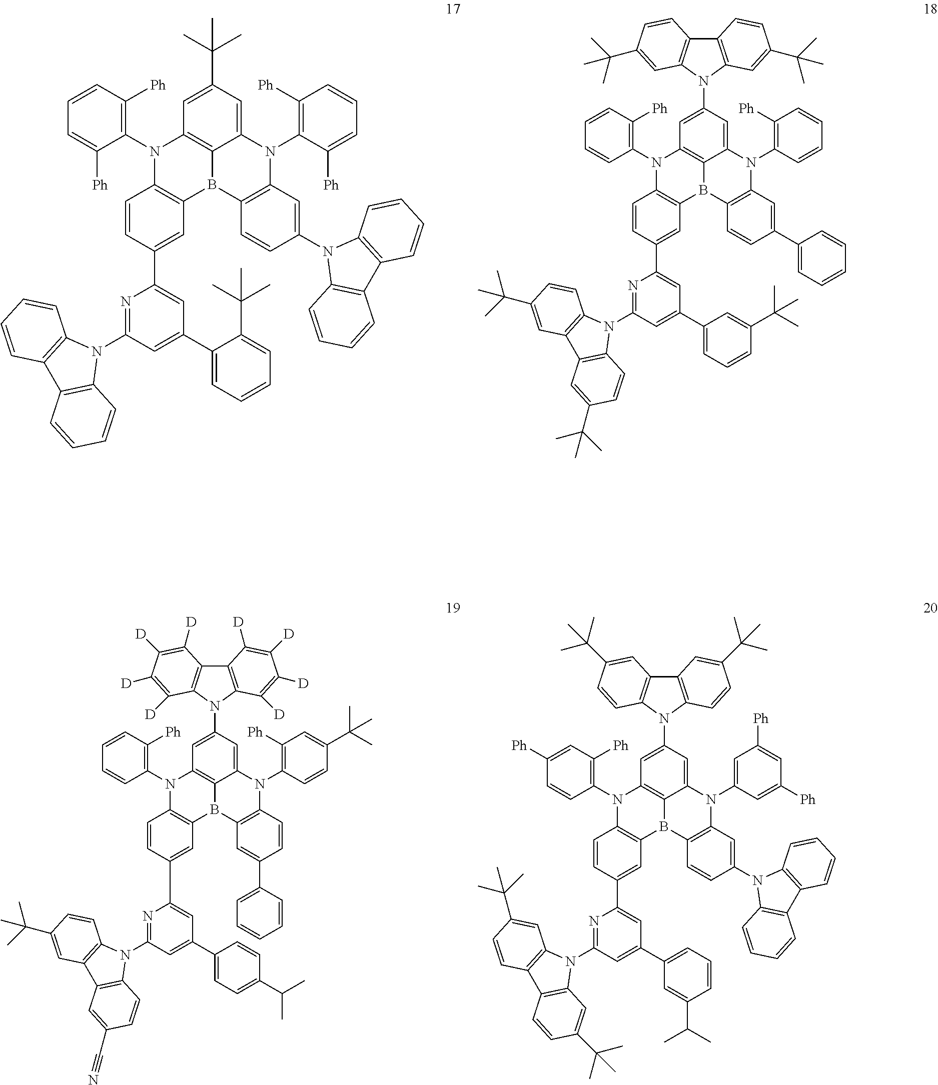 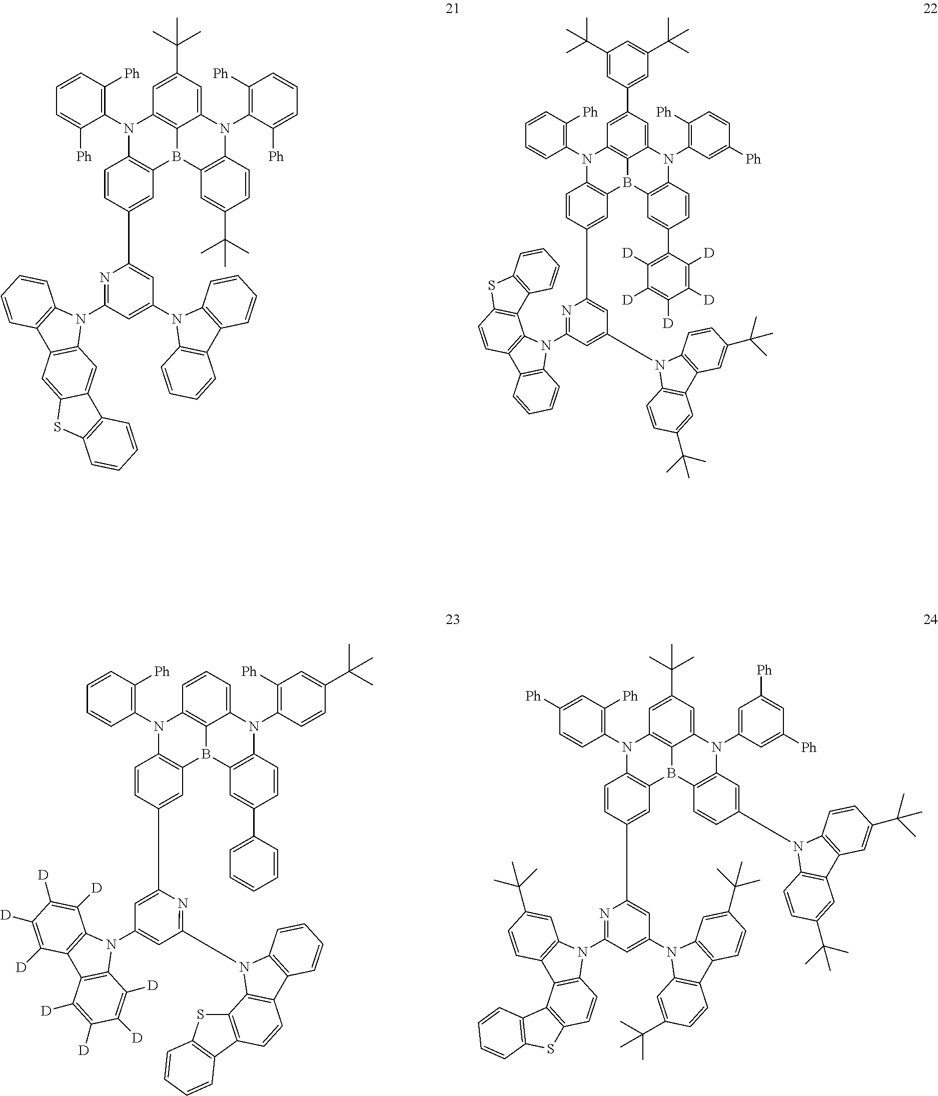 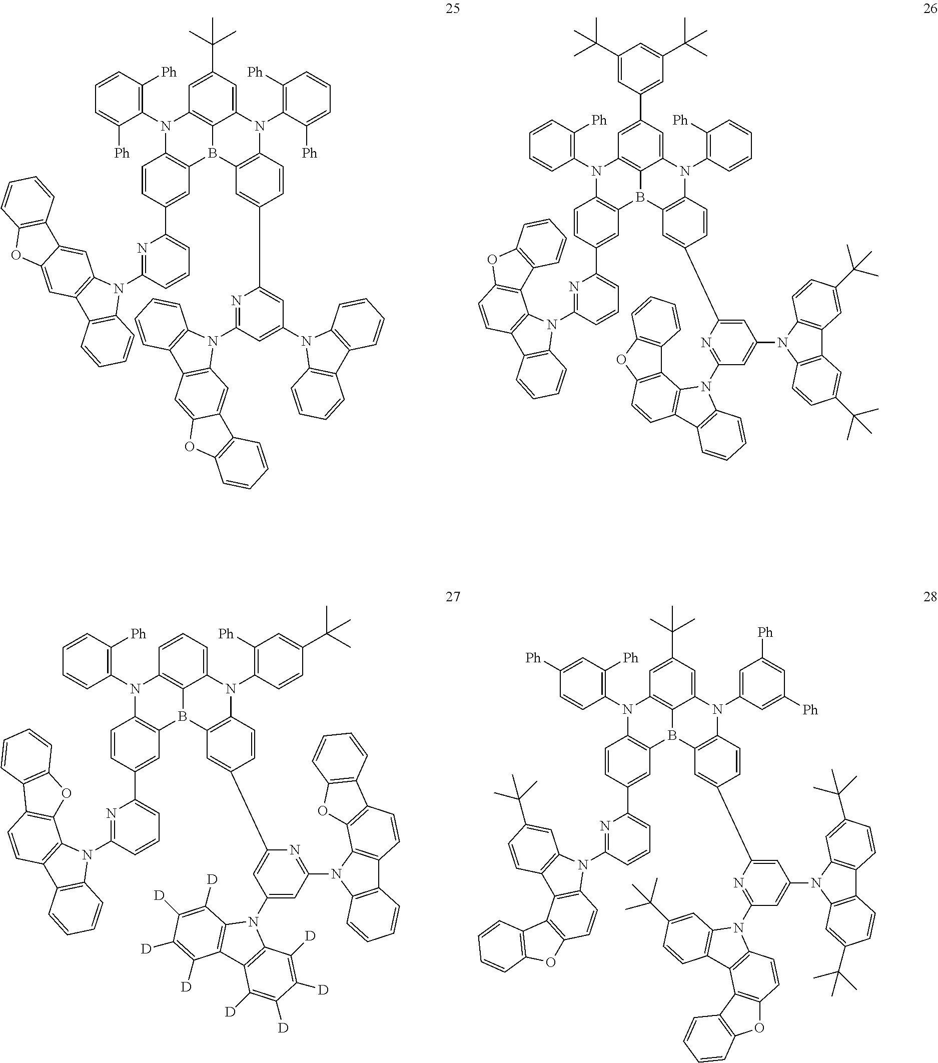 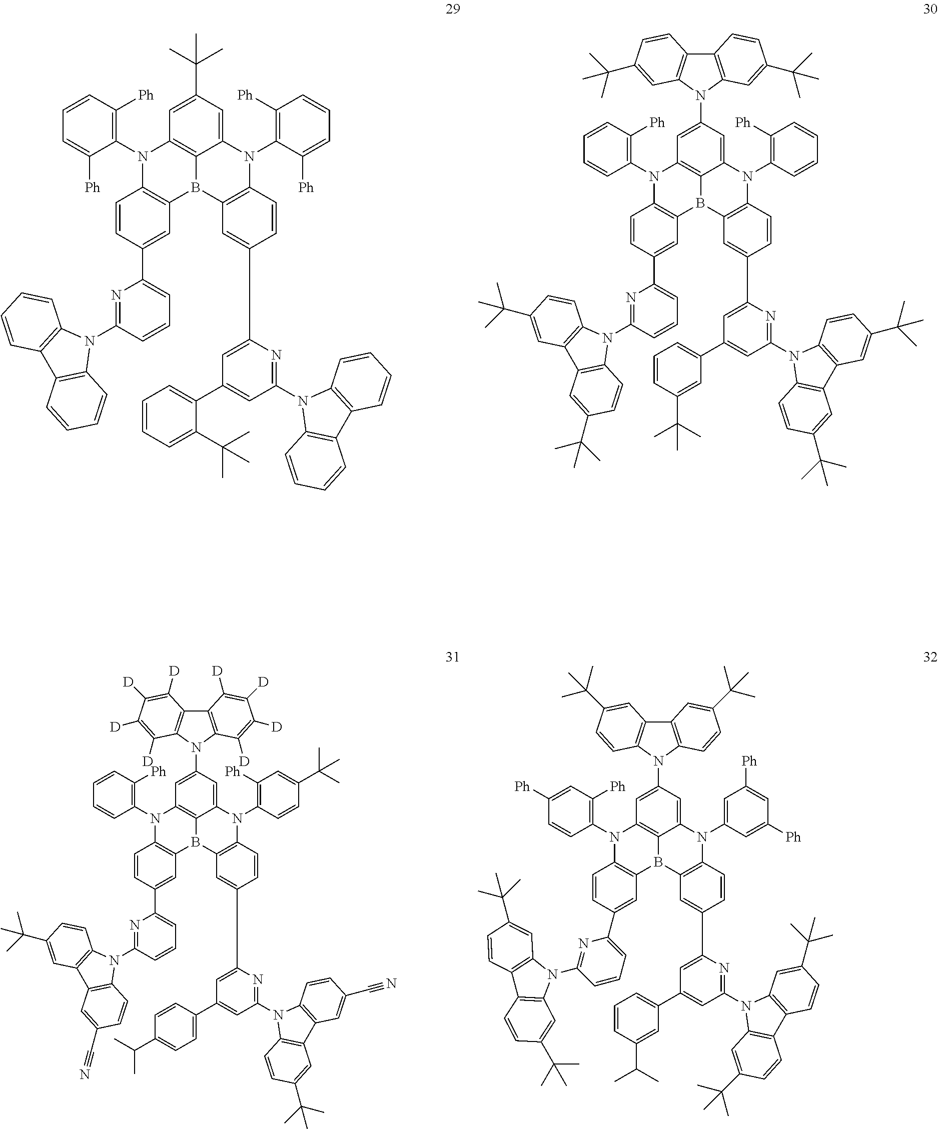 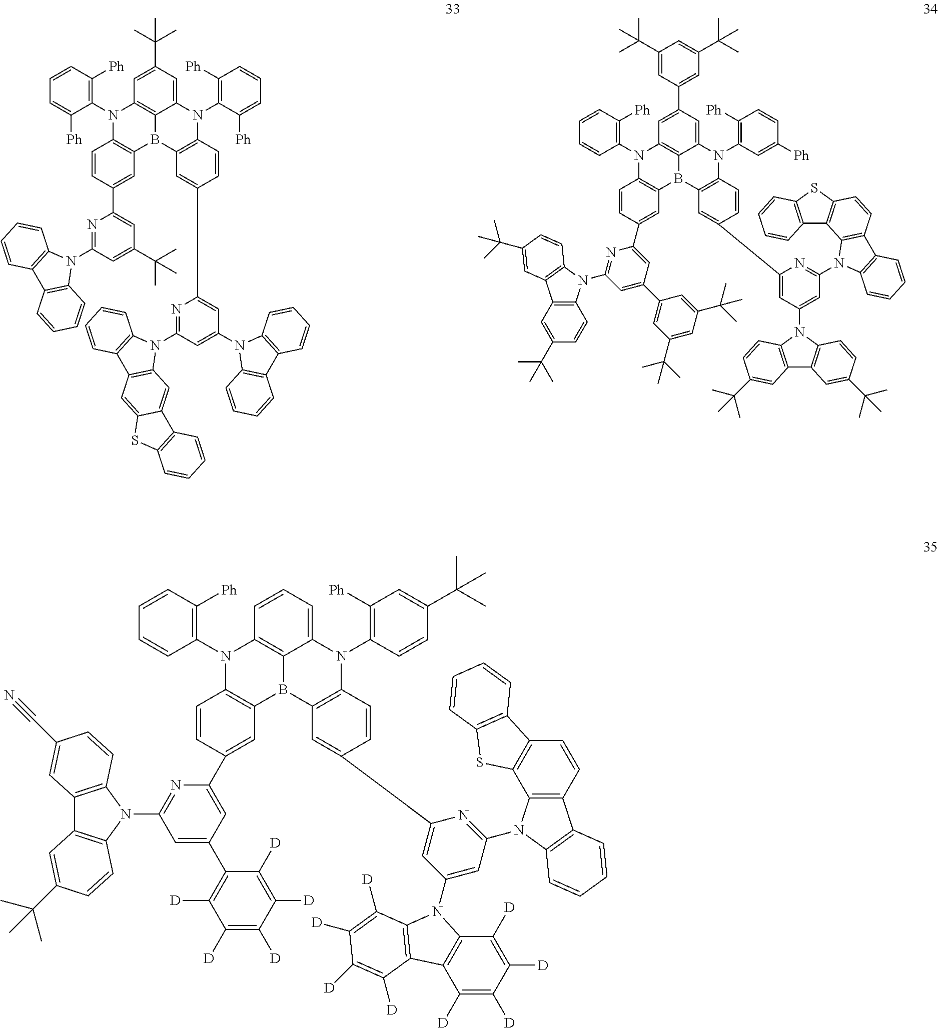 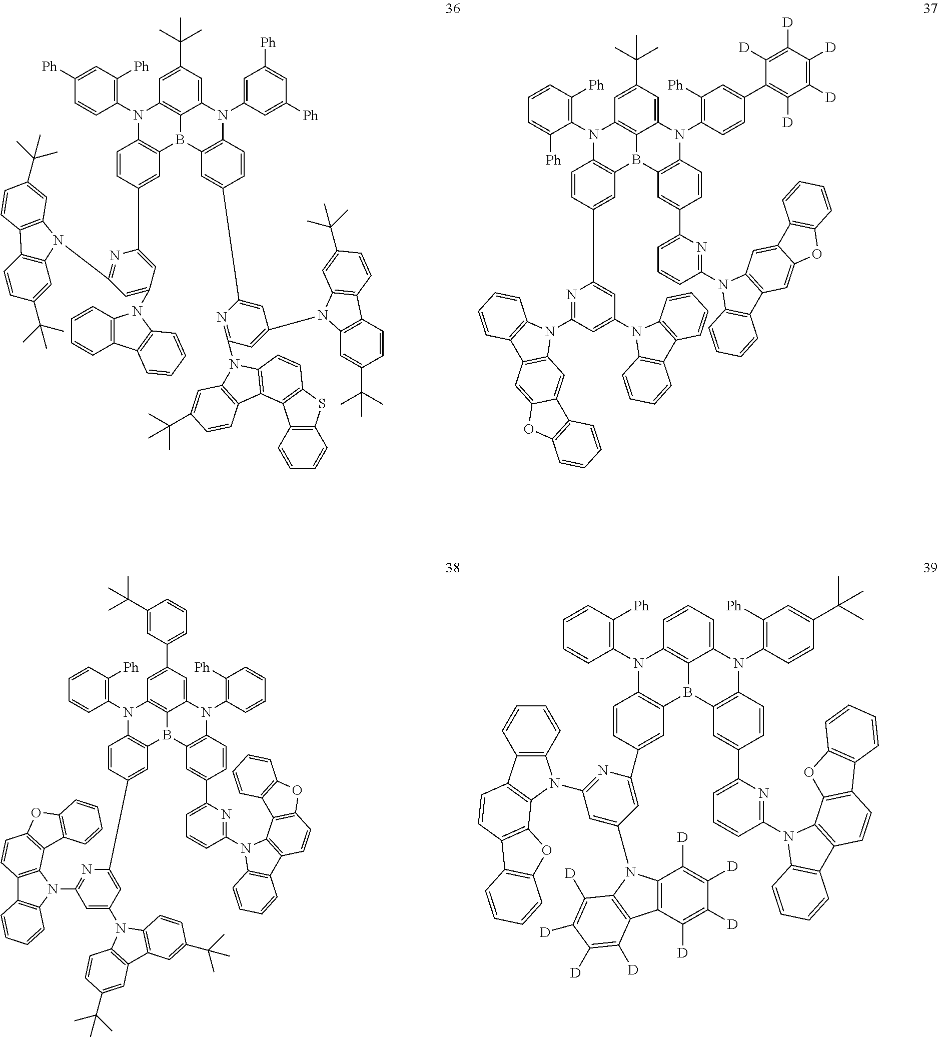 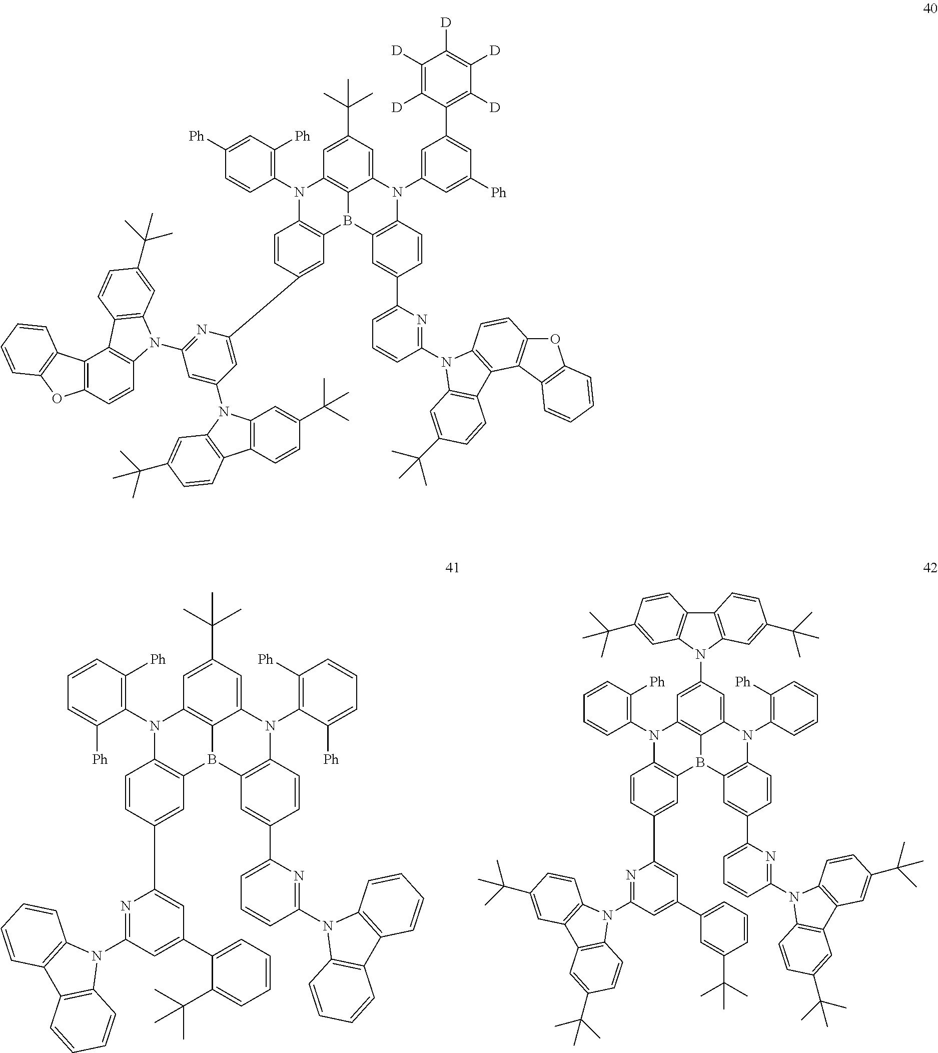 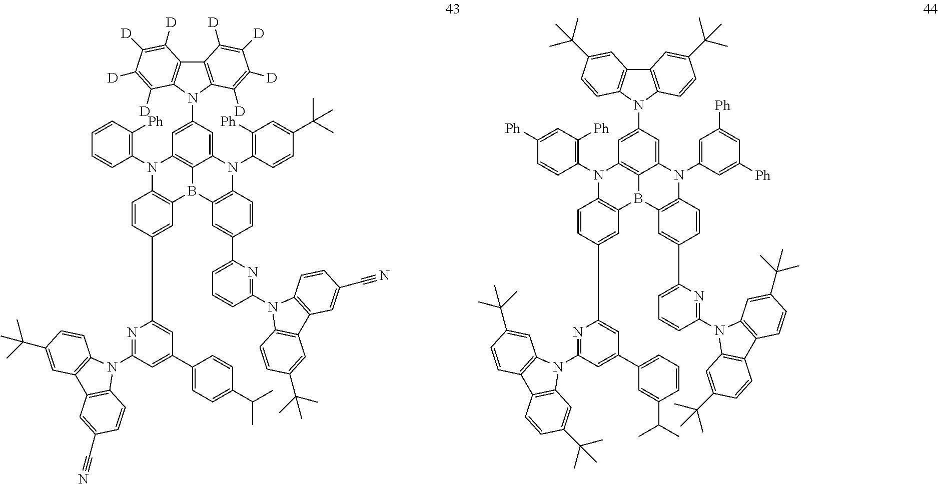 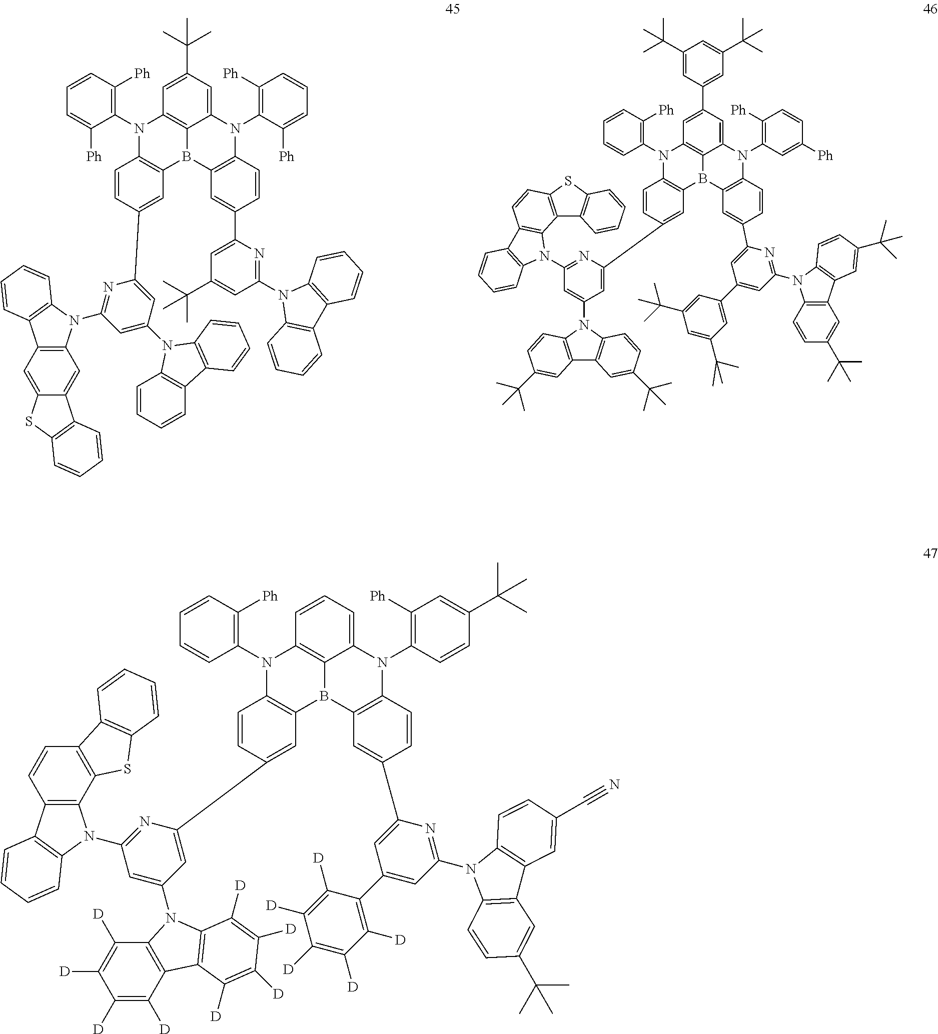 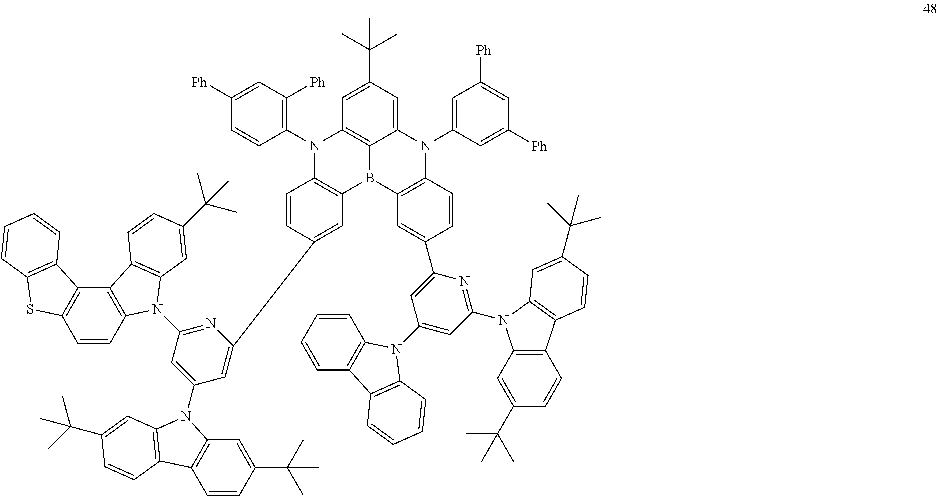 [SMILES: CC(C)(C)c1cc2c3c(c1)N(c1ccc(-c4ccccc4)cc1-c1ccccc1)c1ccc(-c4cc(-n5c6cc(C(C)(C)C)ccc6c6ccc(C(C)(C)C)cc65)cc(-n5c6cc(C(C)(C)C)ccc6c6c7c(ccc65)sc5ccccc57)n4)cc1B3c1cc(-c3cc(-n4c5ccccc5c5ccccc54)cc(-n4c5cc(C(C)(C)C)ccc5c5ccc(C(C)(C)C)cc54)n3)ccc1N2c1cc(-c2ccccc2)cc(-c2ccccc2)c1] 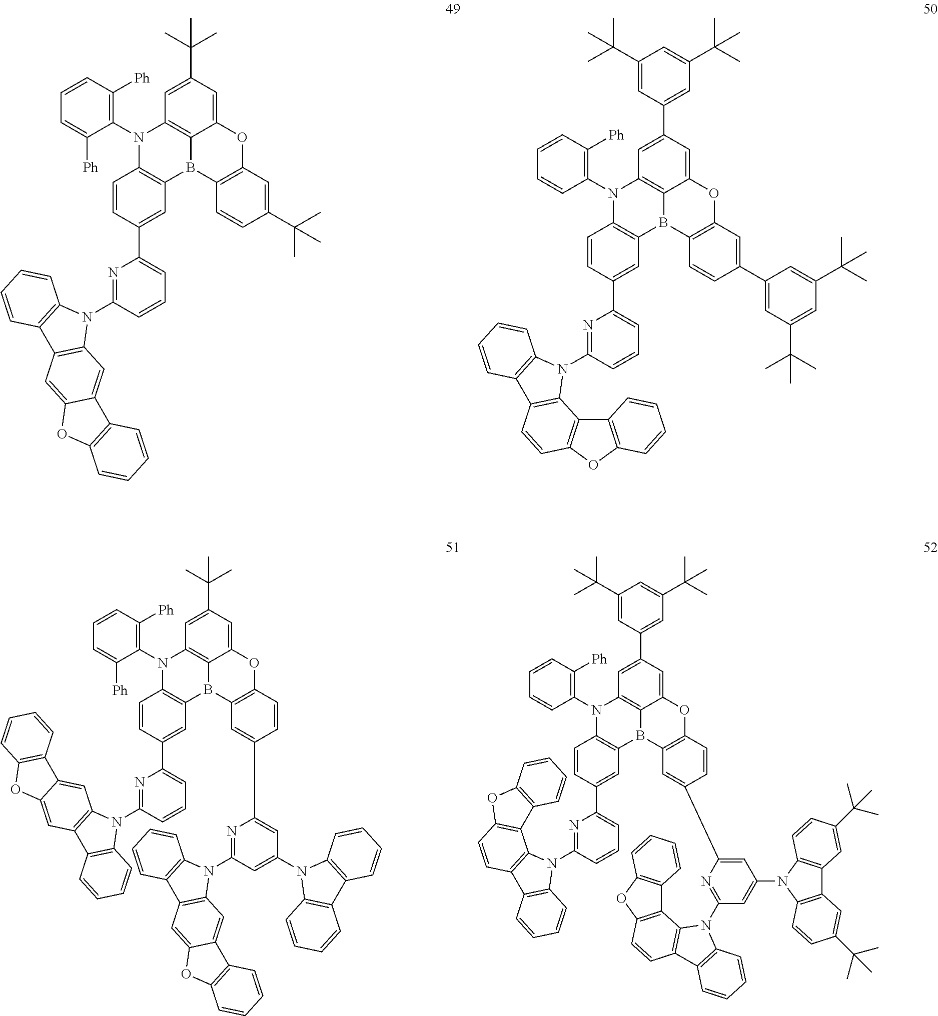 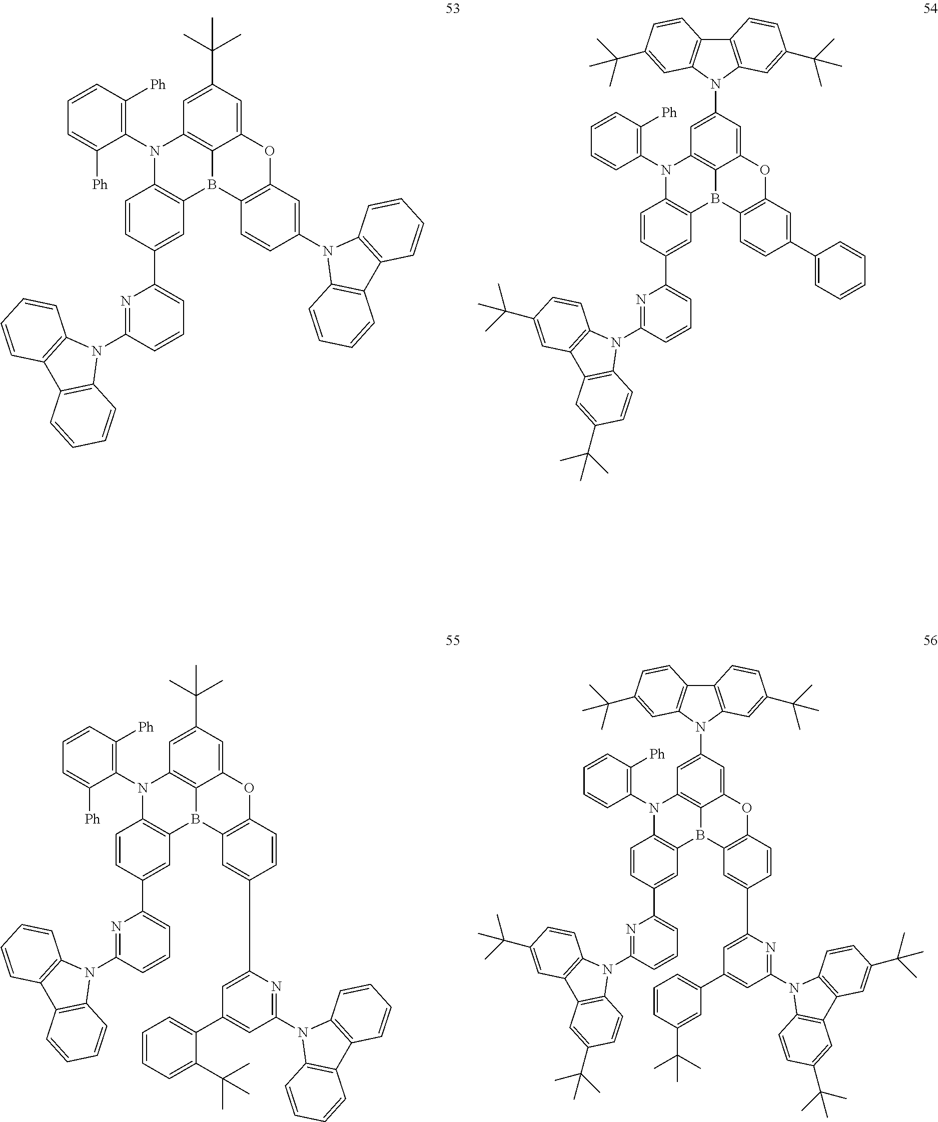 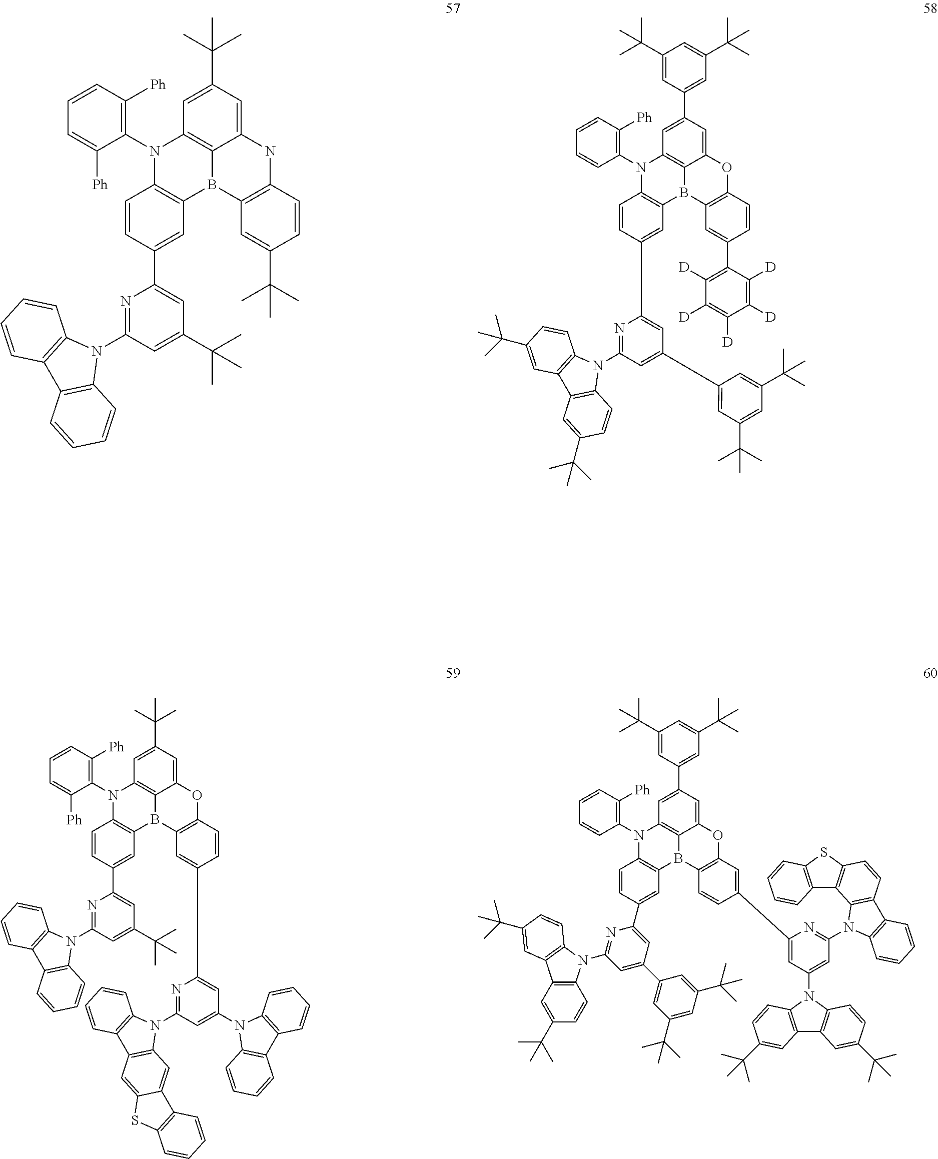 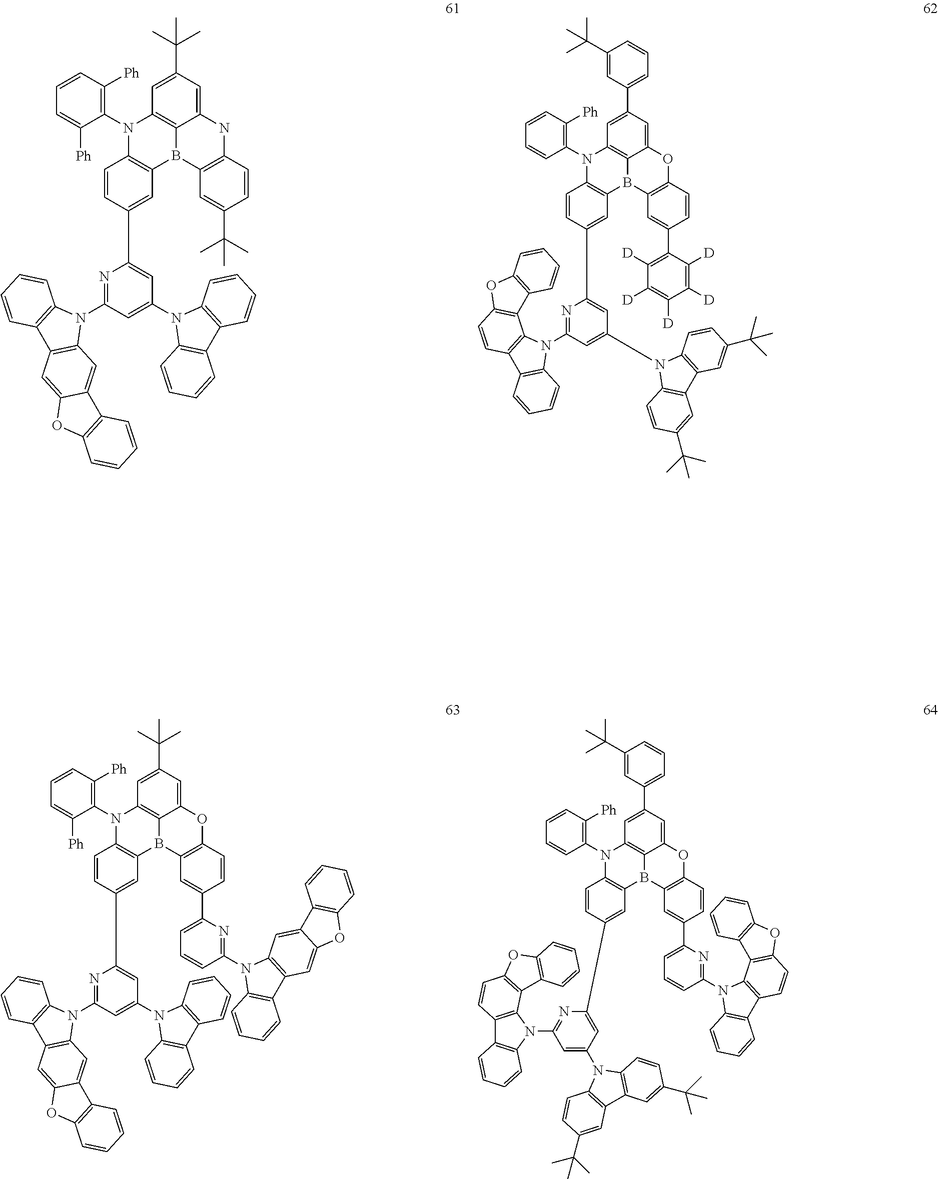 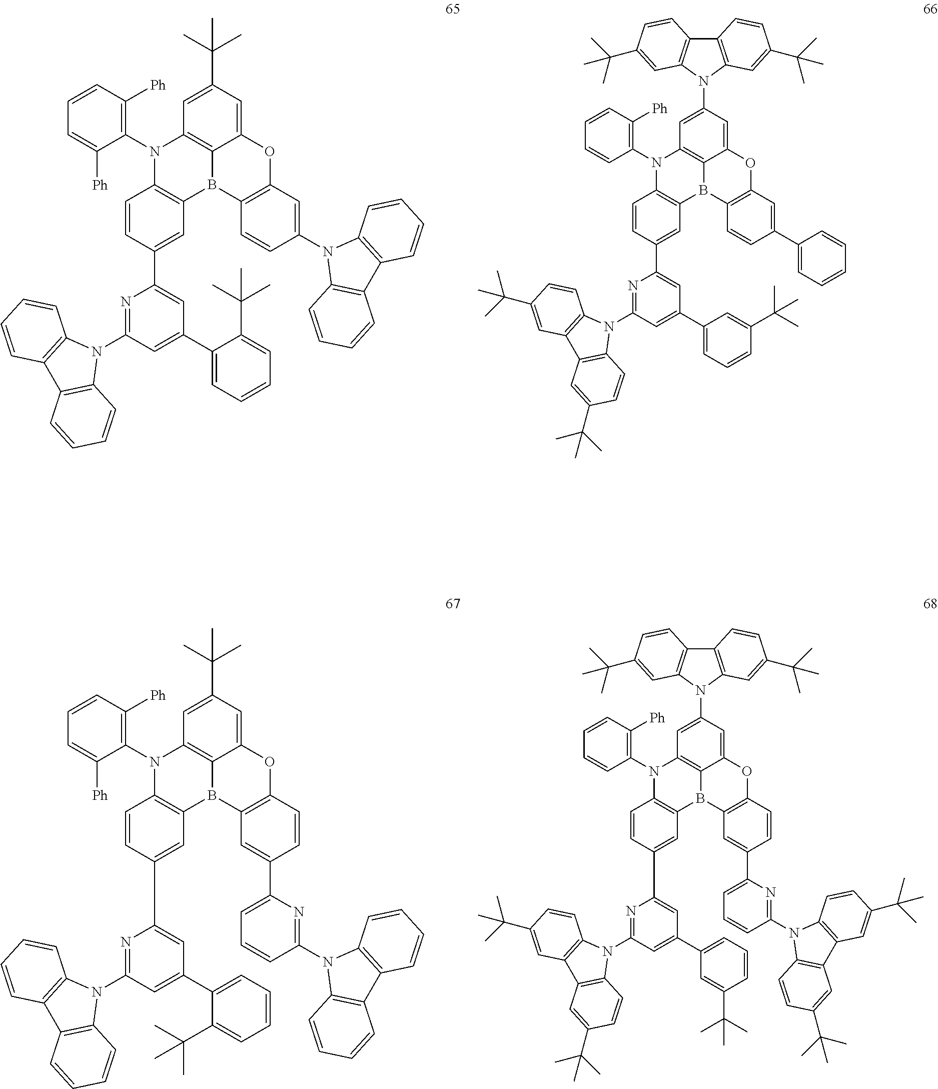 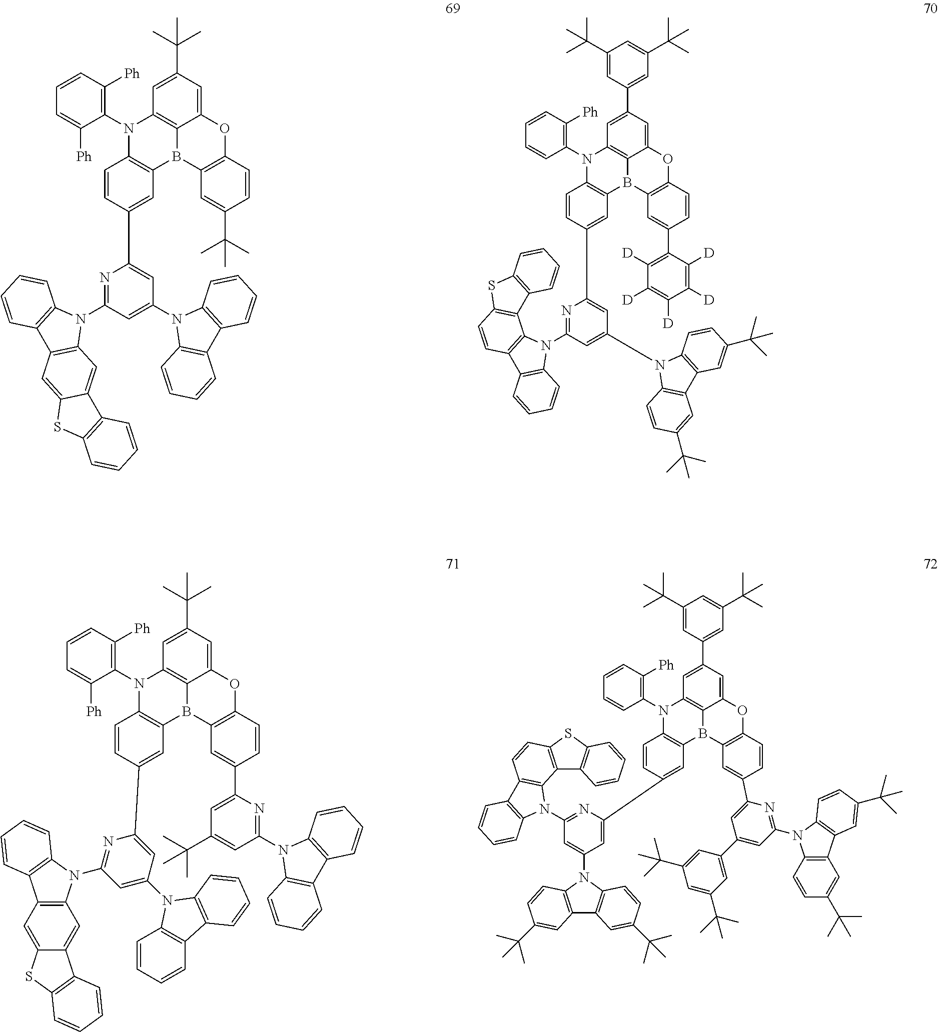 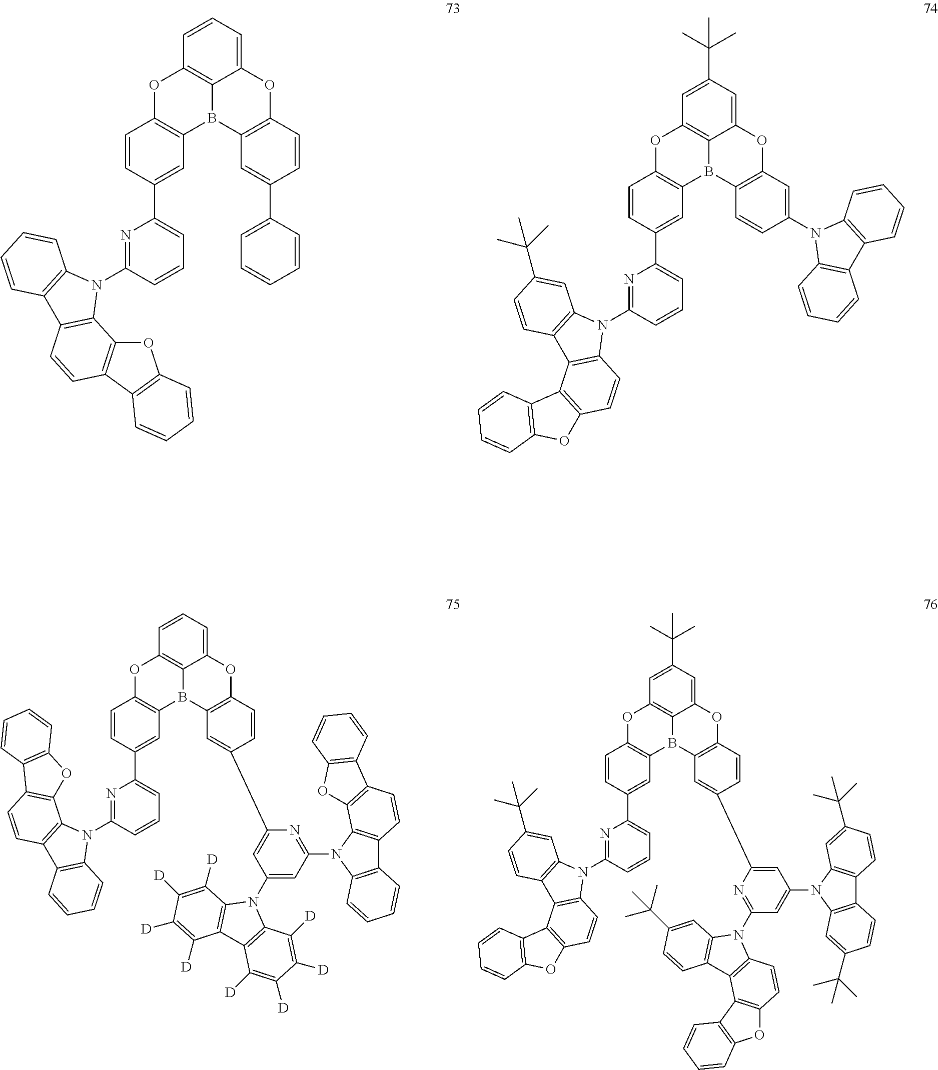 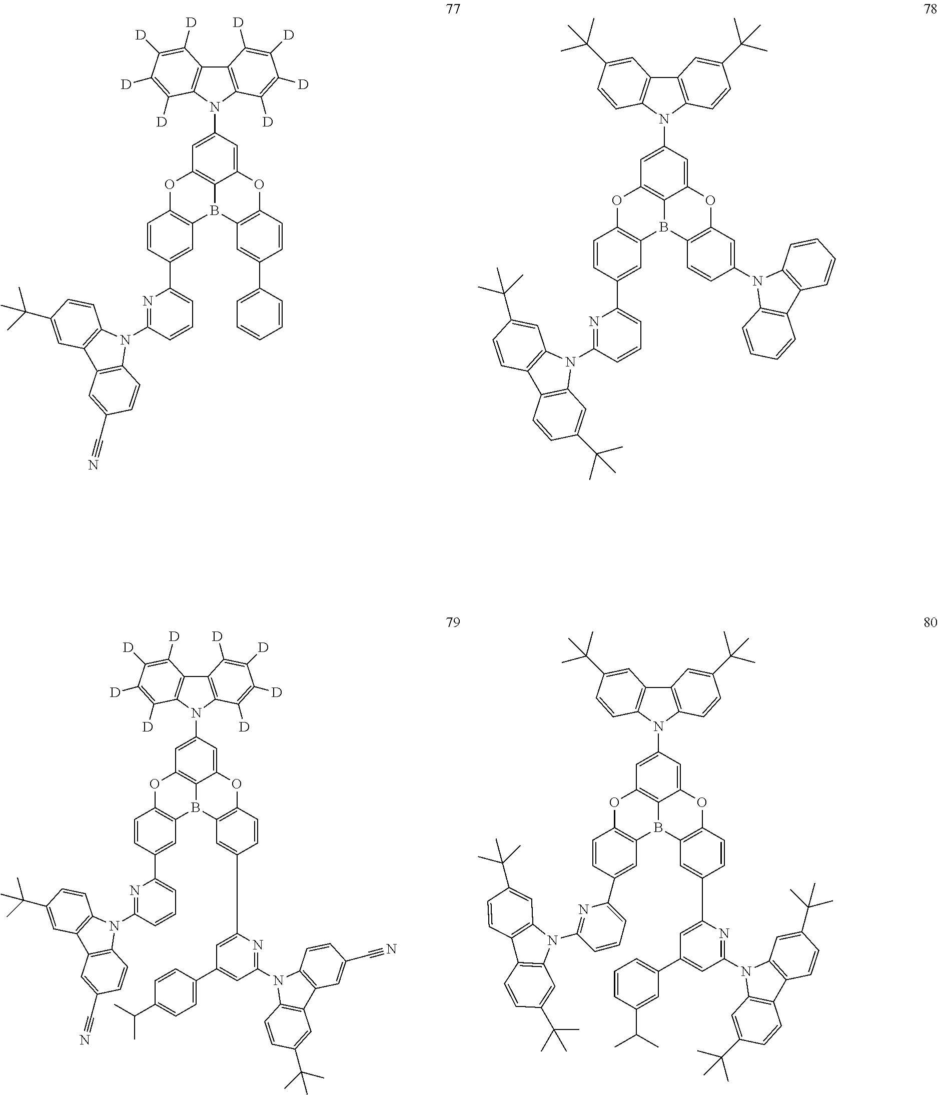 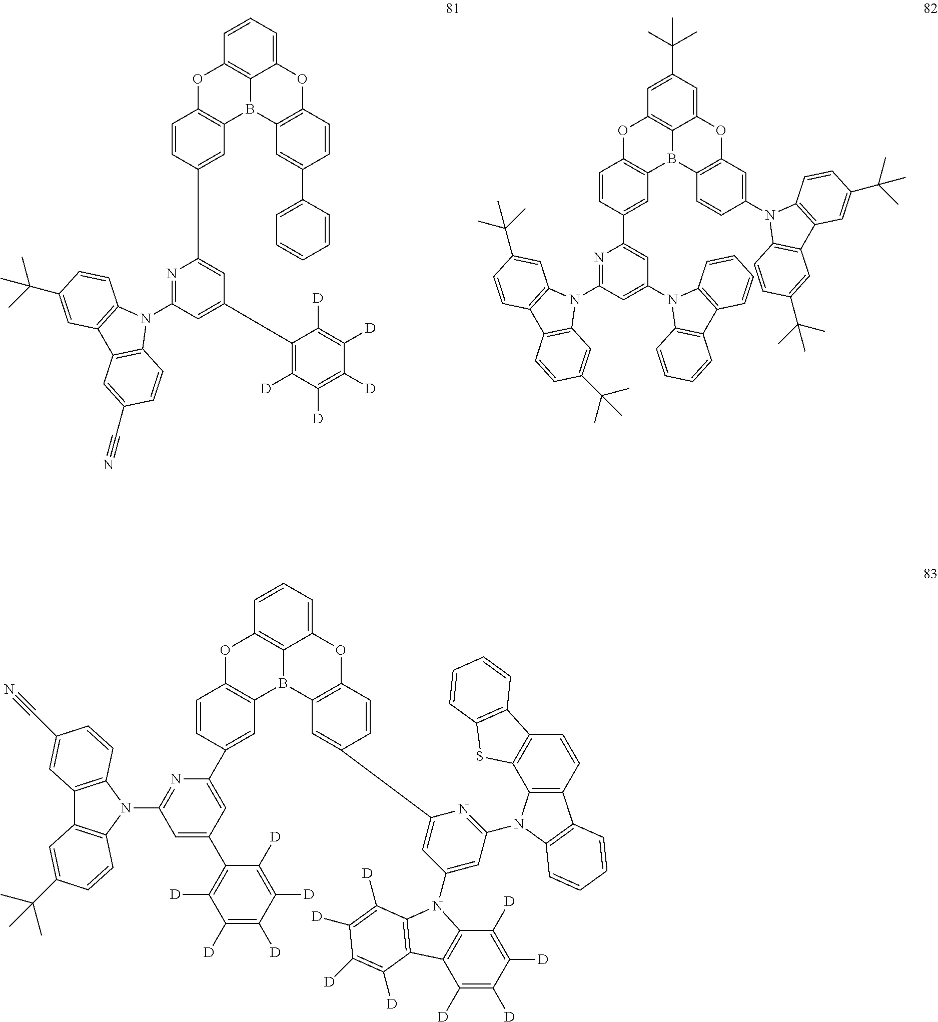 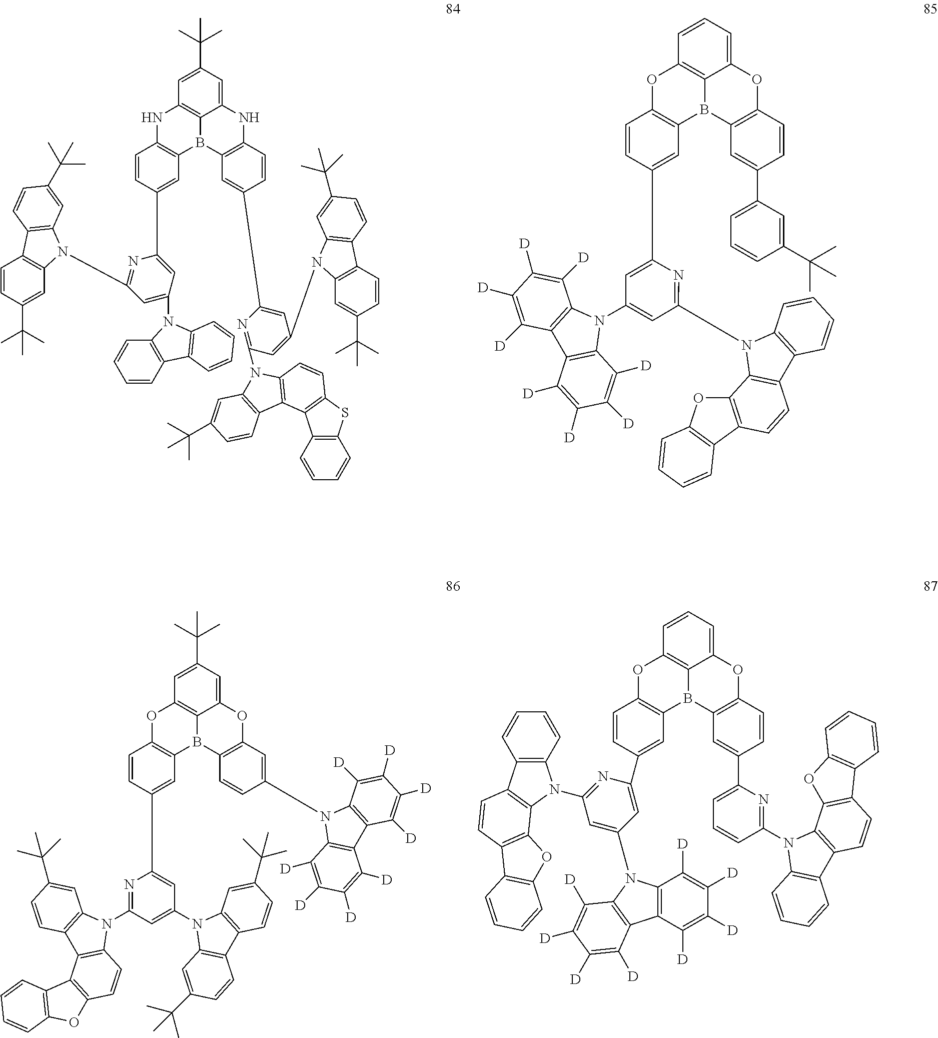 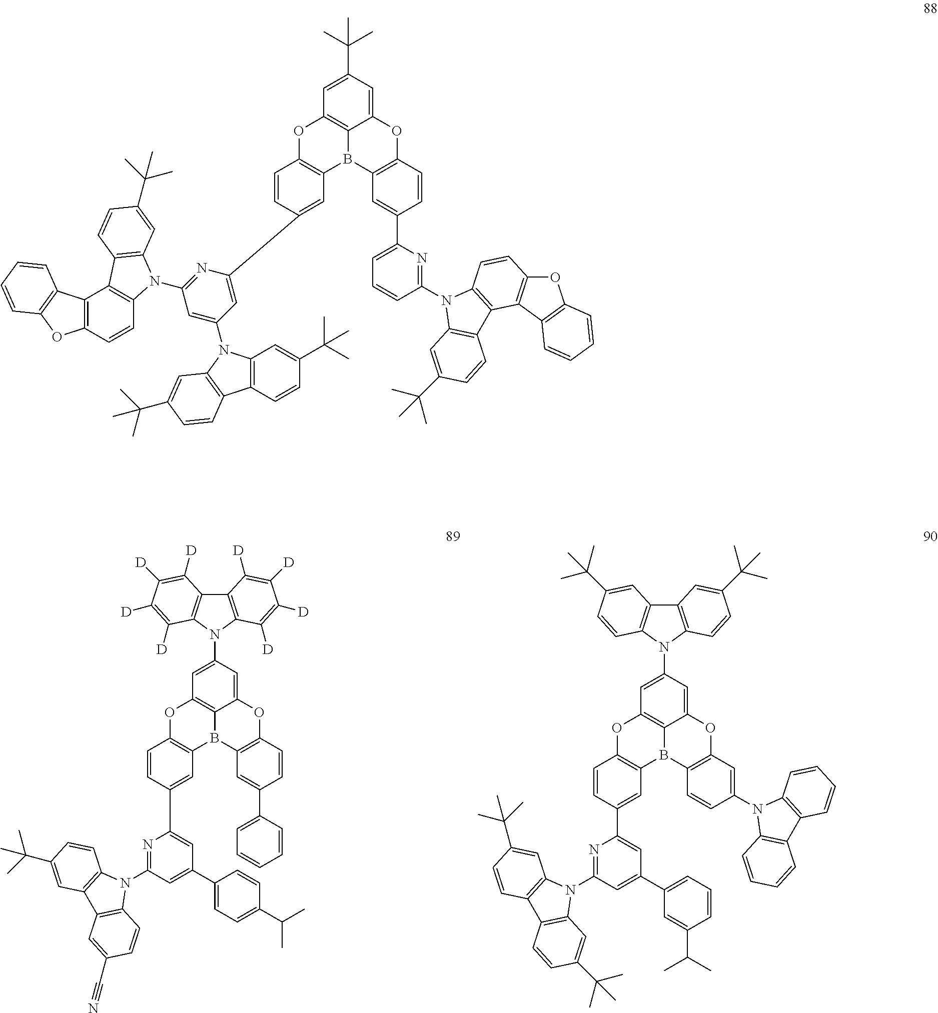 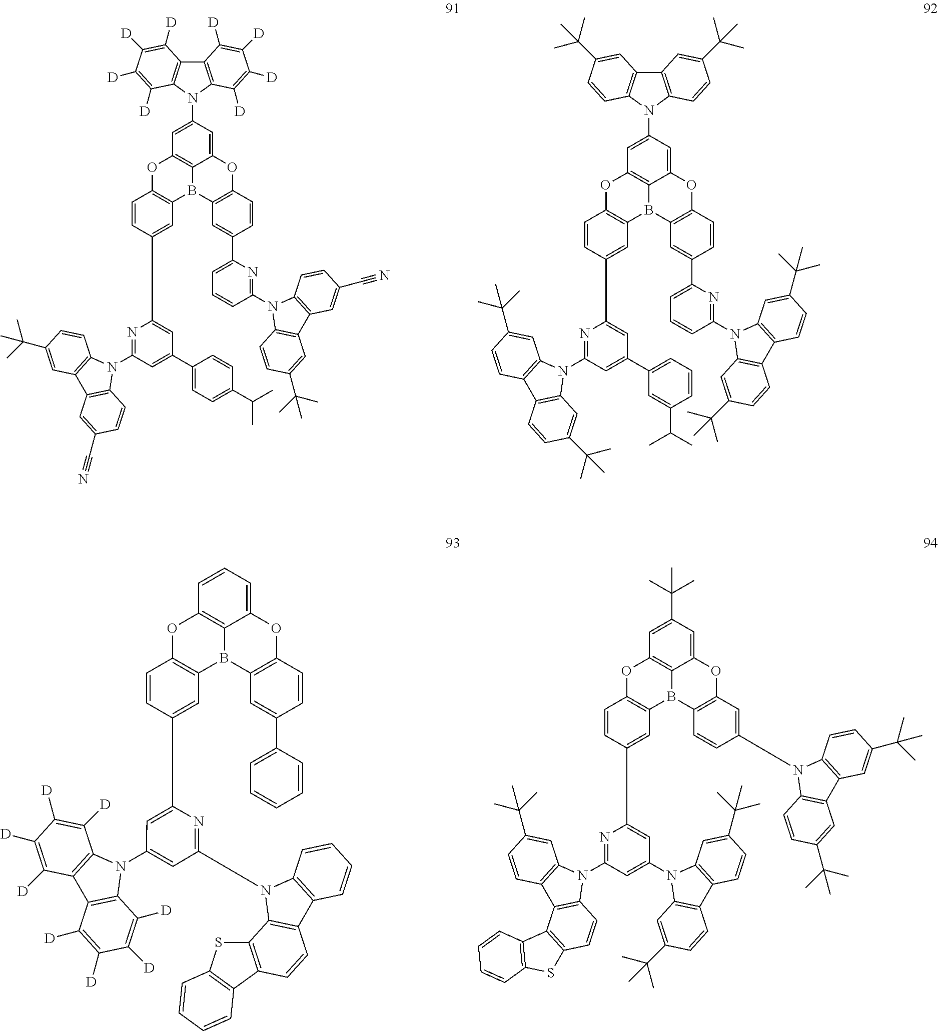 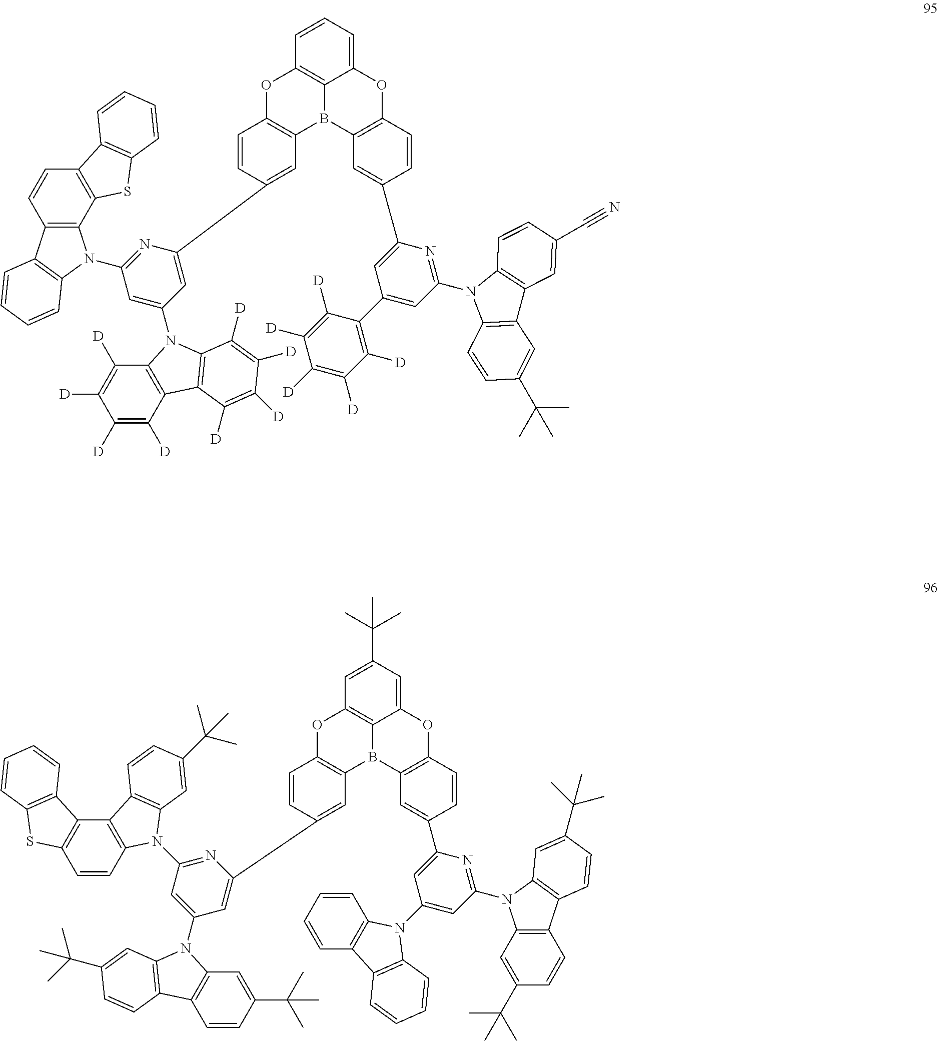 [SMILES: [2H]c1c([2H])c([2H])c(-c2cc(-c3ccc4c(c3)B3c5cc(-c6cc(-n7c8c([2H])c([2H])c([2H])c([2H])c8c8c([2H])c([2H])c([2H])c([2H])c87)cc(-n7c8ccccc8c8ccc9c%10ccccc%10sc9c87)n6)ccc5Oc5cccc(c53)O4)nc(-n3c4ccc(C#N)cc4c4cc(C(C)(C)C)ccc43)c2)c([2H])c1[2H] ; CC(C)(C)c1cc2c3c(c1)Oc1ccc(-c4cc(-n5c6cc(C(C)(C)C)ccc6c6ccc(C(C)(C)C)cc65)cc(-n5c6cc(C(C)(C)C)ccc6c6c7c(ccc65)sc5ccccc57)n4)cc1B3c1cc(-c3cc(-n4c5ccccc5c5ccccc54)cc(-n4c5cc(C(C)(C)C)ccc5c5ccc(C(C)(C)C)cc54)n3)ccc1O2]
wherein in Compound Group 1,
D represents a deuterium atom, and
Ph represents a substituted or unsubstituted phenyl group.
